(19) United States
(12) Patent Application Publication
(10) Pub. No.: US 2026/0101520 A1
(43) Pub. Date: Apr. 9, 2026

(54) SEMICONDUCTOR DEVICES

(71) Applicant: Samsung Electronics Co., Ltd., Suwon-si (KR)

(72) Inventors: Hyeonseok LEE, Suwon-si (KR); Minsoo KIM, Suwon-si (KR); Seunghoon KIM, Suwon-si (KR); Yongkwan KIM, Suwon-si (KR); Huijung KIM, Suwon-si (KR); Jiho PARK, Suwon-si (KR); Kiseok LEE, Suwon-si (KR); Heejae CHAE, Suwon-si (KR)

(73) Assignee: Samsung Electronics Co., Ltd., Suwon-si (KR)

(21) Appl. No.: 19/347,130

(22) Filed: Oct. 1, 2025

(30) Foreign Application Priority Data
Oct. 8, 2024 (KR) 10-2024-0136368

(51) Int. Cl. H10B 80/00; H01L 23/00; H01L 25/00; H01L 25/065; H01L 25/18; H10B 12/00

(52) U.S. Cl. CPC H10B 80/00; H10B 12/315; H10B 12/50; H10W 90/00; H10W 80/312; H10W 80/327; H10W 90/792

(57) ABSTRACT

A semiconductor device includes a peripheral circuit structure including a peripheral circuit pattern, a bonding structure including a bonding layer structure, a cell structure including a channel extending in a vertical direction perpendicular to an upper surface of a substrate, a word line at a side of the channel and extending in a first direction parallel to the upper surface of the substrate, a bit line structure at one end of the channel in the vertical direction and extending in a second direction parallel to the upper surface of the substrate and crossing the first direction, and a capacitor at another end of the channel in the vertical direction and electrically connected thereto, a word line wiring structure electrically connecting the peripheral circuit pattern and the word line, and a bit line wiring structure electrically connecting the peripheral circuit pattern and the bit line structure.

### CROSS-REFERENCE TO RELATED APPLICATION

This application claims priority under 35 U.S.C. § 119 to Korean Patent Application No. 10-2024-0136368 filed on Oct. 8, 2024 in the Korean Intellectual Property Office, the disclosure of which is hereby incorporated by reference in its entirety.

### BACKGROUND

To improve the integration density of semiconductor devices, technology is being researched for forming memory cells and peripheral circuit patterns on separate substrates and bonding them together.

### SUMMARY

Example embodiments of the present disclosure relate to a semiconductor device.

Some example embodiments provide a semiconductor device having improved electrical characteristics.

According to some example embodiments of the inventive concepts, there is a semiconductor device. The semiconductor device may include a peripheral circuit structure including a peripheral circuit pattern on a first front surface of a substrate, a bonding structure including a bonding layer structure on the peripheral circuit structure and a bonding pad structure therein, a cell structure on the bonding structure and including a channel extending in a vertical direction, the vertical direction being perpendicular to an upper surface of the substrate, a word line at a side of the channel and extending in a first direction, the first direction being parallel to the upper surface of the substrate, a bit line structure at one end of the channel in the vertical direction and extending in a second direction, the second direction being parallel to the upper surface of the substrate and crossing the first direction, and a capacitor at another end of the channel in the vertical direction and electrically connected thereto, a word line wiring structure electrically connecting the peripheral circuit pattern and the word line through a word line contact, the word line contact contacting an upper surface of the bonding pad structure, and a bit line wiring structure electrically connecting the peripheral circuit pattern and the bit line structure through a bit line contact, the bit line contact extending through the bonding layer structure.

According to some example embodiments of the inventive concepts, there is a semiconductor device. The semiconductor device may include a cell structure including a channel extending in a first direction, a word line at a side of the channel and extending in a second direction, the second direction being perpendicular to the first direction, a bit line structure at one end of the channel in the first direction and extending in a third direction, the third direction being perpendicular to each of the first direction and the second direction, and a capacitor at another end of the channel in the first direction and electrically connected thereto, a peripheral circuit structure at a side of the cell structure in the first direction and including a peripheral circuit pattern on a first front surface among the first front surface and a first rear surface of a substrate in the first direction, a bonding structure between the cell structure and the peripheral circuit structure and including a bonding layer structure and a bonding pad structure therein, a word line wiring structure electrically connecting the peripheral circuit pattern and the word line through a word line contact, the word line contact contacting a lower surface of the bonding pad structure, and a bit line wiring structure electrically connecting the peripheral circuit pattern and the bit line structure through a bit line contact, the bit line contact extending through the bonding layer structure.

According to some example embodiments of the inventive concepts, there is a semiconductor device. The semiconductor device may include a peripheral circuit structure including a peripheral circuit pattern on a first front surface of a substrate, a bonding structure including a bonding layer structure on the peripheral circuit structure and a bonding pad structure therein, a cell structure on the bonding structure and including a channel extending in a vertical direction, the vertical direction being perpendicular to an upper surface of the substrate, a word line at a side of the channel and extending in a first direction, the first direction being parallel to the upper surface of the substrate, a back gate electrode at another side of the channel and extending in the first direction, a bit line structure at one end of the channel in the vertical direction and extending in a second direction, the second direction being parallel to the upper surface of the substrate and crossing the first direction, and a capacitor at another end of the channel in the vertical direction and electrically connected thereto, a word line wiring structure electrically connecting the peripheral circuit pattern and the word line through a word line contact extending through the bonding layer structure, and a bit line wiring structure electrically connecting the peripheral circuit pattern and the bit line structure through a bit line contact contacting an upper surface of the bonding pad structure.

According to some example embodiments of the inventive concepts, there is a semiconductor device. The semiconductor device may include a cell structure including a channel extending in a first direction, a word line at a side of the channel and extending in a second direction, the second direction being perpendicular to the first direction, a back gate electrode at another side of the channel and extending in the second direction, a bit line structure at one end of the channel in the first direction and extending in a third direction, the third direction being perpendicular to each of the first direction and the second direction, and a capacitor at another end of the channel in the first direction and electrically connected thereto, a peripheral circuit structure at a side of the cell structure in the first direction and including a peripheral circuit pattern on a first front surface among the first front surface and a first rear surface of a substrate in the first direction, a bonding structure between the cell structure and the peripheral circuit structure and including a bonding layer structure and a bonding pad structure therein, a word line wiring structure electrically connecting the peripheral circuit pattern and the word line through a word line contact extending through the bonding layer structure, and a bit line wiring structure electrically connecting the peripheral circuit pattern and the bit line structure through a bit line contact contacting a lower surface of the bonding pad structure.

According to some example embodiments of the inventive concepts, there is a semiconductor device. The semiconductor device may include a peripheral circuit structure including a peripheral circuit pattern on a first front surface of a first substrate, a cell structure on the peripheral circuit structure and including an active pattern on a second front surface of a second substrate, an isolation structure covering sidewalls of the active pattern, a gate structure extending through the active pattern from the second front surface of the second substrate and extending in a first direction, the first direction being parallel to the second front surface of the second substrate, a bit line structure contacting the active pattern at the second front surface of the second substrate and extending in a second direction, the second direction being parallel to the second front surface of the second substrate and crossing the first direction, a contact plug structure contacting an end of the active pattern at the second front surface of the second substrate, and a capacitor contacting the contact plug structure, a bonding structure between the peripheral circuit structure and the cell structure and including a bonding layer structure and a bonding pad structure therein, a word line wiring structure electrically connecting the peripheral circuit pattern and the gate structure through a word line contact, the word line contact contacting an upper surface of the bonding pad structure; and a bit line wiring structure electrically connecting the peripheral circuit pattern and the bit line structure through a bit line contact, the bit line contact extending through the bonding layer structure.

According to some example embodiments of the inventive concepts, there is a semiconductor device. The semiconductor device may include a peripheral circuit structure including a peripheral circuit pattern on a first front surface of a first substrate, a cell structure on the peripheral circuit structure and including an active pattern on a second front surface of a second substrate, an isolation structure covering sidewalls of the active pattern, a gate structure extending through the active pattern from the second front surface of the second substrate and extending in a first direction, the first direction being parallel to the second front surface of the second substrate, a bit line structure contacting the active pattern at the second front surface of the second substrate and extending in a second direction, the second direction being parallel to the second front surface of the second substrate and crossing the first direction, a contact plug structure contacting an end of the active pattern at the second front surface of the second substrate, and a capacitor contacting the contact plug structure, a bonding structure between the peripheral circuit structure and the cell structure and including a bonding layer structure and a bonding pad structure therein, a word line wiring structure electrically connecting the peripheral circuit pattern and the gate structure through a word line contact extending through the bonding layer structure, and a bit line wiring structure electrically connecting the peripheral circuit pattern and the bit line structure through a bit line contact contacting an upper surface of the bonding pad structure.

According to some example embodiments of the inventive concepts, there is a semiconductor device. The semiconductor device may include a cell structure including an active pattern on a first front surface of a first substrate, an isolation structure covering sidewalls of the active pattern, a gate structure extending through the active pattern from the first front surface of the first substrate and extending in a first direction, the first direction being parallel to the first front surface of the first substrate, a bit line structure contacting the active pattern at the first front surface of the first substrate and extending in a second direction, the second direction being parallel to the first front surface of the first substrate and crossing the first direction, a contact plug structure contacting an end of the active pattern at the first front surface of the first substrate, and a capacitor contacting the contact plug structure; a peripheral circuit structure on the cell structure and including a peripheral circuit pattern on a second front surface of a second substrate, a bonding structure between the cell structure and the peripheral circuit structure and including a bonding layer structure and a bonding pad structure therein, a word line wiring structure electrically connecting the peripheral circuit pattern and the gate structure through a word line contact, the word line contact contacting a lower surface of the bonding pad structure, and a bit line wiring structure electrically connecting the peripheral circuit pattern and the bit line structure through a bit line contact, the bit line contact extending through the bonding layer structure.

According to some example embodiments of the inventive concepts, there is a semiconductor device. The semiconductor device may include a cell structure including an active pattern on a first front surface of a first substrate, an isolation structure covering sidewalls of the active pattern, a gate structure extending through the active pattern from the first front surface of the first substrate and extending in a first direction, the first direction being parallel to the first front surface of the first substrate, a bit line structure contacting the active pattern at the first front surface of the first substrate and extending in a second direction, the second direction being parallel to the first front surface of the first substrate and crossing the first direction, a contact plug structure contacting an end of the active pattern at the first front surface of the first substrate, and a capacitor contacting the contact plug structure, a peripheral circuit structure on the cell structure and including a peripheral circuit pattern on a second front surface of a second substrate, a bonding structure between the cell structure and the peripheral circuit structure and including a bonding layer structure and a bonding pad structure therein, a word line wiring structure electrically connecting the peripheral circuit pattern and the gate structure through a word line contact extending through the bonding layer structure, and a bit line wiring structure electrically connecting the peripheral circuit pattern and the bit line structure through a bit line contact contacting a lower surface of the bonding pad structure.

According to some example embodiments of the inventive concepts, there is a semiconductor device. The semiconductor device may include a peripheral circuit structure including a peripheral circuit pattern on a first front surface of a first substrate, a cell structure on the peripheral circuit structure and including a bit line extending in a first direction, the first direction being perpendicular to an upper surface of the first substrate, a channel at least partially surrounding a sidewall of the bit line, a word line on the first substrate, at least a portion of which overlaps the channel in a horizontal direction substantially parallel to the upper surface of the first substrate, and a capacitor electrically connected to the channel, at least a portion of which overlaps the channel and the word line in the horizontal direction, a bonding structure between the cell structure and the peripheral circuit structure and including a bonding layer structure and a bonding pad structure therein, a word line wiring structure electrically connecting the peripheral circuit pattern and the word line through a word line contact extending through the bonding layer structure, and a bit line wiring structure electrically connecting the peripheral circuit pattern and the bit line through a bit line contact contacting an upper surface of the bonding pad structure.

According to some example embodiments of the inventive concepts, there is a semiconductor device. The semiconductor device may include a peripheral circuit structure including a peripheral circuit pattern on a first front surface of a first substrate, a cell structure on the peripheral circuit structure and including a bit line extending in a first direction, the first direction being perpendicular to an upper surface of the first substrate, a channel at least partially surrounding a sidewall of the bit line, a word line on the first substrate, at least a portion of which overlaps the channel in a horizontal direction substantially parallel to the upper surface of the first substrate, and a capacitor electrically connected to the channel, at least a portion of which overlaps the channel and the word line in the horizontal direction, a bonding structure between the cell structure and the peripheral circuit structure and including a bonding layer structure and a bonding pad structure therein, a word line wiring structure electrically connecting the peripheral circuit pattern and the word line through a word line contact, the word line contact contacting an upper surface of the bonding pad structure; and a bit line wiring structure electrically connecting the peripheral circuit pattern and the bit line through a bit line contact, the bit line contact extending through the bonding layer structure and contacting a pad electrically connected to the peripheral circuit pattern.

According to some example embodiments of the inventive concepts, there is a semiconductor device. The semiconductor device may include a cell structure including a bit line extending in a first direction, the first direction being perpendicular to an upper surface of a first substrate, a channel at least partially surrounding a sidewall of the bit line, a word line on the first substrate, at least a portion of which overlaps the channel in a horizontal direction substantially parallel to the upper surface of the first substrate, and a capacitor electrically connected to the channel, at least a portion of which overlaps the channel and the word line in the horizontal direction, a peripheral circuit structure on the cell structure and including a peripheral circuit pattern on a second front surface of a second substrate, a bonding structure between the cell structure and the peripheral circuit structure and including a bonding layer structure and a bonding pad structure therein, a word line wiring structure electrically connecting the peripheral circuit pattern and the word line through a word line contact, the word line contact contacting a lower surface of the bonding pad structure, and a bit line wiring structure electrically connecting the peripheral circuit pattern and the bit line through a bit line contact, the bit line contact extending through the bonding layer structure.

According to some example embodiments of the inventive concepts, there is a semiconductor device. The semiconductor device may include a cell structure including a bit line extending in a first direction, the first direction being perpendicular to an upper surface of a first substrate, a channel at least partially surrounding a sidewall of the bit line, a word line on the first substrate, at least a portion of which overlaps the channel in a horizontal direction substantially parallel to the upper surface of the first substrate, and a capacitor electrically connected to the channel, at least a portion of which overlaps the channel and the word line in the horizontal direction, a peripheral circuit structure on the cell structure and including a peripheral circuit pattern on a second front surface of a second substrate, a bonding structure between the cell structure and the peripheral circuit structure and including a bonding layer structure and a bonding pad structure therein, a word line wiring structure electrically connecting the peripheral circuit pattern and the word line through a word line contact extending through the bonding layer structure and contacting a pad electrically connected to the word line, and a bit line wiring structure electrically connecting the peripheral circuit pattern and the bit line through a bit line contact contacting a lower surface of the bonding pad structure.

In semiconductor devices according to some example embodiments, bit lines or word lines of memory cells may be electrically connected to peripheral circuit patterns through bonding pad structures. Accordingly, an area occupied by contact plugs for electrically connecting the memory cells to the peripheral circuit patterns may be reduced, thereby improving integration density of the semiconductor device.

### BRIEF DESCRIPTION OF THE DRAWINGS

FIGS. 1 to 3 are cross-sectional views illustrating a first semiconductor device in accordance with a first example embodiment 1-1.

FIGS. 4 to 23 are plan views and cross-sectional views illustrating a method of manufacturing a first semiconductor device in accordance with a first example embodiment 1-1.

FIGS. 24 to 26 are cross-sectional views illustrating a first semiconductor device in accordance with a second example embodiment 1-2.

FIGS. 27 to 33 are plan views and cross-sectional views illustrating a method of manufacturing a first semiconductor device in accordance with a second example embodiment 1-2.

FIGS. 34 and 35 are cross-sectional views illustrating a first semiconductor device in accordance with a third example embodiment 1-3.

FIGS. 36 to 38 are cross-sectional views illustrating a method of manufacturing a first semiconductor device in accordance with a third example embodiment 1-3.

FIGS. 39 and 40 are cross-sectional views illustrating a first semiconductor device in accordance with a fourth example embodiment 1-4.

FIG. 41 is a cross-sectional view illustrating a method of manufacturing a first semiconductor device in accordance with a fourth example embodiment 1-4.

FIGS. 42 and 43 are cross-sectional views illustrating a first semiconductor device in accordance with a fifth example embodiment 1-5.

FIGS. 44 to 51 are cross-sectional views illustrating a method of manufacturing a first semiconductor device in accordance with a fifth example embodiment 1-5.

FIGS. 52 and 53 are cross-sectional views illustrating a first semiconductor device in accordance with a sixth example embodiment 1-6.

FIGS. 54 and 55 are cross-sectional views illustrating a first semiconductor device in accordance with a seventh example embodiment 1-7.

FIGS. 56 to 59 are cross-sectional views illustrating a method of manufacturing a first semiconductor device in accordance with a seventh example embodiment 1-7.

FIGS. 60 and 61 are cross-sectional views illustrating a first semiconductor device in accordance with an eighth example embodiment 1-8.

FIGS. 62 to 65 are cross-sectional views illustrating a second semiconductor device in accordance with a first example embodiment 2-1.

FIGS. 66 to 113 are plan views and cross-sectional views illustrating a method of manufacturing a second semiconductor device in accordance with a first example embodiment 2-1.

FIGS. 114 and 115 are cross-sectional views illustrating a second semiconductor device in accordance with a second example embodiment 2-2.

FIGS. 116 and 117 are cross-sectional views illustrating a second semiconductor device in accordance with a third example embodiment 2-3.

FIGS. 118 and 119 are plan views and cross-sectional views illustrating a method of manufacturing a second semiconductor device in accordance with a third example embodiment 2-3.

FIGS. 120 and 121 are cross-sectional views illustrating a second semiconductor device in accordance with a fourth example embodiment 2-4.

FIGS. 122 and 123 are cross-sectional views illustrating a second semiconductor device in accordance with a fifth example embodiment 2-5.

FIGS. 124 and 125 are cross-sectional views illustrating a second semiconductor device in accordance with a sixth example embodiment 2-6.

FIGS. 126 and 127 are cross-sectional views illustrating a second semiconductor device in accordance with a seventh example embodiment 2-7.

FIGS. 128 and 129 are cross-sectional views illustrating a second semiconductor device in accordance with an eighth example embodiment 2-8.

FIGS. 130 to 132 are cross-sectional views illustrating a third semiconductor device in accordance with a first example embodiment 3-1.

FIGS. 133 to 161 are plan views and cross-sectional views illustrating a method of manufacturing a third semiconductor device in accordance with a first example embodiment 3-1.

FIG. 162 is a cross-sectional view illustrating a third semiconductor device in accordance with a second example embodiment 3-2.

FIG. 163 is a cross-sectional view illustrating a third semiconductor device in accordance with a third example embodiment 3-3.

FIG. 164 is a cross-sectional view illustrating a third semiconductor device in accordance with a fourth example embodiment 3-4.

FIG. 165 is a cross-sectional view illustrating a third semiconductor device in accordance with a fifth example embodiment 3-5.

FIG. 166 is a cross-sectional view illustrating a third semiconductor device in accordance with a sixth example embodiment 3-6.

FIG. 167 is a cross-sectional view illustrating a third semiconductor device in accordance with a seventh example embodiment 3-7.

FIG. 168 is a cross-sectional view illustrating a third semiconductor device in accordance with an eighth example embodiment 3-8.

FIGS. 169 and 170 are plan views and cross-sectional views illustrating a first semiconductor device in accordance with a first example embodiment 1-1.

FIG. 171 is a cross-sectional view illustrating a first semiconductor device in accordance with a first example embodiment 1-1.

FIG. 172 is a cross-sectional view illustrating a first semiconductor device in accordance with a fifth example embodiment 1-5.

FIG. 173 is a cross-sectional view illustrating a first semiconductor device in accordance with a fifth example embodiment 1-5.

FIG. 174 is a cross-sectional view illustrating a first semiconductor device in accordance with a fifth example embodiment 1-5.

FIG. 175 is a cross-sectional view illustrating a first semiconductor device in accordance with a first example embodiment 1-1.

### DETAILED DESCRIPTION

The above and other aspects and features of a semiconductor device and a method of forming the same in accordance with example embodiments will become readily understood from detail descriptions that follow, with reference to the accompanying drawings. It will be understood that, although the terms “first,” “second,” and/or “third” may be used herein to describe various materials, layers (films), regions, electrodes, pads, patterns, structures and processes, these materials, layers (films), regions, electrodes, pads, patterns, structures and processes should not be limited by these terms. These terms are only used to distinguish one material, layer (film), region, electrode, pad, pattern, structure and process from another material, layer (film), region, electrode, pad, pattern, structure and process. Thus, a first material, layer (film), region, electrode, pad, pattern, structure and process discussed below could be termed a second or third material, layer (film), region, electrode, pad, pattern, structure and process without departing from the teachings of inventive concepts.

Hereinafter, in the specification (and not necessarily in the claims), two directions that are substantially perpendicular to each other among horizontal directions, which are substantially parallel to an upper surface of each substrates of the first semiconductor device, may be referred to as first and second directions D1_1 and D2_1, respectively, and a vertical direction substantially perpendicular to the upper surface of each of the substrates of the first semiconductor device may be referred to as a third direction D3_1. In example embodiments, the first and second directions D1_1 and D2_1 may be orthogonal to each other. Each of the first to third directions D1_1, D2_1 and D3_1 may include not only a direction shown in the drawings but also a direction reverse thereto.

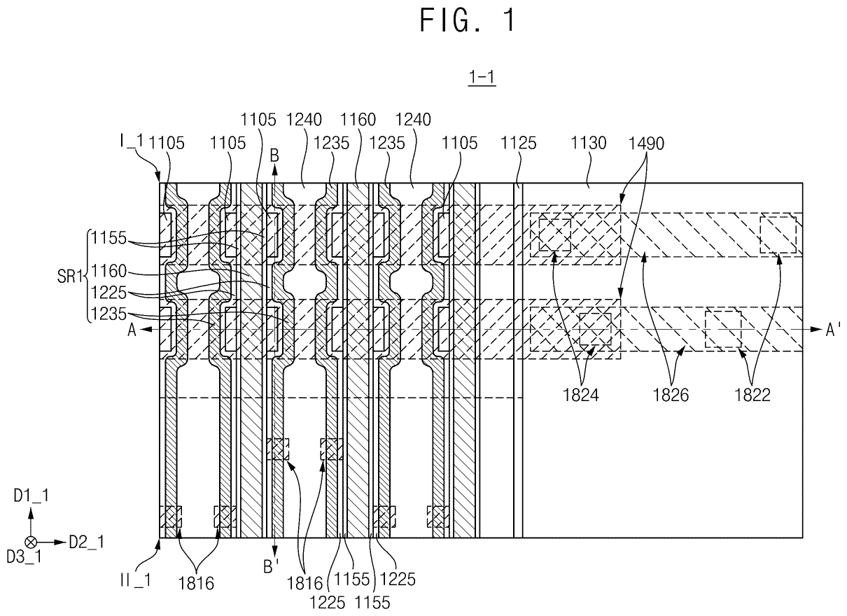

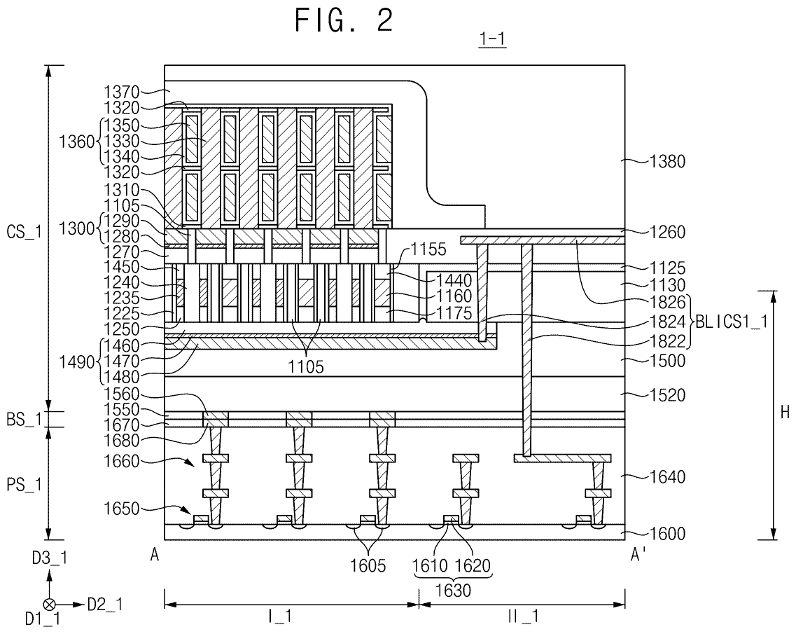

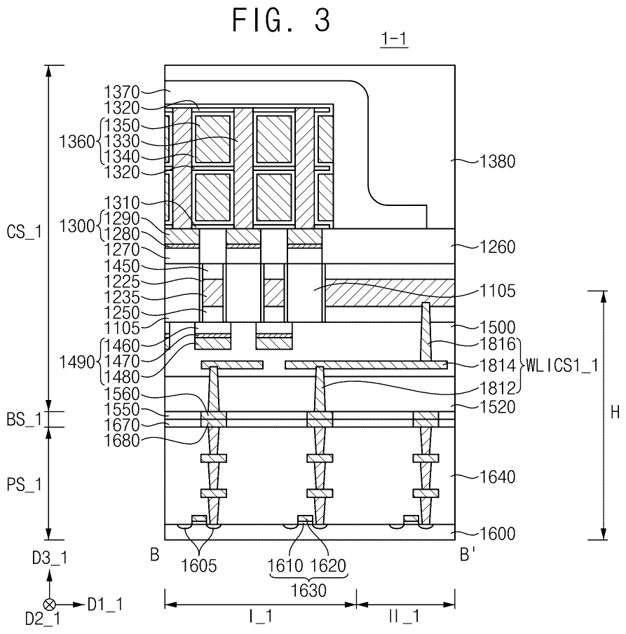

FIGS. 1 to 3 are cross-sectional views illustrating a first semiconductor device in accordance with a first example embodiment 1-1. Specifically, FIG. 1 is a horizontal cross-sectional view of FIGS. 2 and 3 at height H. FIG. 2 is a vertical cross-sectional view taken along line A-A′ of FIG. 1. FIG. 3 is a vertical cross-sectional view taken along line B-B′ of FIG. 1.

Referring to FIGS. 1 to 3, the first example embodiment 1-1 of the first semiconductor device may include a cell structure CS_1, a bonding structure BS_1, a peripheral circuit structure PS_1, a first word line wiring structure WLICS1_1, and a first bit line wiring structure BLICS1_1.

The first example embodiment 1-1 of the first semiconductor device may have a Cell Over Periphery (COP) structure. That is, the cell structure CS_1 including memory cells may be disposed on the peripheral circuit structure PS_1.

The cell structure CS_1 may include a first region I_1 and a second region II_1 surrounding the first region I_1 when viewed from above. In example embodiments, the first region I_1 may be a cell array region, and the second region II_1 may be an extension region, which together may form a cell region.

Hereinafter, for convenience of explanation, a portion of the peripheral circuit structure PS_1 and a portion of the bonding structure BS_1 that overlap with the first region I_1 of the cell structure CS_1 in the third direction D3_1 will also be referred to as the first region I_1, and a portion of the peripheral circuit structure PS_1 and a portion of the bonding structure BS_1 that overlap with the second region II_1 of the cell structure CS_1 in the third direction D3_1 will also be referred to as the second region II_1.

The peripheral circuit structure PS_1 may include a peripheral circuit pattern 1650, a wiring structure 1660, and a third insulating interlayer 1640 on a second substrate 1600.

The second substrate 1600 may include a semiconductor material, e.g., silicon, germanium, silicon-germanium, or a III-V group compound semiconductor, e.g., GaP, GaAs, GaSb, etc.

The peripheral circuit pattern 1650 may include, e.g., a transistor, and the transistor may include, e.g., a third gate structure 1630 on the second substrate 1600 and source/drain regions 1605 at upper portions, respectively, of the second substrate 1600 adjacent thereto. The third gate structure 1630 may include a third gate insulation pattern 1610 and a third gate electrode 1620 sequentially stacked in the third direction D3_1.

The peripheral circuit pattern 1650 may be circuit patterns for, e.g., a bit line sense amplifier (BLSA), a sub-word line driver (SWD), a column decoder, a column select line (CSL) driver, an input/output sense amplifier (I/O SA), a write driver, etc.

The wiring structure 1660 may be disposed on the second substrate 1600, and may be electrically connected to the peripheral circuit pattern 1650. The wiring structure 1660 may include, e.g., contact plugs, vias, wirings, etc.

The third insulating interlayer 1640 may be disposed on the second substrate 1600, and may cover the peripheral circuit pattern 1650 and the wiring structure 1660. The third insulating interlayer 1640 may include, e.g., silicon oxide, silicon nitride, a low-k dielectric material.

The bonding structure BS_1 may include first and second bonding layers 1550 and 1670 and first and second bonding pads 1560 and 1680.

The second and first bonding layers 1670 and 1550 may be sequentially stacked on the third insulating interlayer 1640 to form a bonding layer structure, and the second and first bonding pads 1680 and 1560 may be accommodated in the second and first bonding layers 1670 and 1550, respectively, to form a bonding pad structure. The first and second bonding pads 1560 and 1680 may include a metal, e.g., copper, and the first and second bonding layers 1550 and 1670 may include an insulating material, e.g., silicon carbonitride, silicon oxide, etc.

The cell structure CS_1 may include a bit line structure 1490, first and second gate structures, a channel 1105, a first contact plug 1270, a landing pad structure 1300, a capacitor 1360, and a plate electrode 1370.

The cell structure CS_1 may further include a first etch stop pattern 1125, a second insulation pattern 1130, a third insulation pattern 1240, first to fourth capping patterns 1175, 1250, 1440 and 1450, a semiconductor pattern 1102, first, second, fourth and fifth insulating interlayers 1500, 1520, 1260, and 1380, a second etch stop layer 1310, and a support layer 1320.

The second insulating interlayer 1520 may be disposed on the first bonding layer 1550 and the first bonding pad 1560. The second insulating interlayer 1520 may include, e.g., silicon oxide, silicon nitride, a low-k dielectric material.

The bit line structure 1490 may extend in the second direction D2_1 on the first region I_1 and a portion of the second region II_1 adjacent thereto, and a plurality of bit line structures 1490 may be spaced apart from each other in the first direction D1_1.

In example embodiments, the bit line structure 1490 may include fifth, fourth and third conductive patterns 1480, 1470 and 1460 sequentially stacked in the third direction D3_1. The third conductive pattern 1460 may include, e.g., doped polysilicon, the fourth conductive pattern 1470 may include a metal silicide, e.g., titanium silicide, tungsten silicide, etc., and the fifth conductive pattern 1480 may include a metal, e.g., tungsten, titanium, etc., or a metal nitride, e.g., titanium nitride.

The first insulating interlayer 1500 may be disposed on the second insulating interlayer 1520, and may cover a lower surface and a sidewall of the bit line structure 1490. The first insulating interlayer 1500 may include, e.g., silicon oxide, silicon nitride, a low-k dielectric material.

A plurality of channels 1105 may be spaced apart from each other in the second direction D2_1 on each of the bit line structures 1490 extending in the second direction D2_1 on the first region I_1, and thus, the plurality of channels 1105 may be spaced apart from each other in each of the first and second directions D1_1 and D2_1. Each of the channels 1105 may extend to a given length in the third direction D3_1.

The channel 1105 may include a semiconductor material, e.g., silicon, germanium, silicon-germanium, etc.

The first gate structure may be disposed on the first region I_1 and the second region II_1 adjacent to the first region I_1, and may contact upper surfaces of the bit line structure 1490 and the first insulating interlayer 1500. The first gate structure may include a first gate electrode 1160 extending in the first direction D1_1, and a first gate insulation pattern 1155 extending in the first direction D1_1 on each of opposite sidewalls in the second direction D2_1 of the first gate electrode 1160. The first gate insulation pattern 1155 may contact a sidewall in the second direction D2_1 of the channel 1105.

In example embodiments, the first gate electrode 1160 may serve as a back gate of the first semiconductor device.

The first gate electrode 1160 may include a conductive material, e.g., a metal, a metal nitride, a metal silicide, etc., and the first gate insulation pattern 1155 may include an oxide, e.g., silicon oxide.

The third and first capping patterns 1440 and 1175 may be on and beneath, respectively, the first gate electrode 1160, and a lower surface of the first capping pattern 1175 may contact the upper surface of the bit line structure 1490. The first gate insulation pattern 1155 may contact each of opposite sidewalls in the second direction D2_1 of each of the first and third capping patterns 1175 and 1440.

In example embodiments, a lower surface of the first capping pattern 1175 may be substantially coplanar (and/or substantially coplanar) with lower surfaces of the first gate insulation pattern 1155 and the channel 1105, and an upper surface of the third capping pattern 1440 may be substantially coplanar (and/or substantially coplanar) with upper surfaces of the first gate insulation pattern 1155 and the channel 1105.

Each of the first and third capping patterns 1175 and 1440 may include an insulating nitride, e.g., silicon nitride.

The second gate structure may be disposed on the first region I_1 and the second region II_1 adjacent to the first region I_1, and may contact the upper surfaces of the bit line structure 1490 and the first insulating interlayer 1500. The second gate structure may include a second gate electrode 1235 extending in the first direction D1_1, and a second gate insulation pattern 1215 extending in the first direction D1_1 on each of opposite sidewalls of the second gate electrode 1235 in the second direction D2_1. The second gate insulation pattern 1215 may contact another sidewall in the second direction D2_1 and each of opposite sidewalls in the first direction D1_1 of the channel 1105 and a portion of a sidewall of the first gate insulation pattern 1155.

In example embodiments, on the first region I_1, each of the second gate electrode 1235 and the second gate insulation pattern 1215 may extend in the first direction D1_1, however, a sidewall of each of the second gate electrode 1235 and the second gate insulation pattern 1215 may not be in a straight line but have a winding shape in a plan view. In example embodiments, on the second region II_1, each of the second gate electrode 1235 and the second gate insulation pattern 1215 may extend in the first direction D1_1, and, a sidewall of each of the second gate electrode 1235 and the second gate insulation pattern 1215 may be in a straight line.

In example embodiments, the second gate electrode 1235 may serve as a front-gate electrode, that is, a word line of the first semiconductor device.

The second gate electrode 1235 may include a conductive material, e.g., a metal, a metal nitride, a metal silicide, etc., and the second gate insulation pattern 1215 may include an oxide, e.g., silicon oxide.

The fourth and second capping patterns 1450 and 1250 may be on and beneath, respectively, the second gate electrode 1235, and a lower surface of the second capping pattern 1250 may contact the upper surface of the bit line structure 1490. The second gate insulation pattern 1215 may contact each of opposite sidewalls in the second direction D2_1 of each of the second and fourth capping patterns 1250 and 1450.

In example embodiments, a lower surface of the second capping pattern 1250 may be substantially coplanar (and/or substantially coplanar) with lower surfaces of the second gate insulation pattern 1215 and the channel 1105, and an upper surface of the fourth capping pattern 1450 may be substantially coplanar (and/or substantially coplanar) with upper surfaces of the second gate insulation pattern 1215 and the channel 1105.

Each of the second and fourth capping patterns 1250 and 1450 may include an insulating nitride, e.g., silicon nitride.

Meanwhile, the first gate structure including the first gate electrode 1160 and the first gate insulation pattern 1155, and the second gate structures including the second gate electrode 1235 and the second gate insulation pattern 1225 and disposed on opposite sides of the first gate structure in the second direction D2_1 may together form a first structure SR1.

In example embodiments, a plurality of first structures SR1 may be spaced apart from each other along the second direction D2_1.

The third insulation pattern 1240 may be disposed on the first region I_1 and the second region II_1 adjacent to the first region I_1 in the first direction D1_1, and may contact the upper surfaces of the bit line structure 1490 and the first insulating interlayer 1500. The third insulation pattern 1240 may extend in the first direction D1_1 between neighboring ones of the first structures SR1 in the second direction D2_1, and may contact a sidewall of each of the second gate electrode 1235 and the second and fourth capping patterns 1250 and 1450.

In example embodiments, each of opposite sidewalls in the second direction D2_1 of the third insulation pattern 1240 in the first region I_1 may have a winding shape in the first direction D1_1 in a plan view. That is, a width in the second direction D2_1 of the third insulation pattern 1240 may periodically vary in the first direction D1_1. In example embodiments, each of opposite sidewalls in the second direction D2_1 of the third insulation pattern 1240 in the second region II_1 may be in a straight line extending in the first direction D1_1 in a plan view. That is, a width in the second direction D2_1 of the third insulation pattern 1240 in the second region II_1 may be substantially constant along the first direction D1_1.

In example embodiments, an upper surface of the third insulation pattern 1240 may be disposed at substantially the same height as the upper surface of the fourth capping pattern 1450.

The third insulation pattern 1240 may include an oxide, e.g., silicon oxide, an insulating nitride, e.g., silicon nitride, etc.

The semiconductor pattern 1102 may be disposed on a portion of the first region I_1 adjacent to the second region II_1 in the second direction D2_1, and may contact the upper surfaces of the bit line structure 1490 and the first insulating interlayer 1500. The semiconductor pattern 1102 may extend in the first direction D1_1, and may contact a sidewall in the second direction D2_1 of the first gate insulation pattern 1155.

In example embodiments, the semiconductor pattern 1102 may include a material substantially the same as that of the channel 1105, e.g., a semiconductor material such as silicon, germanium, silicon-germanium, etc.

The second insulation pattern 1130 may be disposed in the second region II_1 and contact an upper surface of the bit line structure 1490 and an upper surface of the first insulating interlayer 1500.

The first etch stop pattern 1125 may include a first portion and a second portion. The first portion may contact an upper surface of the second insulation pattern 1130 and have a flat plate shape extending in the horizontal direction. The second portion may extend from the first portion in the third direction D3_1, have a flat plate shape extending in the vertical direction, and contact a sidewall of the semiconductor pattern 1102 in the second direction D2_1. Thus, a cross-section of the first etch stop pattern 1125 cut along a plane defined by the second and third directions D2_1 and D3_1 may have an upside-down “L”shape.

In example embodiments, an upper surface of the first portion of the first etch stop pattern 1125 may be disposed at substantially the same height as upper surfaces of the semiconductor pattern 1102, the channel 1105, the third and fourth capping patterns 1440, 1450, and the first and second gate insulation patterns 1155 and 1225. In example embodiments, the second portion of the first etch stop pattern 1125 may contact an upper surface of the bit line structure 1490 and an upper surface of the first insulating interlayer 1500.

In some example embodiments, a lower surface of the second portion of the first etch stop pattern 1125 may be convex upwardly. Thus, an edge portion the lower surface of the first etch stop pattern 1125 may be substantially coplanar (and/or substantially coplanar) with lower surfaces of the semiconductor pattern 1102 and the second insulation pattern 1130, while a central portion of the first etch stop pattern 1125 may be higher than the lower surfaces of the semiconductor pattern 1102 and the second insulation pattern 1130.

Alternatively, the lower surface of the second portion of the first etch stop pattern 1125 may be substantially flat, and thus an entire portion of the first etch stop pattern 1125 may be substantially coplanar (and/or substantially coplanar) with the lower surfaces of the semiconductor pattern 1102 and the second insulation pattern 1130.

The first etch stop pattern 1125 may include an insulating nitride, e.g., silicon nitride.

The first contact plug 1270 may contact an upper surface of each of the channels 1105, and the landing pad structure 1300 may contact an upper surface of the first contact plug 1270. Thus, a plurality of first contact plugs 1270 may be spaced apart from each other in each of the first and second directions D1_1 and D2_1, a plurality of landing pad structures 1300 may be spaced apart from each other in each of the first and second directions D1_1 and D2_1, and the first contact plugs 1270 and the landing pad structures 1300 may be arranged in a lattice pattern or a honeycomb pattern in a plan view.

The first contact plug 1270 may also contact portions of upper surfaces of the first and second gate insulation patterns 1155 and 1215, the third capping pattern 1440, the fourth capping pattern 1450, and the third insulation pattern 1240 adjacent to each of the channels 1105 in the second direction D2_1.

The landing pad structure 1300 may include first and second conductive patterns 1280 and 1290 sequentially stacked in the third direction D3_1.

The first contact plug 1270 may include, e.g., doped polysilicon, the first conductive pattern 1280 may include a metal silicide, e.g., titanium silicide, tungsten silicide, etc., and the second conductive pattern 1290 may include a metal, e.g., tungsten, titanium, etc., or a metal nitride, e.g., titanium nitride.

The fourth insulating interlayer 1260 may be disposed on the first etch stop pattern 1125, the semiconductor pattern 1102, the channel 1105, the first and second gate insulation patterns 1155 and 1215, the third and fourth capping patterns 1440 and 1450 and the third insulation pattern 1240, and may cover sidewalls of the first contact plug 1270 and the landing pad structure 1300. The fourth insulating interlayer 1260 may include, e.g., silicon oxide, silicon nitride, a low-k dielectric material.

The second etch stop layer 1310 may be disposed on the first region I_1, and may contact upper surfaces of the landing pad structure 1300 and the fourth insulating interlayer 1260. The second etch stop layer 1310 may include an insulating nitride, e.g., silicon boronitride.

The capacitor 1360 may include a first capacitor electrode 1330, a dielectric layer 1340 and a second capacitor electrode 1350.

The first capacitor electrode 1330 may contact the upper surface of each of the landing pad structures 1300, and may extend in the third direction D3_1 to a given length. Thus, a plurality of first capacitor electrodes 1330 may be spaced apart from each other in each of the first and second directions D1_1 and D2_1. In example embodiments, the first capacitor electrodes 1330 may be arranged in a lattice pattern or a honeycomb pattern in a plan view.

Each of the first capacitor electrodes 1330 may extend through the second etch stop layer 1310, and the support layer 1320 may be disposed on a sidewall of each of the first capacitor electrodes 1330. In example embodiments, a plurality of support layers 1320 may be spaced apart from each other in the third direction D3_1 on the sidewall of each of the first capacitor electrodes 1330.

The dielectric layer 1340 may be disposed on a sidewall of the first capacitor electrode 1330, lower and upper surfaces and a sidewall of the support layer 1320, and an upper surface and a sidewall of the second etch stop layer 1310. The second capacitor electrode 1350 may be disposed between ones of the support layers 1320 neighboring in the third direction D3_1 and between a lowermost one of the support layers 1320 and the second etch stop layer 1310, and lower and upper surfaces and a sidewall of the second capacitor electrode 1350 may be covered by the dielectric layer 1340.

The plate electrode 1370 may surround upper surfaces and sidewalls of the capacitor 1360, the support layer 1320 and the second etch stop layer 1310.

Each of the first and second capacitor electrodes 1330 and 1350 may include, e.g., a metal, a metal nitride, a metal silicide, etc., and the dielectric layer 1340 may include, e.g., a metal oxide. The support layer 1320 may include an insulating nitride, e.g., silicon nitride. The plate electrode 1370 may include, e.g., doped silicon-germanium, or a metal such as tungsten.

The fifth insulating interlayer 1380 may be disposed on the fourth insulating interlayer 1260 and the landing pad structure 1300, and may cover upper surfaces and sidewalls of the plate electrode 1370. The fifth insulating interlayer 1380 may include, e.g., silicon oxide, silicon nitride, a low-k dielectric material.

Hereinafter, for convenience of explanation, among first and second surfaces of the cell structure CS_1 in the third direction D3_1, a surface adjacent to the capacitor 1360 will be referred to as a first front surface, and an opposite surface thereof will be referred to as a first rear surface. In addition, among third and fourth surfaces of the second substrate 1600 in the third direction D3_1, a surface on which the peripheral circuit pattern 1650 is disposed will be referred to as a second front surface of the second substrate 1600, and an opposite surface thereof will be referred to as a second rear surface.

In example embodiments, the first example embodiment 1-1 of the first semiconductor device may have a structure in which the first rear surface of the cell structure CS_1 and the second front surface of the second substrate 1600 face each other.

The first word line wiring structure WLICS1_1 may include first and second word line contacts 1812 and 1816 and a first word line wiring 1814.

The first word line contact 1812 may extend through a lower portion of the first insulating interlayer 1500 and the second insulating interlayer 1520 to contact an upper surface of the bonding pad structure. The first word line wiring 1814 may extend in the first direction D1_1 within the first insulating interlayer 1500 and contact an upper surface of the first word line contact 1812. The second word line contact 1816 may extend through the second capping pattern 1250 and an upper portion of the second insulating interlayer 1520 to contact a lower surface of the second gate electrode 1235 and an upper surface of the first word line wiring 1814.

That is, the second gate electrode 1235 may be electrically connected to a first transistor of the peripheral circuit pattern 1650 through the first word line wiring structure WLICS1_1, the bonding pad structure, and the wiring structure 1660. In example embodiments, the first transistor may constitute the SWD.

In example embodiments, a width of each of the first and second word line contacts 1812 and 1816 in the horizontal direction may decrease away from the second rear surface of the second substrate 1600 in the third direction D3_1.

The first bit line wiring structure BLICS1_1 may include first and second bit line contacts 1822 and 1824 and a first bit line wiring 1826.

The first bit line contact 1822 may extend through a lower portion of the fourth insulating interlayer 1260, the first etch stop pattern 1125, the second insulation pattern 1130, the first and second insulating interlayers 1500 and 1520, and an upper portion of the third insulating interlayer 1640 to contact a pad of the wiring structure 1660. The second bit line contact 1824 may extend through a lower portion of the fourth insulating interlayer 1260, the first etch stop pattern 1125, and the second insulation pattern 1130 to contact an upper surface of the bit line structure 1490. The first bit line wiring 1826 may extend in the second direction D2_1 within the fourth insulating interlayer 1260 and commonly contact upper surfaces of the first and second bit line contacts 1822 and 1824. Meanwhile, the pad of the wiring structure 2760 may serve as a landing pad for the first bit line contact 1822.

That is, the bit line structure 1490 may be electrically connected to a second transistor of the peripheral circuit pattern 1650 through the first bit line wiring structure BLICS1_1 and the wiring structure 1660. In example embodiments, the second transistor may constitute the BLSA.

In example embodiments, a width of each of the first and second bit line contacts 1822 and 1824 in the horizontal direction may increase away from the second rear surface of the second substrate 1600 in the third direction D3_1.

In example embodiments, an upper surface of the first bit line contact 1822 may be disposed between an upper surface of the channel 1105 and a lower surface of the capacitor 1360.

In the first semiconductor device, the third conductive pattern 1460 of the bit line structure 1490 and the first contact plug 1270 may serve as source/drain layers, respectively, and current may flow in the third direction D3_1 in the channel 1105 between the source/drain layers. Thus, the first semiconductor device may include a vertical channel transistor (VCT) having a vertical channel.

In the first semiconductor device, the second gate structure may be electrically connected to the peripheral circuit pattern 1650 through the bonding pad structure. Since the bonding pad structure may be disposed not only in the second region II_1 but also in the first region I_1, area occupied by contact plugs for electrically connecting the second gate structure to the peripheral circuit pattern 1650 in the second region II_1 may be reduced. Accordingly, integration density of the first semiconductor device may be improved.

Meanwhile, when both of the bit line structure 1490 and the second gate structure is electrically connected to the peripheral circuit pattern 1650 through the bonding pad structure, planar areas of the first and second bonding pads 1560 and 1680 included in the bonding pad structure may be reduced. In this case, mis-alignment between the first and second bonding pads 1560 and 1680 may increase, thereby deteriorating the reliability of the first semiconductor device.

However, in the first semiconductor device, only the second gate structure may be electrically connected to the peripheral circuit pattern 1650 through the bonding pad structure. Accordingly, integration density of the first semiconductor device may be improved while limiting and/or preventing deterioration of reliability due to increased mis-alignment between the first and second bonding pads 1560 and 1680.

Meanwhile, as in the embodiments to be described later, the integration density of the first semiconductor device may also be improved by electrically connecting the bit line structure 1390, rather than the second gate structure, to the peripheral circuit pattern 1650 through the bonding pad structure.

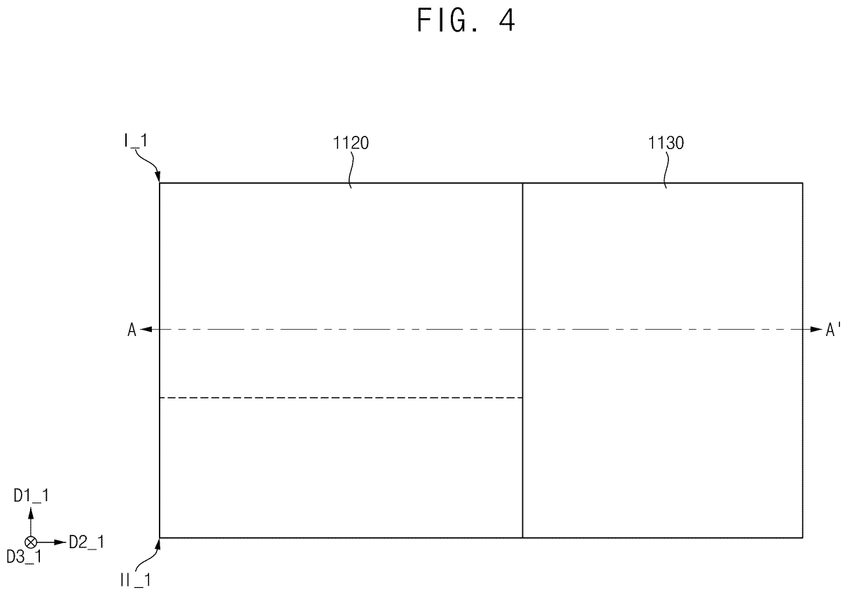

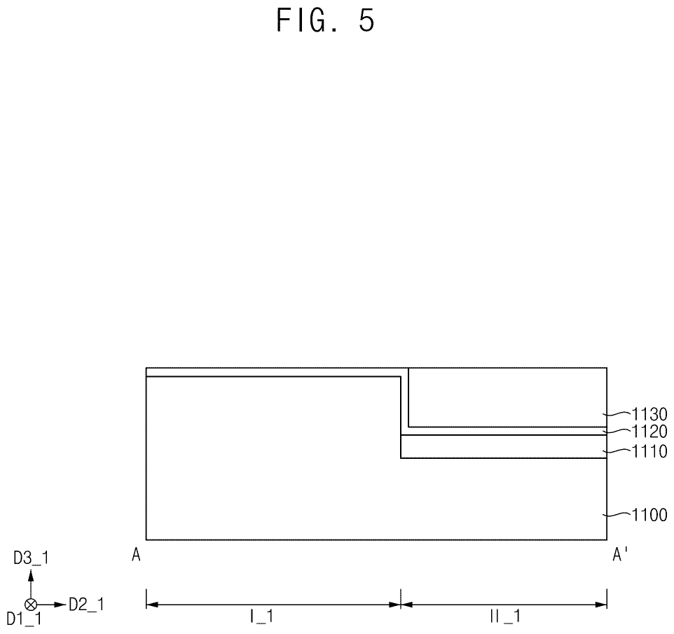

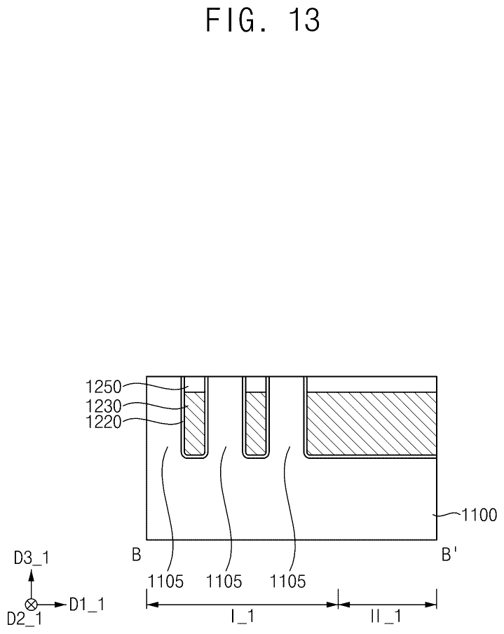

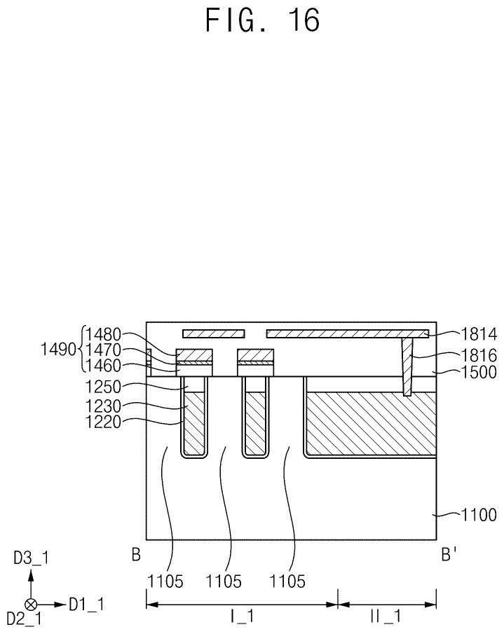

FIGS. 4 to 23 are plan views and cross-sectional views illustrating a method of manufacturing a first semiconductor device in accordance with a first example embodiment 1-1. Specifically, FIGS. 4, 7, 9, 11 and 14 are the plan views. FIGS. 5, 6, 8, 10, 12, 15, 17, 19, 20 and 22 are cross-sectional views taken along lines A-A′ of corresponding plan views, respectively. FIGS. 13, 16, 18, 21 and 23 are cross-sectional views taken along lines B-B′ of corresponding plan views, respectively.

Referring to FIGS. 4 and 5, an upper portion of a second region II_1 of a first substrate 1100 including a first region I_1 and the second region II_1 may be removed to form a first trench 1101, a first insulation pattern 1110 may be formed in a lower portion of the first trench 1101, a first etch stop layer 1120 may be formed on an upper surface and a sidewall of the first substrate 1100 and an upper surface of the first insulation pattern 1110, and a second insulation pattern 1130 may be formed on the first etch stop layer 1120.

The first insulation pattern 1110 may be formed by forming a first insulation layer on the first and second regions I_1 and II_1 of the first substrate 1100 having the first trench 1101 thereon, and performing an etch back process on the first insulation layer to remove an upper portion of the first insulation layer. The first insulation pattern 1110 may include an oxide, e.g., silicon oxide, and the first etch stop layer 1120 may include an insulating nitride, e.g., silicon nitride.

The second insulation pattern 1130 may be formed by forming a second insulation layer on the first etch stop layer 1120, and performing a planarization process, e.g., a chemical mechanical polishing (CMP) process on the second insulation layer until an upper surface of a portion of the first etch stop layer 1120 on the first region I_1 of the first substrate 1100 is exposed. Thus, an upper surface of the second insulation pattern 1130 may be substantially coplanar (and/or substantially coplanar) with the upper surface of the portion of the first etch stop layer 1120 on the first region I_1 of the first substrate 1100.

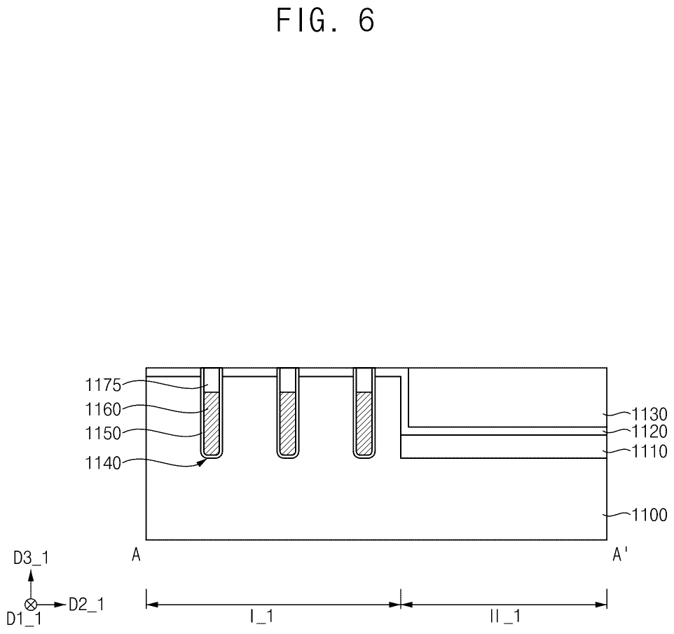

Referring to FIG. 6, the upper portion of the first etch stop layer 1120 on the first etch stop layer 1120 and an upper portion of the first region I_1 of the first substrate 1100 thereunder may be partially removed to form a second trench 1140, a first gate insulation layer 1150 may be formed on an inner wall of the second trench 1140, an upper surface of the first etch stop layer 1120 and an upper surface of the second insulation pattern 1130, a first gate electrode layer may be formed on the first gate insulation layer 1150 to fill the second trench 1140, and a planarization process, e.g., a CMP process may be performed on the first gate electrode layer and the first gate insulation layer until the upper surfaces of the first etch stop layer 1120 and the second insulation pattern 1130 are exposed.

Thus, the first gate insulation layer 1150 may remain on the inner wall of the second trench 1140, and a first gate electrode 1160 may be formed in the second trench 1140. In example embodiments, the second trench 1140 may extend in the first direction D1_1 on the first and second regions I_1 and II_1 of the first substrate 1100, and a plurality of second trenches 1140 may be spaced apart from each other in the second direction D2_1. A cross-section of the first gate insulation layer 1150 taken along a plane defined by the second and third directions D2_1 and D3_1 may have a “U” shape.

An upper portion of the first gate electrode 1160 may be removed by, e.g., an etch back process to form a first recess, and a first capping layer 1170 may be formed on the first gate electrode 1160, the first gate insulation layer 1150, the first etch stop layer 1120 and the second insulation pattern 1130 to fill the first recess.

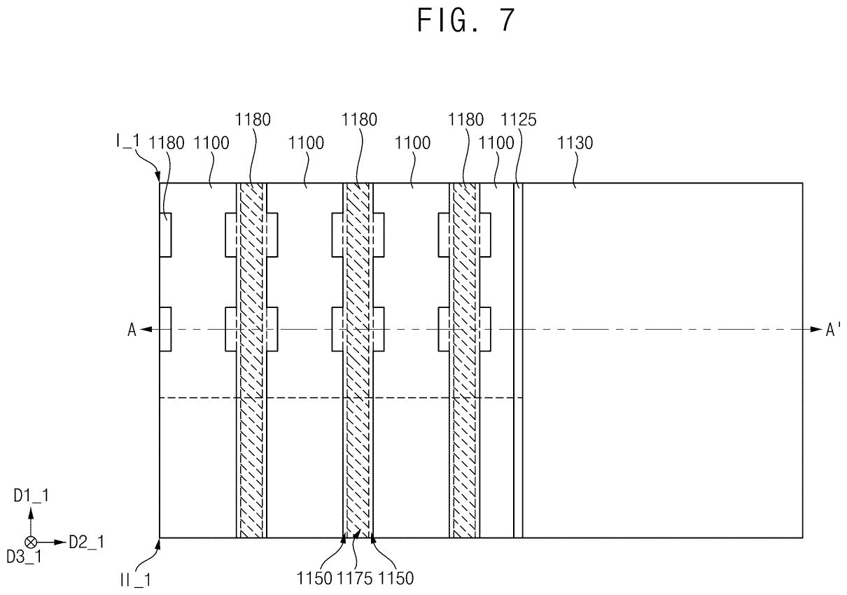

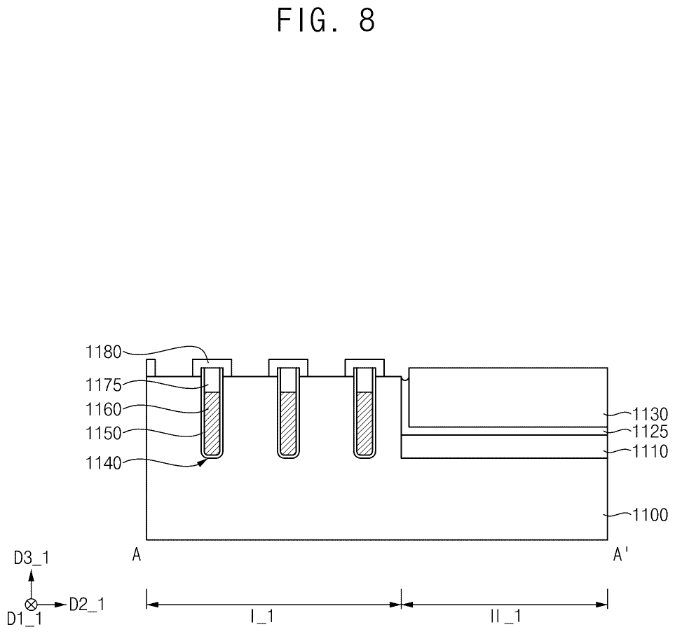

Referring to FIGS. 7 and 8, an upper portion of the first capping layer 1170 may be removed by, e.g., a CMP process and/or an etch back process to expose the upper surface of the first etch stop layer 1120, an uppermost surface of the first gate insulation layer 1150 and the upper surface of the second insulation pattern 1130, and a first capping pattern 1175 may be formed in the first recess.

For example, a wet etching process may be performed to remove a portion of first etch stop layer 1120 on the first region I_1 of the first substrate 1100 and a portion of the first etch stop layer 1120 on a portion of the second region II_1 of the first substrate 1100 adjacent to the first region I_1 of the first substrate 1100, and thus a first etch stop pattern 1125 may remain on the second region II_1 of the first substrate 1100. By the wet etching process, an upper surface of the first region I_1 of the first substrate 1100 and an upper sidewall of the first gate insulation layer 1150 may be exposed.

In example embodiments, an uppermost surface of a portion of the first etch stop pattern 1125 on the portion of the second region II_1 of the first substrate 1100 adjacent to the first region I_1 of the first substrate 1100 may be concave upwardly due to the characteristic of the wet etching process.

A spacer layer may be formed on the first substrate 1100, the first gate insulation layer 1150, the first capping pattern 1175, the first etch stop pattern 1125 and the second insulation pattern 1130, and may be partially etched to form a preliminary spacer 1180. In example embodiments, the preliminary spacer 1180 may cover an upper surface of the first capping pattern 1175 and an uppermost surface of the first gate insulation layer 1150, and may also cover an upper sidewall of a portion of the first gate insulation layer 1150 and an upper surface of a portion of the first substrate 1100 adjacent to the portion of the first gate insulation layer 1150.

In example embodiments, the preliminary spacer 1180 may extend in the first direction D1_1 on the first and second regions I_1 and II_1 of the first substrate 1100, and a plurality of preliminary spacers 1180 may be spaced apart from each other in the second direction D2_1. Each of opposite sidewalls in the second direction D2_1 of the preliminary spacer 1180 may not be formed in a straight line but may have a zigzag pattern in the first direction D1_1.

The preliminary spacer 1180 may include an oxide, e.g., silicon oxide.

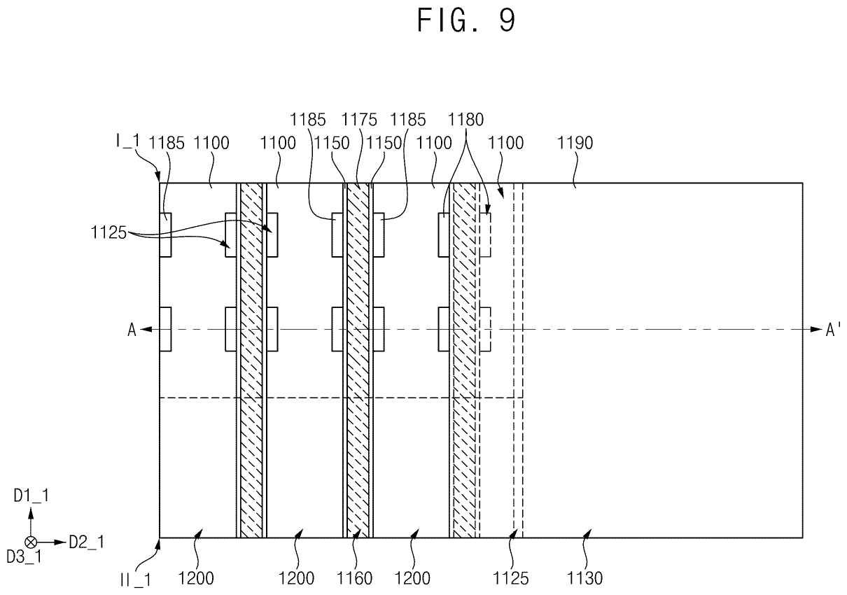

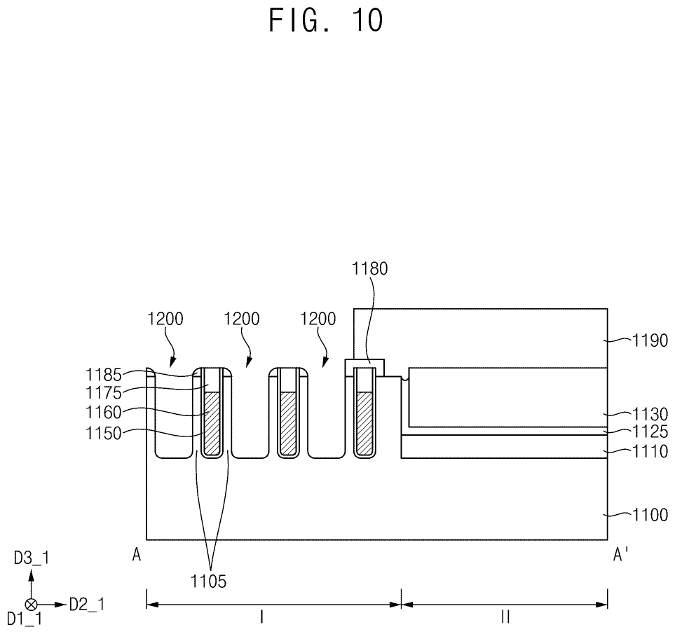

Referring to FIGS. 9 and 10, a mask 1190 covering the second insulation pattern 1130, the first etch stop pattern 1125, a portion of the first region I_1 of the first substrate 1100 adjacent to the second region II_1 of the first substrate 1100, and the first capping pattern 1175, the first gate insulation layer 1150 and the preliminary spacer 1180 disposed on the portion of the first region I_1 of the first substrate 1100 adjacent to the second region II_1 of the first substrate 1100 may be formed.

The mask 1190 may include, e.g., a photoresist layer.

An anisotropic etching process may be performed on the preliminary spacers 1180 on other portions of the first region I_1 of the first substrate 1100 to form a spacer 1185 on the upper sidewall of the first gate insulation layer 1150, and an etching process may be performed using the spacer 1185, the first capping pattern 1175, the first gate insulation layer 1150 and the mask 1190 as an etching mask to partially remove the upper portion of the first substrate 1100 so that a third trench 1200 may be formed.

In example embodiments, the third trench 1200 may extend in the first direction D1_1 on the first region I_1 of the first substrate 1100 and the portion of the second region II_1 of the first substrate 1100 adjacent thereto, and a plurality of third trenches 1200 may be spaced apart from each other in the second direction D2_1.

Each of opposite sidewalls in the second direction D2_1 of the third trench 1200 on the first region I_1 of the first substrate 1100 may not be formed in a straight line but may have a zigzag pattern in the first direction D1_1. That is, a width in the second direction D2_1 of the third trench 1200 on the first region I_1 of the first substrate 1100 may not be uniform in the first direction D1_1, and may periodically vary in the first direction D1_1. Each of opposite sidewalls in the second direction D2_1 of a portion of the third trench 1200 having a relatively large width in the second direction D2_1 may expose a sidewall of the first gate insulation layer 1150. A channel 1105 may be formed between each of opposite sidewalls in the second direction D2_1 of a portion of the third trench 1200 having a relatively small width in the second direction D2_1 and the first gate insulation layer 1150.

Meanwhile, each of opposite sidewalls in the second direction D2_1 of the third trench 1200 on the second region II_1 of the first substrate 1100 may be formed in a straight line along the first direction D1_1. In this case, each of opposite sidewalls in the second direction D2_1 of a portion of the third trench 1200 on the second region II_1 of the first substrate 1100 may expose a sidewall of the first gate insulation layer 1150.

In example embodiments, on the first region I_1, a plurality of channels 1105 may be spaced apart from each other in the first direction D1_1 on a sidewall of the first gate insulation layer 1150.

In some example embodiments, a bottom of the third trench 1200 may be substantially coplanar (and/or substantially coplanar) with a lower surface of the first gate insulation layer 1150, however, the inventive concepts are not limited thereto.

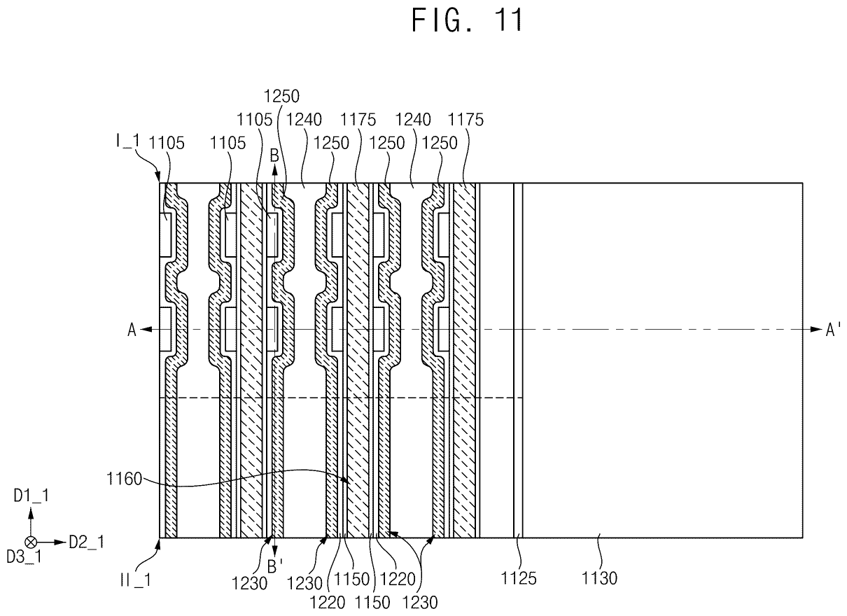

Referring to FIGS. 11 to 13, the mask 1190 may be removed by, e.g., an ashing process and/or a stripping process, and a second gate insulation layer 1220 and a second gate electrode layer 1230 may be sequentially stacked on an inner wall of the third trench 1200, a surface of the spacer 1185, the uppermost surface of the first gate insulation layer 1150, the upper surface of the first capping pattern 1175, an upper surface and a sidewall of the preliminary spacer 1180, the upper surface of the portion of the first region I_1 of the first substrate 1100 adjacent to the second region II_1 thereof, the uppermost surface of the first etch stop pattern 1125 and the upper surface of the second insulation pattern 1130.

A third insulation layer may be formed on the second gate electrode layer 1230 to fill the third trench 1200, and a planarization process, e.g., a CMP process may be performed on the third insulation layer, the second gate electrode layer 1230 and the second gate insulation layer 1220 until the upper surface of the first substrate 1100 is exposed.

Thus, the second gate insulation layer 1220 and the second gate electrode layer 1230 may remain on the inner wall of the third trench 1200, and a third insulation pattern 1240 may be formed in the third trench 1200. A cross-section of each of the second gate insulation layer 1220 and the second gate electrode layer 1230 taken along a plane defined by the second and third directions D2_1 and D3_1 may have a “U” shape. The third insulation layer may include an oxide, e.g., silicon oxide.

During the planarization process, the spacer 1185 and the preliminary spacer 1180 may be removed, and upper portions of the first capping pattern 1175, the first gate insulation layer 1150 and the second insulation pattern 1130 may also be removed.

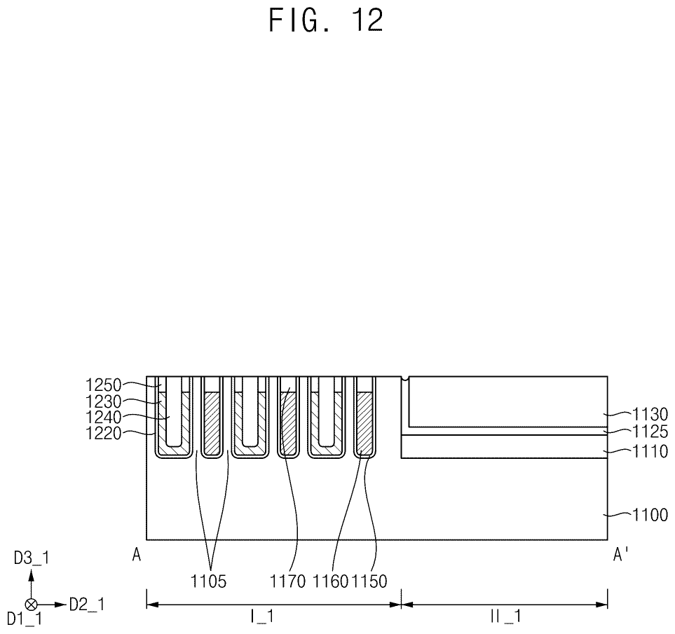

In some example embodiments, the uppermost surface of the first etch stop pattern 1125 may be concave even after the planarization process, which is shown in FIG. 12. Alternatively, the uppermost surface of the first etch stop pattern 1125 may be planarized during the planarization process so as to be substantially flat and coplanar (and/or substantially coplanar) with the upper surfaces of the first substrate 1100 and the second insulation pattern 1130.

In example embodiments, the second gate insulation layer 1220 may extend in the first direction D1_1, and may cover a sidewall in the second direction D2_1 of the first gate insulation layer 1150 and a sidewall in the second direction D2_1 and opposite sidewalls in the first direction D1_1 of the channel 1105. Additionally, the second gate electrode layer 1230 may extend in the first direction D1_1, and may cover a sidewall of the second gate insulation layer 1150.

In example embodiments, each of the second gate insulation layer 1220 and the second gate electrode layer 1230 on the first region I_1 of the first substrate 1100 may not be formed in a straight line in the first direction D1_1 but may have a zigzag shape. In example embodiments, each of the second gate insulation layer 1220 and the second gate electrode layer 1230 on the second region II_1 of the first substrate 1100 may be formed in a straight line along the first direction D1_1.

An upper portion of the second gate electrode layer 1220 may be removed to form a second recess, and a second capping pattern 1250 may be formed in the second recess.

In some example embodiments, a lower surface of the second capping pattern 1250 may be substantially coplanar (and/or substantially coplanar) with a lower surface of the first capping pattern 1175, however, the inventive concepts are not limited thereto.

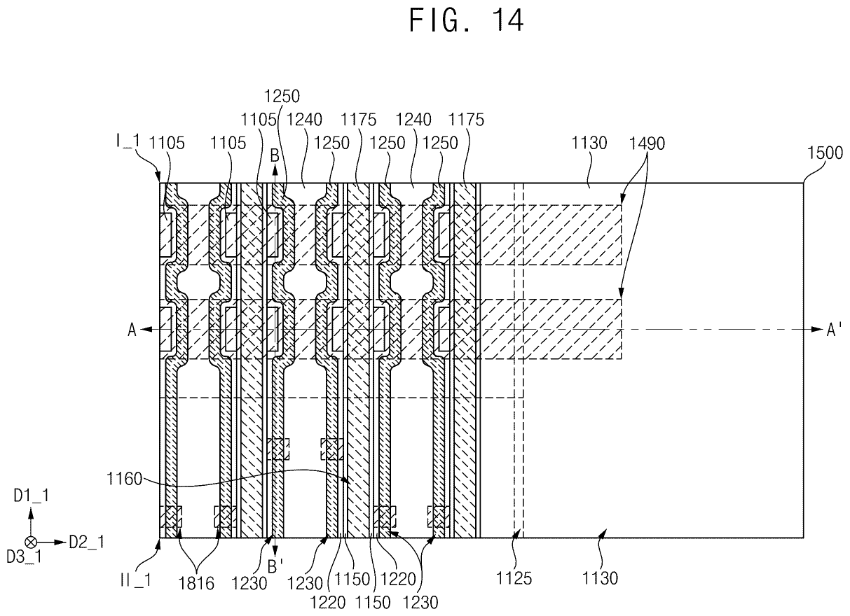

Referring to FIGS. 14 to 16, a bit line structure layer may be formed on the first substrate 1100, the first etch stop pattern 1125, the second insulation pattern 1130, and the first and second capping patterns 1175 and 1250, and then patterned to form bit line structures 1490 extending in the second direction D2_1 and spaced apart from each other in the first direction D1_1 on the first region I_1 of the first substrate 1100 and the second region II_1 of the first substrate 1100 adjacent thereto in the second direction D2_1.

In example embodiments, each of the bit line structures 1490 may contact upper surfaces of the channels 1105 disposed along the second direction D2_1, and may also contact upper surfaces of the first and second capping patterns 1175 and 1250, the first and second gate insulation layers 1150 and 1220, and the third insulation pattern 1240 disposed between the channels 1105.

In example embodiments, the bit line structure 1490 may include third to fifth conductive patterns 1460, 1470 and 1480 sequentially stacked along the third direction D3_1.

A first insulating interlayer 1500 covering the bit line structure 1490 and a second word line contact 1816 and a first word line wiring 1814 accommodated therein may be formed.

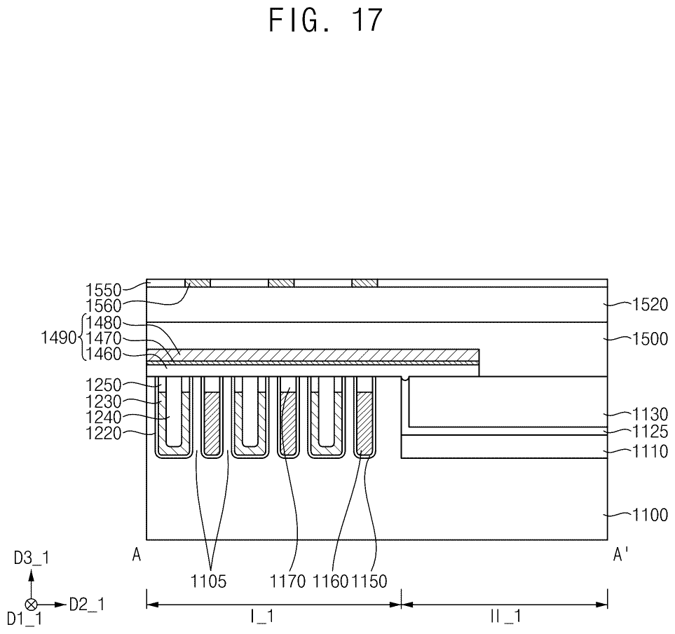

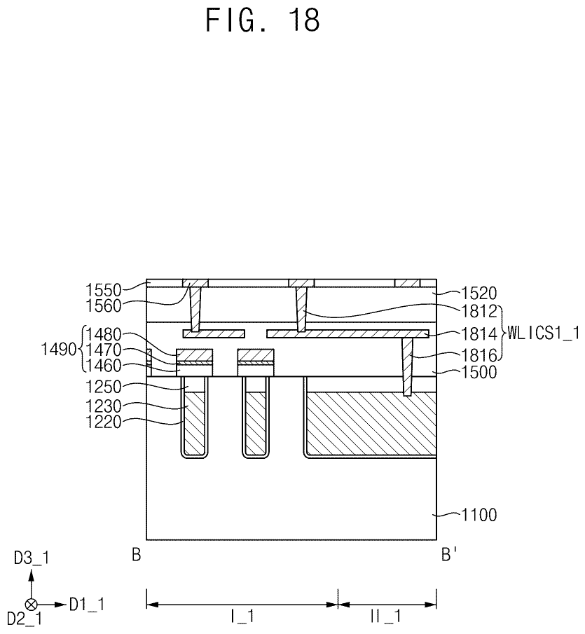

Referring to FIGS. 17 and 18, a second insulating interlayer 1520 and a first word line contact 1812 extending therethrough and contacting an upper surface of the first word line wiring 1814 may be formed on the first insulating interlayer 1500. A first bonding layer 1550 may be formed on the second insulating interlayer 1520, and a first bonding pad 1560 extending therethrough and contacting an upper surface of the first word line contact 1812 may be formed.

The first word line contact 1812, the first word line wiring 1814, and the second word line contact 1816 may together form a first word line wiring structure WLICS1_1.

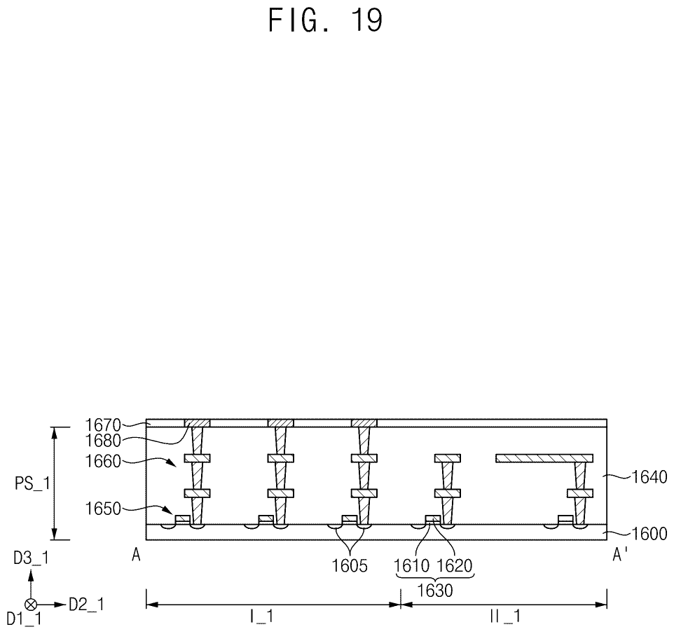

Referring to FIG. 19, a peripheral circuit pattern 1650 including, for example, transistors such as a third gate structure 1630 and source/drain regions 1605, a wiring structure 1660 including contact plugs, wirings, vias, and pads, and a third insulating interlayer 1640 covering the transistors and the wiring structure 1660 may be formed on a third substrate 1600 including first and second regions I_1 and II_1 corresponding to the first and second regions I_1, II_1 of the first substrate 1100, respectively. A second bonding layer 1670 may be formed on the third insulating interlayer 1640, and second bonding pads 1680 may be formed to extend through the second bonding layer 1670 and respectively contact upper surfaces of the vias.

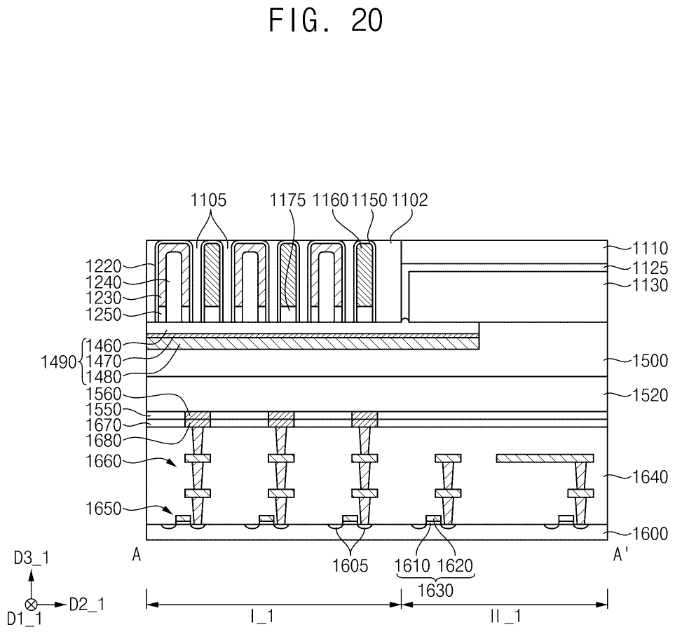

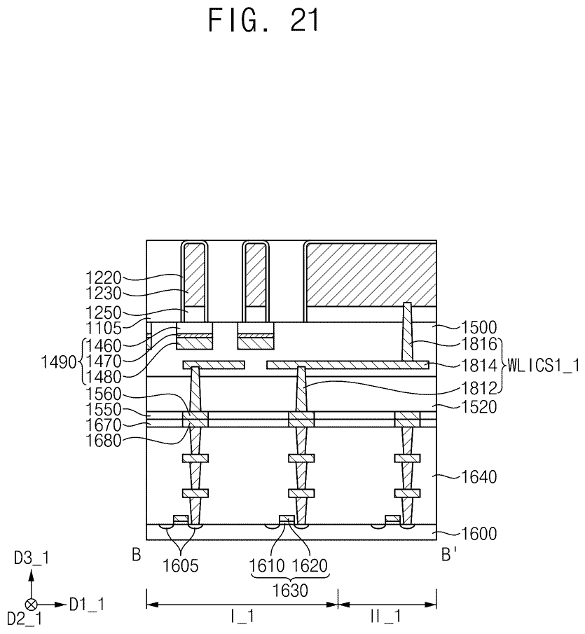

Referring to FIGS. 20 and 21, the first substrate 1100 may be flipped to bond the first and second bonding layers 1550 and 1670 to each other. Accordingly, since the structure formed on the first substrate 1100 is flipped upside down, the following description will be based on this flipped orientation.

An upper portion of the first substrate 1100 may be removed through, for example, a grinding process, and accordingly, upper surfaces of the first insulation pattern 1110 and the first and second gate insulation layers 1150 and 1220 may be exposed. During the grinding process, the first insulation pattern 1110 may serve as a grinding end point.

As the grinding process is performed, only a lower portion of the first substrate 1100 may remain, which will be referred to as a semiconductor pattern 1102 hereinafter. The semiconductor pattern 1102 may be formed between the first etch stop pattern 1125 and the first gate insulation layer 1150 and extend in the first direction D1_1.

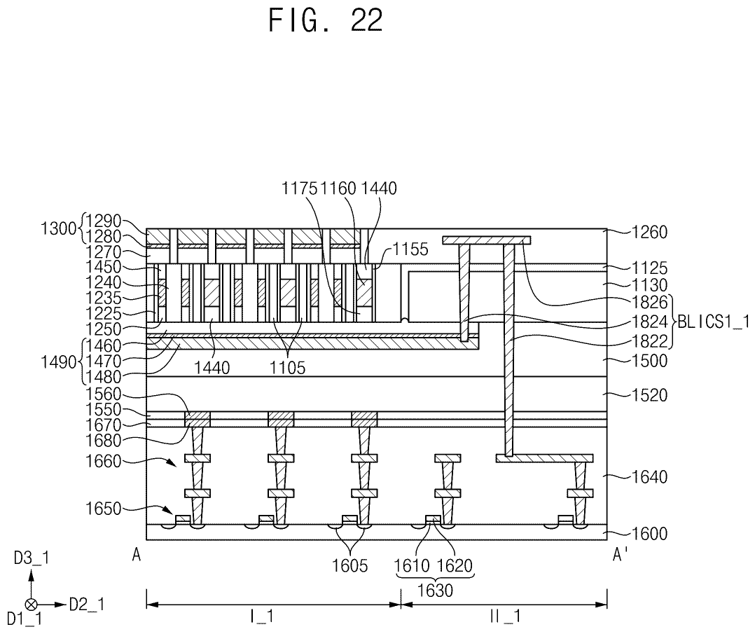

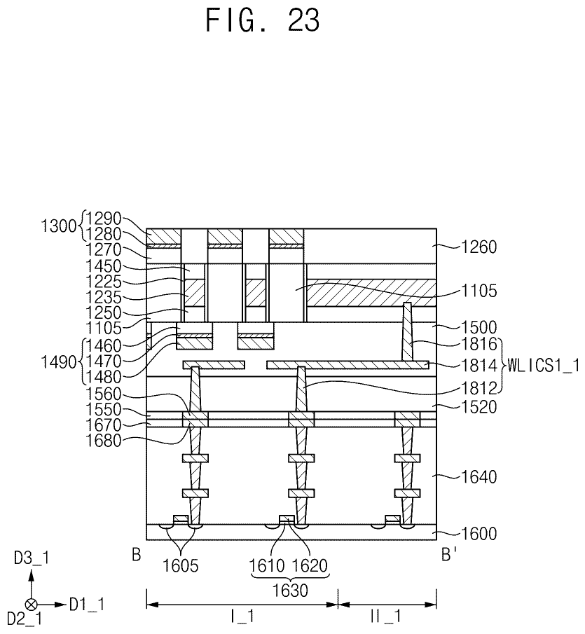

Referring to FIGS. 22 and 23, a planarization process such as, for example, a chemical mechanical polishing (CMP) process may be performed to remove the first insulation pattern 1110, and upper portions of the third insulation pattern 1240, the semiconductor pattern 1102, the channel 1105, the first and second gate insulation layers 1150 and 1220, the first gate electrode 1160, and the second gate electrode layer 1230.

In example embodiments, the first etch stop pattern 1125 may serve as a polishing end point during the chemical mechanical polishing (CMP) process.

As the planarization process is performed, the first and second gate insulation layers 1150 and 1220 and the second gate electrode layer 1230 having a “U” shape in cross-section along a plane defined by the second and third directions D2_1 and D3_1 may be separated into first and second gate insulation patterns 1155 and 1225 and second gate electrodes 1235 extending in the third direction D3_1, respectively. The first gate electrode 1160 and the first gate insulation pattern 1155 may together form a first gate structure, and the second gate electrode 1235 and the second gate insulation pattern 1225 may together form a second gate structure.

Thereafter, upper portions of the first and second gate electrodes 1160 and 1235 may be removed to form third and fourth recesses, respectively, and then third and fourth capping patterns 1440 and 1450 may be formed therein, respectively.

A contact plug layer and a landing pad structure layer may be sequentially formed on the third and fourth capping patterns 1440 and 1450, the first and second gate insulation patterns 1155 and 1225, the third insulation pattern 1240, the channel 1105, the semiconductor pattern 1102, and the first etch stop pattern 1125, and then patterned to form a first contact plug 1270 contacting an upper surface of the channel 1105 and a landing pad structure 1300 contacting an upper surface of the first contact plug 1270. Thereafter, a fourth insulating interlayer 1260 covering sidewalls the first contact plug 1270 and the landing pad structure 1300 may be formed.

The first contact plug 1270 may contact not only the upper surface of the channel 1105 but also portions of upper surfaces of the first and second gate insulation patterns 1155 and 1225, the third capping pattern 1440, the fourth capping pattern 1450, and the third insulation pattern 1240 at opposite sides of the channels 1105 in the second direction D2_1.

The landing pad structure 1300 may include first and second conductive patterns 1280 and 1290 stacked in the third direction D3_1.

In example embodiments, a plurality of first contact plugs 1270 may be formed to be spaced apart from each other along the first and second directions D1_1 and D2_1 on the first region I_1 of the first substrate 1100, and a plurality of landing pad structures 1300 may be formed to be spaced apart from each other along the first and second directions D1_1 and D2_1 on the first region I_1 of the first substrate 1100. In some example embodiments, each of the first contact plugs 1270 and the landing pad structures 1300 may be arranged in a lattice shape. In some example embodiments, each of the first contact plugs 1270 and the landing pad structures 1300 may be arranged in a honeycomb shape.

A first bit line wiring structure BLICS1_1 including a first bit line contact 1822, a second bit line contact 1824, and a first bit line wiring 1826 may be formed.

Referring again to FIGS. 1 to 3, a capacitor 1360 and a plate electrode 1370 may be formed on the fourth insulating interlayer 1260 and the landing pad structure 1300.

The capacitor 1360 and the plate electrode 1370 may be formed through, for example, the following processes.

That is, a second etch stop layer 1310 may be formed on the landing pad structure 1300 and the fourth insulating interlayer 1260, and mold layers and support layers 1320 may be alternately and repeatedly stacked on the second etch stop layer 1310.

First openings may be formed on the first region I_1 of the first substrate 1100, each extending through the support layers 1320, the mold layers and the second etch stop layer 1310 to expose upper surfaces of the landing pad structures 1300. A first capacitor electrode layer filling the first openings may be formed on the upper surfaces of the landing pad structures 1300 exposed by the first openings and an upper surface of the uppermost support layer 1320. A planarization process may be performed on the first capacitor electrode layer until the upper surface of the uppermost support layer 1320 is exposed, whereby a first capacitor electrode 1330 may be formed in each of the first openings.

The planarization process may include, for example, a chemical mechanical polishing (CMP) process and/or an etch back process.

Portions of the support layers 1320 and the mold layers on the second region II_1 of the first substrate 1100 may be removed, the support layers 1320 and the mold layers remaining on the first region I_1 of the first substrate 1100 may be partially removed to form a second opening exposing an upper surface of the second etch stop layer 1310, and the mold layer may be removed through the second opening.

In example embodiments, the mold layer may be removed through a wet etching process, and as the wet etching process is performed, a third opening exposing sidewalls of the first capacitor electrode 1330 and an upper surface of the second etch stop layer 1310 may be formed. However, the support layers 1320 may remain on sidewalls of each of the first capacitor electrodes 1330, and accordingly, surfaces of each of the support layers 1320 may also be exposed by the third opening.

A dielectric layer 1340 may be formed on the sidewalls of each of the first capacitor electrodes 1330, the upper surface of the second etch stop layer 1310, and surfaces of each of the support layers 1320 exposed by the third opening, and a second capacitor electrode layer filling a remaining portion of the third opening may be formed on the dielectric layer 1340. The dielectric layer 1340 and the second capacitor electrode layer may also be stacked on an upper surface of the first capacitor electrode 1330 and the upper surface of the uppermost support layer 1320.

For example, a wet etching process may be performed on the second capacitor electrode layer to form a second capacitor electrode 1350 in the third opening. The first capacitor electrode 1330, the dielectric layer 1340, and the second capacitor electrode 1350 may together form a capacitor 1360.

A plate electrode 1370 may be formed on an upper surface and a sidewall of the capacitor 1360 and an upper surface of the first insulating interlayer 1260. The plate electrode 1370 may be formed on the first region I_1 of the first substrate 1100 and a portion of the second region II_1 of the first substrate 1100 adjacent thereto.

A fifth insulating interlayer 1380 covering the plate electrode 1370 may be formed on the fourth insulating interlayer 1260.

The manufacturing of the first semiconductor device may be completed by forming contact plugs, wirings, etc. connected to the plate electrode 1370 and the like.

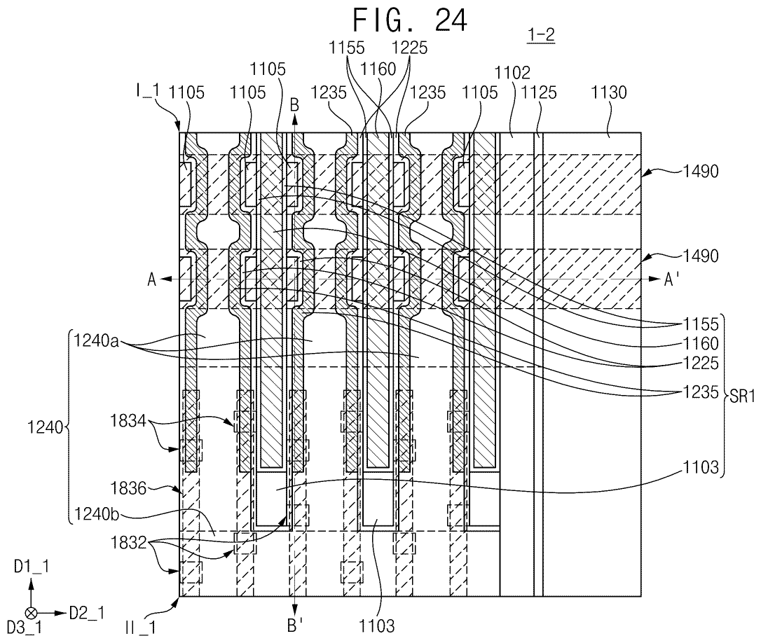

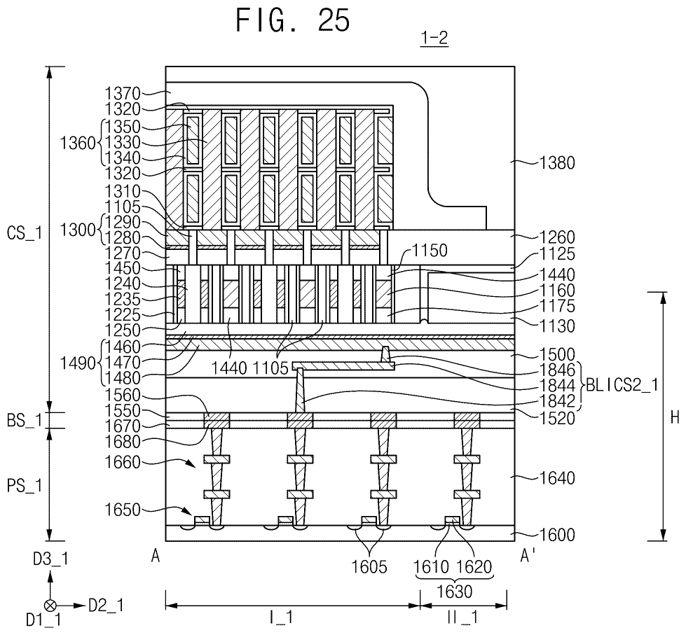

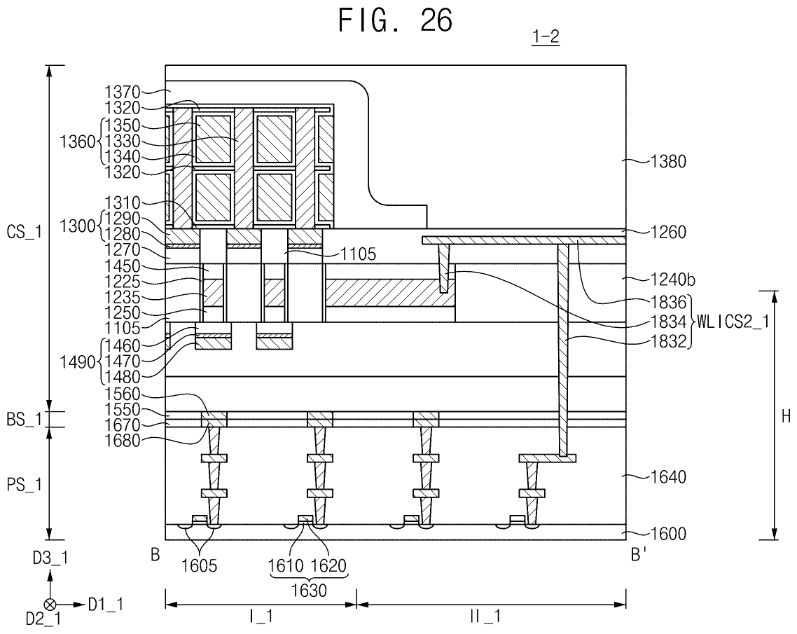

FIGS. 24 to 26 are cross-sectional views illustrating a first semiconductor device in accordance with a second example embodiment 1-2, which may correspond to FIGS. 1 to 3, respectively.

The second example embodiment 1-2 of the first semiconductor device may be substantially the same as or similar to that of FIGS. 1 to 3, except for further including a fourth insulation pattern 1103, the shape of the third insulation pattern 1240, and including a second word line wiring structure WLICS2_1 and a second bit line wiring structure BLICS2_1 instead of the first word line wiring structure WLICS1_1 and the first bit line wiring structure BLICS1_1, respectively, and thus repeated explanations are omitted herein.

Referring to FIGS. 24 to 26, the fourth insulation pattern 1103 may be disposed at an end of the first gate structure in the first direction D1_1 on the second region II_1. Accordingly, a plurality of fourth insulation patterns 1103 may be spaced apart from each other along the second direction D2_1.

In example embodiments, the fourth insulation pattern 1103 may include an oxide such as silicon oxide, an insulating nitride such as silicon nitride, etc.

In example embodiments, the first gate insulation pattern 1155 may be formed on a sidewall of the first gate electrode 1160 in the first direction D1_1. Accordingly, the first gate insulation pattern 1155 may be interposed between the first gate electrode 1160 and the fourth insulation pattern 1103.

In example embodiments, the second gate insulation pattern 1225 may be formed along another sidewall in the first direction D1_1 and opposite sidewalls in the second direction D2_1 of the fourth insulation pattern 1103 in the second region II_1.

Meanwhile, the first structure SR1 may further include the fourth insulation pattern 1103 disposed at the end of the first gate structure in the first direction D1_1.

The third insulation pattern 1240 may include a first portion 1240a and a second portion 1240b. The first portion 1240a may extend in the first direction D1_1 between the first structures SR1 adjacent to each other in the second direction D2_1, and accordingly, a plurality of first portions 1240a may be spaced apart from each other along the second direction D2_1. The second portion 1240b may extend in the second direction D2_1 along ends of the first structures SR1 in the first direction D1_1. The plurality of first portions 1240a and the second portion 1240b may be formed integrally.

In example embodiments, the first structure SR1 and the first portion 1240a of the third insulation pattern 1240 may be alternately and repeatedly arranged along the second direction D2_1.

In example embodiments, the third insulation pattern 1240 including the plurality of first portions 1240a and the second portion 1240b may have a shape of a Korean letter “ [symbol] ”.

In example embodiments, each of opposite sidewalls of the first portion 1240b of the third insulation pattern 1240 in the second direction D2_1 on the first region I_1 may not be in a straight line extending in the first direction D1_1 in a plan view, but may have a winding shape.

In example embodiments, the first portion 1240a of the third insulation pattern 1240 on the second region II_1 may include a third portion overlapping with the second gate electrode 1235 in the second direction D2_1 and a fourth portion excluding the third portion. The fourth portion of the third insulation pattern 1240 may overlap with the fourth insulation pattern 1103 in the second direction D2_1.

In example embodiments, each of opposite sidewalls of the third portion of the third insulation pattern 1240 in the second direction D2_1 may be in a straight line extending in the first direction D1_1 in a plan view. Accordingly, a first width of the third portion of the third insulation pattern 1240 in the second direction D2_1 may be constant along the first direction D1_1. In example embodiments, each of opposite sidewalls of the fourth portion of the third insulation pattern 1240 in the second direction D2_1 may in straight line extending in the first direction D1_1 in a plan view. Accordingly, a second width of the fourth portion of the third insulation pattern 1240 in the second direction D2_1 may be constant along the first direction D1_1.

In example embodiments, the first width of the third portion of the third insulation pattern 1240 may be smaller than the second width of the fourth portion of the third insulation pattern 1240.

The second word line wiring structure WLICS2_1 may include third and fourth word line contacts 1832 and 1834 and a second word line wiring 1836.

The third word line contact 1832 may extend through a lower portion of the fourth insulating interlayer 1260, the second portion 1240b of the third insulation pattern 1240, the first and second insulating interlayers 1500 and 1520, and an upper portion of the third insulating interlayer 1640 to contact a pad of the wiring structure 1660. The fourth word line contact 1834 may extend through an upper portion of the fourth insulating interlayer 1260 and the fourth capping pattern 1450 to contact an upper surface of the second gate electrode 1235. The second word line wiring 1836 may extend in the first direction D1_1 within the fourth insulating interlayer 1260 and commonly contact upper surfaces of the third and fourth word line contacts 1832 and 1834. Meanwhile, the pad of the wiring structure 2760 may serve as a landing pad for the third word line contact 1832.

In example embodiments, a width of each of the third and fourth word line contacts 1832 and 1834 in the horizontal direction may increase away from the second front surface of the second substrate 1600 in the third direction D3_1.

The second bit line wiring structure BLIC2S_1 may include a third bit line contact 1842, a second bit line wiring 1844, and a fourth bit line contact 1846.

The third bit line contact 1842 may extend through a lower portion of the first insulating interlayer 1500 and the second insulating interlayer 1520 to contact an upper surface of the bonding pad structure. The second bit line wiring 1844 may extend in the second direction D2_1 within the first insulating interlayer 1500 and contact an upper surface of the third bit line contact 1842. The fourth bit line contact 1846 may extend through an upper portion of the first insulating interlayer 1500 to contact a lower surface of the bit line structure 1490 and an upper surface of the second bit line wiring 1844.

In example embodiments, a width of each of the third and fourth bit line contacts 1842 and 1846 in the horizontal direction may decrease away from the second front surface of the second substrate 1600 in the third direction D3_1.

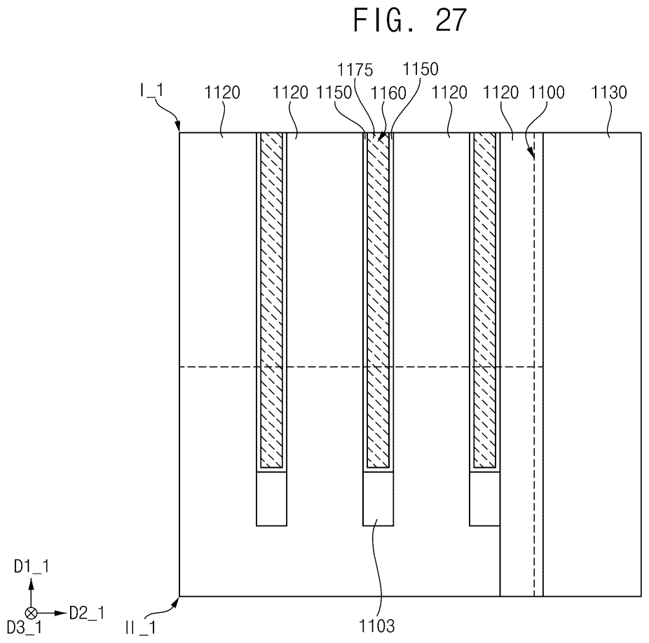

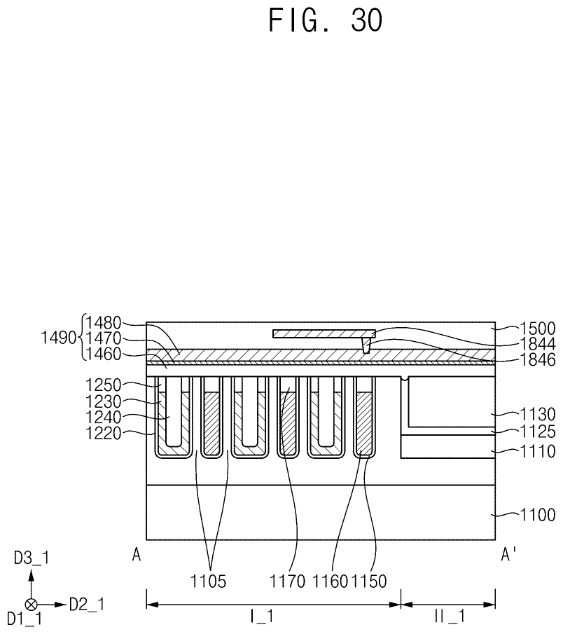

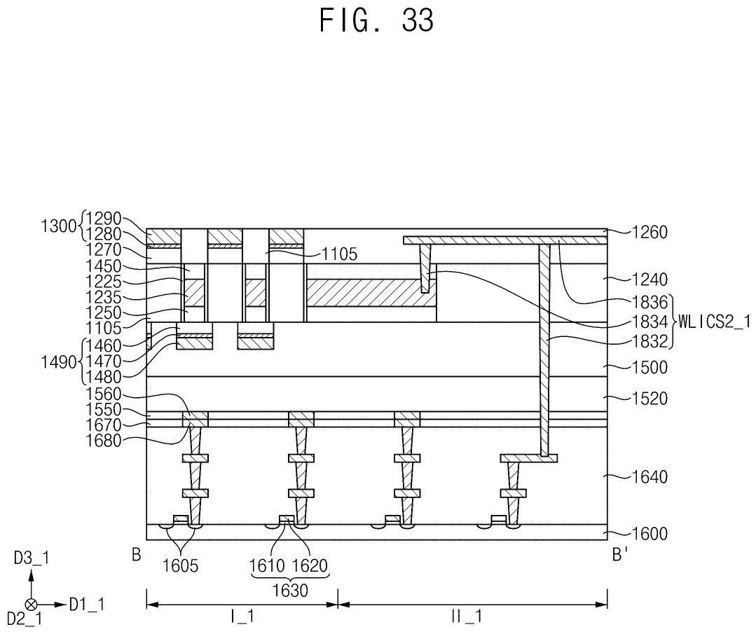

FIGS. 27 to 33 are plan views and cross-sectional views illustrating a method of manufacturing a first semiconductor device in accordance with the second example embodiment 1-2, where FIGS. 27 to 29 are plan views, FIGS. 30 to 32 are cross-sectional views taken along lines A-A′ of corresponding plan views, respectively, and FIG. 33 is a cross-sectional view taken along line B-B′ of the corresponding plan view.

This method of the second example embodiment 1-2 of the first semiconductor device may include processes substantially the same as or similar to those illustrated with respect to FIGS. 4 to 23 and FIGS. 1 to 3, and thus repeated explanations are omitted herein.

Referring to FIG. 27, processes substantially the same as or similar to the processes described with reference to FIGS. 4 and 5 may be performed. Thereafter, a fourth insulation pattern 1103 extending through the first etch stop layer 1120 and an upper portion of the first substrate 1100 may be formed in the second region II_1 adjacent to the first region I_1 in the first direction D1_1.

In example embodiments, a plurality of fourth insulation patterns 1103 may be formed to be spaced apart from each other along the second direction D2_1.

Processes substantially the same as or similar to the processes described with reference to FIG. 6 may be performed. The second trench 1140 may be formed to expose a sidewall of the fourth insulation pattern 1103 in the first direction D1_1.

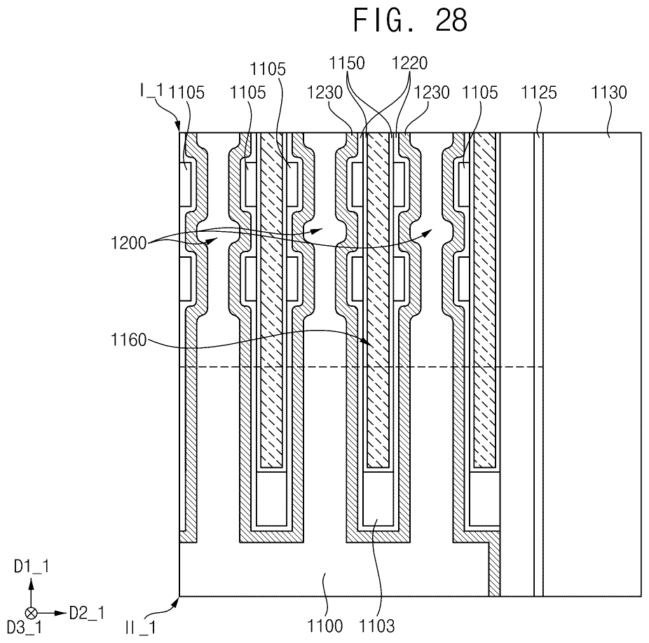

Referring to FIG. 28, processes substantially the same as or similar to the processes described with reference to FIGS. 7 to 10 may be performed. However, the third trench 1200 may be formed to include not only third portions each extending in the first direction D1_1 between the first gate electrodes 160 adjacent to each other in the second direction D2_1, but also a fourth portion extending in the second direction D2_1 from sides of the fourth insulation patterns 1103 to connect the third portions.

Thereafter, processes substantially the same as or similar to the processes described with reference to FIGS. 11 to 13 may be performed to sequentially form the second gate insulation layer 1220 and the second gate electrode layer 1230 on inner walls of the third trench 1200. The second gate insulation layer 1220 and the second gate electrode layer 1230 may be sequentially stacked in the horizontal direction at a sidewall in the first direction D1_1 and opposite sidewalls in the second direction D2_1 of each of the fourth insulation patterns 1103.

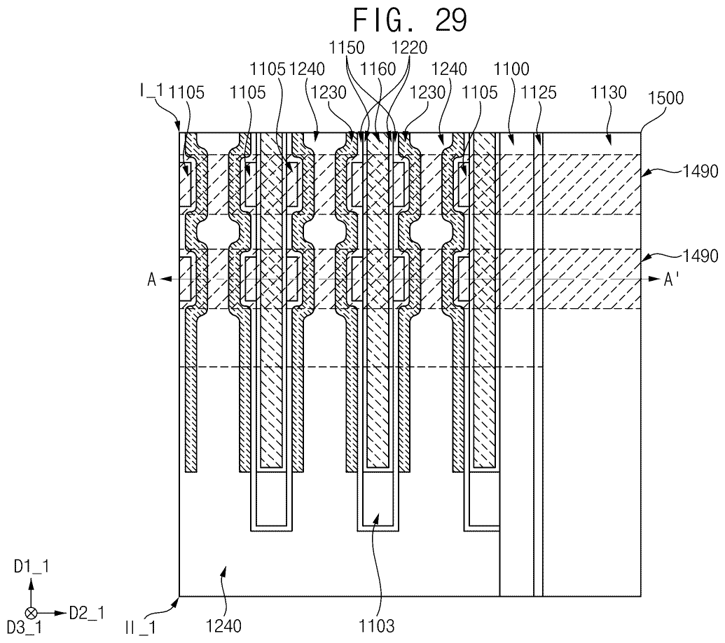

Referring to FIGS. 29 and 30, portions of the second gate electrode layer 1230 formed on the sidewall in the first direction D1_1 and the opposite sidewalls in the second direction D2_1 of each of the fourth insulation patterns 1103 may be removed. Processes substantially the same as or similar to the processes described with reference to FIGS. 11 to 13 may be performed to form the third insulation pattern 1240 and the second capping pattern 1250.

Processes substantially the same as or similar to the processes described with reference to FIGS. 14 to 16 may be performed to form the bit line structure 1490, the first insulating interlayer 1500, the fourth bit line contact 1846, and the second bit line wiring 1844.

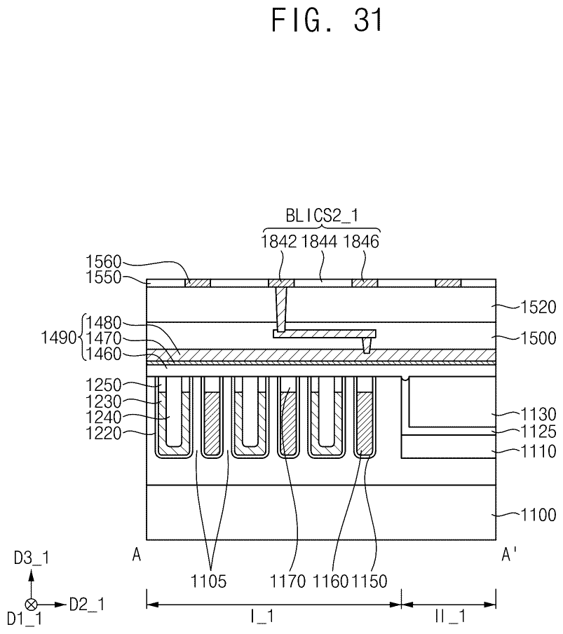

Referring to FIG. 31, processes substantially the same as or similar to the processes described with reference to FIGS. 17 and 18 may be performed to form the second insulating interlayer 1520, the third bit line contact 1842, the first bonding layer 1550, and the first bonding pad 1560.

The third bit line contact 1842, the second bit line wiring 1844, and the fourth bit line contact 1846 may together form the second bit line wiring structure BLICS1_1.

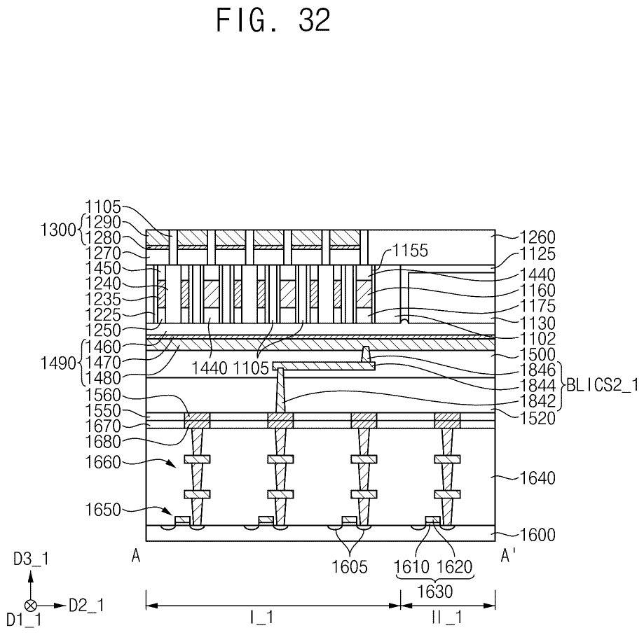

Referring to FIGS. 32 and 33, processes substantially the same as or similar to the processes described with reference to FIGS. 19 to 23 may be performed to flip the first substrate 1100 so as to bond the first and second bonding layers 1550 and 1670 to each other, and form the first contact plug 1270 and the landing pad structure 1300.

Referring again to FIGS. 24 to 26, processes substantially the same as or similar to the processes described with reference to FIGS. 1 to 3 may be performed to form the capacitor 1360 and the second word line wiring structure WLICS2_1, thereby completing the manufacturing of the first semiconductor device.

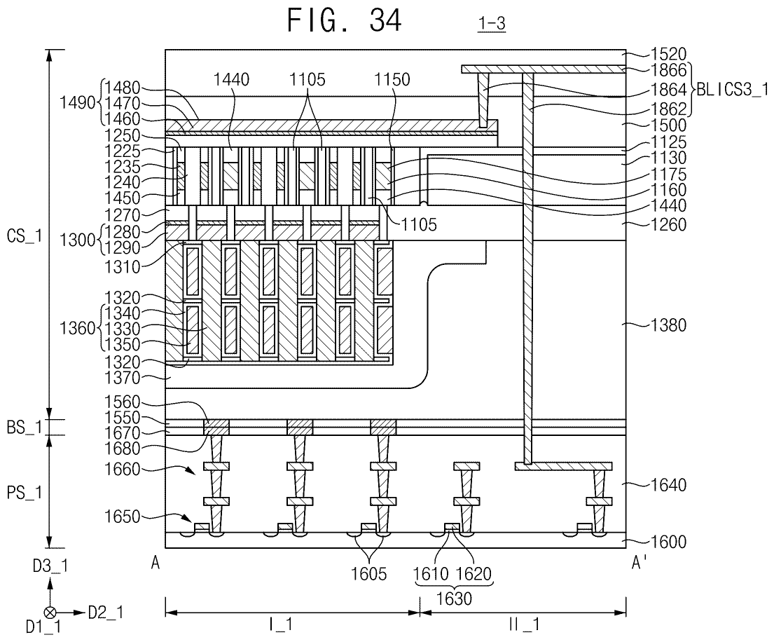

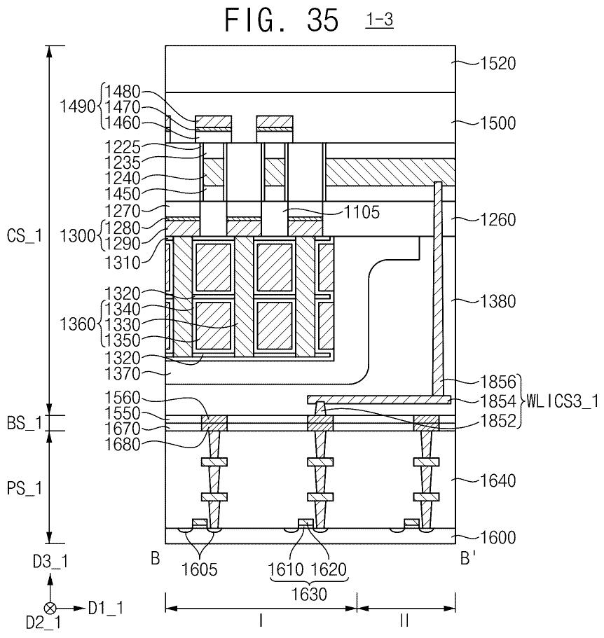

FIGS. 34 and 35 are cross-sectional views illustrating a first semiconductor device in accordance with a third example embodiment 1-3, which may correspond to FIGS. 2 and 3, respectively.

The third example embodiment 1-3 of the first semiconductor device may be substantially the same as or similar to that of FIGS. 1 to 3, except for the arrangement of the cell structure CS_1 and the peripheral circuit structure PS_1, and including a third word line wiring structure WLICS3_1 and a third bit line wiring structure BLICS3_1 instead of the first word line wiring structure WLICS1_1 and the first bit line wiring structure BLICS1_1, respectively, and thus repeated explanations are omitted herein.

Referring to FIGS. 34 and 35, the third example embodiment 1-3 of the first semiconductor device may have a structure in which the first front surface of the cell structure CS_1 and the second front surface of the second substrate 1600 face each other.

The third word line wiring structure WLICS3_1 may include a fifth word line contact 1852, a third word line wiring 1854, and a sixth word line contact 1856.

The fifth word line contact 1852 may extend through a lower portion of the fifth insulating interlayer 1380 to contact the bonding pad structure. The third word line wiring 1854 may extend in the first direction D1_1 within the fifth insulating interlayer 1380 and contact an upper surface of the fifth word line contact 1852. The sixth word line contact 1856 may extend through the fourth capping pattern 1450, the fourth insulating interlayer 1260, and an upper portion of the fifth insulating interlayer 1380 to contact a lower surface of the second gate electrode 1235 and an upper surface of the third word line wiring 1854.

In example embodiments, a width of each of the fifth and sixth word line contacts 1852 and 1856 in the horizontal direction may decrease away from the second front surface of the second substrate 1600 in the third direction D3_1.

The third bit line wiring structure BLICS3_1 may include fifth and sixth bit line contacts 1862 and 1864 and a third bit line wiring 1866.

The fifth bit line contact 1862 may extend through a lower portion of the second insulating interlayer 1520, the first insulating interlayer 1500, the first etch stop pattern 1125, the second insulation pattern 1130, the fourth and fifth insulating interlayers 1260, 1380, the bonding layer structure, and an upper portion of the third insulating interlayer 1640 to contact a pad of the wiring structure 1660. The sixth bit line contact 1864 may extend through a lower portion of the second insulating interlayer 1520 and an upper portion of the first insulating interlayer 1500 to contact an upper surface of the bit line structure 490. The third bit line wiring 1866 may extend in the second direction D2_1 within the second insulating interlayer 1520 and commonly contact upper surfaces of the fifth and sixth bit line contacts 1862 and 1864. Meanwhile, the pad of the wiring structure 2760 may serve as a landing pad for the fifth bit line contact 1862.

In example embodiments, a width of each of the fifth and sixth bit line contacts 1862 and 1864 in the horizontal direction may increase away from the second front surface of the second substrate 1600 in the third direction D3_1.

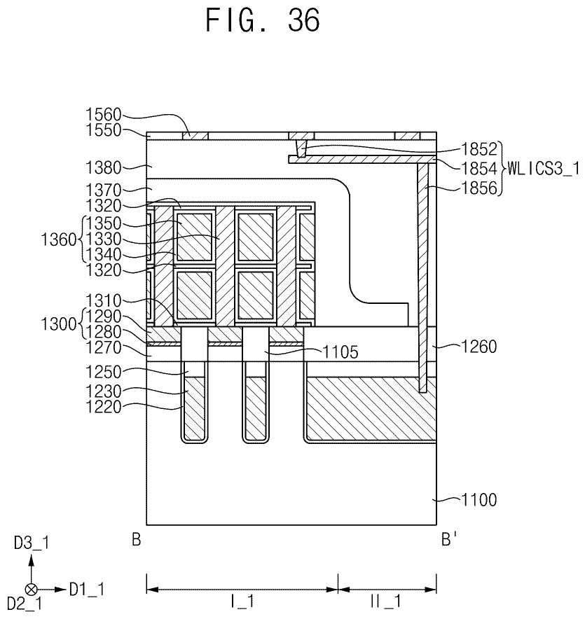

FIGS. 36 to 38 are cross-sectional views illustrating a method of manufacturing a first semiconductor device in accordance with the third example embodiment 1-3, where these are cross-sectional views taken along lines B-B′ of the corresponding plan views.

This method of the third example embodiment 1-3 of the first semiconductor device may include processes substantially the same as or similar to those illustrated with respect to FIGS. 4 to 23 and FIGS. 1 to 3, and thus repeated explanations are omitted herein.

Referring to FIG. 36, after performing processes substantially the same as or similar to the processes described with reference to FIGS. 4 to 13, and before forming the bit line structure 1490 by performing processes substantially the same as or similar to the processes described with reference to FIGS. 22 and 23 and FIGS. 1 to 3, the first contact plug 1270, the landing pad structure 1300, the capacitor 1360, and the third word line wiring structure WLICS3_1 may be formed. Thereafter, the first bonding layer 1550 and the first bonding pad 1560 may be formed on the fifth insulating interlayer 1380.

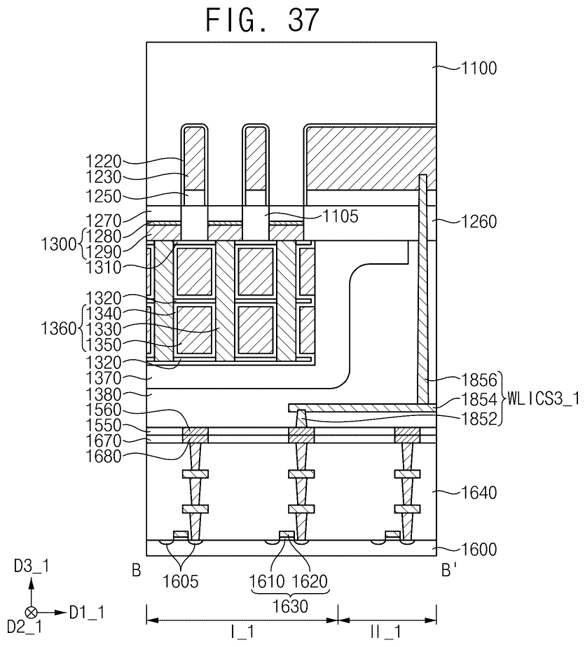

Referring to FIG. 37, the first substrate 1100 may be flipped to bond the first and second bonding layers 1550 and 1670 to each other. Accordingly, since the structure formed on the first substrate 1100 is flipped upside down, the following description will be based on this flipped orientation.

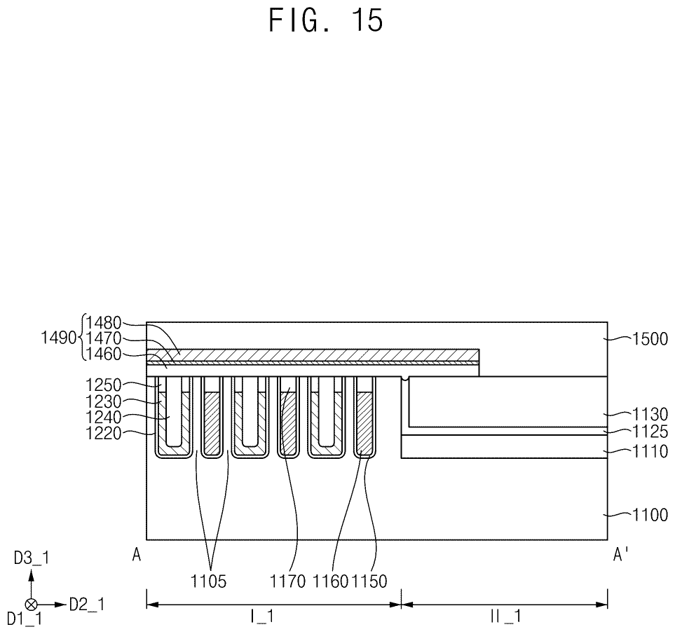

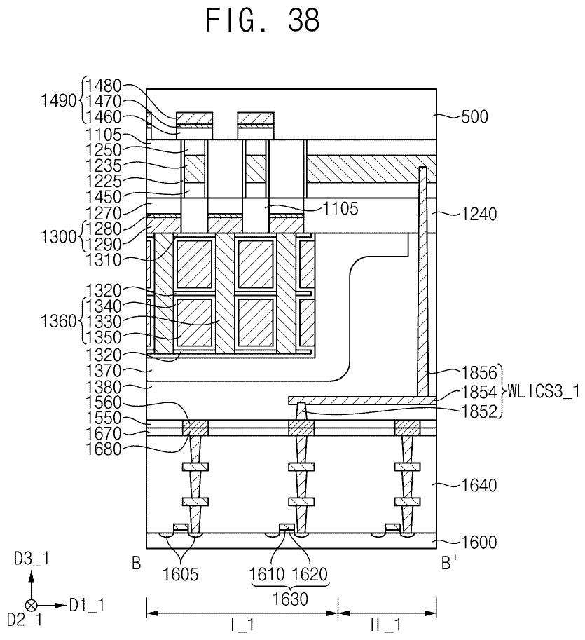

Referring to FIG. 38, processes substantially the same as or similar to the processes described with reference to FIGS. 14 and 15 may be performed to form the bit line structure 1490. Thereafter, referring again to FIGS. 34 and 35, the manufacturing of the first semiconductor device may be completed by forming the third bit line wiring structure BLICS3_1.

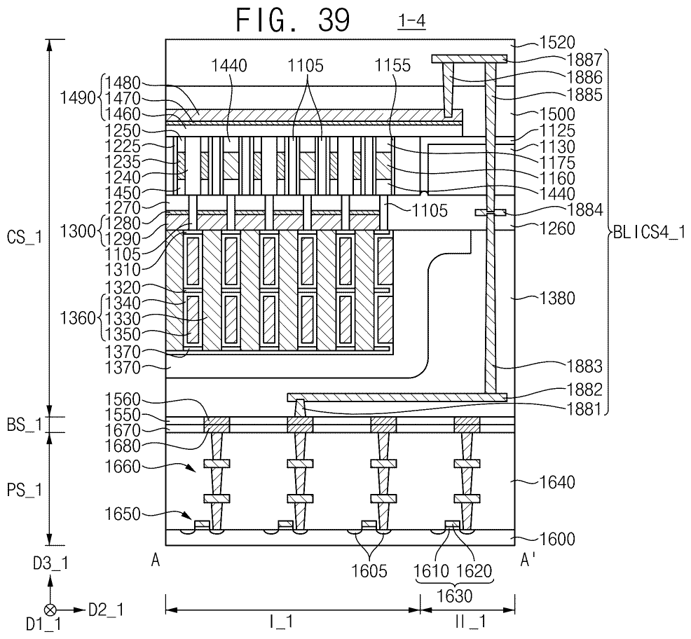

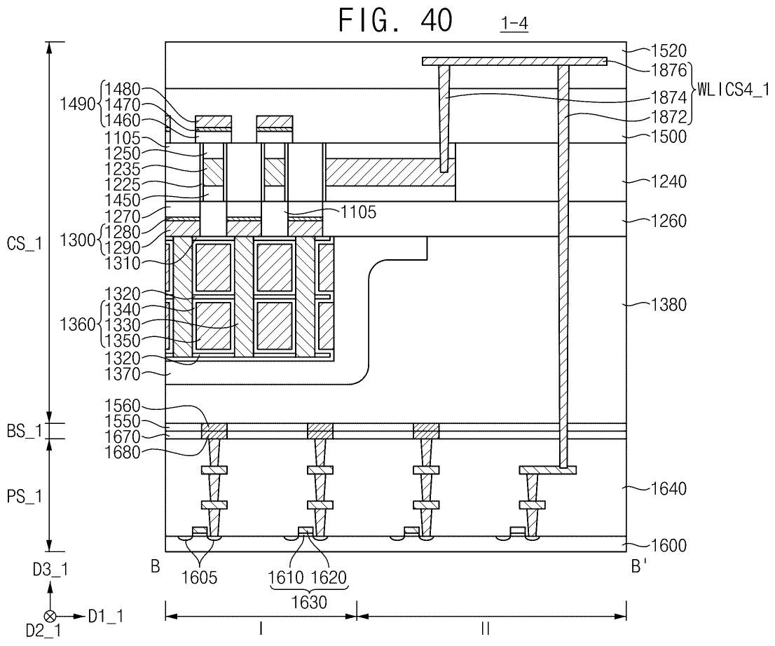

FIGS. 39 and 40 are cross-sectional views illustrating a first semiconductor device in accordance with a fourth example embodiment 1-4, which may correspond to FIGS. 34 and 35, respectively.

The fourth example embodiment 1-4 of first semiconductor devices may be substantially the same as or similar to that of FIGS. 34 to 35, except for including a fourth word line wiring structure WLICS4_1 and a fourth bit line wiring structure BLICS4_1 instead of the third word line wiring structure WLICS3_1 and the third bit line wiring structure BLICS3_1, respectively, and thus repeated explanations are omitted herein.

Referring to FIGS. 39 and 40, similar to FIGS. 34 and 35, the fourth example embodiment 1-4 of the first semiconductor device may have a structure in which the first front surface of the cell structure CS_1 and the second front surface of the second substrate 1600 face each other.

The fourth word line wiring structure WLICS4_1 may include seventh and eighth word line contacts 1872 and 1874 and a fourth word line wiring 1876.

The seventh word line contact 1872 may extend through a lower portion of the second insulating interlayer 1520, the first insulating interlayer 1500, the second portion 1240b of the third insulation pattern 1240, the fourth insulating interlayer 1260, the fifth insulating interlayer 1380, the bonding layer structure, and an upper portion of the third insulating interlayer 1640 to contact the pad of the wiring structure 1660. The eighth word line contact 1874 may extend through a lower portion of the second insulating interlayer 1520, the first insulating interlayer 1500, and the second capping pattern 1250 to contact an upper surface of the second gate electrode 1235. The fourth word line wiring 1876 may extend in the first direction D1_1 within the second insulating interlayer 1520 and commonly contact upper surfaces of the seventh and eighth word line contacts 1872 and 1874. Meanwhile, the pad of the wiring structure 2760 may serve as a landing pad for the seventh word line contact 1872.

In example embodiments, a width of each of the seventh and eighth word line contacts 1872 and 1874 in the horizontal direction may increase away from the second front surface of the second substrate 1600 in the third direction D3_1.

The fourth bit line wiring structure BLICS4_1 may include a seventh bit line contact 1881, a fourth bit line wiring 1882, an eighth bit line contact 1883, a fifth bit line wiring 1884, a ninth bit line contact 1885, a tenth bit line contact 1886, and a sixth bit line wiring 1887.

The seventh bit line contact 1881 may extend through a lower portion of the fifth insulating interlayer 1380 to contact an upper surface of the bonding pad structure. The fourth bit line wiring 1882 may extend in the second direction D2_1 within the fifth insulating interlayer 1380 and contact an upper surface of the seventh bit line contact 1881. The eighth bit line contact 1883 may extend through a lower portion of the fourth insulating interlayer 1260 and an upper portion of the fifth insulating interlayer 1380 to contact an upper surface of the fourth bit line wiring 1882. The fifth bit line wiring 1884 may extend in the second direction D2_1 within the fourth insulating interlayer 1260 and contact an upper surface of the eighth bit line contact 1883. The ninth bit line contact 1885 may extend through a lower portion of the second insulating interlayer 1520, the first insulating interlayer 1500, the first etch stop pattern 1125, the second insulation pattern 1130, and an upper portion of the fourth insulating interlayer 1260 to contact an upper surface of the fifth bit line wiring 1884. The tenth bit line contact 1886 may extend through a lower portion of the second insulating interlayer 1520 and an upper portion of the first insulating interlayer 1500 to contact an upper surface of the bit line structure 1490. The sixth bit line wiring 1887 may extend in the second direction D2_1 within the second insulating interlayer 1520 and commonly contact upper surfaces of the ninth and tenth bit line contacts 1885 and 1886.

In example embodiments, a width of each of the seventh and eighth bit line contacts 1881 and 1883 in the horizontal direction may decrease away from the second front surface of the second substrate 1600 in the third direction D3_1, and a width of each of the ninth and tenth bit line contacts 1885 and 1886 in the horizontal direction may increase away from the second front surface of the second substrate 1600 in the third direction D3_1.

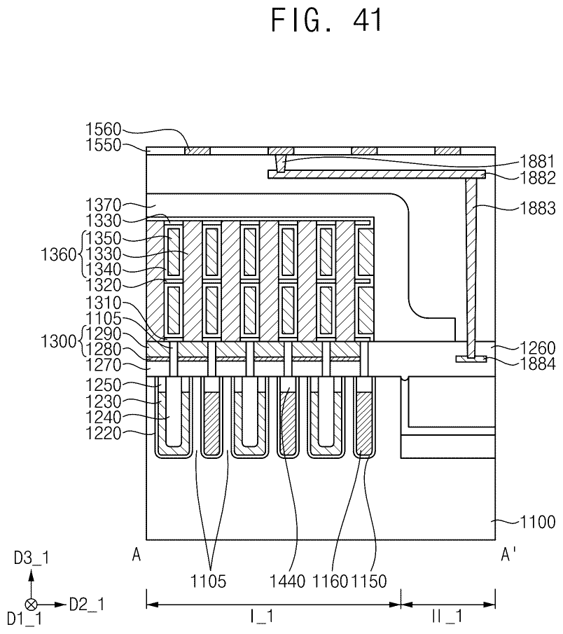

FIG. 41 is cross-sectional views illustrating a method of manufacturing a first semiconductor device in accordance with the fourth example embodiment 1-4, where FIG. 41 is a cross-sectional view taken along line B-B′ of the corresponding plan view.

This method of the fourth example embodiment 1-4 of the first semiconductor device may include processes substantially the same as or similar to those illustrated with respect to FIGS. 36 to 38 and FIGS. 34 and 35, and thus repeated explanations are omitted herein.

Referring to FIG. 41, processes substantially the same as or similar to FIG. 36 may be performed. However, unlike FIG. 36, the fifth bit line wiring 1884, the eighth bit line contact 1883, the fourth bit line wiring 1882, and the seventh bit line contact 1881 included in the fourth bit line wiring structure BLICS4_1 may be formed.

Referring again to FIGS. 39 and 40, processes substantially the same as or similar to the processes described with reference to FIGS. 37 and 38 and FIGS. 34 and 35 may be performed. However, the ninth bit line contact 1885, the tenth bit line contact 1886, and the sixth bit line wiring 1887 included in the fourth bit line wiring structure BLICS4_1, and the fourth word line wiring structure WLICS4_1 may be formed to complete the manufacturing of the first semiconductor device.

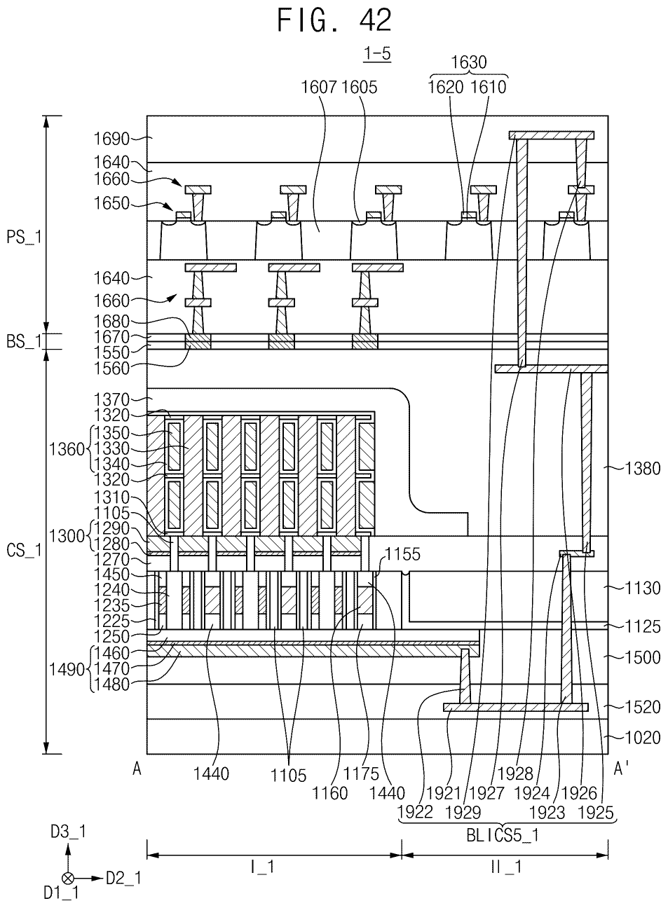

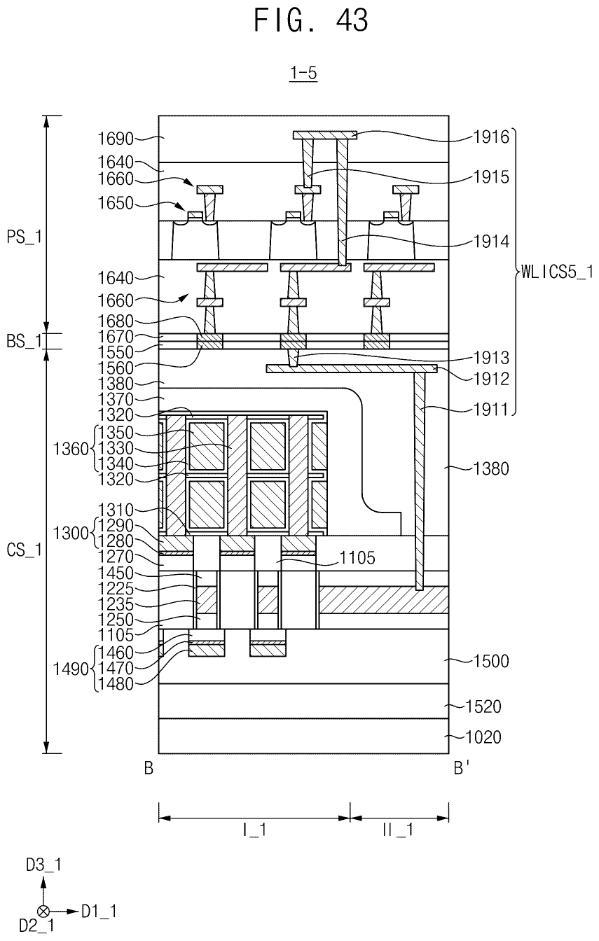

FIGS. 42 and 43 are cross-sectional views illustrating a first semiconductor device in accordance with a fifth example embodiment 1-5, which may correspond to FIGS. 2 to 3, respectively.

The fifth example embodiment 1-5 of first semiconductor devices may be substantially the same as or similar to that of FIGS. 1 to 3, except for the arrangement of the cell structure CS_1 and the peripheral circuit structure PS_1, the configuration of the peripheral circuit structure PS_1, and including a fifth word line wiring structure WLICS5_1 and a fifth bit line wiring structure BLICS5_1 instead of the first word line wiring structure WLICS1_1 and the first bit line wiring structure BLICS1_1, respectively, and thus repeated explanations are omitted herein.

Referring to FIGS. 42 and 43, the cell structure CS_1, the bonding structure PS_1, and the peripheral circuit structure PS_1 may be sequentially stacked on the second handling substrate 1020. Accordingly, the first semiconductor device may have a Periphery Over Cell (POC) structure in which the peripheral circuit structure PS_1 is disposed on the cell structure CS_1 including memory cells.

The second handling substrate 1020 may include, for example, a semiconductor material such as silicon, or an insulating material such as glass.

In example embodiments, the fifth example embodiment 1-5 of the first semiconductor device may have a structure in which the first front surface of the cell structure CS_1 and the second rear surface of the peripheral circuit structure PS_1 face each other.

The peripheral circuit structure PS_1 may further include an isolation pattern 1607 and a sixth insulating interlayer 1690.

The isolation pattern 1607 may extend through the second substrate 1600. The isolation pattern 1607 may include, for example, an oxide such as silicon oxide. The sixth insulating interlayer 1690 may be disposed on the third insulating interlayer 1640. The sixth insulating interlayer 1690 may include, for example, an oxide such as silicon oxide.

Meanwhile, the third insulating interlayer 1640 and the wiring structure 1660 accommodated therein may be disposed not only on the second front surface of the second substrate 1600 on which the peripheral circuit pattern 1650 is formed, but also on the second rear surface of the second substrate 1600.

Hereinafter, for convenience of explanation, a portion of the third insulating interlayer 1640 disposed on the second front surface of the second substrate 1600 will be referred to as an upper portion of the third insulating interlayer 1640, a portion of the third insulating interlayer 1640 disposed on the second rear surface of the second substrate 1600 will be referred to as a lower portion of the third insulating interlayer 1640, a portion of the wiring structure 1660 disposed on the second front surface of the second substrate 1600 will be referred to as an upper portion of the wiring structure 1660, and a portion of the wiring structure 1660 disposed on the second rear surface of the second substrate 1600 will be referred to as a lower portion of the wiring structure 1660.

The fifth word line wiring structure WLICS5_1 may include a ninth word line contact 1911, a fifth word line wiring 1912, tenth to twelfth word line contacts 1913, 1914 and 1915, and a sixth word line wiring 1916.

The ninth word line contact 1911 may extend through a lower portion of the fifth insulating interlayer 1380, the fourth insulating interlayer 1260, and the fourth capping pattern 1450 to contact an upper surface of the second gate electrode 1235. The fifth word line wiring 1912 may extend in the first direction D1_1 within the fifth insulating interlayer 1380 and contact an upper surface of the ninth word line contact 1911. The tenth word line contact 1913 may extend through an upper portion of the fifth insulating interlayer 1380 to contact a lower surface of the corresponding insulation pattern structure and an upper surface of the fifth word line wiring 1912. The eleventh word line contact 1914 may extend through a lower portion of the sixth insulating interlayer 1690, the upper portion of the third insulating interlayer 1640, the isolation pattern 1607, and the lower portion of the third insulating interlayer 1640 to be electrically connected to the lower portion of the wiring structure 1660. The twelfth word line contact 1915 may extend through a lower portion of the sixth insulating interlayer 1690 and the upper portion of the third insulating interlayer 1640 to be electrically connected to the upper portion of the wiring structure 1660. The sixth word line wiring 1916 may extend in the first direction D1_1 within the sixth insulating interlayer 1690 and commonly contact upper surfaces of the eleventh and twelfth word line contacts 1914 and 1915.

In example embodiments, a width of each of the ninth to twelfth word line contacts 1911, 1913, 1914 and 1915 in the horizontal direction may increase away from an upper surface of the second handling substrate 1020.

The fifth bit line wiring structure BLICS5_1 may include a seventh bit line wiring 1921, an eleventh bit line contact 1922, a twelfth bit line contact 1923, an eighth bit line wiring 1924, a thirteenth bit line contact 1925, a ninth bit line wiring 1926, a fourteenth bit line contact 1927, a fifteenth bit line contact 1928, and a tenth bit line wiring 1929.

The seventh bit line wiring 1921 may extend in the second direction D2_1 within the second insulating interlayer 1520. The eleventh bit line contact 1922 may extend through a lower portion of the first insulating interlayer 1500 and an upper portion of the second insulating interlayer 1520 to contact a lower surface of the bit line structure 1490 and an upper surface of the seventh bit line wiring 1921. The twelfth bit line contact 1923 may extend through a lower portion of the fourth insulating interlayer 1260, the second insulation pattern 1130, the first etch stop pattern 1125, the first insulating interlayer 1500, and an upper portion of the second insulating interlayer 1520 to contact an upper surface of the seventh bit line wiring 1921. The eighth bit line wiring 1924 may extend in the second direction D2_1 within the fourth insulating interlayer 1260 and contact an upper surface of the twelfth bit line contact 1923. The thirteenth bit line contact 1925 may extend through a lower portion of the fifth insulating interlayer 1380 and an upper portion of the fourth insulating interlayer 1260 to contact an upper surface of the eighth bit line wiring 1924. The ninth bit line wiring 1926 may extend in the first direction D1_1 within the fifth insulating interlayer 1380 and contact an upper surface of the thirteenth bit line contact 1925. The fourteenth bit line contact 1927 may extend through a lower portion of the sixth insulating interlayer 1690, the upper portion of the third insulating interlayer 1640, the isolation pattern 1607, the lower portion of the third insulating interlayer 1640, and an upper portion of the fifth insulating interlayer 1380 to contact an upper surface of the ninth bit line wiring 1926. The fifteenth bit line contact 1928 may extend through a lower portion of the sixth insulating interlayer 1690 and the upper portion of the third insulating interlayer 1640 to be electrically connected to the upper portion of the wiring structure 1660. The tenth bit line wiring 1929 may extend in the first direction D1_1 within the sixth insulating interlayer 1690 and commonly contact upper surfaces of the fourteenth and fifteenth bit line contacts 1927 and 1928. Meanwhile, the ninth bit line wiring 1926 may serve as a landing pad for the fourteenth bit line contact 1927.

In example embodiments, a width of each of the eleventh and twelfth bit line contacts 1922 and 1923 in the horizontal direction may decrease away from an upper surface of the second handling substrate 1020, and a width of each of the thirteenth to fifteenth bit line contacts 1925, 1927 and 1928 in the horizontal direction may increase away from an upper surface of the second handling substrate 1020.

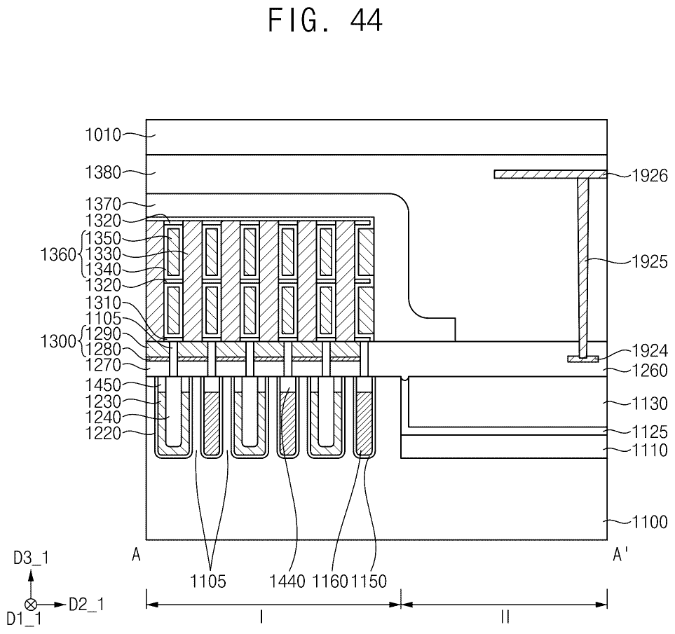

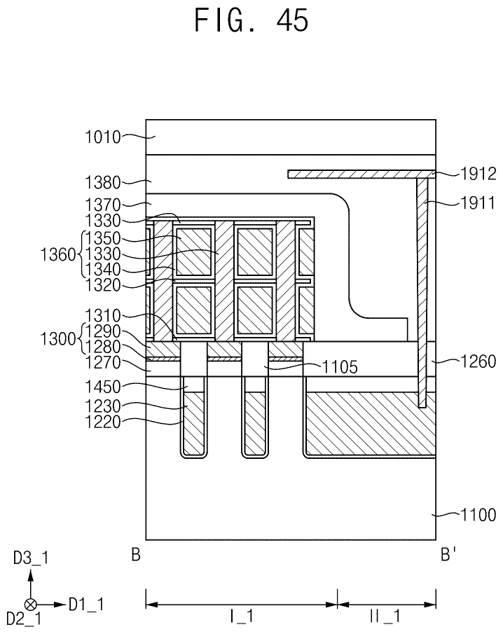

FIGS. 44 to 51 are cross-sectional views illustrating a method of manufacturing a first semiconductor device in accordance with the fifth example embodiment 1-5, where FIGS. 44, 46, 48, and 50-51 are cross-sectional views taken along lines A-A′ of corresponding plan views, respectively, and FIGS. 45, 47, and 49 are cross-sectional views taken along line B-B′ of the corresponding plan views, respectively.

This method of the fifth example embodiment 1-5 of the first semiconductor device may include processes substantially the same as or similar to those illustrated with respect to FIGS. 4 to 23 and FIGS. 1 to 3, and thus repeated explanations are omitted herein.

Referring to FIGS. 44 and 45, after performing processes substantially the same as or similar to the processes described with reference to FIGS. 4 to 13, and before forming the bit line structure 1490 by performing processes substantially the same as or similar to the processes described with reference to FIGS. 22 and 23 and FIGS. 1 to 3, the first contact plug 1270, the landing pad structure 1300, the capacitor 1360, the ninth word line contact 1911 and the fifth word line wiring 1912 of the fifth word line wiring structure WLICS5_1, and the eighth bit line wiring 1924, the thirteenth bit line contact 1925, and the ninth bit line wiring 1926 of the fifth bit line wiring structure BLICS5_1 may be formed.

The first handling substrate 1010 may be bonded on the fifth insulating interlayer 1380 via a third bonding layer (not shown). The first handling substrate 1010 may include, for example, a semiconductor material such as silicon, or an insulating material such as glass. The third bonding layer may include, for example, silicon carbonitride, silicon oxide, and the like.

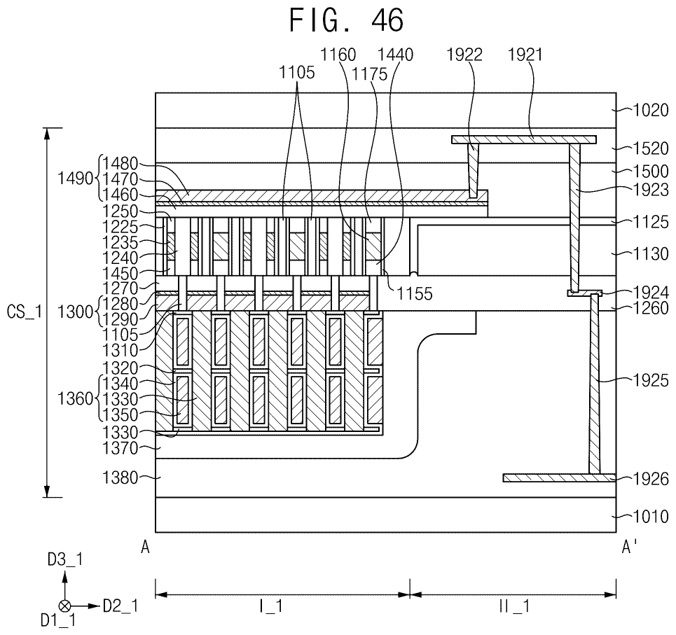

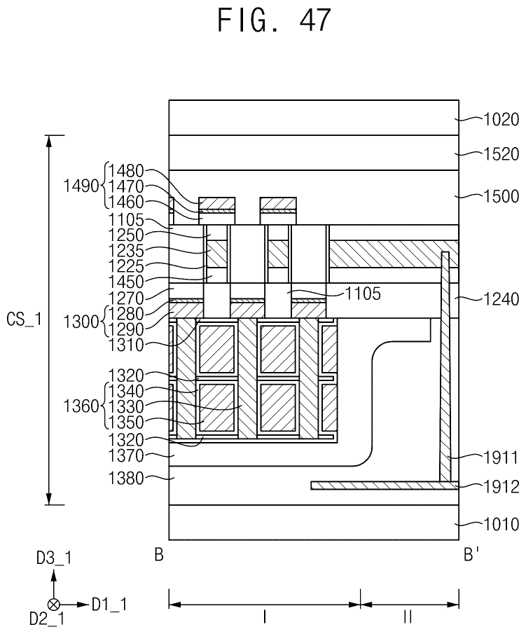

Referring to FIGS. 46 and 47, the first handling substrate 1010 may be flipped. Thereafter, processes substantially the same as or similar to the processes described with reference to FIGS. 14 to 18 may be performed to form the bit line structure 1490, the first and second insulating interlayers 1500 and 1520, and the seventh bit line wiring 1921, the eleventh bit line contact 1922, and the twelfth bit line contact 1923 of the fifth bit line wiring structure BLICS5_1.

The second handling substrate 1020 may be bonded on the second insulating interlayer 1520 via a fourth bonding layer (not shown). The second handling substrate 1020 may include, for example, a semiconductor material such as silicon, or an insulating material such as glass. The fourth bonding layer may include, for example, silicon carbonitride, silicon oxide, and the like.

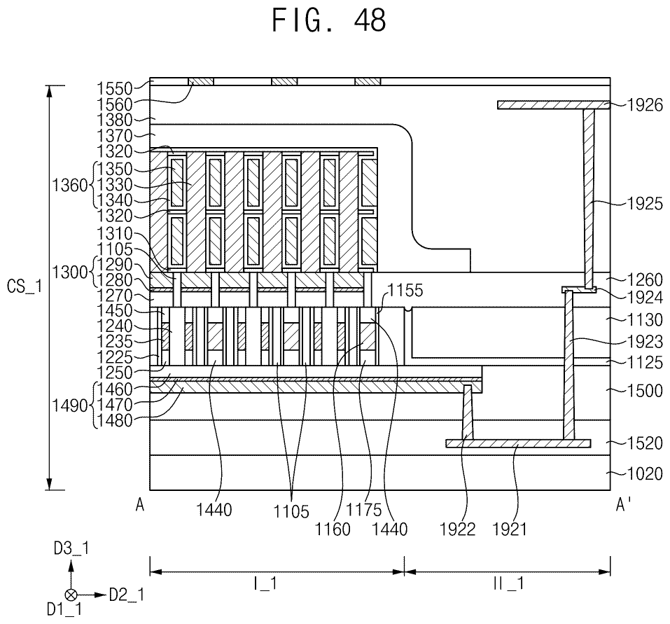

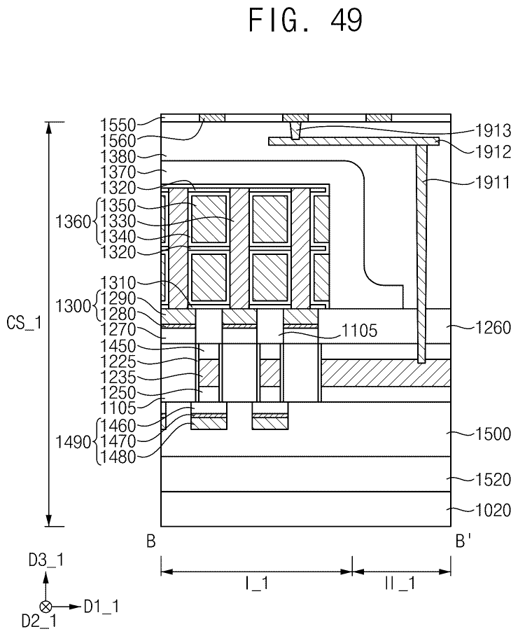

Referring to FIGS. 48 and 49, the second handling substrate 1020 may be flipped. Thereafter, the first handling substrate 1010 and the third bonding layer may be removed from the fifth insulating interlayer 1380 through, for example, a grinding process and/or a chemical mechanical polishing (CMP) process.

Thereafter, the tenth word line contact 1913 of the fifth word line wiring structure WLICS5_1 may be formed, and the first bonding layer 1550 and the first bonding pad 1560 accommodated therein may be formed on the fifth insulating interlayer 1380.

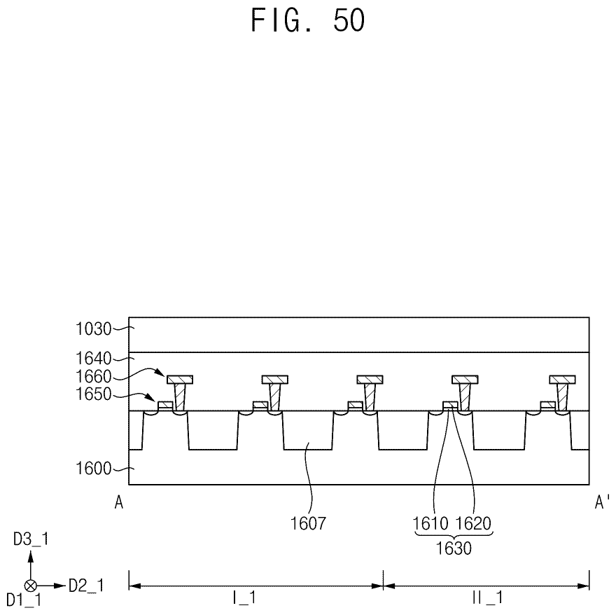

Referring to FIG. 50, processes substantially the same as or similar to the processes described with reference to FIG. 19 may be performed. However, the isolation pattern 1607 may be further formed on an upper portion of the second substrate 1600.

Thereafter, the third handling substrate 1030 may be bonded on the third insulating interlayer 1640 via a fifth bonding layer (not shown). The third handling substrate 1030 may include, for example, a semiconductor material such as silicon, or an insulating material such as glass. The fifth bonding layer may include, for example, silicon carbonitride, silicon oxide, and the like.

Referring to FIG. 51, the third handling substrate 1030 may be flipped. Accordingly, since the structure formed on the second substrate 1600 is flipped upside down, the following description will be based on this flipped orientation.

An upper portion of the second substrate 1600 may be removed through, for example, a grinding process, and accordingly, an upper surface of the isolation pattern 1607 may be exposed. During the grinding process, the isolation pattern 1607 may serve as a grinding end point.

The third insulating interlayer 1640 and the wiring structure 1660 accommodated therein may be additionally formed on the second rear surface of the second substrate 1600 and the isolation pattern 1607, and the second bonding layer 1670 and the second bonding pad 1680 accommodated therein may be formed on the third insulating interlayer 1640.

Referring again to FIGS. 42 and 43, the third handling substrate 1030 may be flipped to bond the first and second bonding layers 1550 and 1670 to each other.

An upper portion of the third handling substrate 1030 may be removed through, for example, a grinding process, and accordingly, an upper surface of the third insulating interlayer 1640 may be exposed. Thereafter, the eleventh word line contact 1914, the twelfth word line contact 1915, and the sixth word line wiring 1916 of the fifth word line wiring structure WLICS5_1, the fourteenth bit line contact 1927, the fifteenth bit line contact 1928, and the tenth bit line wiring 1929 of the fifth bit line wiring structure BLICS5_1, and the sixth insulating interlayer 1690 covering them may be formed on the third insulating interlayer 1640 to complete the manufacturing of the first semiconductor device.

The second handling substrate 1020 and the fourth bonding layer may also be removed through, for example, a grinding process and/or a chemical mechanical polishing (CMP) process.

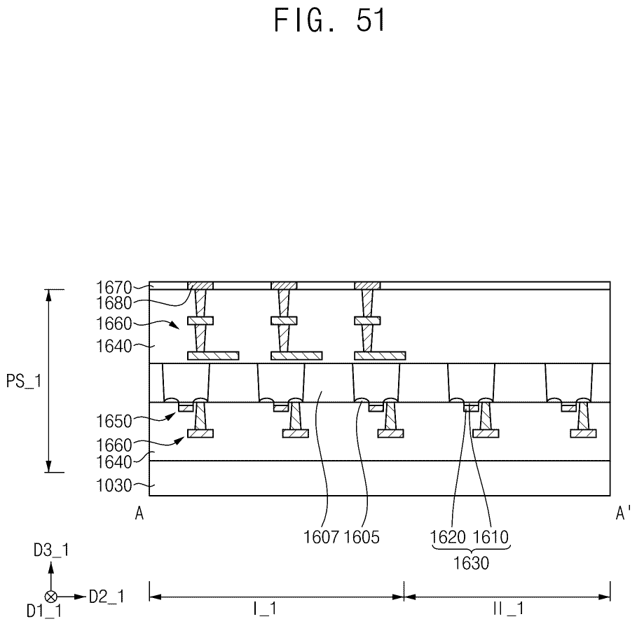

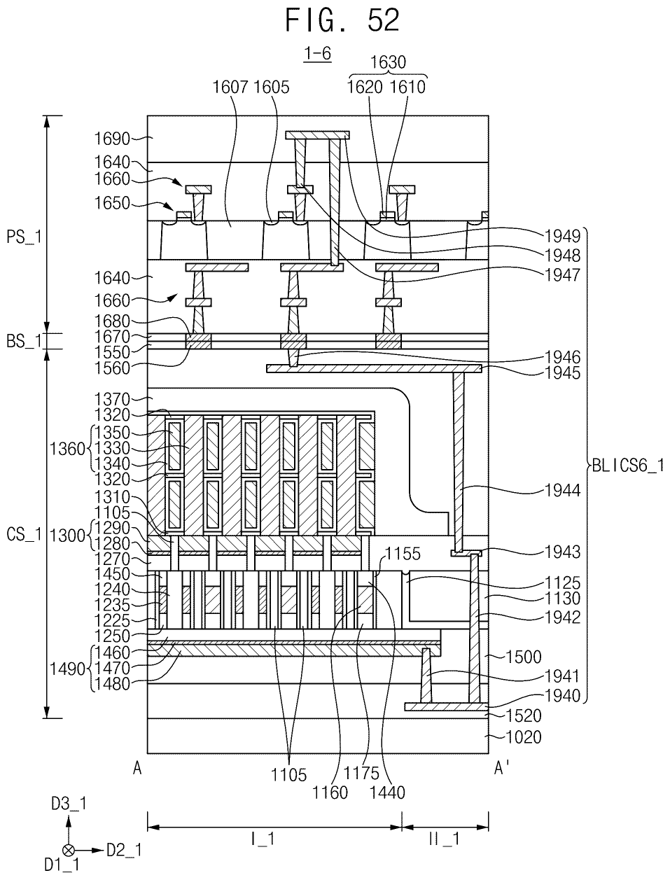

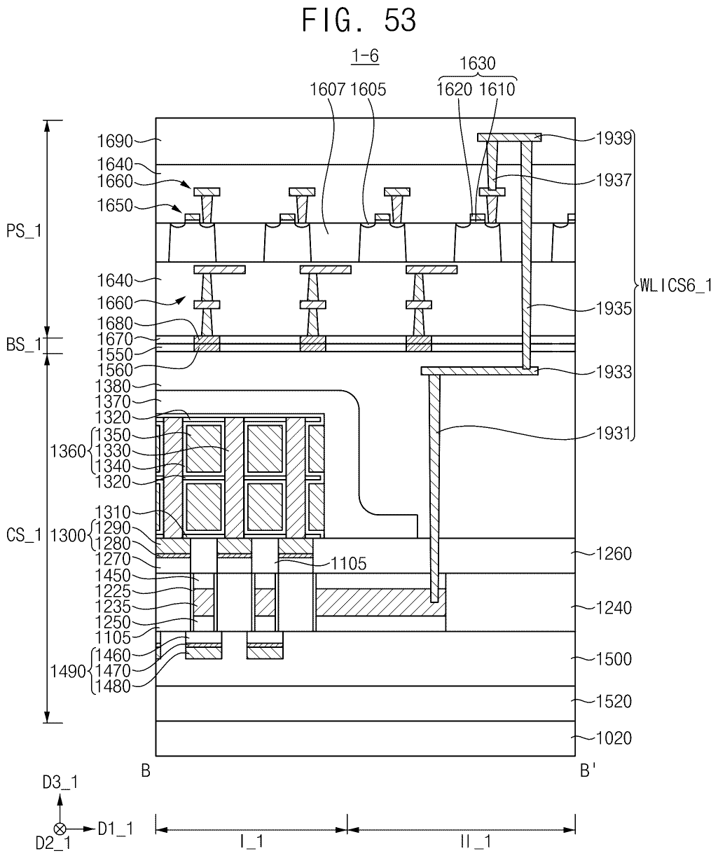

FIGS. 52 and 53 are cross-sectional views illustrating a first semiconductor device in accordance with a sixth example embodiment 1-6, which may correspond to FIGS. 42 and 43, respectively.

The sixth example embodiment 1-6 of first semiconductor devices may be substantially the same as or similar to that of FIGS. 42 and 43, except for including a sixth word line wiring structure WLICS6_1 and a sixth bit line wiring structure BLICS6_1 instead of the fifth word line wiring structure WLICS5_1 and the fifth bit line wiring structure BLICS5_1, respectively, and thus repeated explanations are omitted herein.

Referring to FIGS. 52 and 53, the sixth word line wiring structure WLICS6_1 may include a thirteenth word line contact 1931, a seventh word line wiring 1933, a fourteenth word line contact 1935, a fifteenth word line contact 1937, and an eighth word line wiring 1939.

The thirteenth word line contact 1931 may extend through a lower portion of the fifth insulating interlayer 1380, the fourth insulating interlayer 1260, and the fourth capping pattern 1450 to contact the second gate electrode 1235. The seventh word line wiring 1933 may extend in the first direction D1_1 within the fifth insulating interlayer 1380 and contact an upper surface of the thirteenth word line contact 1931. The fourteenth word line contact 1935 may extend through a lower portion of the sixth insulating interlayer 1690, the upper portion of the third insulating interlayer 1640, the isolation pattern 1607, the lower portion of the third insulating interlayer 1640, the bonding layer structure, and an upper portion of the fifth insulating interlayer 1380 to contact an upper surface of the seventh word line wiring 1933. The fifteenth word line contact 1937 may extend through a lower portion of the sixth insulating interlayer 1690 and the upper portion of the third insulating interlayer 1640 to be electrically connected to the corresponding wiring structure 1660. The eighth word line wiring 1939 may extend in the first direction D1_1 within the sixth insulating interlayer 1690 and commonly contact upper surfaces of the fourteenth and fifteenth word line contacts 1935 and 1937. Meanwhile, the seventh word line wiring 1933 may serve as a landing pad for the fourteenth word line contact 1935.

In example embodiments, a width of each of the thirteenth to fifteenth word line contacts 1931, 1935 and 1937 in the horizontal direction may increase away from an upper surface of the second handling substrate 1020.

The sixth bit line wiring structure BLICS6_1 may include an eleventh bit line wiring 1940, a sixteenth bit line contact 1941, a seventeenth bit line contact 1942, a twelfth bit line wiring 1943, an eighteenth bit line contact 1944, a thirteenth bit line wiring 1945, a nineteenth bit line contact 1946, a twentieth bit line contact 1947, a twenty-first bit line contact 1948, and a fourteenth bit line wiring 1949.

The eleventh bit line wiring 1940 may extend in the second direction D2_1 within the second insulating interlayer 1520. The sixteenth bit line contact 1941 may extend through a lower portion of the first insulating interlayer 1500 and an upper portion of the second insulating interlayer 1500 to contact a lower surface of the bit line structure 1490 and an upper surface of the eleventh bit line wiring 1940. The seventeenth bit line contact 1942 may extend through a lower portion of the fourth insulating interlayer 1260, the second insulation pattern 1130, the first etch stop pattern 1125, the first insulating interlayer 1500, and an upper portion of the second insulating interlayer 1520 to contact an upper surface of the eleventh bit line wiring 1940. The twelfth bit line wiring 1943 may extend in the second direction D2_1 within the fourth insulating interlayer 1260 and contact an upper surface of the seventeenth bit line contact 1942. The eighteenth bit line contact 1944 may extend through a lower portion of the fifth insulating interlayer 1380 and an upper portion of the fourth insulating interlayer 1260 to contact an upper surface of the twelfth bit line wiring 1943. The thirteenth bit line wiring 1945 may extend in the second direction D2_1 within the fifth insulating interlayer 1380 and contact an upper surface of the eighteenth bit line contact 1944. The nineteenth bit line contact 1946 may extend through an upper portion of the fifth insulating interlayer 1380 to contact a lower surface of the bonding pad structure and an upper surface of the thirteenth bit line wiring 1945. The twentieth bit line contact 1947 may extend through a lower portion of the sixth insulating interlayer 1690, the upper portion of the fifth insulating interlayer 1640, the isolation pattern 1607, and the lower portion of the fifth insulating interlayer 1640 to be electrically connected to the lower portion of the wiring structure 1660. The twenty-first bit line contact 1948 may extend through a lower portion of the sixth insulating interlayer 1690 and the upper portion of the fifth insulating interlayer 1640 to be electrically connected to the upper portion of the wiring structure 1660. The fourteenth bit line wiring 1949 may extend in the second direction D2_1 within the sixth insulating interlayer 1690 and commonly contact upper surfaces of the twentieth and twenty-first bit line contacts 1947 and 1948.

In example embodiments, a width of each of the sixteenth and seventeenth bit line contacts 1941 and 1942 in the horizontal direction may decrease away from an upper surface of the second handling substrate 1020, and a width of each of the eighteenth to twenty-first bit line contacts 1944, 1946, 1947 and 1948 in the horizontal direction may increase away from an upper surface of the second handling substrate 1020.

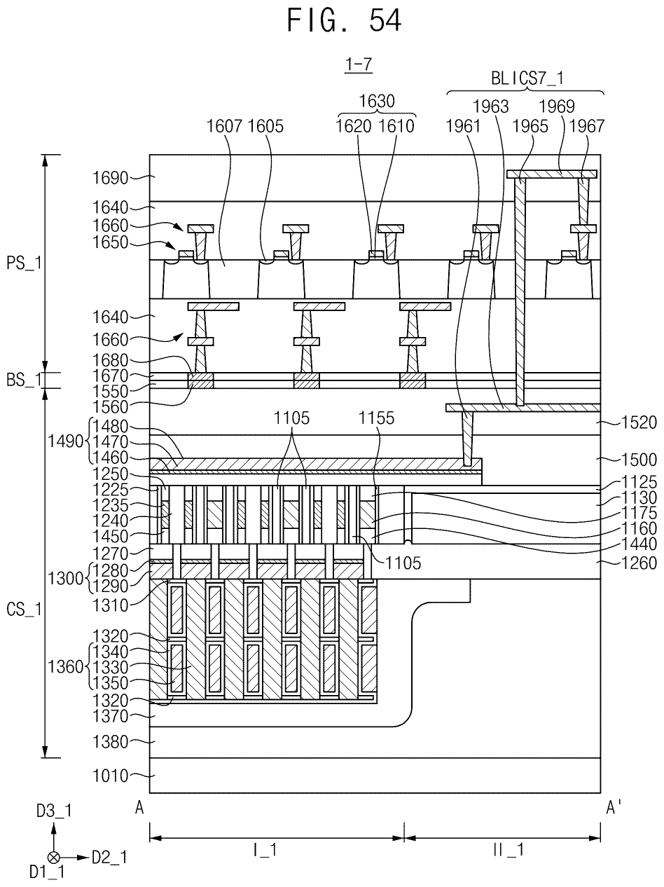

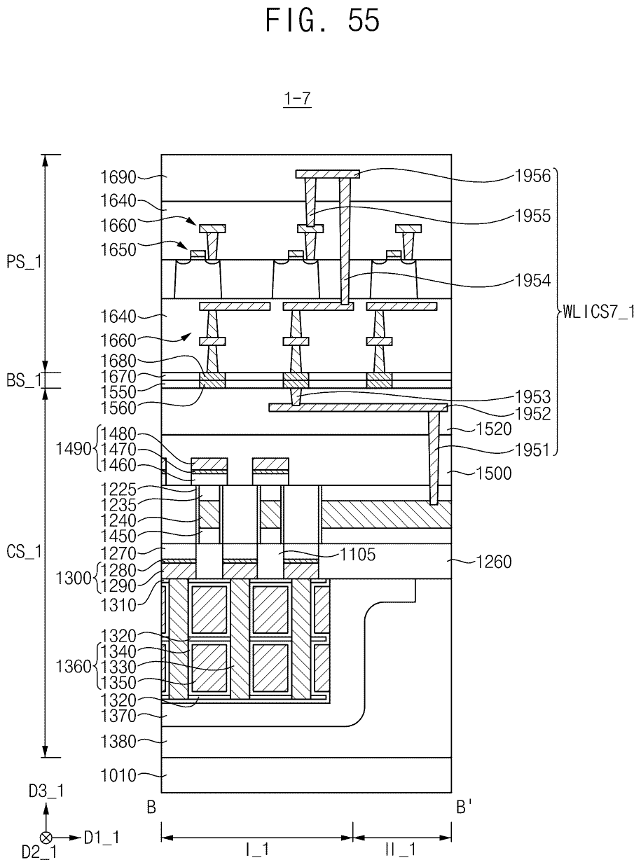

FIGS. 54 and 55 are cross-sectional views illustrating a first semiconductor device in accordance with a seventh example embodiment 1-7, which may correspond to FIGS. 42 and 43, respectively.

The seventh example embodiment 1-7 of first semiconductor devices may be substantially the same as or similar to that of FIGS. 42 and 43, except for the arrangement of the cell structure CS_1 and the peripheral circuit structure PS_1, and including a seventh word line wiring structure WLICS7_1 and a seventh bit line wiring structure BLICS7_1 instead of the fifth word line wiring structure WLICS5_1 and the fifth bit line wiring structure BLICS5_1, respectively, and thus repeated explanations are omitted herein.

Referring to FIGS. 54 and 55, the seventh example embodiment 1-7 of the first semiconductor device may have a structure in which the first rear surface of the cell structure CS_1 and the second rear surface of the peripheral circuit structure PS_1 face each other.

The seventh word line wiring structure WLICS7_1 may include a sixteenth word line contact 1951, a ninth word line wiring 1952, a seventeenth word line contact 1953, an eighteenth word line contact 1954, a nineteenth word line contact 1955, and a tenth word line wiring 1956.

The sixteenth word line contact 1951 may extend through a lower portion of the second insulating interlayer 1520, the first insulating interlayer 1500, and the second capping pattern 1250 to contact an upper surface of the second gate electrode 1235. The ninth word line wiring 1952 may extend in the first direction D1_1 within the second insulating interlayer 1520 and contact an upper surface of the sixteenth word line contact 1951. The seventeenth word line contact 1953 may extend through an upper portion of the second insulating interlayer 1520 to contact a lower surface of the bonding pad structure and an upper surface of the ninth word line wiring 1952. The eighteenth word line contact 1954 may extend through a lower portion of the sixth insulating interlayer 1690, the upper portion of the third insulating interlayer 1640, the isolation pattern 1607, and the lower portion of the third insulating interlayer 1640 to be electrically connected to the lower portion of the wiring structure 1660. The nineteenth word line contact 1955 may extend through a lower portion of the sixth insulating interlayer 1690 and the upper portion of the third insulating interlayer 1640 to be electrically connected to the upper portion of the wiring structure 1660. The tenth word line wiring 1956 may extend in the first direction D1_1 within the sixth insulating interlayer 1690 and commonly contact upper surfaces of the eighteenth and nineteenth word line contacts 1954 and 1955.

In example embodiments, a width of each of the sixteenth to nineteenth word line contacts 1951, 1953, 1954 and 1955 in the horizontal direction may increase away from an upper surface of the first handling substrate 1010.

The seventh bit line wiring structure BLICS7_1 may include a twenty-second bit line contact 1961, a fifteenth bit line wiring 1963, a twenty-third bit line contact 1965, a twenty-fourth bit line contact 1967, and a sixteenth bit line wiring 1969.

The twenty-second bit line contact 1961 may extend through a lower portion of the second insulating interlayer 1520 and an upper portion of the first insulating interlayer 1500 to contact an upper surface of the bit line structure 1490. The fifteenth bit line wiring 1963 may extend in the second direction D2_1 within the second insulating interlayer 1520 and contact an upper surface of the twenty-second bit line contact 1961. The twenty-third bit line contact 1965 may extend through a lower portion of the sixth insulating interlayer 1690, the upper portion of the third insulating interlayer 1640, the isolation pattern 1607, the lower portion of the third insulating interlayer 1640, the bonding layer structure, and an upper portion of the second insulating interlayer 1520 to contact an upper surface of the fifteenth bit line wiring 1963. The twenty-fourth bit line contact 1967 may extend through a lower portion of the sixth insulating interlayer 1690 and the upper portion of the third insulating interlayer 1640 to be electrically connected to an upper portion of the wiring structure 1660. The sixteenth bit line wiring 1969 may extend in the second direction D2_1 within the sixth insulating interlayer 1690 and commonly contact upper surfaces of the twenty-third and twenty-fourth bit line contacts 1965 and 1967. Meanwhile, the fifteenth bit line wiring 1963 may serve as a landing pad for the twenty-third bit line contact 1965.

In example embodiments, a width of each of the twenty-second to twenty-fourth bit line contacts 1961, 1965 and 1967 in the horizontal direction may increase away from an upper surface of the first handling substrate 1010.

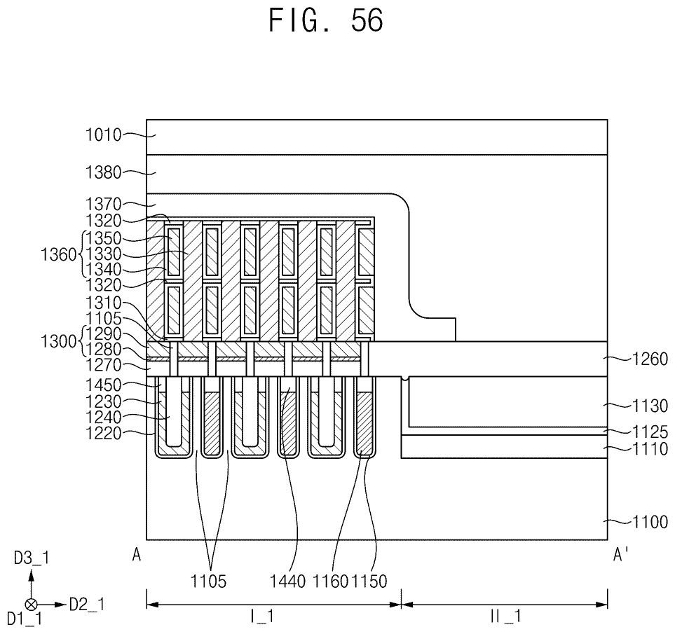

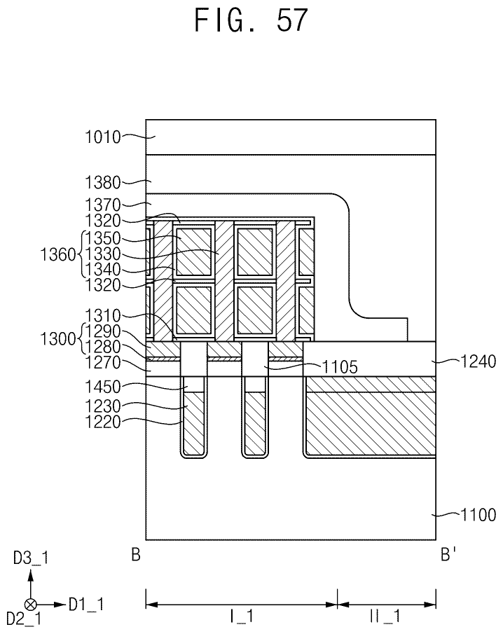

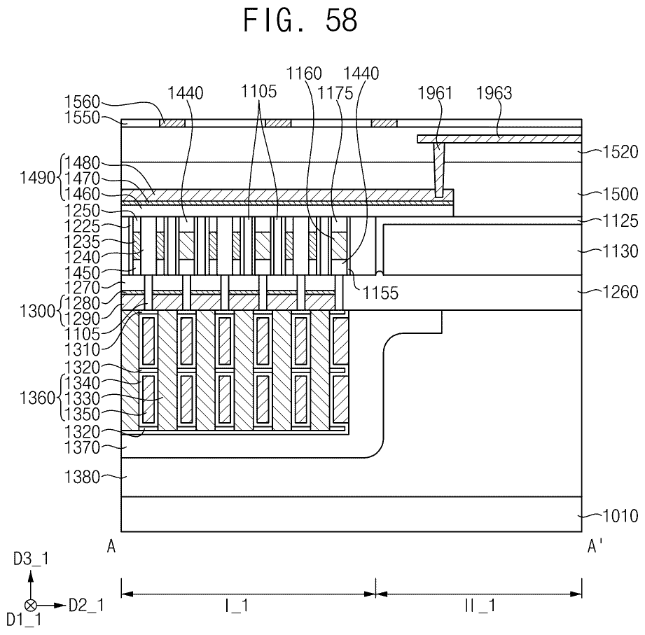

FIGS. 56 to 59 are cross-sectional views illustrating a method of manufacturing a first semiconductor device in accordance with the seventh example embodiment 1-7, where FIGS. 56 and 58 are cross-sectional views taken along lines A-A′ of corresponding plan views, respectively, and FIGS. 57 and 59 are cross-sectional views taken along line B-B′ of the corresponding plan views, respectively.

This method of the seventh example embodiment 1-7 of the first semiconductor device may include processes substantially the same as or similar to those illustrated with respect to FIGS. 44 to 51 and FIGS. 42 and 43, and thus repeated explanations are omitted herein.

Referring to FIGS. 56 and 57, before forming the bit line structure 1490 by performing processes substantially the same as or similar to the processes described with reference to FIGS. 44 and 45, the first contact plug 1270, the landing pad structure 1300, and the capacitor 1360 may be formed, and the first handling substrate 1010 may be bonded on the fifth insulating interlayer 1380 via a third bonding layer (not shown).

Referring to FIGS. 58 and 59, processes substantially the same as or similar to the processes described with reference to FIGS. 46 and 47 may be performed to flip the first handling substrate 1010, and form the bit line structure 1490, the first and second insulating interlayers 1500 and 1520, the sixteenth word line contact 1951, the ninth word line wiring 1952, and the seventeenth word line contact 1953 of the seventh word line wiring structure WLICS7_1, and the twenty-second word line contact 1961 and the fifteenth word line wiring 1963 of the seventh bit line wiring structure BLICS7_1.

Thereafter, the first bonding layer 1550 and the first bonding pad 1560 accommodated therein may be formed on the second insulating interlayer 1520.

Referring again to FIGS. 54 and 55, processes substantially the same as or similar to the processes described with reference to FIGS. 50 and 51 may be performed to form the peripheral circuit structure PS_1.

Processes substantially the same as or similar to the processes described with reference to FIGS. 42 and 43 may be performed to flip the third handling substrate 1030 so as to bond the first and second bonding layers 1550 and 1670 to each other, and remove an upper portion of the third handling substrate 1030 through, for example, a grinding process.

Thereafter, the eighteenth word line contact 1954, the nineteenth word line contact 1955, and the tenth word line wiring 1956 included in the seventh word line wiring structure WLICS7_1, the twenty-third bit line contact 1965, the twenty-fourth bit line contact 1967, and the sixteenth bit line wiring 1969 included in the seventh bit line wiring structure BLICS7_1, and the sixth insulating interlayer 1690 covering them may be formed to complete the manufacturing of the first semiconductor device.

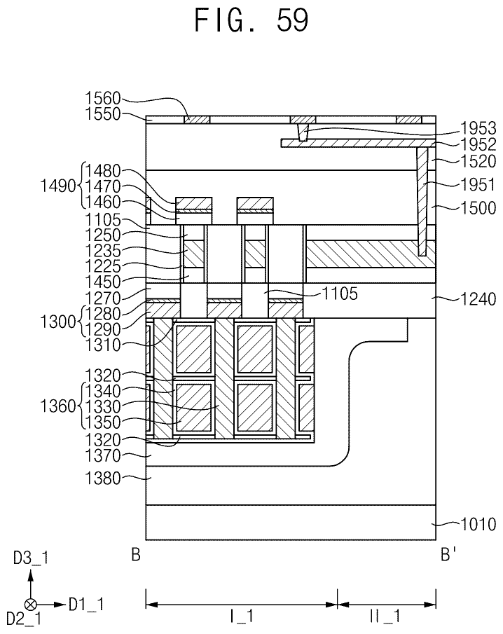

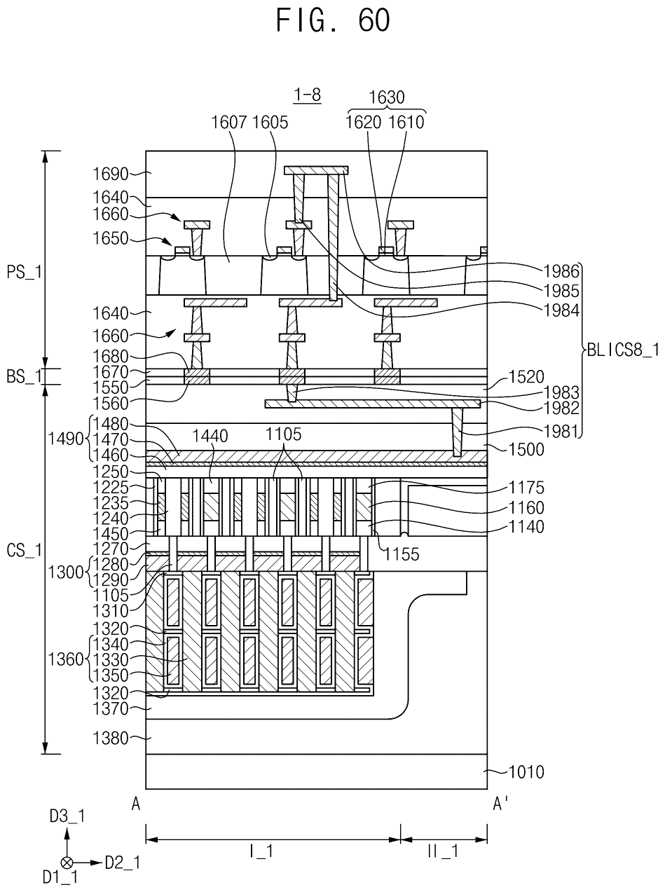

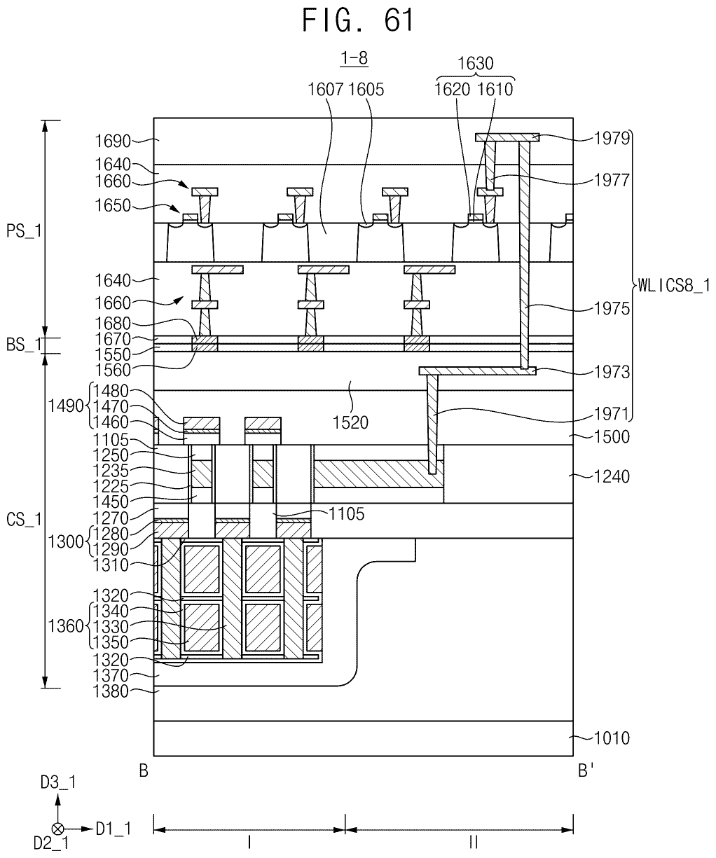

FIGS. 60 and 61 are cross-sectional views illustrating a first semiconductor device in accordance with an eighth example embodiment 1-8, which may correspond to FIGS. 54 and 55, respectively.

The eighth example embodiment 1-8 of first semiconductor devices may be substantially the same as or similar to that of FIGS. 54 and 55, except for including an eighth word line wiring structure WLICS8_1 and an eighth bit line wiring structure BLICS8_1 instead of the seventh word line wiring structure WLICS7_1 and the seventh bit line wiring structure BLICS7_1, respectively, and thus repeated explanations are omitted herein.

Referring to FIGS. 60 and 61, the eighth word line wiring structure WLICS8_1 may include a twentieth word line contact 1971, an eleventh word line wiring 1973, a twenty-first word line contact 1975, a twenty-second word line contact 1977, and a twelfth word line wiring 1979.

The twentieth word line contact 1971 may extend through a lower portion of the second insulating interlayer 1520, the first insulating interlayer 1500, and the second capping pattern 1250 to contact an upper surface of the second gate electrode 1235. The eleventh word line wiring 1973 may extend in the first direction D1_1 within the second insulating interlayer 1520 and contact an upper surface of the twentieth word line contact 1971. The twenty-first word line contact 1975 may extend through a lower portion of the sixth insulating interlayer 1690, the upper portion of the third insulating interlayer 1640, the isolation pattern 1607, the lower portion of the third insulating interlayer 1640, the insulating layer structure, and an upper portion of the second insulating interlayer 1520 to contact an upper surface of the eleventh word line wiring 1973. The twenty-second word line contact 1977 may extend through a lower portion of the sixth insulating interlayer 1690 and the upper portion of the third insulating interlayer 1640 to be electrically connected to the upper portion of the wiring structure 1660. The twelfth word line wiring 1979 may extend in the first direction D1_1 within the sixth insulating interlayer 1690 and commonly contact upper surfaces of the twenty-first and twenty-second word line contacts 1975 and 1977. Meanwhile, the eleventh word line wiring 1973 may serve as a landing pad for the twenty-first word line contact 1975.

In example embodiments, a width of each of the twentieth to twenty-second word line contacts 1971, 1975 and 1977 in the horizontal direction may increase away from an upper surface of the first handling substrate 1010.

The eighth bit line wiring structure BLICS8_1 may include a twenty-fifth bit line contact 1981, a seventeenth bit line wiring 1982, a twenty-sixth bit line contact 1983, a twenty-seventh bit line contact 1984, a twenty-eighth bit line contact 1985, and an eighteenth bit line wiring 1986.

The twenty-fifth bit line contact 1981 may extend through a lower portion of the second insulating interlayer 1520 and an upper portion of the first insulating interlayer 1500 to contact an upper surface of the bit line structure 1490. The seventeenth bit line wiring 1982 may extend in the second direction D2_1 within the second insulating interlayer 1520 and contact an upper surface of the twenty-fifth bit line contact 1981. The twenty-sixth bit line contact 1983 may extend through an upper portion of the second insulating interlayer 1520 to contact a lower surface of the bonding pad structure and an upper surface of the seventeenth bit line wiring 1982. The twenty-seventh bit line contact 1984 may extend through a lower portion of the sixth insulating interlayer 1690, the upper portion of the third insulating interlayer 1640, the isolation pattern 1607, and the lower portion of the third insulating interlayer 1640 to be electrically connected to the lower portion of the wiring structure 1660. The twenty-eighth bit line contact 1985 may extend through a lower portion of the sixth insulating interlayer 1690 and the upper portion of the third insulating interlayer 1640 to be electrically connected to the upper portion of the wiring structure 1660. The eighteenth bit line wiring 1986 may be commonly connected to upper surfaces of the twenty-seventh and twenty-eighth bit line contacts 1984 and 1985.

In example embodiments, a width of each of the twenty-fifth to twenty-eighth bit line contacts 1981, 1983, 1984 and 1985 in the horizontal direction may increase away from an upper surface of the first handling substrate 1010.

Hereinafter, in the specification (and not necessarily in the claims), two directions substantially parallel to an upper surface of each of substrates of the second semiconductor device and substantially perpendicular to each other may be referred to as first and second directions D1_2 and D2_2, respectively, and a direction substantially parallel to the upper surface of each of the substrates of the second semiconductor device and having an acute angle with respect to each of the first and second directions D1_2 and D2_2 may be referred to as a third direction D3_2. A direction substantially perpendicular to the upper surface each of the substrates of the second semiconductor device may be referred to as a vertical direction. Each of the first to third directions D1_2, D2_2 and D3_2 may represent not only a direction shown in the drawing, but also a reverse direction to the direction.

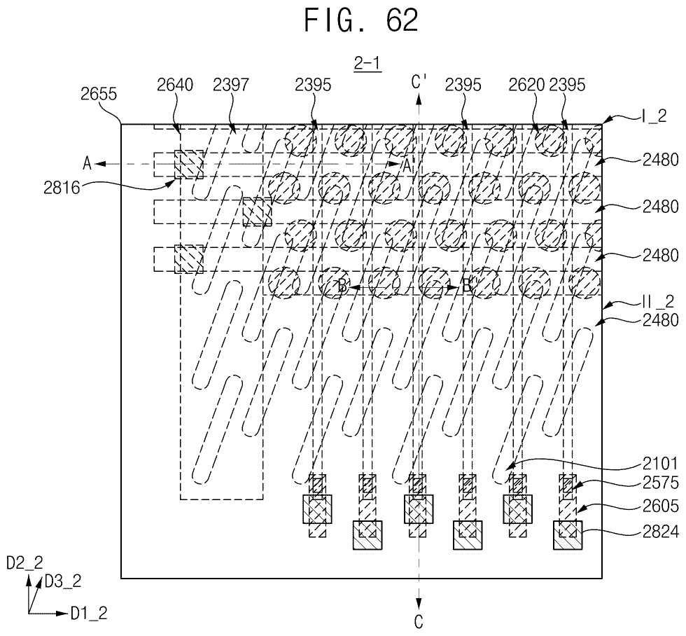

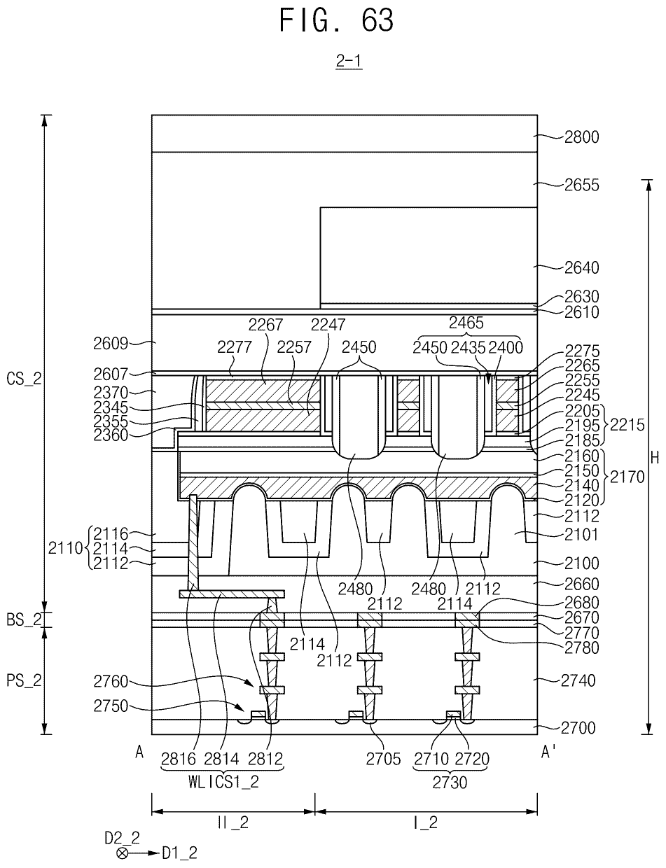

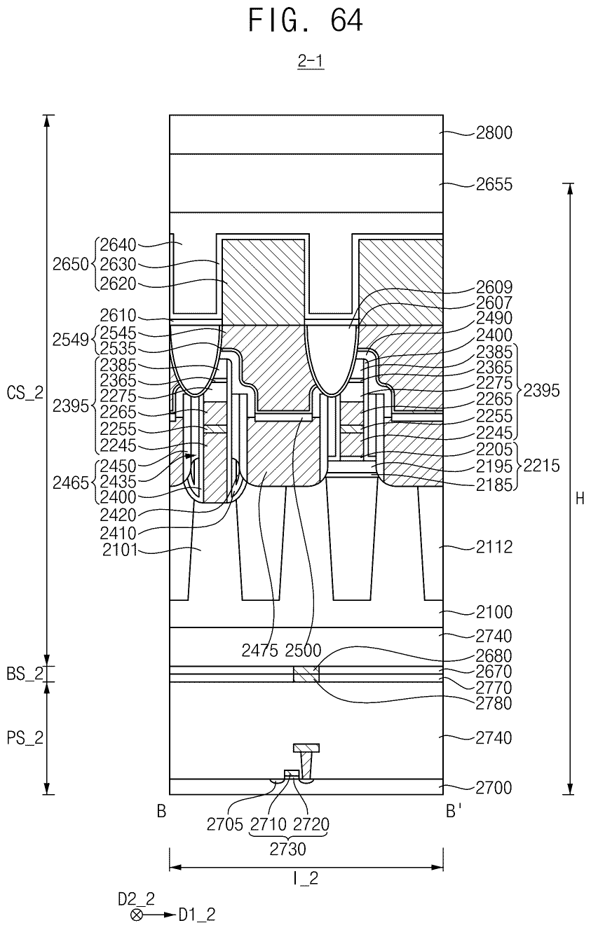

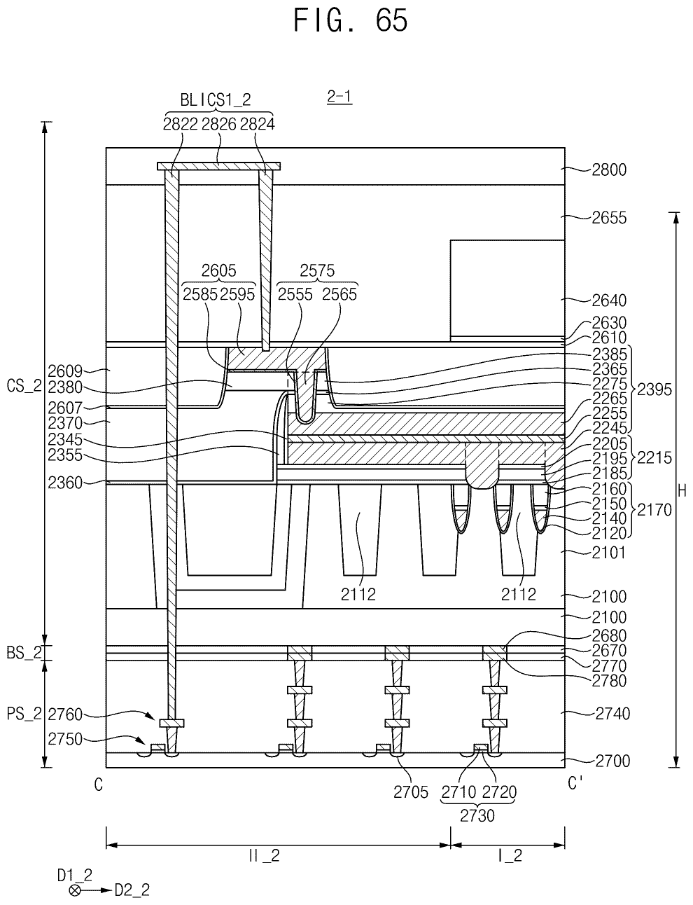

FIGS. 62 to 65 are plan views and cross-sectional views illustrating a method of manufacturing a second semiconductor device according to a second example embodiment 2-1. Specifically, FIG. 62 is a horizontal cross-sectional view at height H of FIGS. 63 to 65. FIG. 63 is a vertical cross-sectional view taken along line A-A′ of FIG. 62. FIG. 64 is a vertical cross-sectional view taken along line B-B′ of FIG. 62. FIG. 65 is a vertical cross-sectional view taken along line C-C′ of FIG. 62.

The second semiconductor device may include a peripheral circuit structure PS_2, a bonding structure BS_2, a cell structure CS_2, a first word line wiring structure WLICS1_2, and a first bit line wiring structure BLICS1_2.

The second semiconductor device may have a Cell Over Periphery (COP) structure. That is, a cell structure CS_2 including memory cells may be disposed on a peripheral circuit structure PS_2.

The cell structure CS_2 may include a first region I_2 and a second region II_2 surrounding the first region I_2 when viewed from above. In example embodiments, the first region I_2 may be a cell array region, and the second region II_2 may be an extension region, and the first and second regions I_2 and II_2 may together form a cell region.

Hereinafter, for convenience of description, a portion of the peripheral circuit structure PS_2 and a portion of the bonding structure BS_2 overlapping with the first region I_2 of the cell structure CS_2 in the vertical direction will also be referred to as the first region I_2, and a portion of the peripheral circuit structure PS_2 and a portion of the bonding structure BS_2 overlapping with the second region II_2 of the cell structure CS_2 in the vertical direction will also be referred to as the second region II_2.

The peripheral circuit structure PS_2 may include a peripheral circuit pattern 2750, a wiring structure 2760, and a fifth insulating interlayer 2740 on a second substrate 2700.

The second substrate 2700, the peripheral circuit pattern 2750, the wiring structure 2760, and the fifth insulating interlayer 2740 of the peripheral circuit structure PS_2 included in the second semiconductor device may be substantially the same as or similar to the second substrate 1600, the peripheral circuit pattern 1650, the wiring structure 1660, and the third insulating interlayer 1640 of the peripheral circuit structure PS_1 included in the first semiconductor device, respectively, and thus redundant description is omitted.

The bonding structure BS_2 may include first and second bonding layers 2670 and 2770 and first and second bonding pads 2680 and 2780 accommodated therein, respectively. Here, the first and second bonding pads 2680 and 2780 may together form a bonding pad structure, and the first and second bonding layers 2670 and 2770 may together form a bonding layer structure.

The first and second bonding layers 2670 and 2770 and the first and second bonding pads 2680 and 2780 of the bonding structure BS_2 included in the second semiconductor device may be substantially the same as or similar to the first and second bonding layers 1550 and 1670 and the first and second bonding pads 1560 and 1680 of the bonding structure BS_1 included in the first semiconductor device, respectively, and thus redundant description is omitted.

The cell structure CS_2 may include an active pattern 2101, a gate structure 2170, a bit line structure 2395, a dummy bit line structure 2397, a contact plug structure, a third contact plug 2575, a first wiring 2605, and a capacitor 2650 on a first substrate 2100.

Further, the cell structure CS_2 may further include an isolation structure 2110, a first spacer structure, a second spacer structure 2465, a sixth spacer 2490, a fence pattern 2480, an insulation pattern structure 2215, a second insulating interlayer, fourth and fifth insulation patterns 2410 and 2420, and a metal silicide pattern 2500.

The active pattern 2101 may extend in the third direction D3_2 on the first region I_2 and a portion of the second region II_2 adjacent to the first region I_2, and a plurality of active patterns 2101 may be spaced apart from each other in each of the first and second directions D1_2 and D2_2. The isolation structure 2110 may cover sidewalls of the active patterns 2101.

Referring to FIGS. 62 to 65 together with FIGS. 66 to 68, the isolation structure 2110 may include first, second and third isolation patterns 2112, 2114 and 2116 sequentially stacked on an inner wall of a third recess 2106.

The active pattern 2101 may include substantially the same material as the first substrate 2100. Each of the first and third isolation patterns 2112 and 2116 may include an oxide, e.g., silicon oxide, and the second isolation pattern 2114 may include an insulating nitride, e.g., silicon nitride.

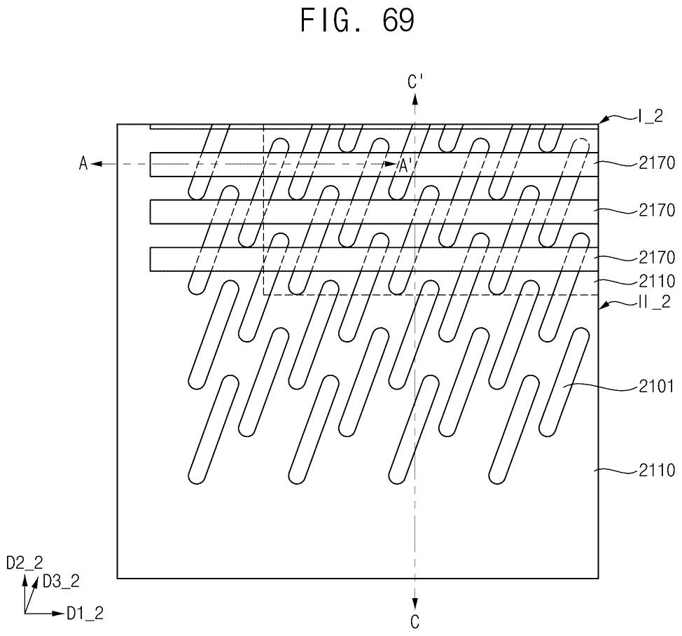

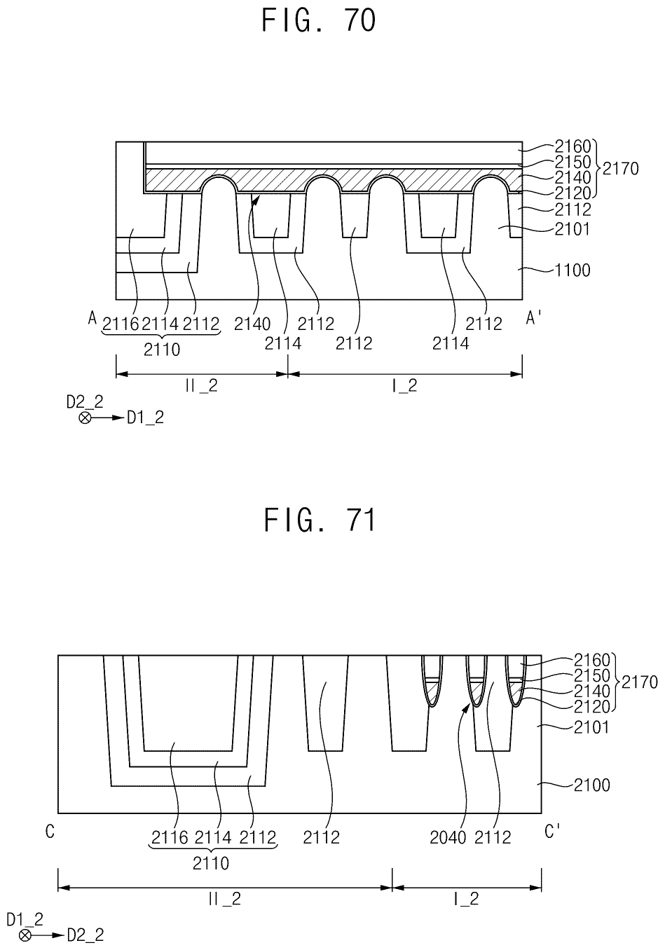

Referring to FIGS. 62 to 65 together with FIGS. 69 to 71, the gate structure 2170 may include a first gate insulation pattern 2120, a first barrier pattern (not shown), a first conductive pattern 2140, a second conductive pattern 2150, and a first gate mask 2160 in a fourth recess 2040.

In example embodiments, the gate structure 2170 may extend through end portions in the third direction D3_2 of the active patterns 2101 on the first region I_2 of the first substrate 2100 and a portion of the second region II_2 of the first substrate 2100 adjacent thereto in the first direction D1_2, and may extend in the first direction D1_2 within the first region I_2 of the first substrate 2100 and the portion of the second region II_2 of the first substrate 2100 adjacent thereto in the first direction D1_2. Accordingly, a plurality of gate structures 2170 may be spaced apart from each other along the second direction D2_2. Ends of the gate structures 2170 in the first direction D1_2 may be aligned with each other in the second direction D2_2 within the portion of the second region II_2 of the first substrate 2100 adjacent to the first region I_2 in the first direction D1_2.

The first gate insulation pattern 2120 may include, for example, an oxide such as silicon oxide. The first barrier pattern may include, for example, a metal nitride such as titanium nitride, tantalum nitride, etc. The first conductive pattern 2140 may include, for example, a metal such as tungsten, a metal nitride such as titanium nitride, tantalum nitride, etc., a metal silicide, doped polysilicon, etc. The second conductive pattern 2150 may include doped polysilicon. The first gate mask 2160 may include, for example, a nitride such as silicon nitride.

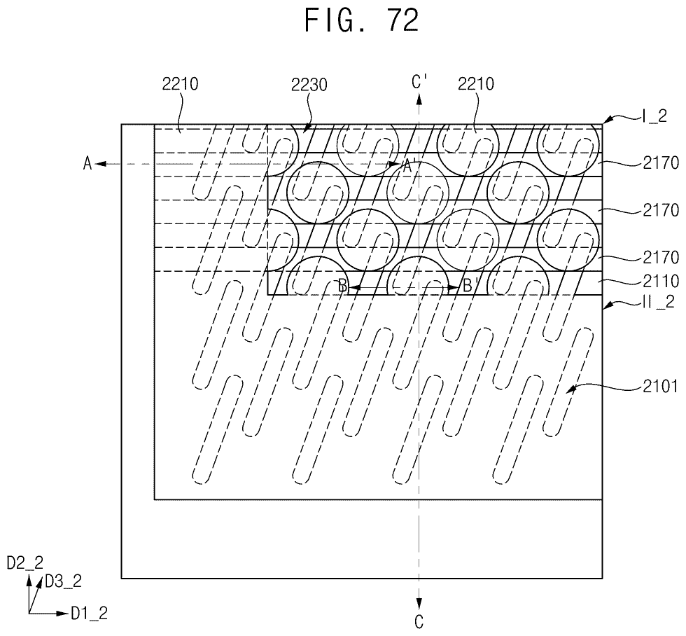

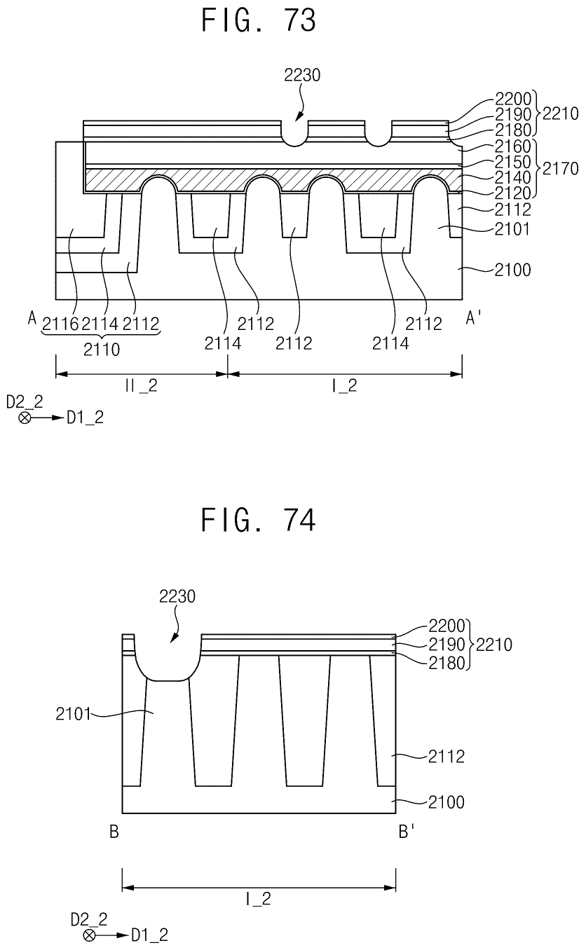

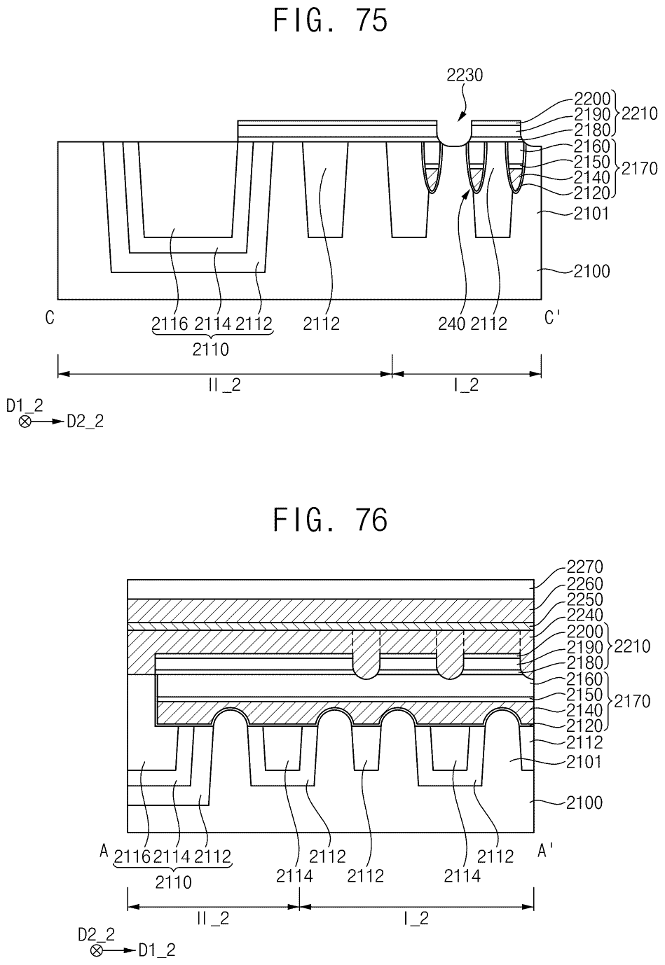

Referring to FIGS. 62 to 65 together with FIGS. 72 to 75, a first opening 2230 may be formed in the first region I_2 to extend through the insulation layer structure 2210 and expose upper surfaces of the active pattern 2101, the isolation structure 2110, and the gate mask 2165 included in the gate structure 2170, and an upper surface of a central portion in the third direction D3_2 of the active pattern 2101 may be exposed by the first opening 2230.

In example embodiments, a bottom surface of the first opening 2230 may be wider than the upper surface of the active pattern 2101 exposed by the first opening 2230. Accordingly, the first opening 2230 may also expose the upper surface of the isolation structure 2110 adjacent to the active pattern 2101. Further, the first opening 2230 may extend through an upper portion of the active pattern 2101 and an upper portion of the isolation structure 2110 adjacent thereto, and accordingly, the bottom surface of the first opening 2230 may be lower than upper surfaces of portions of the active pattern 2101 where the first opening 2230 is not formed, that is, respective edge portions in the third direction D3_2 of the active pattern 2101.

The bit line structure 2395 may include a third conductive pattern 2245, a second barrier pattern 2255, a fourth conductive pattern 2265, a first mask 2275, a first etch stop pattern 2365, and a first capping pattern 2385 sequentially stacked in the vertical direction on the first opening 2230 or the insulation pattern structure 2215 in the first region I_2 and the second region II_2 adjacent thereto in the second direction D2_2. The third conductive pattern 2245, the second barrier pattern 2255, and the fourth conductive pattern 2265 may together form a conductive structure, and the first mask 2275, the first etch stop pattern 2365, and the first capping pattern 2385 may together form an insulating structure.

In example embodiments, the bit line structure 2395 may extend in the second direction D2_2 on the first substrate 2100, and a plurality of bit line structures 2395 may be spaced apart from each other along the first direction D1_2.

Meanwhile, the dummy bit line structure 2397 may include a fifth conductive pattern 2247, a third barrier pattern 2257, a sixth conductive pattern 2267, a second mask 2277, a second etch stop pattern 2367, and a second capping pattern 2387 sequentially stacked in the vertical direction on the insulation pattern structure 2215 in the second region II_2 adjacent to the first region I_2 in the first direction D1_2.

Each of the third and fifth conductive patterns 2245 and 2247 may include, for example, doped polysilicon. Each of the second and third barrier patterns 2255 and 2257 may include, for example, a metal nitride such as titanium nitride or a metal silicon nitride such as titanium silicon nitride. Each of the fourth and sixth conductive patterns 2265 and 2267 may include, for example, a metal such as tungsten. Each of the first and second masks 2275 and 2277, the first and second etch stop patterns 2365 and 2367, and the first and second capping patterns 2385 and 2387 may include, for example, an insulating nitride such as silicon nitride.

The fourth and fifth insulation patterns 2410 and 2420 may be disposed within the first opening 2230 and may contact a lower sidewall of the bit line structure 2395. The fourth insulation pattern 2410 may include, for example, an oxide such as silicon oxide. The fifth insulation pattern 2420 may include, for example, an insulating nitride such as silicon nitride.

The insulation pattern structure 2215 may be disposed below the bit line structure 2395 on the active pattern 2101 and the isolation structure 2110, and may include first to third insulation patterns 2185, 2195 and 2205 sequentially stacked along the vertical direction. The first and third insulation patterns 2185 and 2225 may include, for example, an oxide such as silicon oxide, and the second insulation pattern 2195 may include, for example, an insulating nitride such as silicon nitride.

The first spacer structure may be disposed on opposite sidewalls in the second direction D2_2 of the bit line structure 2395, and on opposite sidewalls in the second direction D2_2 and a sidewall in the first direction D1_2 of the dummy bit line structure 2397 in the second region II_2.

The first spacer structure may include first and second spacers 2345 and 2355 sequentially stacked along the horizontal direction on the opposite sidewall in the second direction D2_2 of the bit line structure 2395, and on the opposite sidewalls in the second direction D2_2 and the sidewall in the first direction D1_2 of the dummy bit line structure 2397 in the second region II_2.

The first spacer 2345 may include, for example, a nitride such as silicon nitride, and the second spacer 2355 may include, for example, an oxide such as silicon oxide. However, the configuration of the first spacer structure is not limited thereto, and may include only a single spacer or may have a configuration in which three or more spacers are stacked.

The contact plug structure may include a first contact plug 2475, a metal silicide pattern 2500, and a second contact plug 2549 sequentially stacked along the vertical direction on the active pattern 2101 and the isolation structure 2110.

The first contact plug 2475 may contact upper surfaces of respective edge portions in the third direction D3_2 of the active pattern 2101. In example embodiments, a plurality of first contact plugs 2475 may be spaced apart from each other along the second direction D2_2 between the bit line structures 2395, and a fence pattern 2480 may be disposed between neighboring ones of the contact plugs 2475 in the second direction D2_2. The fence pattern 2480 may include, for example, an insulating nitride such as silicon nitride.

The first contact plug 2475 may include, for example, doped polysilicon, and the metal silicide pattern 2500 may include, for example, titanium silicide, cobalt silicide, nickel silicide, etc.

The second contact plug 2549 may include a first metal pattern 2545 and a fourth barrier pattern 2535 covering a lower surface of the first metal pattern 2545. The first metal pattern 2545 may include, for example, a metal such as tungsten, and the fourth barrier pattern 2535 may include, for example, a metal nitride such as titanium nitride.

In example embodiments, a plurality of second contact plugs 2549 may be spaced apart from each other along each of the first and second directions D1_2 and D2_2 in the first region I_2, and may be arranged in a honeycomb pattern or a lattice pattern when viewed from above. An upper surface of each of the second contact plugs 2549 may have a circular, elliptical, or polygonal shape.

The second spacer structure 2465 may include a third spacer 2400 covering the opposite sidewalls in the first direction D1_2 of the bit line structure 2395 and a sidewall of the third insulation pattern 2205 in the first region I_2, an air spacer 2435 on a lower outer sidewall of the third spacer 2400, and a fifth spacer 2450 covering an outer sidewall of the air spacer 2435, sidewalls of the insulation pattern structure 2215, and upper surfaces of the fourth and fifth insulation patterns 2410 and 2420.

Each of the third and fifth spacers 2400 and 2450 may include, for example, an insulating nitride such as silicon nitride, and the air spacer 2435 may include air.

The sixth spacer 2490 may be disposed on an outer sidewall of a portion of the third spacer 2400 on an upper sidewall of the bit line structure 2395, and may cover a top end of the air spacer 2435 and an upper surface of the fifth spacer 2450. The sixth spacer 2490 may include, for example, an insulating nitride such as silicon nitride.

The third contact plug 2575 may extend through the first capping pattern 2385, the first etch stop pattern 2365, and the second mask 2275 in the second region II_2 to contact the fourth conductive pattern 2265, and accordingly may apply electrical signals to the bit line structure 2395. The third contact plug 2575 may include a second metal pattern 2565 and a fifth barrier pattern 2555.

The first wiring 2605 may overlap with the third contact plug 2575 in the vertical direction, and may include a third metal pattern 2595 and a sixth barrier pattern 2585 covering a lower surface of the third metal pattern 2595.

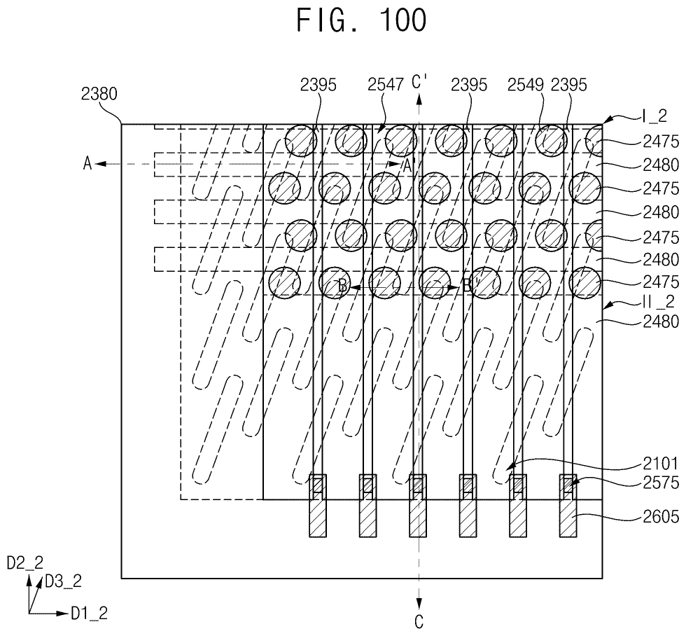

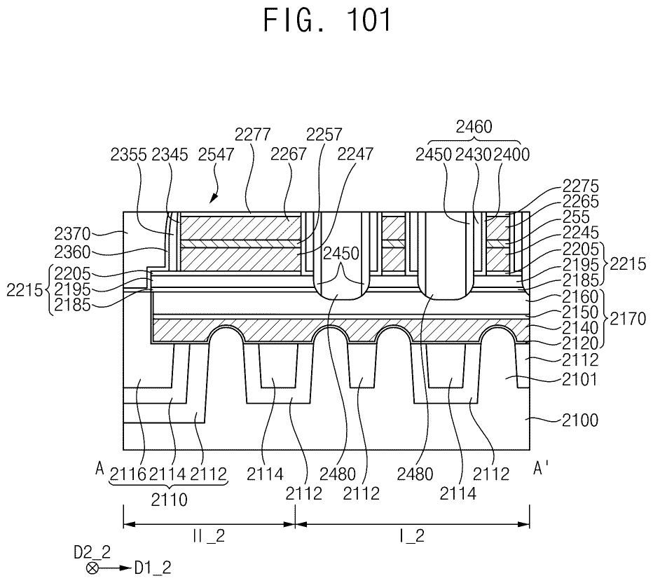

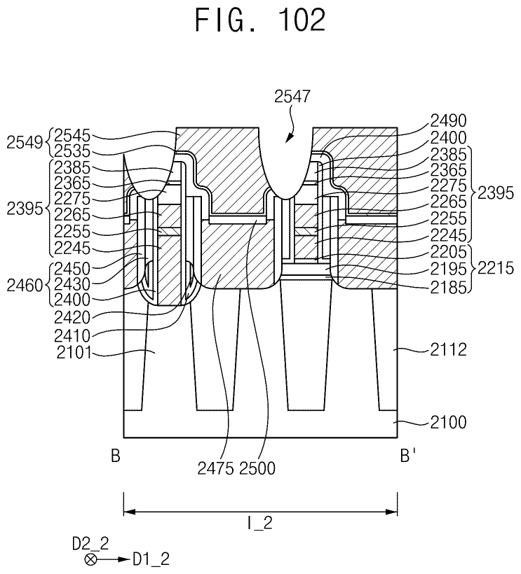

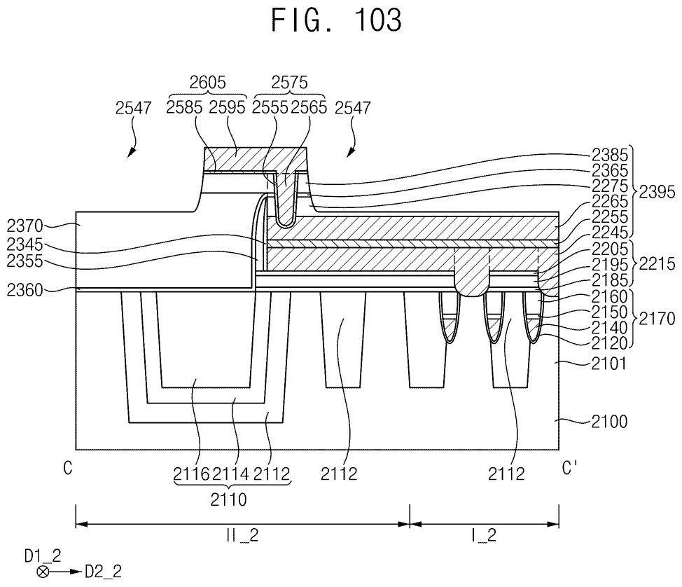

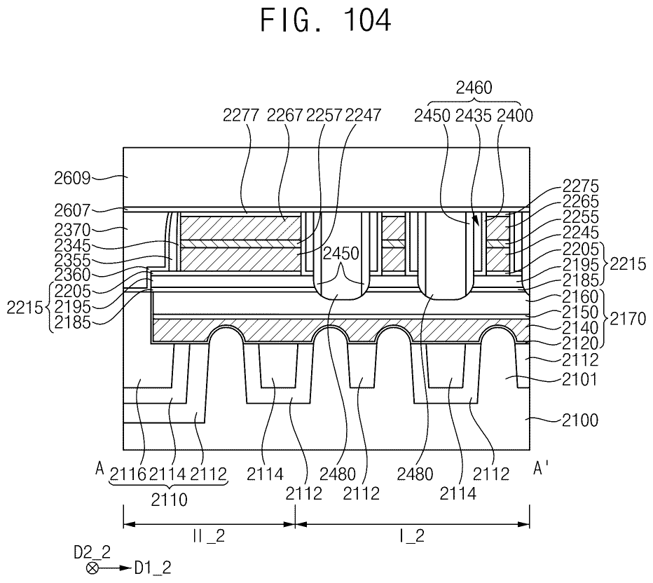

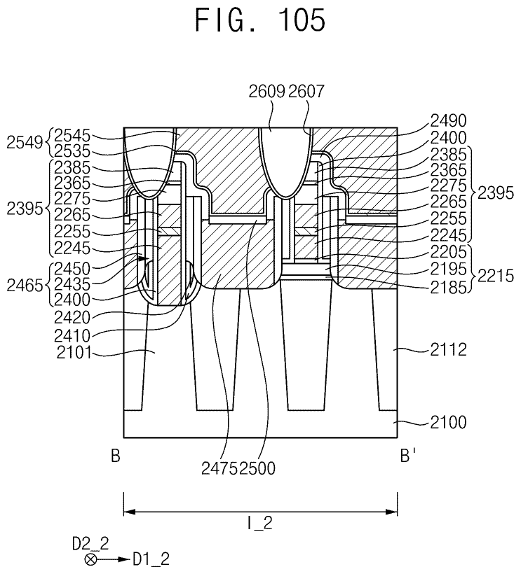

Referring to FIGS. 62 to 65 together with FIGS. 100 to 103, the second insulating interlayer may include a sixth insulation pattern 2607 and a seventh insulation pattern 2609. The sixth insulation pattern 2607 may be disposed on an inner wall of an eighth opening 2547 that extends through the second contact plug 2549, the first wiring 2605, a portion of the insulating structure included in the bit line structure 2395, and portions of the third, fifth, and sixth spacers 2400, 2450 and 2490 and surrounds the second contact plug 2549 and the first wiring 2605 when viewed from above. The seventh insulation pattern 2609 may be disposed on the sixth insulation pattern 2607 to fill a remaining portion of the eighth opening 2547. The top end of the air spacer 2435 may be closed by the sixth insulation pattern 2607.

The sixth and seventh insulation patterns 2607 and 2609 may include, for example, an insulating nitride such as silicon nitride.

The second etch stop layer 2610 may be disposed on the sixth and seventh insulation patterns 2607 and 2609, the fence pattern 2480, and the first wiring 2605.

The capacitor 2650 may contact an upper surface of the second contact plug 2549. The capacitor 2650 may include a lower electrode 2620, a dielectric layer 2630, and an upper electrode 2640 that are sequentially stacked. Each of the lower electrode 2620 and the upper electrode 2640 may include, for example, a metal, a metal nitride, a metal silicide, doped polysilicon, doped silicon-germanium, etc., and the dielectric layer 2630 may include, for example, a metal oxide such as hafnium oxide, zirconium oxide, etc.

Hereinafter, for convenience of description, among first and second surfaces in the vertical direction of the cell structure CS_2, a surface adjacent to the capacitor 2650 will be referred to as a first front surface, and an opposite surface will be referred to as a first rear surface. Further, among third and fourth surfaces in the vertical direction of the second substrate 2700, a surface on which the peripheral circuit pattern 2750 is disposed will be referred to as a second front surface of the second substrate 2700, and an opposite surface will be referred to as a second rear surface.

In example embodiments, the second semiconductor device may have a structure in which the first rear surface of the cell structure CS_2 and the second front surface of the second substrate 2700 face each other.

The first word line wiring structure WLICS1_2 may include a first word line contact 2812, a first word line wiring 2814, and a second word line contact 2816.

The first word line contact 2812 may extend through a lower portion of the fourth insulating interlayer 2660 to contact the bonding pad structure. The first word line wiring 2814 may extend in the first direction D1_2 within the fourth insulating interlayer 2660 to contact an upper surface of the first word line contact 2812. The second word line contact 2816 may extend through the isolation structure 2110 and an upper portion of the fourth insulating interlayer 2660 to contact a lower surface of the first conductive pattern 140 included in the gate structure 2170 and an upper surface of the first word line wiring 2814.

In example embodiments, a width in the horizontal direction of each of the first and second word line contacts 2812 and 2816 may decrease away from the upper surface of the second substrate 2700.

The first bit line wiring structure BLICS1_2 may include a first bit line contact 2822, a second bit line contact 2824, and a first bit line wiring 2826.

The first bit line contact 2822 may extend through a lower portion of the sixth insulating interlayer 2800, the third insulating interlayer 2655, the second etch stop layer 2610, the second insulating interlayer, the first insulating interlayer 2370, the first etch stop layer 2360, the isolation structure 2110, the fourth insulating interlayer 2660, the bonding layer structure, and an upper portion of the fifth insulating interlayer 2740 to contact the pad of the wiring structure 2760. The second bit line contact 2824 may extend through a lower portion of the sixth insulating interlayer 2800, the third insulating interlayer 2655, and the second etch stop layer 2610 to contact the first wiring 2605. The first bit line wiring 2826 may extend in the second direction D2_2 within the sixth insulating interlayer 2800 to commonly contact upper surfaces of the first and second bit line contacts 2822 and 2824. Meanwhile, the pad of the wiring structure 2760 may serve as a landing pad for the first bit line contact 2822.

In example embodiments, a width in the horizontal direction of each of the first and second bit line contacts 2822 and 2824 may increase away from the upper surface of the second substrate 2700.

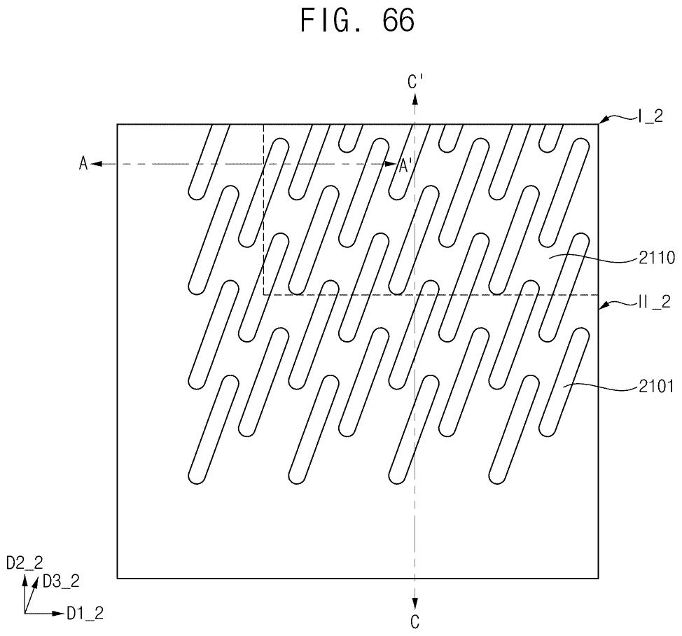

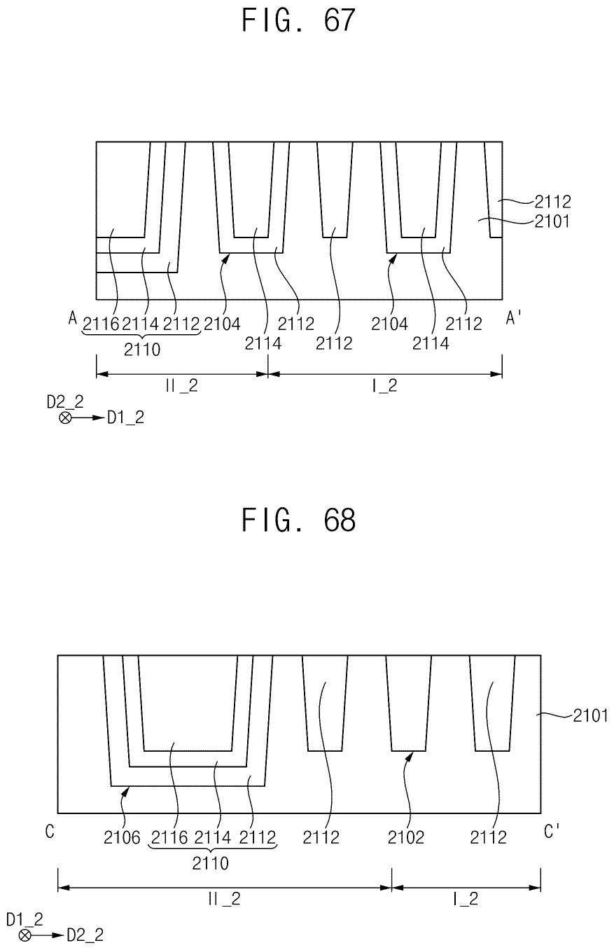

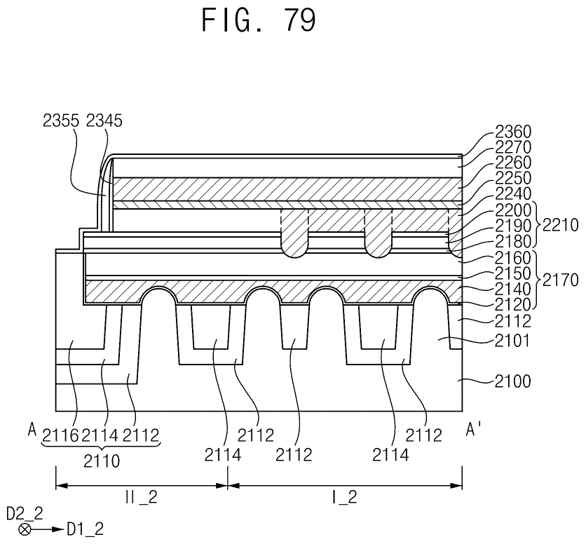

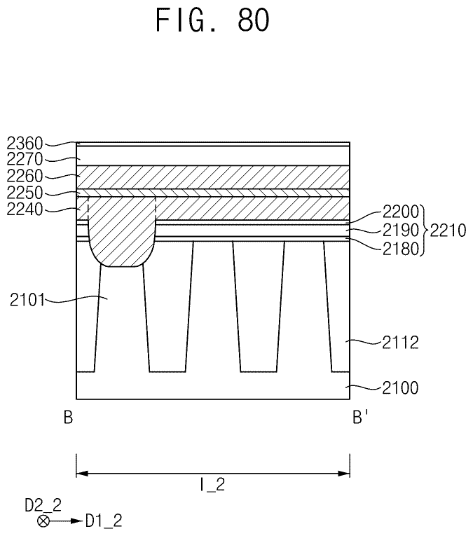

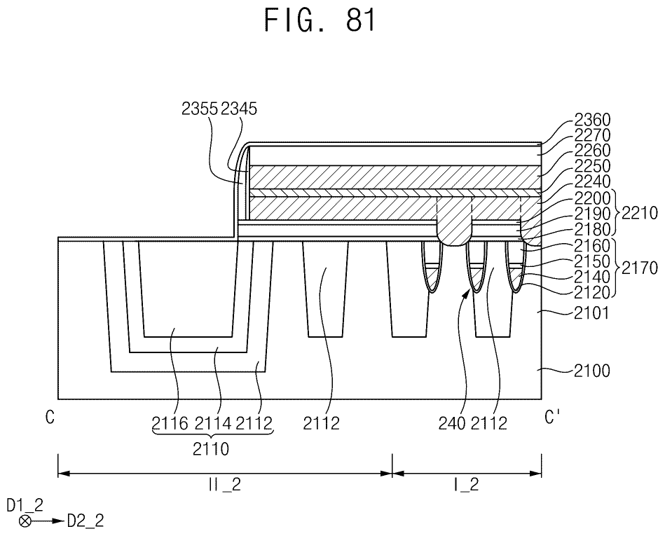

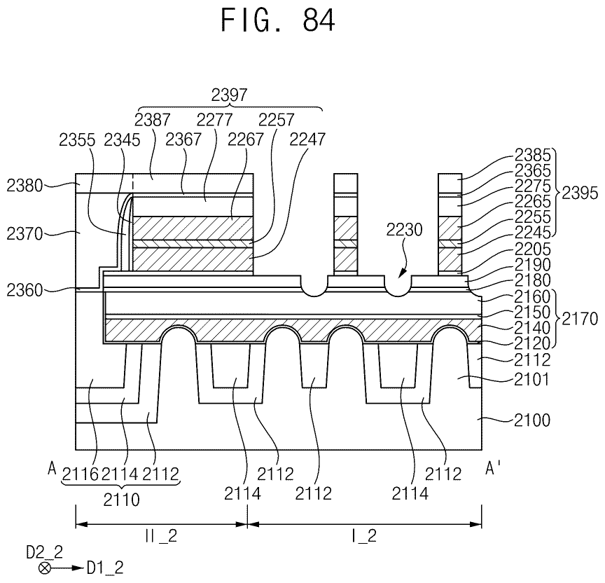

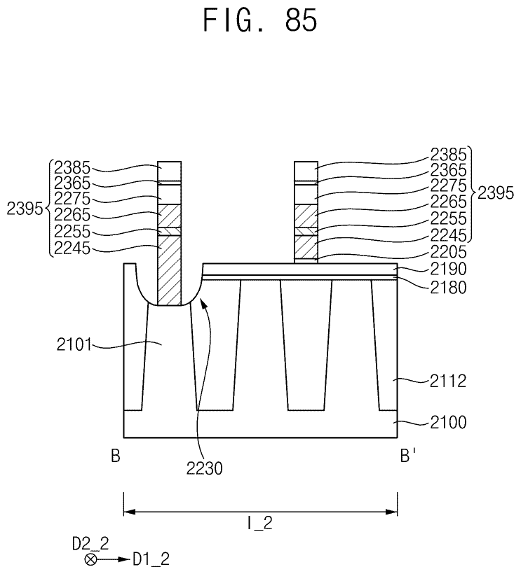

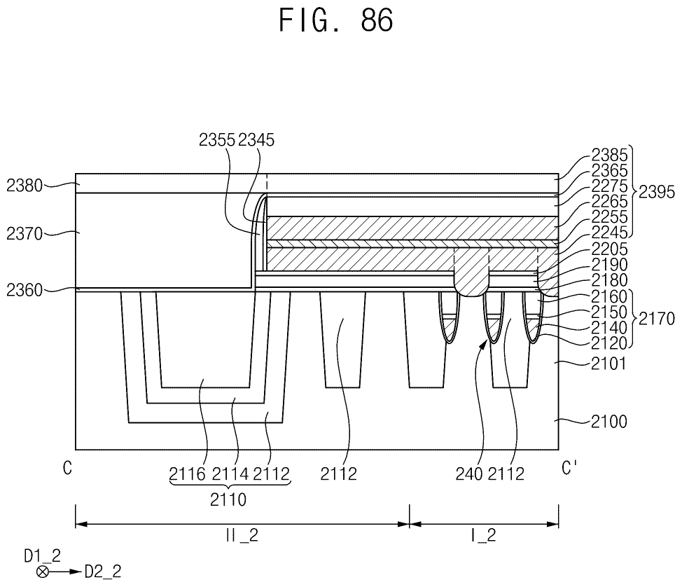

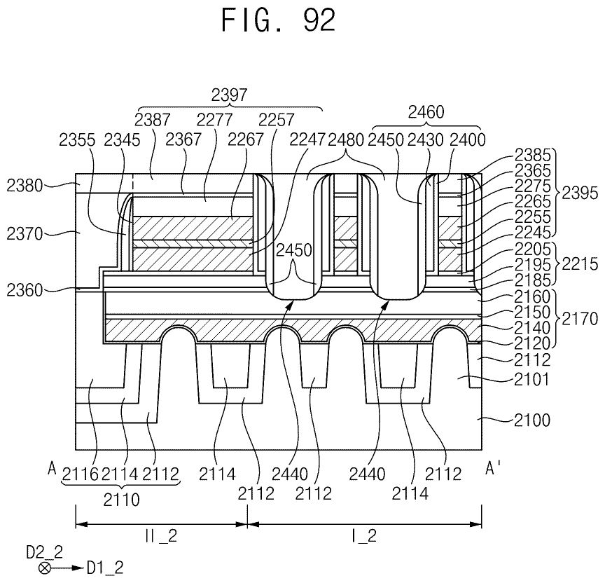

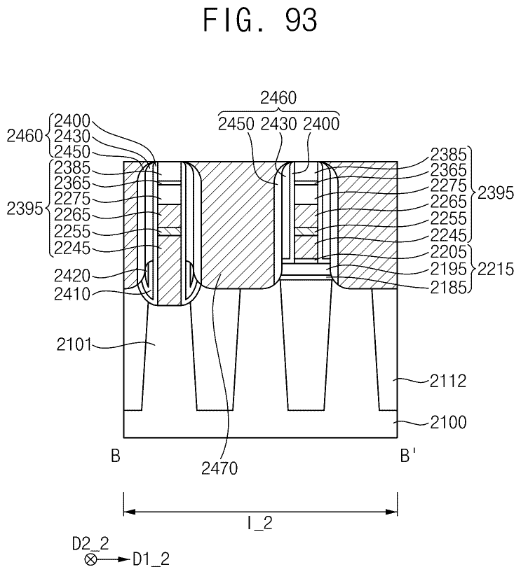

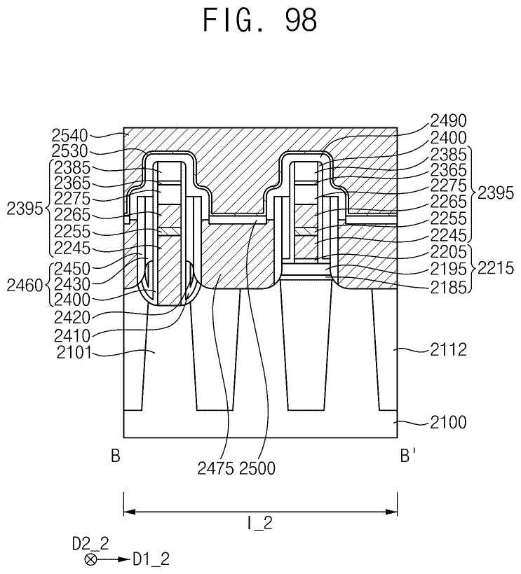

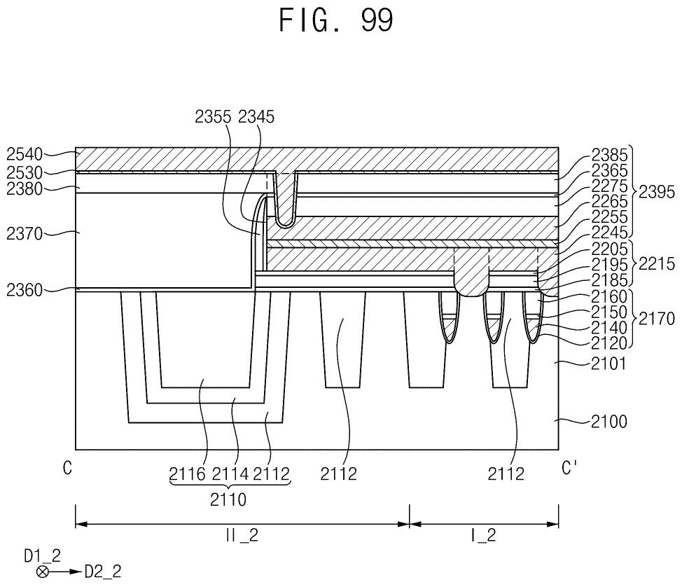

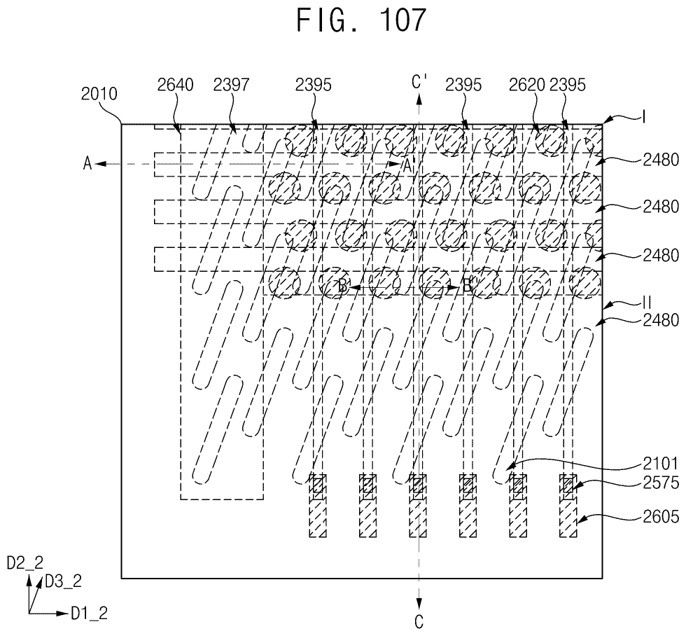

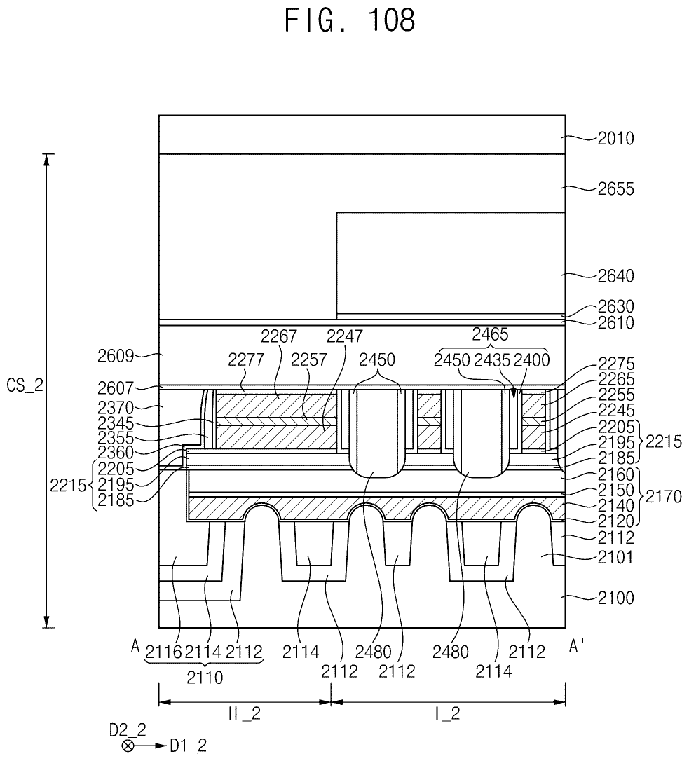

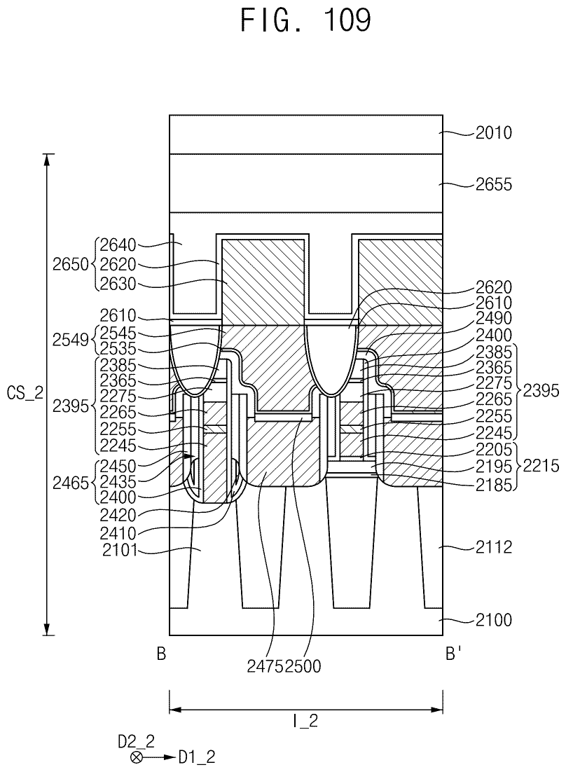

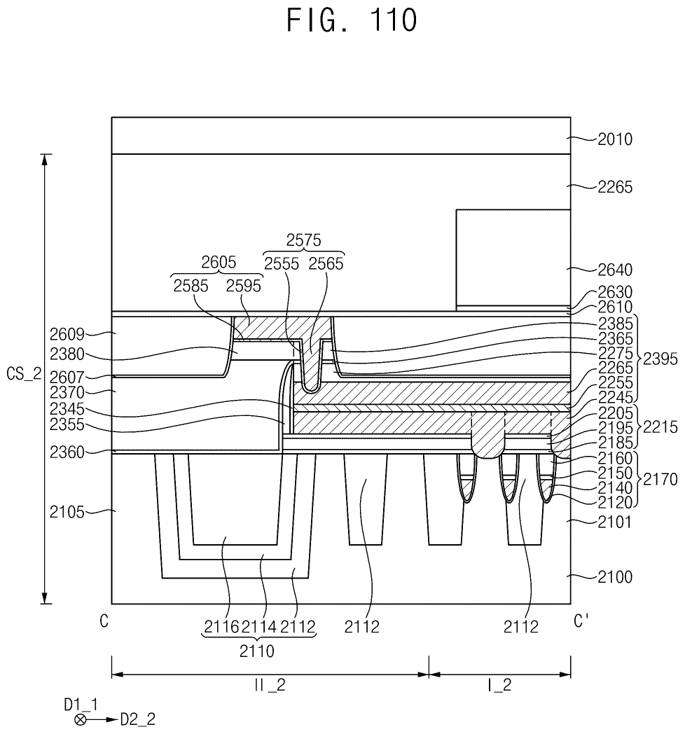

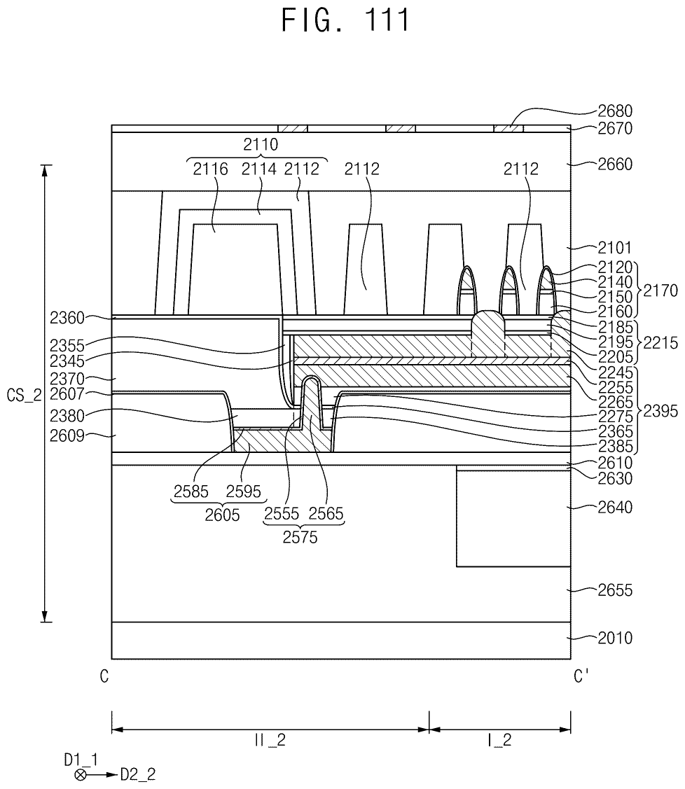

FIGS. 66 to 113 are plan views and cross-sectional views illustrating a method of manufacturing a second semiconductor device according to a first example embodiment 2-1. Specifically, FIGS. 66, 69, 72, 78, 83, 89, 91, 95, 100 and 107 are plan views. FIGS. 67, 70, 73, 76, 79, 82, 84, 87, 92, 97, 101, 104, 108 and 113 are cross-sectional views taken along lines A-A′ of corresponding plan views, respectively. FIGS. 74, 77, 80, 85, 88, 90, 93, 94, 98, 102, 105 and 109 are cross-sectional views taken along lines B-B′ of corresponding plan views, respectively. FIGS. 68, 71, 75, 81, 86, 96, 99, 103, 106, 110, 111 and 112 are cross-sectional views taken along lines C-C′ of corresponding plan views, respectively.

Referring to FIGS. 66 to 68, an active pattern 2101 may be disposed on a first substrate 2100 including first and second regions I_2 and II_2.

The first substrate 2100 may include silicon, germanium, silicon-germanium, or a III-V group compound semiconductor, such as GaP, GaAs, or GaSb. In example embodiments, the first substrate 2100 may be a silicon-on-insulator (SOI) substrate or a germanium-on-insulator (GOI) substrate.

The first region I_2 of the first substrate 2100 may be a cell array region on which memory cells are formed, and the second region II_2 of the first substrate 2100 may be an extension region on which upper contact plugs that transmit electrical signals to memory cells are formed. The first and second regions I_2 and II_2 may collectively form a cell region.

The active patterns 2101 may be formed by removing an upper portion of the first substrate 2100 to form a recess structure.

In example embodiments, the active pattern 2101 may extend in the third direction D3_3 on the first region I_2 of the first substrate 2100 and the second region II_2 adjacent thereto of the first substrate 2100, and a plurality of active patterns 2101 may be spaced apart from each other in each of the first and second directions D1_2 and D2_2.

The recess structure may include first, second and third recesses 2102, 2104 and 2106. The first recess 2102 may be formed between ones of the active patterns 2101 spaced apart from each other by a relatively small distance, the second recess 2104 may be formed between ones of the active patterns 2101 spaced apart from each other by a relatively large distance, and the third recess 2106 may be formed on a portion of the second region II_2 except for a portion of the second region I_2 adjacent to the first region I_2 of the first substrate 2100

In example embodiments, the third recess 2106 may have a width and/or a depth greater than a width and/or a depth of the second recess 2104, and the second recess 2104 may have a width and/or a depth greater than a width and/or a depth of the first recess 2102.

An isolation structure 2110 may be formed to cover sidewalls of the active patterns 2101.

In example embodiments, the isolation structure 2110 may include first, second and third isolation patterns 2112, 2114 and 2116 sequentially stacked on an inner wall of the third recess 2106. However, the first and second isolation patterns 2112 and 2114 may be formed in the second recess 2104 having a width smaller than that of the third recess 2106, and only the first isolation pattern 2112 may be formed in the first recess 2102 having a width smaller than that of the second recess 2104.

Referring to FIGS. 69 to 71, an etching process may be performed on the active pattern 2101 and the isolation structure 2110 on the first region I_2 of the first substrate 2100 to form a fourth recess 40.

In example embodiments, during the etching process, the active pattern 2101 including a semiconductor material may be less etched than the isolation structure 2110 including an insulating material due to the etching selectivity. Thus, the fourth recess 40 may have a concave upper surface on an upper surface of the active pattern 2101.

A first gate insulation layer and a first conductive layer may be sequentially stacked on an inner wall of the fourth recess 40 and upper surfaces of the active patterns 2101 and the isolation structure 2110, the first gate insulation layer and the first conductive layer may be planarized until the upper surfaces of the active patterns 2101 and the isolation structure 2110 are exposed, and an upper portion of the first conductive layer may be removed by, e.g., an etch back process.

The planarization process may include a chemical mechanical polishing (CMP) process and/or an etch back process.

By the planarization process, a first gate insulation pattern 2120 may be formed on the inner wall of the fourth recess 40, and by the etch back process, a first conductive pattern 2140 may be formed on the first gate insulation pattern 2120 to fill a lower portion of the fourth recess 40.

A second conductive pattern 2150 may be formed on the first conductive pattern 2140, a first gate mask layer may be formed on the second conductive pattern 2150, the active patterns 2101 and the isolation structure 2110 to fill the fourth recess 40, and the first gate mask layer may be planarized until the upper surfaces of the active patterns 2101 and the isolation structure 2110 are exposed, so that a first gate mask 2160 may be formed to fill an upper portion of the fourth recess 40. The first conductive pattern 2140 and the second conductive pattern 2150 may collectively form a gate electrode, and a first barrier pattern may be further formed between the first gate insulation pattern 2120 and the first conductive pattern 2140.

Referring to FIGS. 72 to 75, an insulation layer structure 2210 may be formed on the first and second regions I_2 and II_2 of the first substrate 2100, and a portion of the insulation layer structure 2210 on a portion of the second region II_2 except for a portion of the second region I_2 adjacent to the first region I_2 of the first substrate 2100 may be removed.

The insulation layer structure 2210 may be patterned, and the active pattern 2101, the isolation structure 2110, and the first gate mask 2160 of the first gate structure 2170 may be partially etched using the patterned insulation layer structure 2210 as an etching mask to form a first opening 2230.

In example embodiments, the patterned insulation layer structure 2210 may have a shape of a circle or an ellipse in a plan view on the first region I_2 of the first substrate 2100, and a plurality of insulation layer structures 2210 may be spaced apart from each other in the first and second directions D1_2 and D2_2. Each of the insulation layer structures 2210 may overlap in the vertical direction opposite end portions in the third direction D3_2 of adjacent ones of the active patterns 2101. In example embodiments, the insulation layer structure 2210 remaining on the second region II_2 of the first substrate 2100 may have a shape of a rectangle in a plan view.

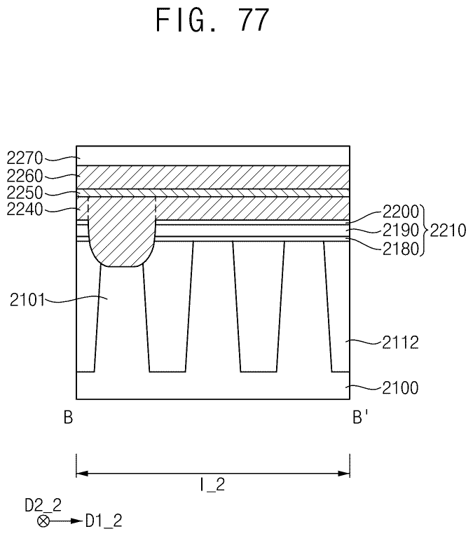

Referring to FIGS. 76 and 77, a third conductive layer 2240, a second barrier layer 2250, a fourth conductive layer 2260 and a first mask layer 2270 may be sequentially stacked on the insulation layer structure 2210, and the upper surfaces of the active pattern 2101, the isolation structure 2110 and the gate structure 2170 exposed by the first opening 2230 on the first region I_2 of the first substrate 2100, and the insulation layer structure 2210, the isolation structure 2110 and the first substrate 2100 on the second region II_2 of the first substrate 2100. The third conductive layer 2240, the second barrier layer 2250, the fourth conductive layer 2260 and the first mask layer 2270 may collectively form a conductive structure layer. The third conductive layer 2240 may fill the first opening 2230.

The third conductive layer 2240 may include doped polysilicon, the second barrier layer 2250 may include a metal silicon nitride, e.g., titanium silicon nitride, the fourth conductive layer 2260 may include a metal, e.g., tungsten, and the first mask layer 2270 may include a nitride, e.g., silicon nitride.

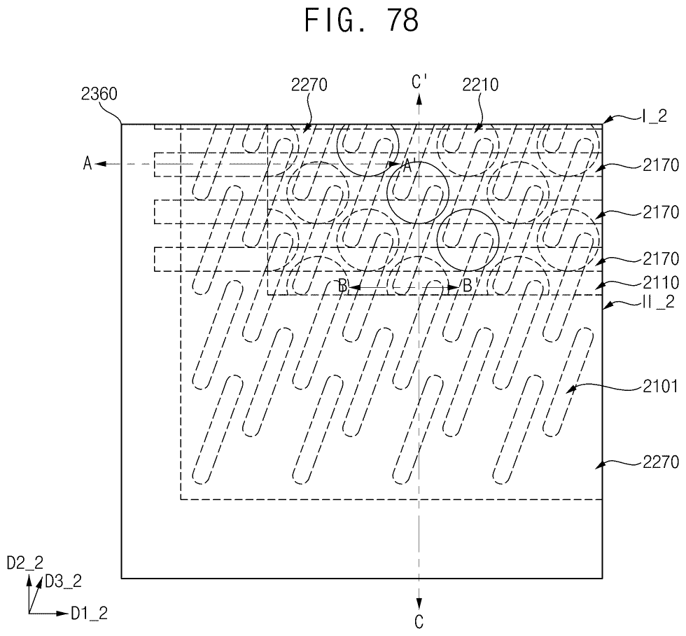

Referring to FIGS. 78 to 81, the conductive structure layer may be patterned to remove the conductive structure layer formed on a portion of the second region II_2 except for a portion of the second region I_2 adjacent to the first region I_2 of the first substrate 2100.

A first spacer structure may be formed on sidewalls of the remaining conductive structure layer. The first spacer structure may include first and second spacers 2345 and 2355 sequentially stacked from the sidewalls of the conductive structure layer along the horizontal direction.

The first spacer 2345 may be formed by forming a first spacer layer on the first substrate 2100 on which the conductive structure layer is formed and anisotropically etching the first spacer layer, and the second spacer 2355 may be formed by forming a second spacer layer on the first substrate 2100 on which the conductive structure layer and the first spacer 2345 are formed and anisotropically etching the second spacer layer.

The first spacer 2345 may include, for example, a nitride such as silicon nitride, and the second spacer 2355 may include, for example, an oxide such as silicon oxide.

However, the configuration of the first spacer structure is not limited thereto, and may include only a single spacer or may have a configuration in which three or more spacers are stacked.

A first etch stop layer 2360 may be formed on the first substrate 2100 on which the conductive structure layer, the first spacer structure, and the isolation structure 2110 are formed. The first etch stop layer 2360 may include, for example, a nitride such as silicon nitride.

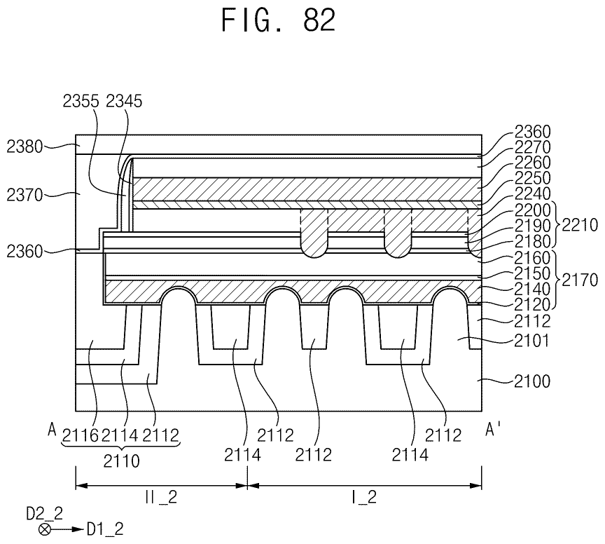

Referring to FIG. 82, a first insulating interlayer 2370 may be formed on the first etch stop layer 2360 to a sufficient height, the first insulating interlayer 2370 may be planarized until an upper surface of a portion of the first etch stop layer 2360 on the conductive structure layer are exposed, and a capping layer 2380 may be formed on the first insulating interlayer 2370 and the first etch stop layer 2360.

The first insulating interlayer 2370 may include an oxide, e.g., silicon oxide, and the capping layer 2380 may include a nitride, e.g., silicon nitride.

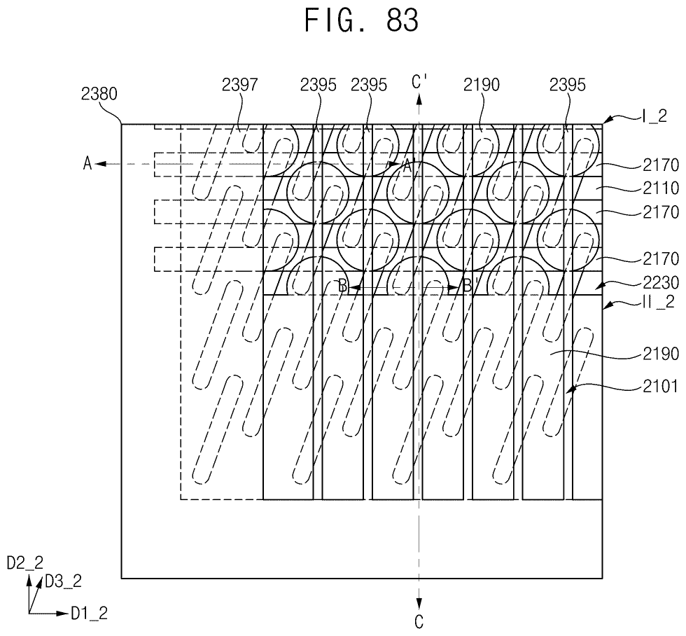

Referring to FIGS. 83 to 86, a portion of the capping layer 2380 on the first and second regions I_2 and II_2 of the first substrate 2100 may be etched to form a capping pattern 2385, and the first etch stop layer 2360, the first mask layer 2270, the fourth conductive layer 2260, the second barrier layer 2250 and the third conductive layer 2240 may be sequentially etched using the capping pattern 2385 as an etching mask.

In example embodiments, the capping pattern 2385 may extend in the second direction D2_2 on the first region I_2 and the second region II_2 adjacent thereto of the first substrate 2100, and a plurality of capping patterns 2385 may be formed to be spaced apart from each other in the first direction D1_2. The capping layer 2380 may remain on a portion the second region II_2 of the first substrate 2100.

By the etching process, on the first region I_2 and the second region II_2 adjacent thereto of the first substrate 2100, a third conductive pattern 2245, a second barrier pattern 2255, a fourth conductive pattern 2265, a first mask 2275, a first etch stop pattern 2365 and the capping pattern 2385 may be sequentially stacked on the first opening 2230, and a third insulation pattern 2205, the third conductive pattern 2245, the second barrier pattern 2255, the fourth conductive pattern 2265, the first mask 2275, the first etch stop pattern 2365 and the capping pattern 2385 may be sequentially stacked on the second insulation layer 2190 of the insulation layer structure 2210 at an outside of the first opening 2230.

Hereinafter, the third conductive pattern 2245, the second barrier pattern 2255, the fourth conductive pattern 2265, the first mask 2275, the first etch stop pattern 2365 and the capping pattern 2385 sequentially stacked may be referred to as a bit line structure 2395. In example embodiments, the bit line structure 2395 may extend in the second direction D2_2 on the first and second regions I_2 and II_2 adjacent thereto of the first substrate 2100, and a plurality of bit line structures 2395 may be spaced apart from each other in the first direction D1_2.

A dummy bit line structure 2397 may be formed on the second region II_2 adjacent to the first region I_2 of the first substrate 2100 in the first direction D1_2, the dummy bit line structure 2397 including a fifth conductive pattern 2247, a third barrier pattern 2257, a sixth conductive pattern 2267, a second mask 2277, a second etch stop pattern 2367, and a second capping pattern 2387 sequentially stacked and extending in the second direction D2_2.

Here, the first etch stop layer 2360 may remain on the first spacer structure, a portion of the insulation layer structure 2210, and the isolation structure 2110.

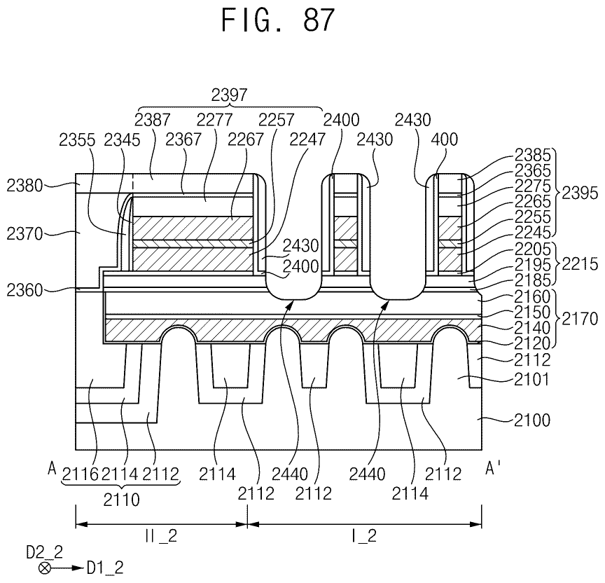

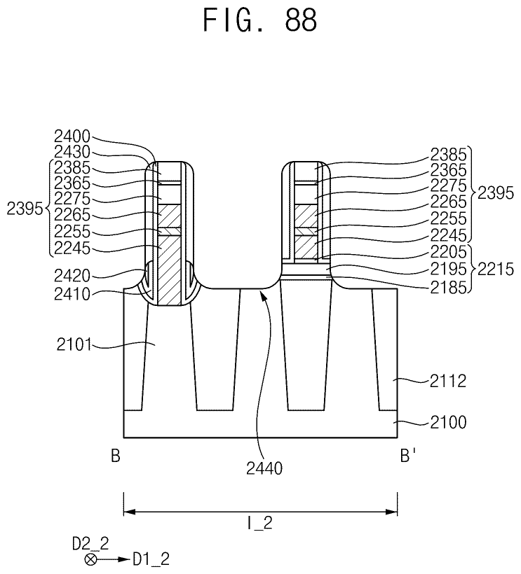

Referring to FIGS. 87 and 88, a third spacer layer may be formed on the bit line structure 2395, the dummy bit line structure 2397, and the capping layer 2380 on the first substrate 2100, and fourth and fifth fourth insulation layers may be formed on the third spacer layer.

The third spacer layer may also cover a sidewall of the third insulation pattern 2205 between the second insulation layer 2190 and the bit line structure 2395, and the fifth insulation pattern 2420 may fill the remaining portion of the first opening 2230.

The third spacer layer may include an insulating nitride, e.g., silicon nitride, the fourth insulation layer may include an oxide, e.g., silicon oxide, or a carbonate, e.g., silicon carbonate, the fifth insulation layer may include an insulating nitride, e.g., silicon nitride.

Thereafter, an etching process may be performed to etch the fourth and fifth insulation layers. In example embodiments, the etching process may be performed by a wet etch process using an etching solution including, for example, phosphoric acid (H₃PO₄), SC1, and hydrofluoric acid (HF), and other portions of the fourth and fifth insulation layers except for portions formed in the first opening 2230 may be removed. Thus, most of an entire surface of the third spacer layer, that is, an entire surface except for a portion thereof formed in the first opening 2230 may be exposed, and portions of the fourth and fifth insulation layers remaining in the first opening 2230 may form fourth and fifth insulation patterns 2410 and 2420, respectively.

Thereafter, a fourth spacer layer may be formed on the exposed third spacer layer surface and the fourth and fifth insulation patterns 2410 and 2420 formed in the first opening 2230, and anisotropically etched to form a fourth spacer 2430 covering sidewalls of the bit line structure 2395 on the third spacer layer and the fourth and fifth insulation patterns 2410 and 2420. The fourth spacer 2430 may also be formed on a sidewall of the dummy bit line structure 2397. The fourth spacer 2430 may include, for example, an oxide such as silicon oxide.

For example, a dry etching process may be additionally performed to form a second opening 2440 exposing an upper surface of the active pattern 2101 on the first region I_2 of the first substrate 2100. The second opening 2440 may also expose an upper surface of the isolation structure 2110 and an upper surface of the first gate mask 2160.

By the dry etching process, a portion of the third spacer layer formed on upper surfaces of the capping layer 2380, the first and second capping patterns 2385 and 2387, and the second insulation layer 2190 may be removed, and accordingly, a third spacer 2400 covering sidewalls of the bit line structure 2395 may be formed. The third spacer 2400 may also cover sidewalls of the dummy bit line structure 2397.

Further, in the dry etching process, the first and second insulation layers 2180 and 2190 may also be partially removed to remain as first and second insulation patterns 2185 and 2195, respectively, below the bit line structure 2395. The first to third insulation patterns 2185, 2195 and 2205 sequentially stacked below the bit line structure 2395 may together form an insulation pattern structure 2215.

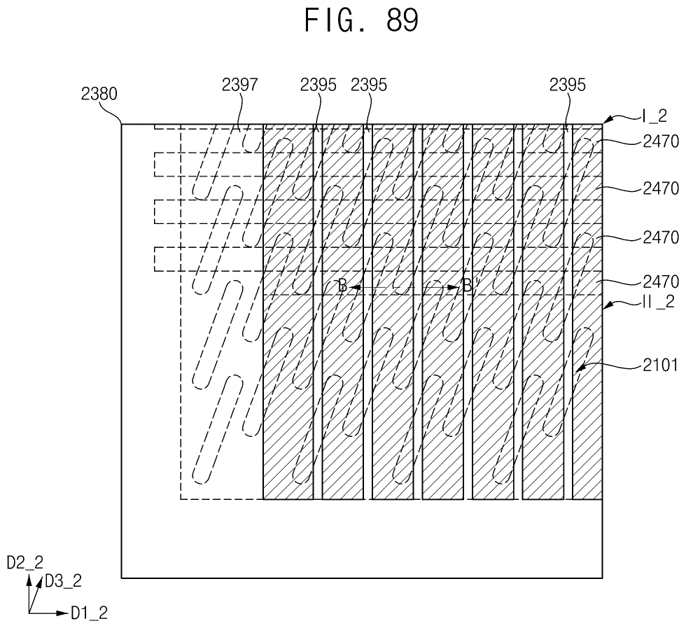

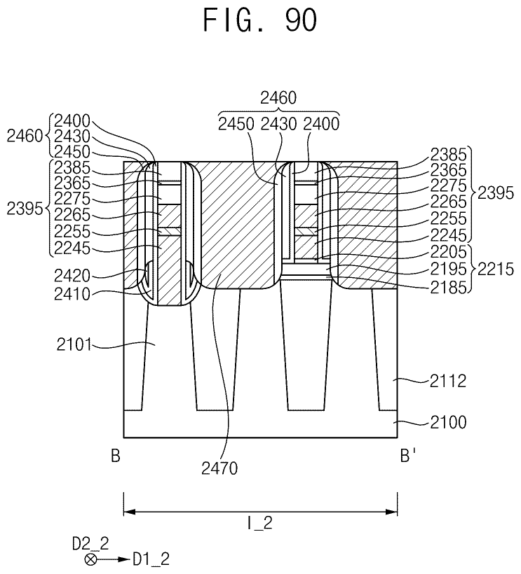

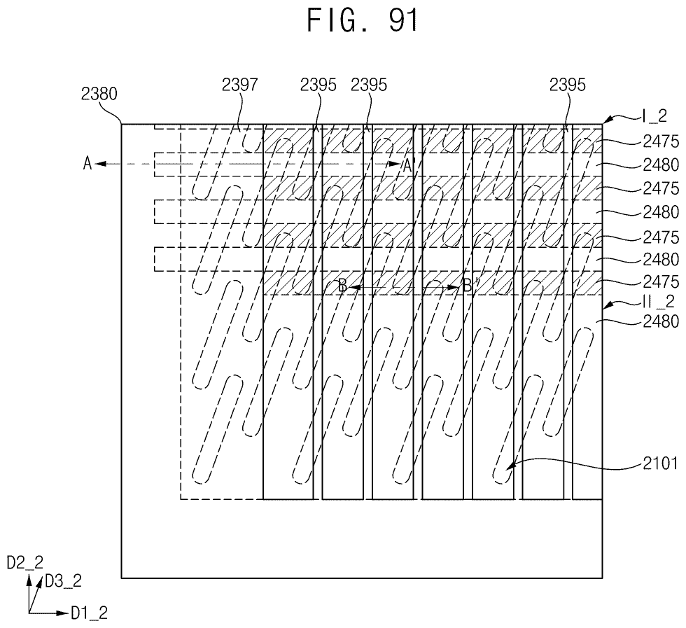

Referring to FIGS. 89 and 90, a fifth spacer layer may be formed on upper surfaces of the capping layer 2380 and the first and second capping patterns 2385 and 2387, an outer sidewall of the fourth spacer 2430, portions of upper surfaces of the fourth and fifth insulation patterns 2410 and 2420 and the upper surfaces of the active pattern 2101, the isolation structure 2110, and the first gate mask 2160 exposed by the second opening 2440, and the fifth spacer layer may be anisotropically etched to form a fifth spacer 2450 covering outer sidewalls of the fourth spacer 2430 formed on sidewalls of the bit line structure 2395 and the dummy bit line structure 2397. The fifth spacer 2450 may include, for example, a nitride such as silicon nitride.

The third to fifth spacers 2400, 2430 and 2450 sequentially stacked along the horizontal direction on sidewalls of the bit line structure 2395 on the first and second regions I_2 and II_2 of the first substrate 2100 may together be referred to as a preliminary second spacer structure 2460.

A first contact plug layer 2470 filling the second opening 2440 may be formed to a sufficient height on the first region I_2 of the first substrate 2100, and an upper portion of the first contact plug layer 2470 may be planarized until upper surfaces of the capping layer 2380 and the first and second capping patterns 2385 and 2387 are exposed.

The first contact plug layer 2470 may be formed between the bit line structures 2395 neighboring each other in the first direction D1_2 and between the bit line structure 2395 and the dummy bit line structure 2397 on the first region I_2 of the first substrate 2100 and a portion of the second region II_2 adjacent to the first region I_2 of the first substrate 2100 in the second direction D2_2, and may extend in the second direction D2_2. A plurality of first contact plug layers 2470 may be spaced apart from each other along the first direction D1_2. Each of the first contact plug layers 2470 may contact upper surfaces of respective end portions in the third direction D3_2 of the active pattern 2101 extending in the third direction D3_2.

Referring to FIGS. 91 to 93, an etching mask having third openings respectively extending in the first direction D1_2 and spaced apart from each other in the second direction D2_2 may be formed on the capping layer 2380, the bit line structure 2395, the dummy bit line structure 2397, and the first contact plug 2475, and an etching process using the etching mask may be performed on the first contact plug layer 2470 to form a fourth opening 2445.

In example embodiments, the third opening may overlap with the gate structure 2170 along the vertical direction on the first region I_2 of the first substrate 2100, and may overlap with a portion of the first contact plug layer 2470 formed on the second region II_2 of the first substrate 2100 in the vertical direction. Accordingly, the fourth opening 2445 may be formed to expose an upper surface of the first gate mask 2160 included in the gate structure 2170 on the first region I_2 of the first substrate 2100 and an upper surface of the second insulation layer 2190 on the second region II_2 of the first substrate 2100. As the fourth opening 2445 is formed, the first contact plug layer 2470 extending in the second direction D2_2 on the first region I_2 of the first substrate 2100 may be separated into a plurality of first contact plugs 2475 spaced apart from each other in the second direction D2_2.

After removing the etching mask, a fence pattern 2480 filling the fourth opening 2445 may be formed. On the first region I_2 of the first substrate 2100, a plurality of fence patterns 2480 may be formed between the bit line structures 2395 neighboring each other in the first direction D1_2 and between the bit line structure 2395 and the dummy bit line structure 2397 to be spaced apart from each other along the second direction D2_2. On the second region II_2 of the first substrate 2100, a plurality of fence patterns 2480 may be formed between the bit line structures 2395 neighboring each other in the first direction D1_2 and between the bit line structure 2395 and the dummy bit line structure 2397 to extend along the second direction D2_2.

As described above, the first contact plugs 2475 and the fence patterns 2480 that may be alternately and repeatedly arranged in the second direction D2_2 may be formed by forming the first contact plug layer 2470 extending in the second direction D2_2 between the bit line structures 2395 neighboring each other in the first direction D1_2, planarizing an upper portion of the first contact plug layer 2470, forming the fourth openings 2445 through the first contact plug layer 2470 that are spaced apart from each other along the second direction D2_2, and forming the fence pattern 2480 filling the fourth openings 2445, however, the inventive concepts may not be limited thereto.

That is, in another embodiment, the first contact plugs 2475 and the fence patterns 2480 that may be alternately and repeatedly arranged along the second direction D2_2 may be formed by forming a fence layer extending in the second direction D2_2 between the bit line structures 2395 neighboring each other in the first direction D1_2, forming fifth openings through the fence layer that are spaced apart from each other along the second direction D2_2 to divide the fence layer into fence patterns 2480 spaced apart from each other in the second direction D2_2, forming the first contact plug layer 2470 filling the fifth openings, and planarizing an upper portion thereof to form the first contact plugs 2475.

In yet another embodiment, the first contact plugs 2475 and the fence patterns 2480 that may be alternately and repeatedly arranged along the second direction D2_2 may be formed by forming a sacrificial layer extending in the second direction D2_2 between the bit line structures 2395 neighboring each other in the first direction D1_2 and including an oxide such as silicon oxide, forming fence patterns 2480 through the sacrificial layer that are spaced apart from each other along the second direction D2_2, removing the remaining sacrificial layer to form sixth openings, forming the first contact plug layer 2470 filling the sixth openings, and planarizing an upper portion thereof to form the first contact plugs 2475.

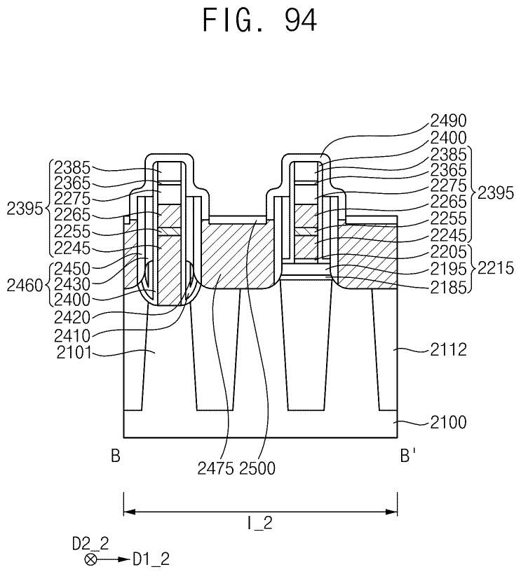

Referring to FIG. 94, an upper portion of the first contact plug 2475 may be removed to expose an upper portion of the preliminary second spacer structure 2460 formed on sidewalls of the bit line structure 2395 and the dummy bit line structure 2397, and upper portions of the fourth and fifth spacers 2430 and 2450 of the exposed preliminary second spacer structure 2460 may be removed.

An upper portion of the first contact plug 2475 may be additionally removed. Accordingly, an upper surface of the first contact plug 2475 may be lower than upper surfaces of the fourth and fifth spacers 2430 and 2450.

Thereafter, a sixth spacer layer may be formed on the bit line structure 2395, the dummy bit line structure 2397, the preliminary second spacer structure 2460, the fence pattern 2480, the capping layer 2380, and the first contact plug 2475 and anisotropically etched to form a sixth spacer 2490 covering upper portions of the preliminary second spacer structure 2460 formed on respective sidewalls in the first direction D1_2 of the bit line structure 2395. Accordingly, an upper surface of the first contact plug 2475 may be exposed.

An ohmic contact pattern 2500 may be formed on the exposed upper surface of the first contact plug 2475. In example embodiments, the ohmic contact pattern 2500 may be formed by forming a first metal layer on the first and second capping patterns 2385, 2387, the fence pattern 2480, the capping layer 2380, the sixth spacer 2490, and the first contact plug 2475, thermally treating the first metal layer, and removing an unreacted portion of the first metal layer. The ohmic contact pattern 2500 may include a metal silicide, e.g., cobalt silicide, nickel silicide, titanium silicide, etc.

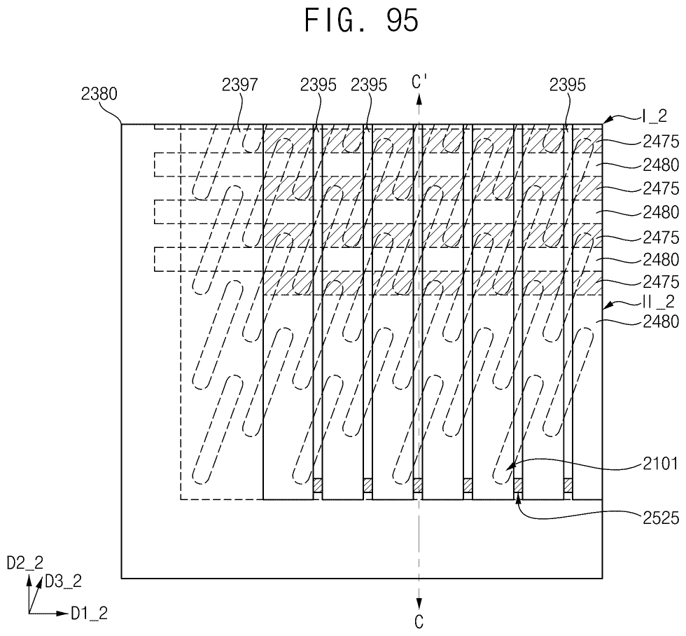

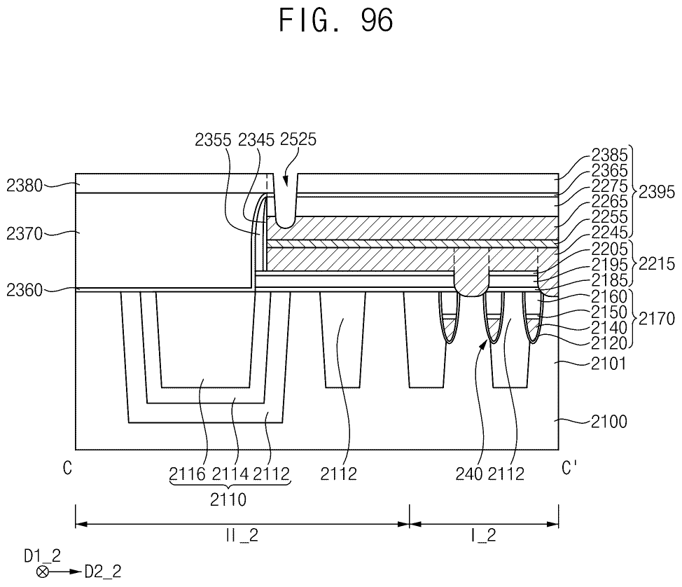

Referring to FIGS. 95 and 96, a seventh opening 2525 may be formed to extend through the first capping pattern 2385, the first etch stop pattern 2365, and the first mask 2275 formed on a portion of the second region II_2 of the first substrate 2100 adjacent to the first region I_2 of the first substrate 2100 in the second direction D2_2 to expose the sixth conductive pattern 2265.

In example embodiments, the seventh opening 2525 may be formed to overlap with an end in the second direction D2_2 of each bit line structure 2395 in the vertical direction. Accordingly, a plurality of seventh openings 2525 may be formed to be spaced apart from each other in the first direction D1_2 on the second region II_2 of the first substrate 2100. Meanwhile, although the seventh openings 2525 are shown aligned in the first direction D1_2 in the drawings, the inventive concepts are not limited thereto and may be arranged in various layouts.

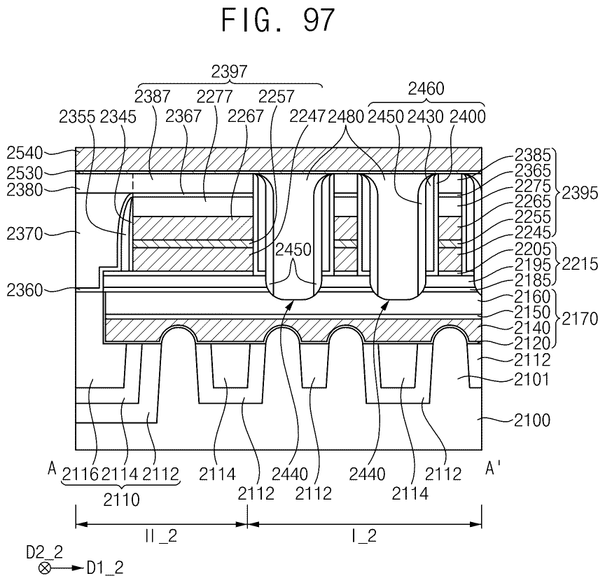

Referring to FIGS. 97 to 99, a fourth barrier layer 2530 may be formed on the first and second capping patterns 2385 and 2387, the fence pattern 2480, the sixth spacer 2490, the ohmic contact pattern 2500, the first contact plug 2475, sidewalls of the seventh opening 2525 and the fourth conductive pattern 2265 exposed thereby, and the capping layer 2380, and a second metal layer 2540 may be formed on the fourth barrier layer 2530 to fill spaces between the bit line structures 2395, spaces between the bit line structure 2395 and the dummy bit line structure 2397, and the seventh openings 2525.

Referring to FIGS. 100 to 103, the second metal layer 2540 and the fourth barrier layer 2530 may be patterned.

Accordingly, a second contact plug 2549 may be formed on the first region I_2 of the first substrate 2100, and a first wiring 2605 may be formed on a portion of the second region II_2 of the first substrate 2100 adjacent to the first region I_2 of the first substrate 2100 in the first direction D1_2. An eighth opening 2547 may be formed between the second contact plug 2549 and the first wirings 2605.

The eighth opening 2547 may be formed by partially removing not only the second metal layer 2540 and the fourth barrier layer 2530, but also the first and second capping patterns 2385 and 2387, the fence pattern 2480, the capping layer 2380, the preliminary second spacer structure 2460, the sixth spacer 2490, the first etch stop layer 2360, the first etch stop pattern 2365, and the first and second masks 2275 and 2277, and accordingly may expose an upper surface of the fourth spacer 2430.

As the eighth opening 2547 is formed, the second metal layer 2540 and the fourth barrier layer 2530 on the first region I_2 of the first substrate 2100 may be converted to a first metal pattern 2545 and a fourth barrier pattern 2535 covering a lower surface thereof, respectively, and they may together form a second contact plug 2549. In example embodiments, a plurality of second contact plugs 2549 may be formed to be spaced apart from each other along each of the first and second directions D1_2 and D2_2 on the first region I_2 of the first substrate 2100, and may be arranged in a honeycomb pattern when viewed from above. Each of the second contact plugs 2549 may have, for example, a circular, elliptical, or polygonal shape when viewed from the top surface. The first contact plug 2475, the ohmic contact pattern 2500, and the second contact plug 2549 sequentially stacked on the first region I_2 of the first substrate 2100 may together form a first contact plug structure.

Additionally, as the eighth opening 2547 is formed, a third contact plug 2575 including a second metal pattern 2565 and a fifth barrier pattern 2555 may be formed in the seventh opening 2520 on the second region II_2 of the first substrate 2100, and a first wiring 2605 including a third metal pattern 2595 and a sixth barrier pattern 2585 covering a lower surface thereof may be formed on the third contact plug 2575.

In example embodiments, the first wiring 2605 may be formed to overlap with the seventh opening 2525 in the vertical direction, and accordingly, a plurality of first wirings 2605 may be formed to be spaced apart from each other in the second direction D2_2. The first wiring 2605 may contact the fourth conductive pattern 2265 through the third contact plug 2575, and accordingly may apply electrical signals to the bit line structure 2395.

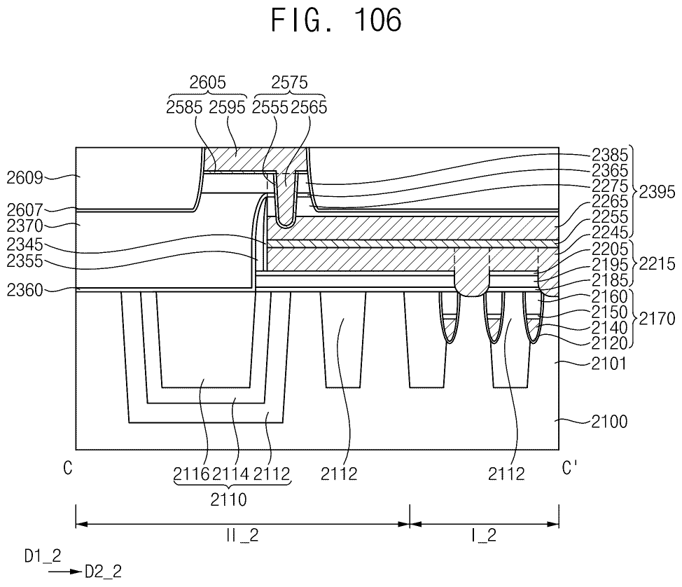

Referring to FIGS. 104 to 106, the exposed fourth spacer 2430 may be removed to form an air gap 2435 connected with the eighth opening 2547. The sixth spacer 2430 may be removed by, for example, a wet etching process.

In example embodiments, the fourth spacer 2430 formed on sidewalls of the bit line structure 2395 and the dummy bit line structure 2397 extending in the second direction D2_2 may be removed not only from portions directly exposed by the eighth opening 2547, but also from portions parallel to the exposed portions in the horizontal direction. That is, not only portions of the fourth spacer 2430 exposed by the eighth opening 2547 and not covered by the second contact plug 2549, but also portions covered by the second contact plug 2549 may all be removed.

Thereafter, a second insulating interlayer filling the eighth opening 2547 may be formed.

In example embodiments, the second insulating interlayer may include sixth and seventh insulation patterns 2607 and 2609 sequentially stacked. The sixth insulation pattern 2607 may be formed using an insulating material having low gap-fill characteristics, and accordingly, the air gap 2435 below the eighth opening 2547 may remain without being filled. The air gap 2435 may also be referred to as an air spacer 2435, and may form a second spacer structure 2465 together with the third and fifth spacers 2400 and 2450. That is, the air gap 2435 may be a spacer including air. The seventh insulation pattern 2609 may include, for example, an oxide such as silicon oxide or a nitride such as silicon nitride.

Referring to FIGS. 107 to 110, a second etch stop layer 2610 and a mold layer (not shown) may be sequentially formed on the second contact plug 2549, the first wiring 2605, and the sixth and seventh insulation patterns 2607 and 2609.

Thereafter, the second etch stop layer 2610 may be formed on the mold layer, and the second etch stop layer 2610 and the mold layer may be partially etched to form a tenth opening partially exposing an upper surface of the second contact plug 2549.

A lower electrode layer filling the tenth opening may be formed on the exposed upper surface of the second contact plug 2549 and the mold layer, and the lower electrode layer may be separated by planarizing an upper portion of the lower electrode layer until an upper surface of the mold layer is exposed. Thereafter, the mold layer may be removed by, for example, performing a wet etching process, and accordingly, a pillar-shaped lower electrode 2620 may be formed on the exposed upper surface of the second contact plug 2549. Alternatively, a cylindrical lower electrode 2620 may be formed in the tenth opening.

Thereafter, a dielectric layer 2630 may be formed on a surface of the lower electrode 2620 and the second etch stop layer 2610, and an upper electrode 2640 may be formed on the dielectric layer 2630, thereby forming a capacitor 2650 including the lower electrode 2620, the dielectric layer 2630, and the upper electrode 2640 on the first region I_2 of the first substrate 2100. The dielectric layer 2630 and the upper electrode 2640 formed on the second region II_2 of the first substrate 2100 may be removed.

A third insulating interlayer 2655 covering the capacitor 2650 may be formed, and a first handling substrate 2010 may be bonded on the third insulating interlayer 2655 via a third bonding layer (not shown). The first handling substrate 2010 may include, for example, a semiconductor material such as silicon, or an insulating material such as glass. The third bonding layer may include, for example, silicon carbonitride, silicon oxide, etc.

Meanwhile, the first substrate 2100 and structures formed between the first substrate 2100 and the first handling substrate 10 may together form a cell structure CS_2.

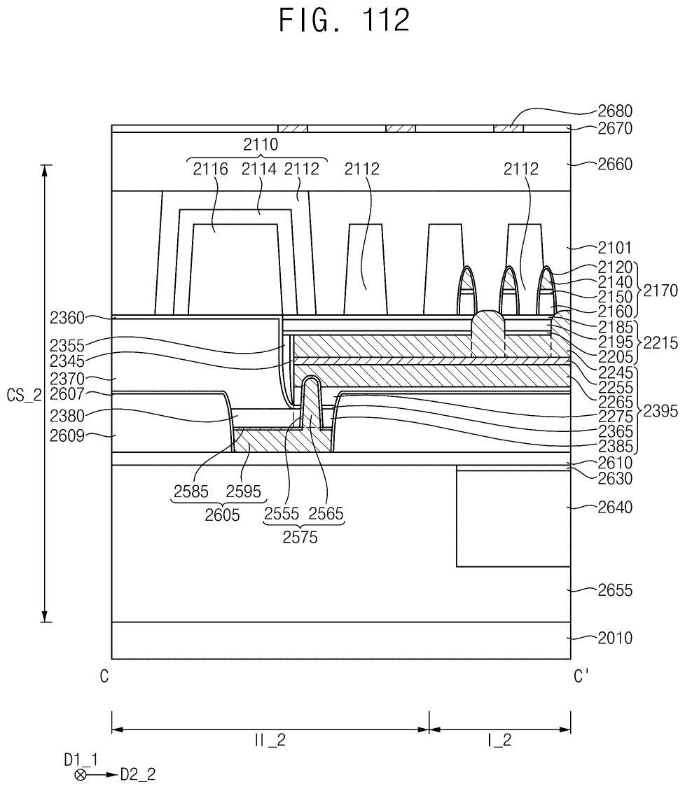

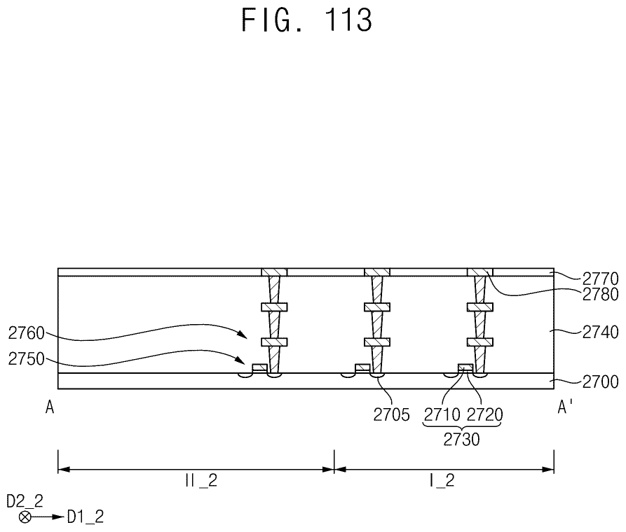

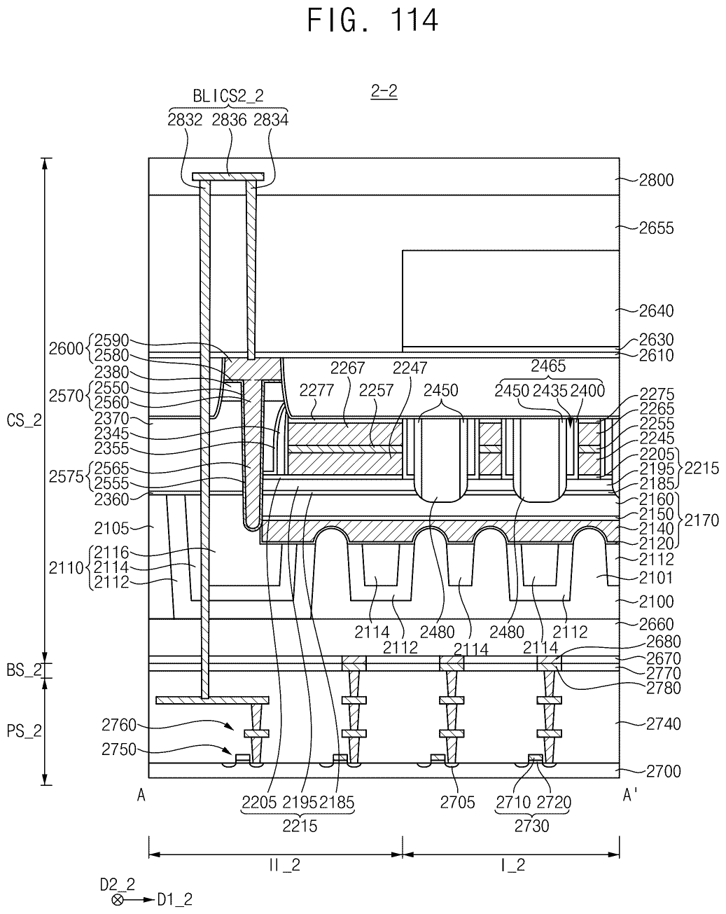

Referring to FIGS. 111 and 112, the first handling substrate 2010 may be flipped. Accordingly, since structures formed on the first substrate 2100 are flipped upside down, the following description will be based on this orientation.

An upper portion of the first substrate 2100 may be removed through, for example, a grinding process, and accordingly, an upper surface of the isolation structure 2110 may be exposed. During the grinding process, the isolation structure 2110 may serve as a grinding endpoint.

A fourth insulating interlayer 2660 and a first word line wiring structure WLICS1_2 accommodated therein may be formed on the first substrate 2100 and the isolation structure 2110, and a first bonding layer 2670 and a first bonding pad 2680 accommodated therein may be formed on the fourth insulating interlayer 2660.

Referring to FIG. 113, peripheral circuit patterns 2750 such as transistors including, for example, a second gate structure 2730 and source/drain layers 2705, a wiring structure 2760 including contact plugs, wirings, vias, and pads, and a fifth insulating interlayer 2740 covering the peripheral circuit patterns 2750 and the wiring structure 2760 may be formed on a second substrate 2700 including first and second regions I_2 and II_2 corresponding to the first and second regions I_2 and II_2 of the first substrate 2100, respectively. A second bonding layer 2770 may be formed on the fifth insulating interlayer 2740, and second bonding pads 2780 may be formed to extend therethrough and respectively contact upper surfaces of the vias.

The second substrate 2700 and structures formed on the second substrate 2700 may together form a peripheral circuit structure PS_2.

Referring again to FIGS. 62 to 65, the first handling substrate 2010 may be flipped again to bond the first and second bonding layers 2670 and 2770 to each other. Accordingly, since structures formed on the first substrate 2100 are flipped upside down, the following description will be based on this orientation.

The first handling substrate 2010 and the third bonding layer may be removed from the third insulating interlayer 2655 through, for example, a grinding process and/or a chemical mechanical polishing (CMP) process.

Thereafter, a sixth insulating interlayer 2800 and a first bit line wiring structure BLICS1_2 accommodated therein may be formed on the third insulating interlayer 2655 to complete the manufacture of the second semiconductor device.

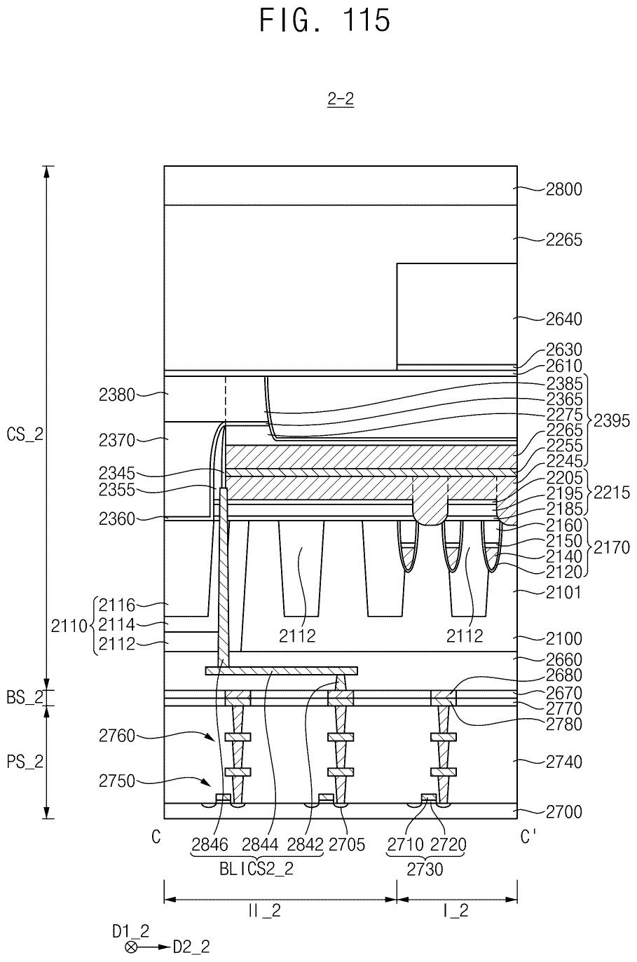

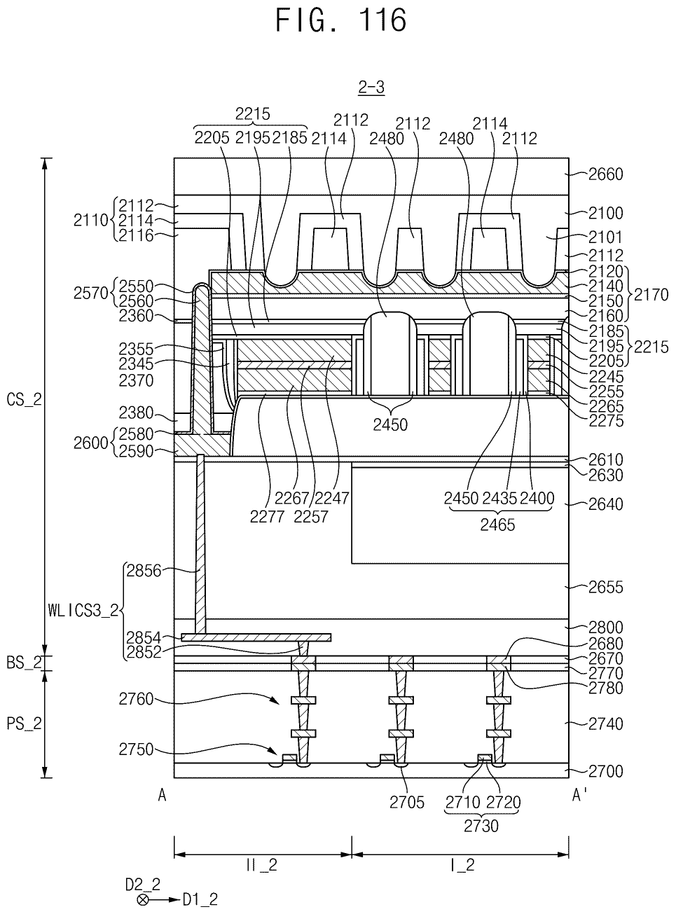

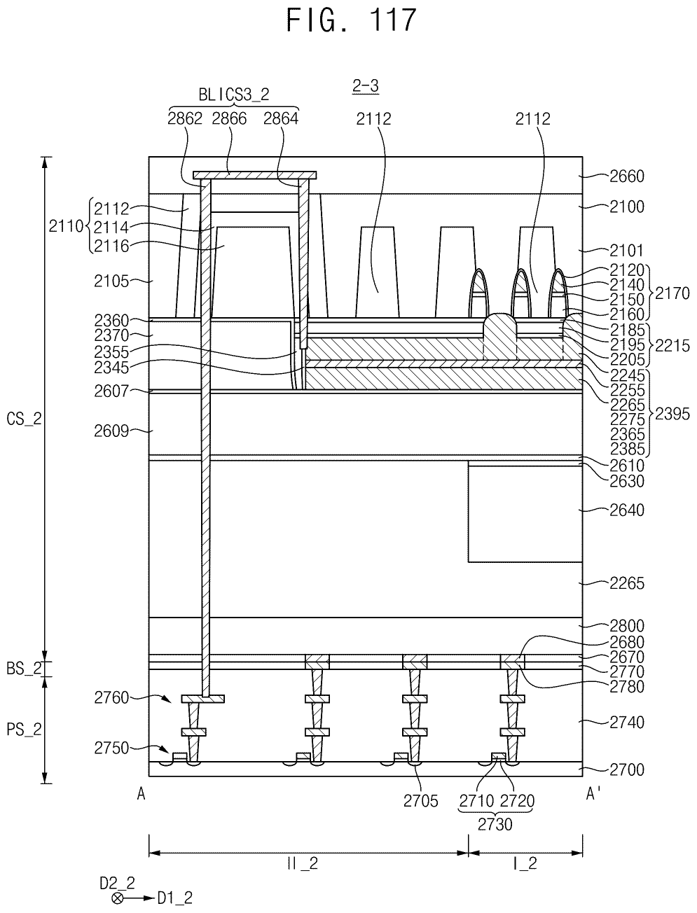

FIGS. 114 and 115 are cross-sectional views illustrating a second semiconductor device in accordance with a second example embodiment 2-2, which may correspond to FIGS. 63 and 65, respectively.

The second example embodiment 2-2 of the second semiconductor device may be substantially the same as or similar to the first example embodiment 2-1 of the second semiconductor device shown in FIGS. 63 and 65, except for including a fourth contact plug 2570 and a second wiring 2600 instead of the third contact plug 2575 and the first wiring 2605, respectively, and including a second word line wiring structure WLICS2_2 and a second bit line wiring structure BLICS2_2 instead of the first word line wiring structure WLICS1_2 and the first bit line wiring structure BLICS1_2, respectively, and thus repeated explanations are omitted herein.

Referring to FIGS. 114 and 115, the fourth contact plug 2570 may extend through the capping layer 2380, the first insulating interlayer 370, the first etch stop layer 2360, the insulation pattern structure 2215, the isolation structure 2110, the first gate mask 2160, and the second conductive pattern 2150 on the second region II_2 to contact the first conductive pattern 140 of the gate structure 2170. Accordingly the fourth contact plug 2570 may apply electrical signals to the gate structure 2170. The fourth contact plug 2570 may include a fourth metal pattern 2560 and a seventh barrier pattern 2550.

The second wiring 2600 may overlap with the fourth contact plug 2570 in the vertical direction, and may include a fifth metal pattern 2590 and an eighth barrier pattern 2580 covering a lower surface thereof.

The second word line wiring structure WLICS2_2 may include a third word line contact 2832, a fourth word line contact 2834, and a second word line wiring 2836.

The third word line contact 2832 may extend through a lower portion of the sixth insulating interlayer 2800, the third insulating interlayer 2655, the second etch stop layer 2610, the second insulating interlayer, the first insulating interlayer 370, the first etch stop layer 2360, the isolation structure 2110, the fourth insulating interlayer 2660, the bonding layer structure, and an upper portion of the fifth insulating interlayer 2740 to contact the pad of the wiring structure 2760. The fourth word line contact 2834 may extend through a lower portion of the sixth insulating interlayer 2800, the third insulating interlayer 2655, and the second etch stop layer 2610 to contact an upper surface of the second wiring 2600. The second word line wiring 2836 may extend in the first direction D1_2 within the sixth insulating interlayer 2800 to commonly contact upper surfaces of the third and fourth word line contacts 2832 and 2834. Meanwhile, the pad of the wiring structure 2760 may serve as a landing pad for the third word line contact 2832.

In example embodiments, a width in the horizontal direction of each of the third and fourth word line contacts 2832 and 2834 may increase away from the second front surface of the second substrate 2700.

The second bit line wiring structure BLICS2_2 may include a third bit line contact 2842, a second bit line wiring 2844, and a fourth bit line contact 2846.

The third bit line contact 2842 may extend through a lower portion of the fourth insulating interlayer 2660 to contact an upper surface of the bonding pad structure. The second bit line wiring 2844 may extend in the second direction D2_2 within the fourth insulating interlayer 2660 to contact an upper surface of the third bit line contact 2842. The fourth bit line contact 2846 may extend through the insulation pattern structure 2215, the isolation structure 2110, and an upper portion of the fourth insulating interlayer 2660 to contact a lower surface of the third conductive pattern 2245 of the bit line structure 2395 and an upper surface of the second bit line wiring 2844.

In example embodiments, a width in the horizontal direction of each of the third and fourth bit line contacts 2842 and 2846 may decrease away from the second front surface of the second substrate 2700.

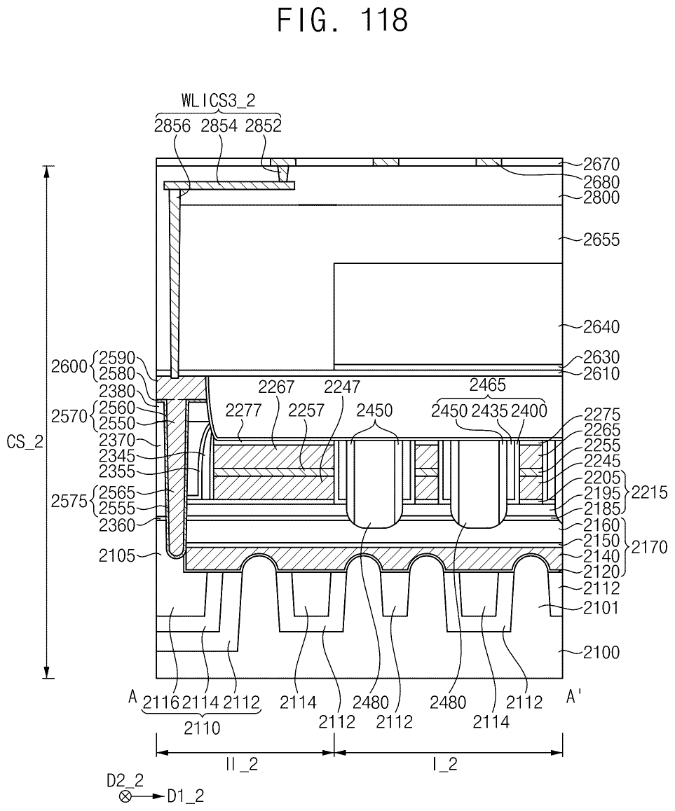

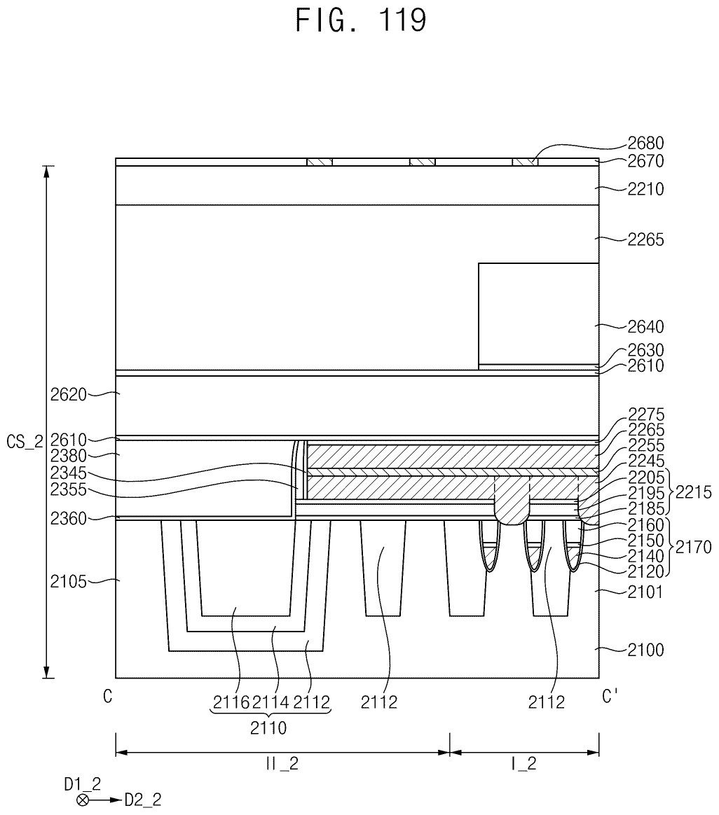

FIGS. 116 and 117 are cross-sectional views illustrating a second semiconductor device in accordance with a third example embodiment 2-3, which may correspond to FIGS. 114 and 115, respectively.

The third example embodiment 2-3 of the second semiconductor device may be substantially the same as or similar to the second example embodiment 2-2 of the second semiconductor device shown in FIGS. 114 and 115, except for the arrangement of the cell structure CS_2 and the peripheral circuit structure PS_2, and including a third word line wiring structure WLICS3_2 and a third bit line wiring structure BLICS3_2 instead of the second word line wiring structure WLICS2_2 and the second bit line wiring structure BLICS2_2, respectively, and thus repeated explanations are omitted herein.

Referring to FIGS. 116 and 117, the third example embodiment 2-3 of the second semiconductor device may have a structure in which the first front surface of the cell structure CS_2 and the second front surface of the second substrate 2700 face each other.

The third word line wiring structure WLICS3_2 may include a fifth word line contact 2852, a sixth word line contact 2856, and a third word line wiring 2854.

The fifth word line contact 2852 may extend through a lower portion of the sixth insulating interlayer 2800 to contact an upper surface of the bonding pad structure. The third word line wiring 2854 may extend in the first direction D1_2 within the sixth insulating interlayer 2800 to contact an upper surface of the fifth word line contact 2852. The sixth word line contact 2856 may extend through the second etch stop layer 2610, the third insulating interlayer 2655, and an upper portion of the sixth insulating interlayer 2800 to contact a lower surface of the second wiring 2600 and an upper surface of the third word line wiring 2854.

In example embodiments, a width in the horizontal direction of each of the fifth and sixth word line contacts 2852 and 2856 may decrease away from the second front surface of the second substrate 2700.

The third bit line wiring structure BLICS3_2 may include a fifth bit line contact 2862, a sixth bit line contact 2864, and a third bit line wiring 2866.

The fifth bit line contact 2862 may extend through a lower portion of the fourth insulating interlayer 2660, the isolation structure 2110, the first etch stop layer 2360, the first insulating interlayer 370, the second insulating interlayer, the second etch stop layer 2610, the third insulating interlayer 2655, the sixth insulating interlayer 2800, the bonding layer structure, and an upper portion of the fifth insulating interlayer 2740 to contact the pad of the wiring structure 2760. The sixth bit line contact 2864 may extend through a lower portion of the fourth insulating interlayer 2660, the isolation structure 2110, and the insulation pattern structure 2215 to contact an upper surface of the third conductive pattern 2245 of the bit line structure 2395. The third bit line wiring 2866 may extend in the second direction D2_2 within the fourth insulating interlayer 2660 to commonly contact upper surfaces of the fifth and sixth bit line contacts 2864 and 2862. Meanwhile, the pad of the wiring structure 2760 may serve as a landing pad for the fifth bit line contact 2862.

In example embodiments, a width in the horizontal direction of each of the fifth and sixth bit line contacts 2864 and 2862 may increase away from the second front surface of the second substrate 2700.

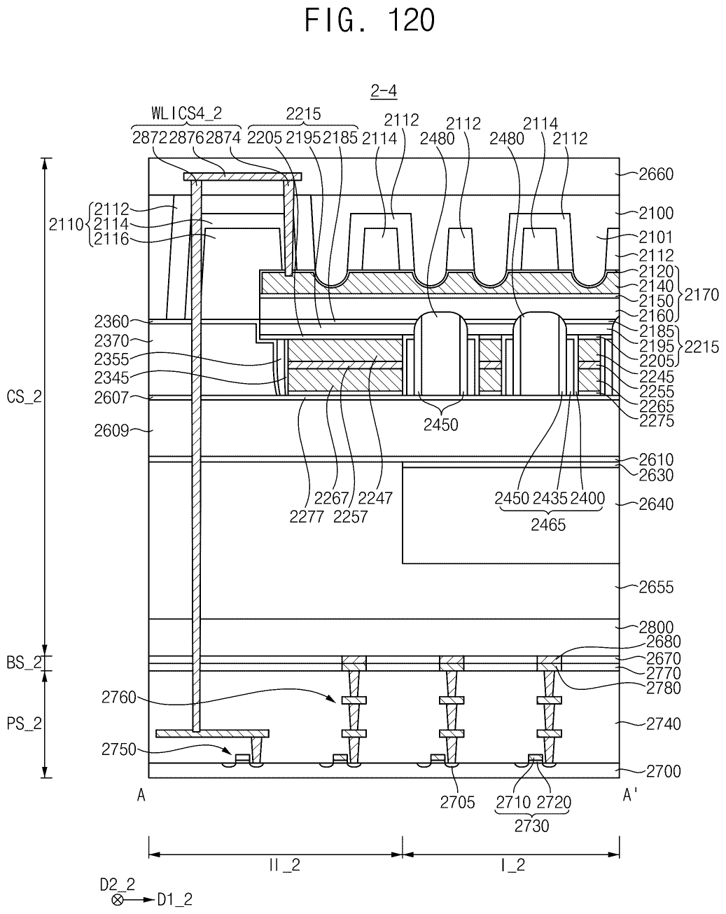

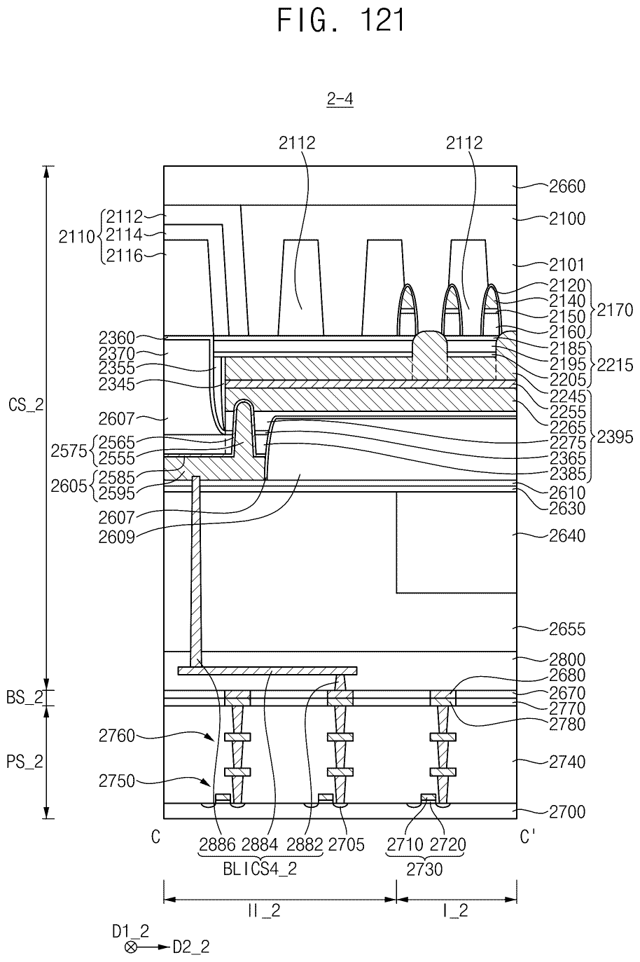

FIGS. 118 and 119 are cross-sectional views illustrating a method of manufacturing a second semiconductor device in accordance with a third example embodiment 2-3, where FIG. 118 is a cross-sectional view taken along line A-A′ of a corresponding plan view, and FIG. 119 is a cross-sectional view taken along line C-C′ of a corresponding plan view.

This method of manufacturing the third example embodiment 2-3 of the second semiconductor device may include processes substantially the same as or similar to those illustrated with respect to FIGS. 66 to 113, and FIGS. 62 to 65, and thus repeated explanations are omitted herein.

Referring to FIGS. 118 and 119, the cell structure CS_2 may be formed by performing processes substantially the same as or similar to those illustrated with respect to FIGS. 66 to 110. However, unlike the processes illustrated with respect to FIGS. 107 to 110, the cell structure CS_2 may be formed to include a fourth contact plug 2570 and a second wiring 2600 instead of the third contact plug 2575 and the first wiring 2605, respectively, and the first handling substrate 2010 may not be formed.

A sixth insulating interlayer 2800 and a third word line wiring structure WLICS3_2 accommodated therein may be formed on the third insulating interlayer 2655, and a first insulation layer 2670 and a first bonding pad 2680 accommodated therein may be formed on the sixth insulating interlayer 2800.

Referring again to FIGS. 116 and 117, the peripheral circuit structure PS_2 may be formed by performing processes substantially the same as or similar to those illustrated with respect to FIG. 113, and the first substrate 2100 may be flipped to bond the first and second bonding layers 2670 and 2770 to each other.

An upper portion of the first substrate 2100 may be removed through, for example, a grinding process, and accordingly, an upper surface of the isolation structure 2110 may be exposed. During the grinding process, the isolation structure 2110 may serve as a grinding endpoint.

A fourth insulating interlayer 2660 and a third bit line wiring structure BLICS3_2 accommodated therein may be formed on the first substrate 2100 and the isolation structure 2110 to complete the manufacture of the second semiconductor device.

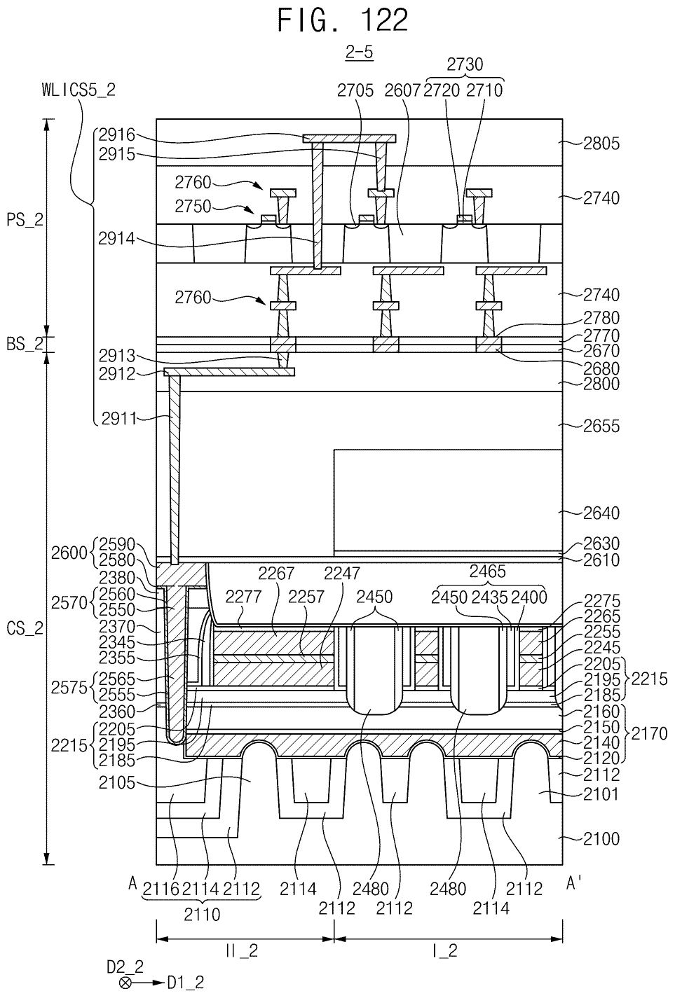

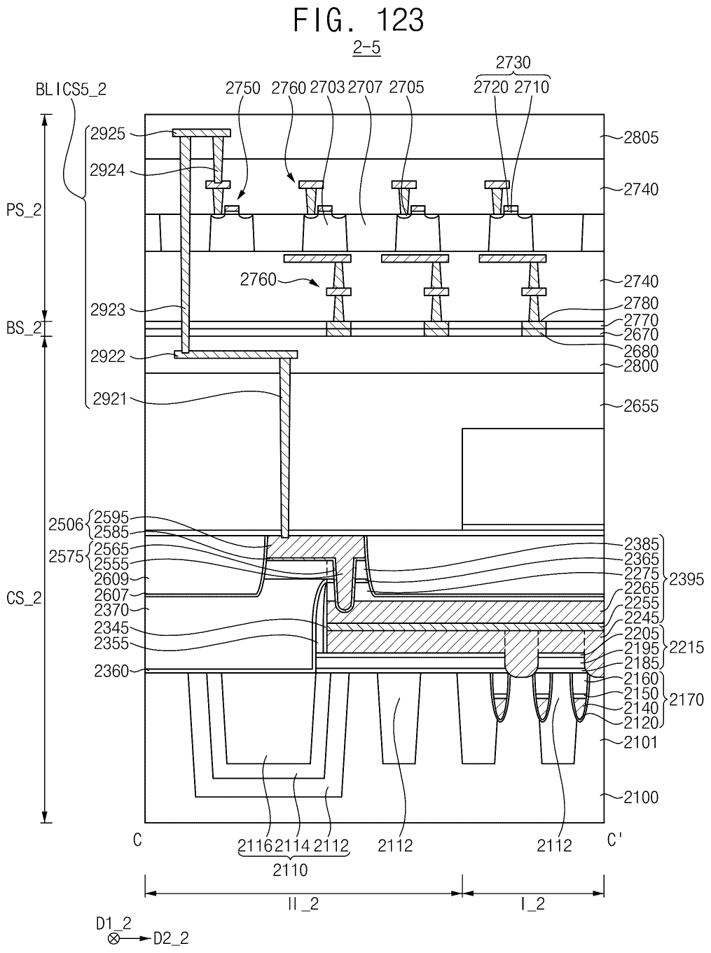

FIGS. 120 and 121 are cross-sectional views illustrating a second semiconductor device in accordance with a fourth example embodiment 2-4, which may correspond to FIGS. 116 and 117, respectively.

The fourth example embodiment 2-4 of the second semiconductor device may be substantially the same as or similar to the third example embodiment 2-3 of the second semiconductor device shown in FIGS. 116 and 117, except for including the third contact plug 2575 and the first wiring 2605 described with reference to FIGS. 62 to 65 instead of the fourth contact plug 2570 and the second wiring 2600, and including a fourth word line wiring structure WLICS4_2 and a fourth bit line wiring structure BLICS4_2 instead of the third word line wiring structure WLICS3_2 and the third bit line wiring structure BLICS3_2, respectively, and thus repeated explanations are omitted herein.

Referring to FIGS. 120 and 121, the fourth word line wiring structure WLICS4_2 may include a seventh word line contact 2872, an eighth word line contact 2874, and a fourth word line wiring 2876.

The seventh word line contact 2872 may extend through a lower portion of the fourth insulating interlayer 2660, the isolation structure 2110, the first etch stop layer 2360, the first insulating interlayer 370, the second insulating interlayer, the second etch stop layer 2610, the third insulating interlayer 2655, the sixth insulating interlayer 2800, the bonding layer structure, and an upper portion of the fifth insulating interlayer 2740 to contact the pad of the wiring structure 2760. The eighth word line contact 2874 may extend through a lower portion of the fourth insulating interlayer 2660 and the isolation structure 2110 to contact an upper surface of the first conductive pattern 2140 of the gate structure 2170. The fourth word line wiring 2876 may extend in the first direction D1_2 within the fourth insulating interlayer 2660 to commonly contact upper surfaces of the seventh and eighth word line contacts 2872 and 2874. Meanwhile, the pad of the wiring structure 2760 may serve as a landing pad for the seventh word line contact 2872.

In example embodiments, a width in the horizontal direction of each of the seventh and eighth word line contacts 2872 and 2874 may increase away from the second front surface of the second substrate 2700.

The fourth bit line wiring structure BLICS4_2 may include a seventh bit line contact 2882, a fourth bit line wiring 2884, and an eighth bit line contact 2886.

The seventh bit line contact 2882 may extend through a lower portion of the sixth insulating interlayer 2800 to contact an upper surface of the bonding pad structure. The fourth bit line wiring 2884 may extend in the second direction D2_2 within the sixth insulating interlayer 2800 to contact an upper surface of the seventh bit line contact 2882. The eighth bit line contact 2886 may extend through the second etch stop layer 2610, the third insulating interlayer 2655, and an upper portion of the sixth insulating interlayer 2800 to contact a lower surface of the first wiring 2605 and an upper surface of the fourth bit line wiring 2884.

In example embodiments, a width in the horizontal direction of each of the seventh and eighth bit line contacts 2882 and 2886 may decrease away from the second front surface of the second substrate 2700.

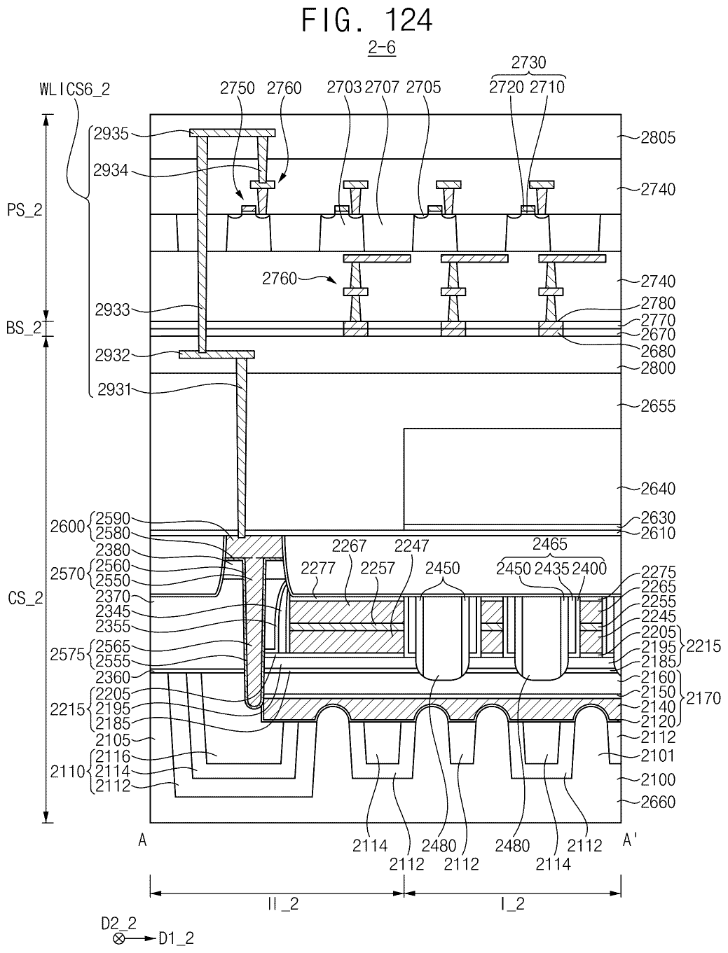

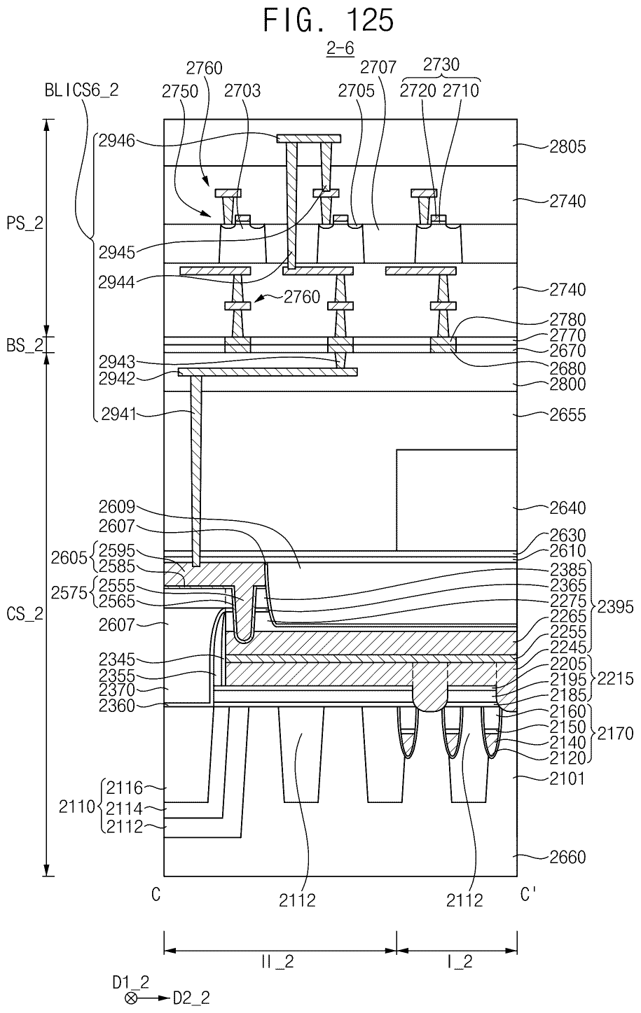

FIGS. 122 and 123 are cross-sectional views illustrating a second semiconductor device in accordance with a fifth example embodiment 2-5, which may correspond to FIGS. 63 and 65, respectively.

The fifth example embodiment 2-5 of the second semiconductor device may be substantially the same as or similar to the first example embodiment 2-1 of the second semiconductor device shown in FIGS. 62 to 65, except for the arrangement of the cell structure CS_2 and the peripheral circuit structure PS_2, further including the fourth contact plug 2570 and the second wiring 2600 described with reference to FIGS. 114 and 115, and including a fifth word line wiring structure WLICS5_2 and a fifth bit line wiring structure BLICS5_2 instead of the first word line wiring structure WLICS1_2 and the first bit line wiring structure BLICS1_2, respectively, and thus repeated explanations are omitted herein.

Referring to FIGS. 122 and 123, the fifth example embodiment 2-5 of the second semiconductor device may have a Periphery Over Cell (POC) structure in which a peripheral circuit structure PS_2 is disposed on a cell structure CS_2 including memory cells.

In example embodiments, the fifth example embodiment 2-5 of the second semiconductor device may have a structure in which the first front surface of the cell structure CS_2 and the second rear surface of the second substrate 2700 face each other.

The peripheral circuit structure PS_2 of the fifth example embodiment 2-5 of the second semiconductor device may further include a fourth isolation pattern 2707 substantially the same as or similar to the isolation pattern 1607 of the peripheral circuit structure PS_1 included in the first semiconductor device. The fifth insulating interlayer 2740 may include an upper portion disposed on the second front surface of the second substrate 2700 on which the peripheral circuit pattern 2750 is formed and a lower portion disposed on the second rear surface of the second substrate 2700, and the wiring structure 2760 may include an upper portion disposed on the second front surface of the second substrate 2700 and a lower portion disposed on the second rear surface of the second substrate 2700.

A seventh insulating interlayer 2805 may be disposed on the upper portion of the fifth insulating interlayer 2740.

The fifth word line wiring structure WLICS5_2 may include a ninth word line contact 2911, a fifth word line wiring 2912, a tenth word line contact 2913, an eleventh word line contact 2914, a twelfth word line contact 2915, and a sixth word line wiring 2916.

The ninth word line contact 2911 may extend through a lower portion of the sixth insulating interlayer 2800, the third insulating interlayer 2655, and the second etch stop layer 2610 to contact an upper surface of the second wiring 2600. The fifth word line wiring 2912 may extend in the first direction D1_2 within the sixth insulating interlayer 2800 to contact an upper surface of the ninth word line contact 2911. The tenth word line contact 2913 may extend through an upper portion of the sixth insulating interlayer 2800 to contact a lower surface of the bonding pad structure and an upper surface of the fifth word line wiring 2912. The eleventh word line contact 2914 may extend through a lower portion of the seventh insulating interlayer 2805, the upper portion of the fifth insulating interlayer 2740, the fourth isolation pattern 607, and the lower portion of the fifth insulating interlayer 2740 to be electrically connected to the lower portion of the wiring structure 2760. The twelfth word line contact 2915 may extend through a lower portion of the seventh insulating interlayer 2805 and the upper portion of the fifth insulating interlayer 2740 to be electrically connected to the upper portion of the wiring structure 2760. The sixth word line wiring 2916 may extend in the first direction D1_2 within the seventh insulating interlayer 2805 to commonly contact upper surfaces of the eleventh and twelfth word line contacts 2914 and 2915.

In example embodiments, a width in the horizontal direction of each of the ninth to twelfth word line contacts 2911, 2913, 2914 and 2915 may increase away from an upper surface of the first substrate 2100.

The fifth bit line wiring structure BLICS5_2 may include a ninth bit line contact 2921, a fifth bit line wiring 2922, a tenth bit line contact 2923, an eleventh bit line contact 2924, and a sixth bit line wiring 2925.

The ninth bit line contact 2921 may extend through a lower portion of the sixth insulating interlayer 2800, the third insulating interlayer 2655, and the second etch stop layer 2610 to contact an upper surface of the first wiring 2605. The fifth bit line wiring 2922 may extend in the second direction D2_2 within the sixth insulating interlayer 2800 to contact an upper surface of the ninth bit line contact 2921. The tenth bit line contact 2923 may extend through a lower portion of the seventh insulating interlayer 2805, the upper portion of the fifth insulating interlayer 2740, the fourth isolation pattern 707, the lower portion of the fifth insulating interlayer 2740, the bonding layer structure, and an upper portion of the sixth insulating interlayer 2800 to contact an upper surface of the fifth bit line wiring 2922. The eleventh bit line contact 2924 may extend through a lower portion of the seventh insulating interlayer 2805 and the upper portion of the fifth insulating interlayer 2740 to be electrically connected to the upper portion of the wiring structure 2760. The sixth bit line wiring 2925 may extend in the second direction D2_2 within the seventh insulating interlayer 2805 to commonly contact upper surfaces of the tenth and eleventh bit line contacts 2923 and 2924. Meanwhile, the fifth bit line wiring 2922 may serve as a landing pad for the tenth bit line contact 2923.

In example embodiments, a width in the horizontal direction of the ninth to eleventh bit line contacts 2921, 2923 and 2924 may increase away from an upper surface of the first substrate 2100.

FIGS. 124 and 125 are cross-sectional views illustrating a second semiconductor device in accordance with a sixth example embodiment 2-6, which may correspond to FIGS. 122 and 123, respectively.

The sixth example embodiment 2-6 of the second semiconductor device may be substantially the same as or similar to the fifth example embodiment 2-5 of the second semiconductor device shown in FIGS. 122 and 123, except for including a sixth word line wiring structure WLICS6_2 and a sixth bit line wiring structure BLICS6_2 instead of the fifth word line wiring structure WLICS5_2 and the fifth bit line wiring structure BLICS5_2, respectively, and thus repeated explanations are omitted herein.

Referring to FIGS. 124 and 125, the sixth word line wiring structure WLICS6_2 may include a thirteenth word line contact 2931, a seventh word line wiring 2932, a fourteenth word line contact 2933, a fifteenth word line contact 2934, and an eighth word line wiring 2935.

The thirteenth word line contact 2931 may extend through a lower portion of the sixth insulating interlayer 2800, the third insulating interlayer 2655, and the second etch stop layer 2610 to contact an upper surface of the second wiring 2600. The seventh word line wiring 2932 may extend in the first direction D1_2 within the sixth insulating interlayer 2800 to contact an upper surface of the thirteenth word line contact 2931. The fourteenth word line contact 2933 may extend through a lower portion of the seventh insulating interlayer 2805, the upper portion of the fifth insulating interlayer 2740, the fourth isolation pattern 707, the lower portion of the fifth insulating interlayer 2740, the bonding layer structure, and an upper portion of the sixth insulating interlayer 2800 to contact an upper surface of the seventh word line wiring 2932. The fifteenth word line contact 2934 may extend through a lower portion of the seventh insulating interlayer 2805 and the upper portion of the fifth insulating interlayer 2740 to be electrically connected to the upper portion of the corresponding wiring structure 2760. The eighth word line wiring 2935 may extend in the first direction D1_2 within the seventh insulating interlayer 2805 to commonly contact upper surfaces of the fourteenth and fifteenth word line contacts 2933 and 2934. Meanwhile, the seventh word line wiring 2932 may serve as a landing pad for the fourteenth word line contact 2933.

In example embodiments, a width in the horizontal direction of each of the thirteenth to fifteenth word line contacts 2931, 2933 and 2934 may increase away from an upper surface of the first substrate 2100.

The sixth bit line wiring structure BLICS6_2 may include a twelfth bit line contact 2941, a seventh bit line wiring 2942, a thirteenth bit line contact 2943, a fourteenth bit line contact 2944, a fifteenth bit line contact 2945, and an eighth bit line wiring 2946.

The twelfth bit line contact 2941 may extend through a lower portion of the sixth insulating interlayer 2800, the third insulating interlayer 2655, and the second etch stop layer 2610 to contact an upper surface of the first wiring 2605. The seventh bit line wiring 2942 may extend in the second direction D2_2 within the sixth insulating interlayer 2800 to contact an upper surface of the twelfth bit line contact 2941. The thirteenth bit line contact 2943 may extend through an upper portion of the sixth insulating interlayer 2800 to contact a lower surface of the bonding pad structure and an upper surface of the seventh bit line wiring 2942. The fourteenth bit line contact 2944 may extend through a lower portion of the seventh insulating interlayer 2805, the upper portion of the fifth insulating interlayer 2740, the fourth isolation pattern 707, and the lower portion of the fifth insulating interlayer 2740 to be electrically connected to the lower portion of the wiring structure 2760. The fifteenth bit line contact 2945 may extend through a lower portion of the seventh insulating interlayer 2805 and the upper portion of the fifth insulating interlayer 2740 to be electrically connected to the upper portion of the wiring structure 2760. The eighth bit line wiring 2946 may extend in the second direction D2_2 within the seventh insulating interlayer 2805 to commonly contact upper surfaces of the fourteenth and fifteenth bit line contacts 2944 and 2945.

In example embodiments, a width in the horizontal direction of each of the twelfth to fifteenth bit line contacts 2941, 2943, 2944 and 2945 may increase away from an upper surface of the first substrate 2100.

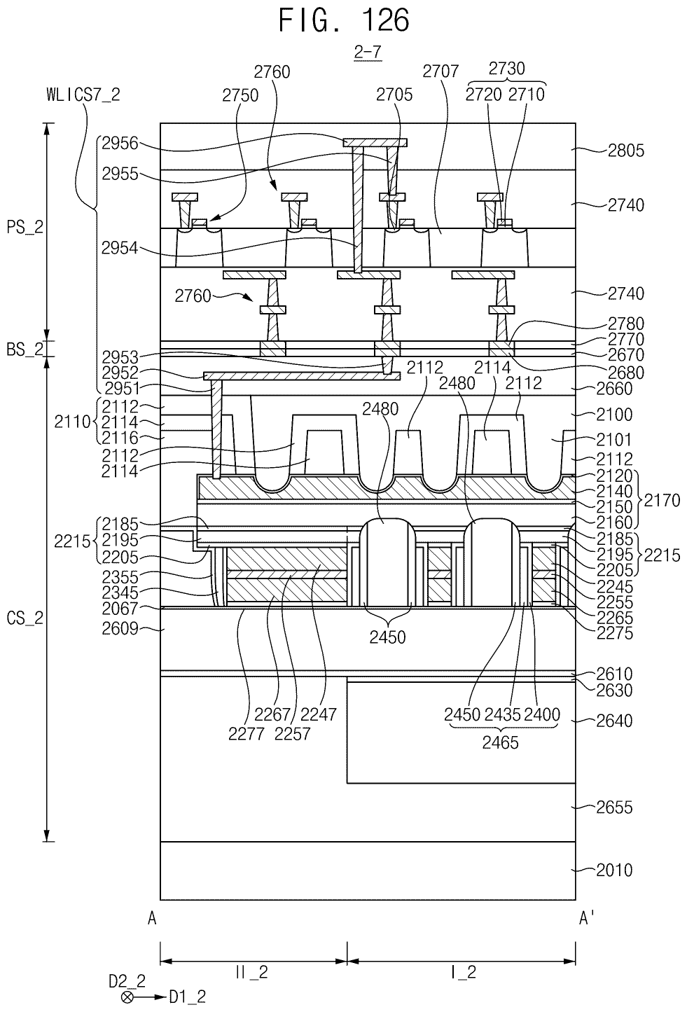

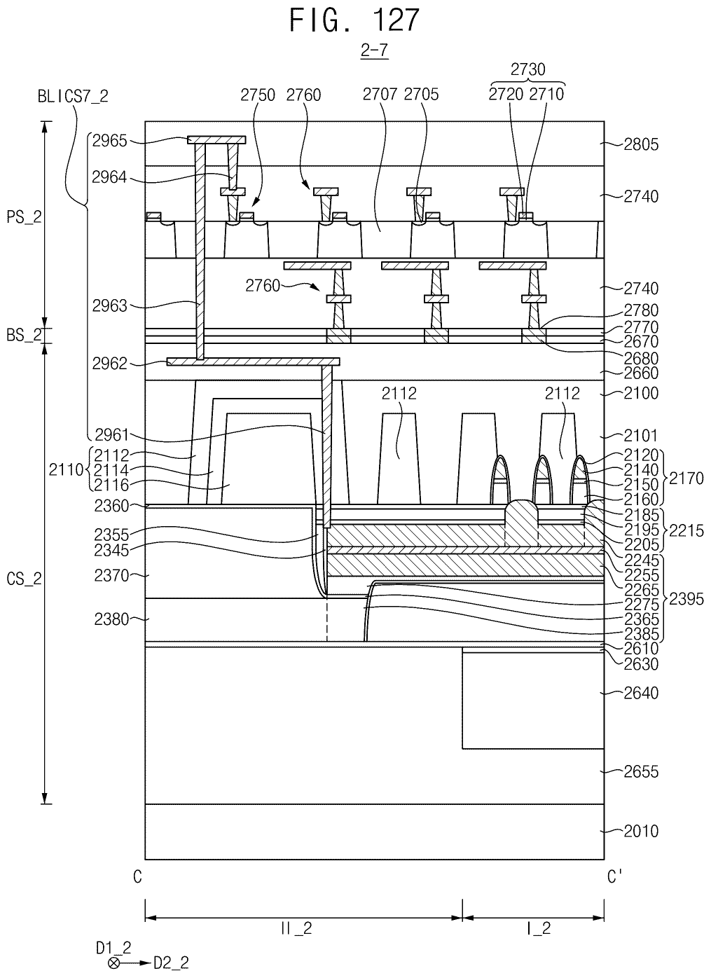

FIGS. 126 and 127 are cross-sectional views illustrating a second semiconductor device in accordance with a seventh example embodiment 2-7, which may correspond to FIGS. 122 and 123, respectively.

The seventh example embodiment 2-7 of the second semiconductor device may be substantially the same as or similar to the fifth example embodiment 2-5 of the second semiconductor device shown in FIGS. 122 and 123, except for the arrangement of the cell structure CS_2 and the peripheral circuit structure PS_2, and including a seventh word line wiring structure WLICS7_2 and a seventh bit line wiring structure BLICS7_2 instead of the fifth word line wiring structure WLICS5_2 and the fifth bit line wiring structure BLICS5_2, respectively, and thus repeated explanations are omitted herein.

Referring to FIGS. 126 and 127, the device may further include a first handling substrate 2010 disposed on the first rear surface of the cell structure CS_2.

The seventh example embodiment 2-7 of the second semiconductor device may have a structure in which the first rear surface of the cell structure CS_2 and the second rear surface of the second substrate 2700 face each other.

The seventh word line wiring structure WLICS7_2 may include a sixteenth word line contact 2951, a ninth word line wiring 2952, a seventeenth word line contact 2953, an eighteenth word line contact 2954, a nineteenth word line contact 2955, and a tenth word line wiring 2956.

The sixteenth word line contact 2951 may extend through a lower portion of the fourth insulating interlayer 2660 and the isolation structure 2110 to contact the first conductive pattern 2140 of the gate structure 2170. The ninth word line wiring 2952 may extend in the first direction D1_2 within the fourth insulating interlayer 2660 to contact an upper surface of the seventeenth word line contact 2951. The seventeenth word line contact 2953 may extend through an upper portion of the fifth insulating interlayer 2660 to contact a lower surface of the bonding pad structure and an upper surface of the ninth word line wiring 2952. The eighteenth word line contact 2954 may extend through a lower portion of the seventh insulating interlayer 2805, the upper portion of the fifth insulating interlayer 2740, the fourth isolation pattern 707, and the lower portion of the fifth insulating interlayer 2740 to be electrically connected to the lower portion of the wiring structure 2760. The nineteenth word line contact 2955 may extend through a lower portion of the seventh insulating interlayer 2805 and the upper portion of the fifth insulating interlayer 2740 to be electrically connected to the upper portion of the wiring structure 2760. The tenth word line wiring 2956 may extend in the first direction D1_2 within the seventh insulating interlayer 2805 to commonly contact upper surfaces of the eighteenth and nineteenth word line contacts 2954 and 2955.

In example embodiments, a width in the horizontal direction of each of the sixteenth to nineteenth word line contacts 2951, 2953, 2954 and 2955 may increase away from the first front surface of the cell structure CS_2.

The seventh bit line wiring structure BLICS7_2 may include a sixteenth bit line contact 2961, a ninth bit line wiring 2962, a seventeenth bit line contact 2963, an eighteenth bit line contact 2964, and a tenth bit line wiring 2965.

The sixteenth bit line contact 2961 may extend through a lower portion of the fourth insulating interlayer 2660, the isolation structure 2110, and the insulation pattern structure 2215 to contact an upper surface of the third conductive pattern 2245 of the bit line structure 2395. The ninth bit line wiring 2962 may extend in the second direction D2_2 within the fourth insulating interlayer 2660 to contact an upper surface of the sixteenth bit line contact 2961. The seventeenth bit line contact 2963 may extend through a lower portion of the seventh insulating interlayer 2805, the upper portion of the fifth insulating interlayer 2740, the fourth isolation pattern 707, the lower portion of the fifth insulating interlayer 2740, the bonding layer structure, and the upper portion of the fourth insulating interlayer 2660 to contact an upper surface of the ninth bit line wiring 2962. The eighteenth bit line contact 2964 may extend through a lower portion of the seventh insulating interlayer 2805 and the upper portion of the fifth insulating interlayer 2740 to be electrically connected to the upper portion of the wiring structure 2760. The tenth bit line wiring 2965 may extend in the second direction D2_2 within the seventh insulating interlayer 2805 to commonly contact upper surfaces of the seventeenth and eighteenth bit line contacts 2963, 2964. Meanwhile, the ninth bit line wiring 2962 may serve as a landing pad for the seventeenth bit line contact 2963.

In example embodiments, a width in the horizontal direction of each of the sixteenth to eighteenth bit line contacts 2961, 2963 and 2964 may increase away from the first front surface of the cell structure CS_2.

The seventh example embodiment 2-7 of the second semiconductor device described with reference to FIGS. 126 and 127 may be completed by performing processes substantially the same as or similar to those illustrated with respect to FIGS. 66 to 112 to form the cell structure CS_2, and bonding the peripheral circuit structure PS_2 described with reference to FIGS. 122 and 123 on the cell structure CS_2.

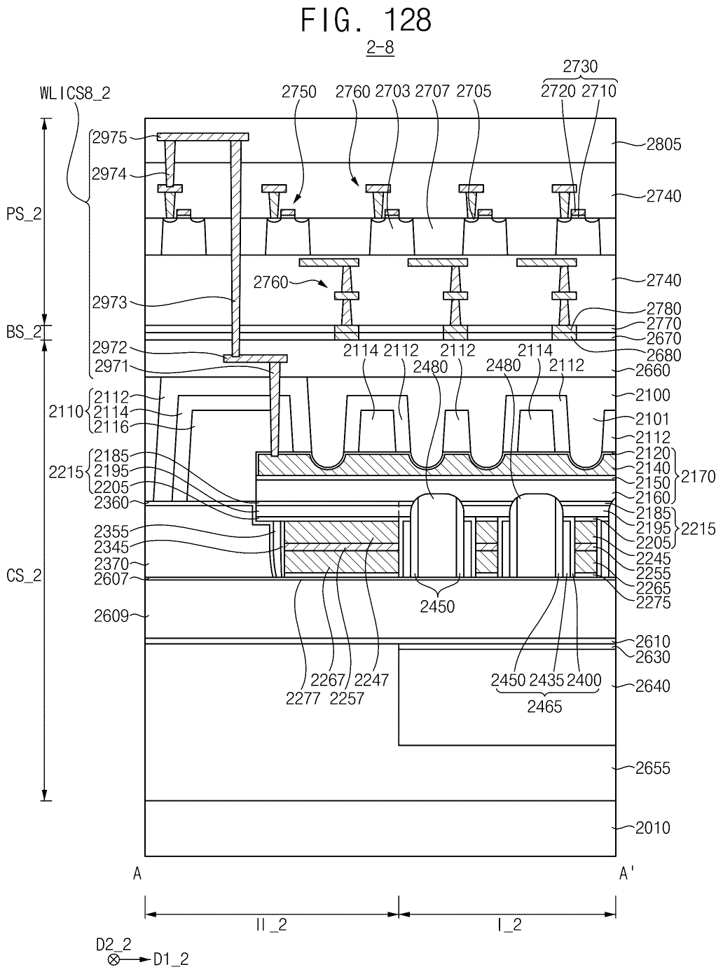

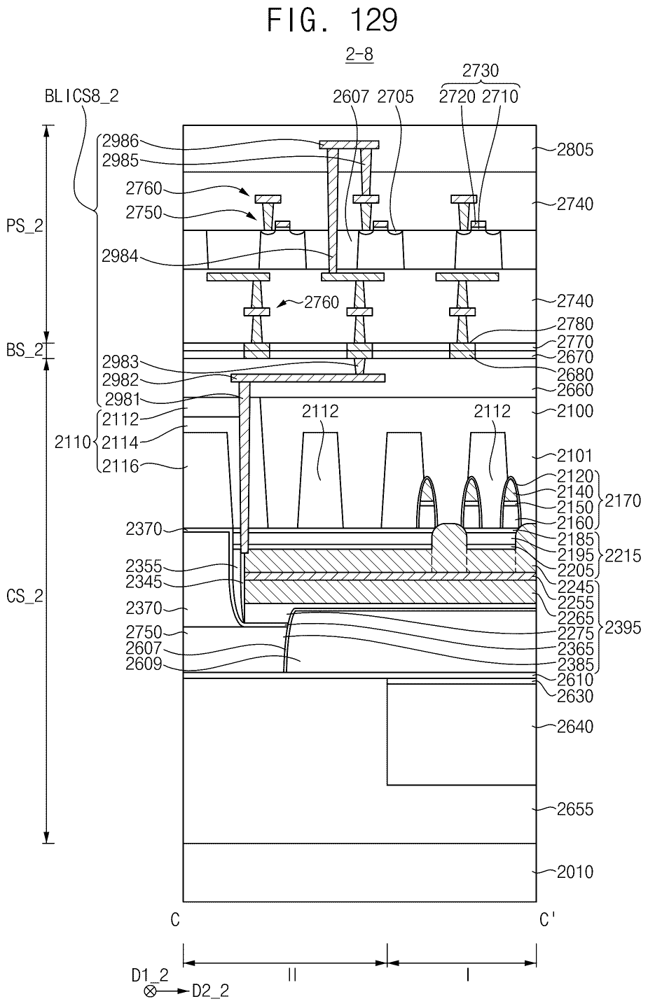

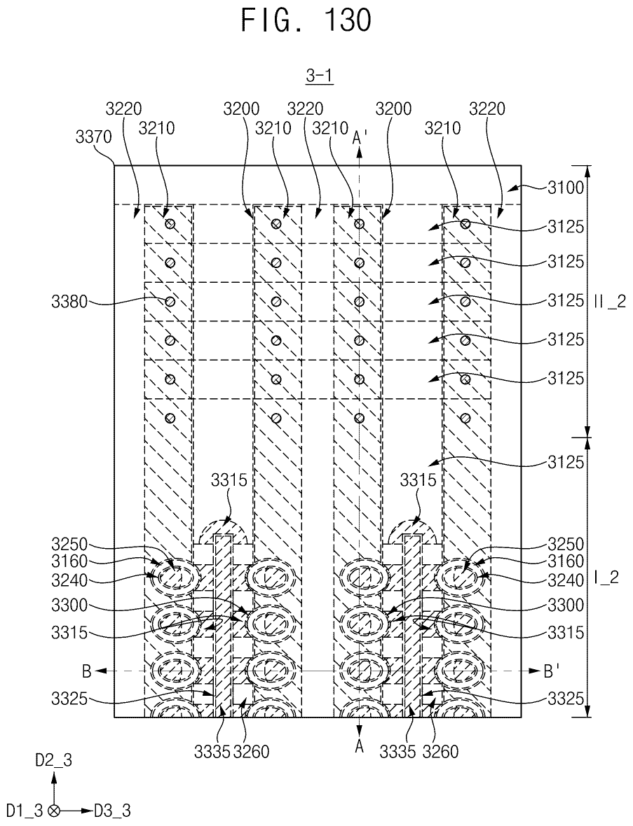

FIGS. 128 and 129 are cross-sectional views illustrating a second semiconductor device in accordance with an eighth example embodiment 2-8, which may correspond to FIGS. 126 and 127, respectively.

The eighth example embodiment 2-8 of the second semiconductor device may be substantially the same as or similar to the seventh example embodiment 2-7 of the second semiconductor device shown in FIGS. 126 and 127, except for including an eighth word line wiring structure WLICS8_2 and an eighth bit line wiring structure BLICS8_2 instead of the seventh word line wiring structure WLICS7_2 and the seventh bit line wiring structure BLICS7_2, respectively, and thus repeated explanations are omitted herein.

Referring to FIGS. 128 and 129, the eighth word line wiring structure WLICS8_2 may include a twentieth word line contact 2971, an eleventh word line wiring 2972, a twenty-first word line contact 2973, a twenty-second word line contact 2974, and a twelfth word line wiring 2975.

The twentieth word line contact 2971 may extend through a lower portion of the fourth insulating interlayer 2660 and the isolation structure 2110 to contact an upper surface of the first conductive pattern 2140 of the gate structure 2170. The eleventh word line wiring 2972 may extend in the first direction D1_2 within the fourth insulating interlayer 2660 to contact an upper surface of the twentieth word line contact 2971. The twenty-first word line contact 2973 may extend through a lower portion of the seventh insulating interlayer 2805, the upper portion of the fifth insulating interlayer 2740, the fourth isolation pattern 707, the lower portion of the fifth insulating interlayer 2740, the bonding layer structure, and an upper portion of the fourth insulating interlayer 2660 to contact an upper surface of the eleventh word line wiring 2972. The twenty-second word line contact 2974 may extend through a lower portion of the seventh insulating interlayer 2805 and the upper portion of the fifth insulating interlayer 2740 to be electrically connected to the upper portion of the wiring structure 2760. The twelfth word line wiring 2975 may extend in the first direction D1_2 within the seventh insulating interlayer 2805 to commonly contact upper surfaces of the twenty-first and twenty-second word line contacts 2973, 2974. Meanwhile, the eleventh word line wiring 2972 may serve as a landing pad for the twenty-first word line contact 2973.

In example embodiments, a width in the horizontal direction of each of the twentieth to twenty-second word line contacts 2971, 2973 and 2974 may increase as they move away from the first front surface of the cell structure CS_2.

The eighth bit line wiring structure BLICS8_2 may include a nineteenth bit line contact 2981, an eleventh bit line wiring 2982, a twentieth bit line contact 2983, a twenty-first bit line contact 2984, a twenty-second bit line contact 2985, and a twelfth bit line wiring 2986.

The nineteenth bit line contact 2981 may extend through a lower portion of the fourth insulating interlayer 2660, the isolation structure 2110, and the insulation pattern structure 2215 to contact an upper surface of the third conductive pattern 2245 of the bit line structure 2395. The eleventh bit line wiring 2982 may extend in the second direction D2_2 within the fourth insulating interlayer 2660 to contact an upper surface of the nineteenth bit line contact 2981. The twentieth bit line contact 2983 may extend through an upper portion of the fourth insulating interlayer 2660 to contact a lower surface of the bonding pad structure and an upper surface of the eleventh bit line wiring 2982. The twenty-first bit line contact 2984 may extend through a lower portion of the seventh insulating interlayer 2805, the upper portion of the fifth insulating interlayer 2740, the fourth isolation pattern 707, and the lower portion of the fifth insulating interlayer 2740 to be electrically connected to the lower portion of the wiring structure 2760. The twenty-second bit line contact 2985 may extend through a lower portion of the seventh insulating interlayer 2805 and the upper portion of the fifth insulating interlayer 2740 to be electrically connected to the upper portion of the wiring structure 2760. The twelfth bit line wiring 2986 may extend in the second direction D2_2 within the seventh insulating interlayer 2805 to commonly contact upper surfaces of the twenty-first and twenty-second bit line contacts 2984 and 2985.

In example embodiments, a width in the horizontal direction of each of the nineteenth to twenty-second bit line contacts 2981, 2983, 2984 and 2985 may increase as they move away from the first front surface of the cell structure CS_2

Hereinafter, in the specification (and not necessarily in the claims), a direction substantially vertical to an upper surface of a substrate may be referred to as a first direction D1_3, and two directions among horizontal directions that are substantially parallel to the upper surface of the substrate, which intersect each other, may be referred to as second and third directions D2_3 and D3_3, respectively. In example embodiments, the second and third directions D2_3 and D3_3 may be substantially perpendicular to each other.

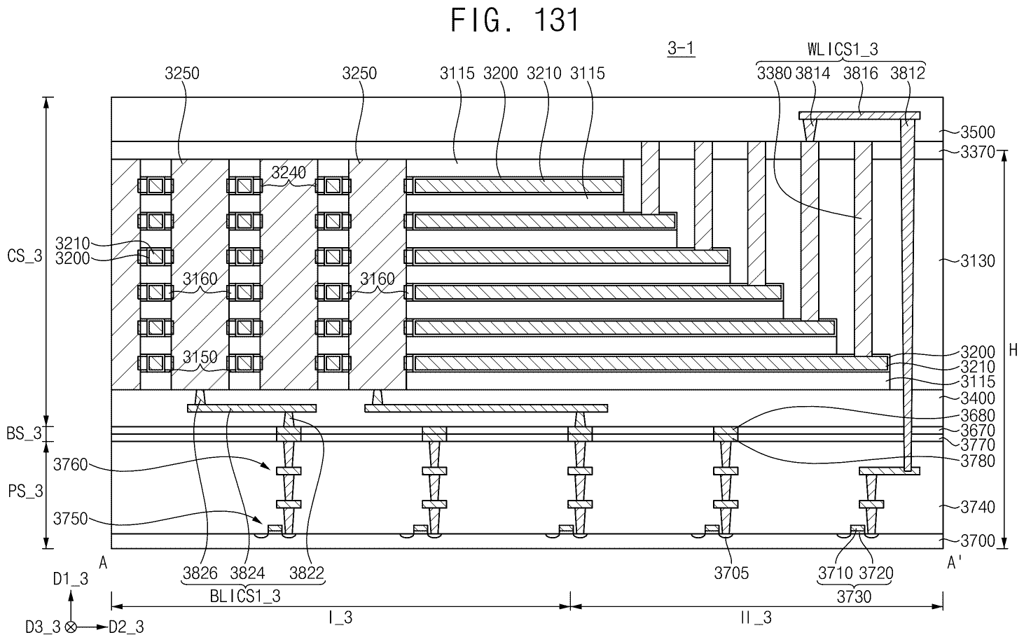

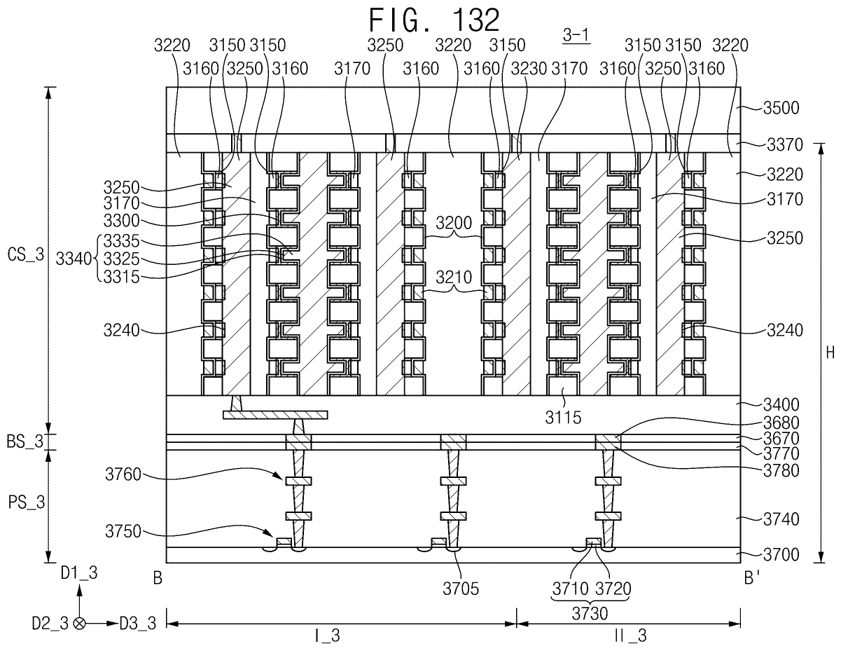

FIGS. 130 to 132 are plan views and cross-sectional views illustrating a third semiconductor device in accordance with a first example embodiment 3-1. Specifically, FIG. 130 is a horizontal cross-sectional view at height H of FIGS. 131 and 132, FIG. 131 is a vertical cross-sectional view taken along line A-A′ of FIG. 130, and FIG. 132 is a vertical cross-sectional view taken along line B-B′ of FIG. 130.

The first example embodiment 3-1 of the third semiconductor device may include a peripheral circuit structure PS_3, a bonding structure BS_3, a cell structure CS_3, a first word line wiring structure WLICS1_3, and a first bit line wiring structure BLICS1_3.

The first example embodiment 3-1 of the third semiconductor device may have a Cell Over Periphery (COP) structure. That is, a cell structure CS_3 including memory cells may be disposed on a peripheral circuit structure PS_3.

The cell structure CS_3 may include a first region I_3 and a second region II_3 surrounding the first region I_3 when viewed from above. In example embodiments, the first region I_3 may be a cell array region, and the second region II_3 may be an extension region, and they may together form a cell region.

Hereinafter, for convenience of description, a portion of the peripheral circuit structure PS_3 and a portion of the bonding structure BS_3 overlapping with the first region I_3 of the cell structure CS_3 in the vertical direction will also be referred to as the first region I_3, and a portion of the peripheral circuit structure PS_3 and a portion of the bonding structure BS_3 overlapping with the second region II_3 of the cell structure CS_3 in the vertical direction will also be referred to as the second region II_3.

The peripheral circuit structure PS_3 may include a peripheral circuit pattern 3750, a wiring structure 3760, and a third insulating interlayer 3740 on a second substrate 3700.

The second substrate 3700, the peripheral circuit pattern 3750, the wiring structure 3760, and the third insulating interlayer 3740 of the peripheral circuit structure PS_3 included in the third semiconductor device are substantially the same as or similar to the second substrate 1600, the peripheral circuit pattern 1650, the wiring structure 1660, and the third insulating interlayer 1640 of the peripheral circuit structure PS_1 included in the first semiconductor device, respectively, and thus repeated explanations are omitted herein.

The bonding structure BS_3 may include first and second bonding layers 3670 and 3770 and first and second bonding pads 3680 and 3780 accommodated therein, respectively. The first and second bonding pads 3680 and 3780 may together form a bonding pad structure, and the first and second bonding layers 3670 and 3770 may together form a bonding layer structure.

The first and second bonding layers 3670 and 3770 and the first and second bonding pads 3680 and 3780 of the bonding structure BS_3 included in the third semiconductor device are substantially the same as or similar to the first and second bonding layers 1550 and 1670 and the first and second bonding pads 1560 and 1680 of the bonding structure BS_1 included in the first semiconductor device, respectively, and thus repeated explanations are omitted herein.

The cell structure CS_3 may include a first gate electrode 3210, a first gate insulation layer 3200, a bit line 3250, a channel 3160, first and second ohmic contact patterns 3240 and 3300, and a capacitor structure 3340.

The cell structure CS_3 may further include first, third, fourth and fifth insulation patterns 3115, 3170, 3220 and 3260, a second insulation layer 3150, and first and second insulating interlayers 3130 and 3370.

The first gate electrode 3210 may extend in the second direction D2_3 on the first and second regions I_3 and II_3, and a plurality of first gate electrodes 3210 may be spaced apart from each other in the first direction D1_3 to form a first gate electrode structure. The first insulation pattern 3115 may be disposed between neighboring ones of the first gate electrodes 3210 in the first direction D1_3, and the first insulation pattern 3115 may also be disposed between the first substrate 3100 and a lowermost one of the first gate electrodes 3210 and on an uppermost one of the first gate electrodes 3210. Each of the first gate electrodes 3210 may serve as a word line of the third semiconductor device, and thus the first gate electrode structure may also be referred to as a word line structure.

In example embodiments, extension lengths in the second direction D2_3 of the first gate electrodes 3210 may decrease from a lowermost level to an uppermost level in a stepwise manner, and thus the first gate electrode structure may have a staircase shape. A portion of each of the first gate electrodes 3210 not overlapped by ones of the first gate electrodes 3210 over each of the first gate electrodes 3210, that is, an end portion in the second direction D2_3 of each of the first gate electrodes 3210 may be referred as a “pad”. In example embodiments, the pads may be disposed in the second direction D2_3 on the second region II_3.

The first gate electrode 3210 may include, e.g., a metal, a metal nitride, a metal silicide, doped polysilicon, etc.

In example embodiments, a plurality of first gate electrode structures may be spaced apart from each other in the third direction D3_3, and the fourth insulation pattern 3220 and the first sacrificial pattern 3125 may be alternately and repeatedly disposed in the third direction D3_3 between the first gate structures. The fourth insulation pattern 3220 may extend in the second direction D2_3 on the first and second regions I_3 and II_3 through the first gate electrode structure and the first insulation patterns 3115. The first sacrificial pattern 3125 and the first insulation pattern 3115 may be alternately and repeatedly stacked in the first direction D1_3, and may extend through the first gate electrode structure between ones of the fourth insulation patterns 3220 neighboring in the third direction D3_3 to divide the first gate electrode structure into two parts in the third direction D3_3.

Each of the first and fourth insulation patterns 3115 and 3220 may include an oxide, e.g., silicon oxide, and the first sacrificial pattern 3125 may include a material having an etching selectivity with respect to the first insulation pattern 3115, e.g., an insulating nitride such as silicon nitride.

The first gate insulation layer 3200 may cover upper and lower surfaces of the first gate electrode 3210, a sidewall of the first gate electrode 3210 facing the first sacrificial pattern 3125 and a sidewall of the first gate electrode 3210 facing the channel 3160, and may also be formed on a sidewall of the first insulation pattern 3115 facing the fourth insulation pattern 3220. The first gate insulation layer 3200 may include an oxide, e.g., silicon oxide.

The bit line 3250 may be disposed on the first region I_3, and may have a shape of a pillar extending in the first direction D1_3. The bit line 3250 may extend through the first gate electrode structure and the first insulation patterns 3115. In example embodiments, a plurality of bit lines 3250 may extend through the first gate electrode structure extending in the second direction D2_3, and may be spaced apart from each other in the second direction D2_3. Thus, a plurality of bit lines 3250 may be spaced apart from each other in the second and third directions D2_3 and D3_3. The bit line 3250 may include, e.g., a metal, a metal nitride, a metal silicide, doped polysilicon, etc.

The third insulation pattern 3170 may be disposed on the first region I_3, and may have a pillar shape extending through the first gate electrode structure and the first insulation patterns 3115. In example embodiments, the third insulation pattern 3170 may contact a sidewall of the bit line 3250 in the third direction D3_3, and the third insulation pattern 3170 together with the bit line 3250 may have a shape of, e.g., a circle, an ellipse, a polygon, a polygon with rounded corners, etc., in a plan view.

The third insulation pattern 3170 may include an oxide, e.g., silicon oxide.

The channel 3160 may be disposed at a level where each of the first gate electrodes 3210 is disposed, and may surround sidewalls of the bit line 3250 and the third insulation pattern 3170. The channel 3160 may contact the sidewall of the third insulation pattern 3170, and the first ohmic contact pattern 3240 may be disposed between the channel 3160 and the bit line 3250. The first gate insulation layer 3200 may be disposed between the channel 3160 and the first gate electrode 3210.

Lower and upper surfaces of the channel 3160 may be covered by the second insulation layer 3150, and the second insulation layer 3150 may contact a sidewall of a portion of the first insulation pattern 3115 between neighboring ones of the channels 3160 in the first direction D1_3 and a sidewall of a portion of the third insulation pattern 3170 opposite thereto. The second insulation layer 3150 may include an oxide, e.g., silicon oxide, and in some cases, may be merged with the first insulation pattern 3115 and/or the third insulation pattern 3170.

In example embodiments, the channel 3160 may have a shape of a circular ring, an elliptical ring, a polygonal ring, etc. The channel 3160 may be disposed at each level where the first gate electrode 3210 is disposed, and thus a plurality of channels 3160 may be disposed in the first direction D1_3. The channel 3160 may surround the sidewalls of the bit line 3250 and the third insulation pattern 3170, and thus a plurality of channels 3160 may be spaced apart from each other in the second and third directions D2_3 and D3_3.

The channel 3160 may include a semiconductor material, e.g., silicon, germanium, silicon-germanium, etc., or an oxide semiconductor material. The oxide semiconductor material may include at least one of zinc tin oxide (ZTO), indium zinc oxide (IZO), zinc oxide (ZnOx), indium gallium zinc oxide (IGZO), indium gallium silicon oxide (IGSO), Indium oxide (InOx, In2O3), tin oxide (SnO2), titanium oxide (TiOx), zinc oxide nitride (ZnxOyNz), magnesium zincoxide (MgxZnyOz), indium zinc oxide (InxZnyOa), indium gallium zinc oxide (InxGayZnzOa), zirconium indium zinc oxide (ZrxInyZnzOa), hafnium indium zinc oxide (HfxInyZnzOa), tin indium zinc oxide (SnxInyZnzOa), aluminum tin indium zinc oxide (AlxSnyInzZnaOd), silicon indiumzinc oxide (SixInyZnzOa), zinc tin oxide (ZnxSnyOz), aluminum zinc tin oxide (AlxZnySnzOa), gallium zinc tin oxide (GaxZnySnzOa), zirconium zinc tin oxide (ZrxZnySnzOa) and indium gallium silicon oxide (InGaSiO).

The first ohmic contact pattern 3240 may include a metal silicide, e.g., cobalt silicide, nickel silicide, titanium silicide, etc.

In some example embodiments, the first ohmic contact pattern 3240 may not be formed between the channel 3160 and the sidewall of the bit line 3250, and in this case, for example, n-type impurity region or a p-type impurity region may be formed at a lateral portion of the channel 3160 facing the sidewall of the bit line 3250 so as to serve as the first ohmic contact pattern 3240.

The capacitor structure 3340 may include a first capacitor electrode 3315, a dielectric pattern 3325 and a second capacitor electrode 3335 sequentially stacked.

The second capacitor electrode 3335 may include an extension portion extending through the first insulation patterns 3115 in the first and second directions D1_3 and D2_3 and a first protrusion portion protruding in the third direction D3_3 from each of opposite sidewalls in the third direction D3_3 of the extension portion on the first region I_3. In example embodiments, the second capacitor electrode 3335 may include a plurality of first protrusion portions facing sidewalls in the third direction D3_3 of corresponding ones, respectively, of the channels 3160. Thus, the second capacitor electrode 3335 may include a plurality of first protrusion portions spaced apart from each other in the first and second directions D1_3 and D2_3 on each of opposite sidewalls in the third direction D3_3.

The second capacitor electrode 3335 may further include a second protrusion portion protruding from each of end portions in the second direction D2_3 of the extension portion and having a shape of a semi-circle in a plan view. A plurality of second protrusion portions may be spaced apart from each other in the first direction D1_3, and the second protrusion portions may be disposed at respective levels where the channels are disposed.

The dielectric pattern 3325 may cover a sidewall of the second capacitor electrode 3335. The dielectric pattern 3325 may cover lower and upper surfaces, opposite sidewalls in the second direction D2_3 and a sidewall in the third direction D3_3 of each of the first protrusion portions of the second capacitor electrode 3335.

The first capacitor electrode 3315 may cover lower and upper surfaces and a sidewall of a portion of the dielectric pattern 3325 covering the lower and upper surfaces and the sidewalls of the first protrusion portion of the second capacitor electrode 3335. A plurality of first capacitor electrodes 3315 may be spaced apart from each other in the second and third directions D2_3 and D3_3 correspondingly to the channels 3160, and may also be spaced apart from each other in the first direction D1_3. Each of the first capacitor electrodes 3315 may be disposed at a level where a corresponding one of the channels 3160 is disposed.

In the capacitor structure 3340, each of the first capacitor electrodes 3315, a portion of the dielectric pattern 3325 that is disposed at the same level as each of the first capacitor electrodes 3315 and a portion of the second capacitor electrode 3335 at the same level as the portion of the dielectric pattern 3325 may collectively form a capacitor. Thus, the capacitor structure 3340 may include a plurality of capacitors spaced apart from each other in the second and third directions D2_3 and D3_3 correspondingly to the layout of the first capacitor electrodes 3315, and a plurality of capacitors may also be disposed at a plurality of levels, respectively, in the first direction D1_3.

In example embodiments, an outer sidewall in the third direction D3_3 of the first capacitor electrode 3315 of each of the capacitors may contact the second ohmic contact pattern 3300, and may be electrically connected to the channel 3160 through the second ohmic contact pattern 3300. The outer sidewall in the third direction D3_3 of the first capacitor electrode 3315 of each of the capacitors may face the sidewall of the bit line 3250 at least partially covered by the channel 3160. Additionally, an outer sidewall in the second direction D2_3 of the first capacitor electrode 3315 may contact the fifth insulation pattern 3260.

The first capacitor electrode 3315 may also be formed on lower and upper surfaces and a sidewall of a portion of the dielectric pattern 3325 covering lower and upper surfaces and a sidewall of the second protrusion portion of the second capacitor electrode 3335.

The fifth insulation pattern 3260 may extend in the first direction D1_3 through the first insulation patterns 3115 on the first region I_3, and may be disposed between neighboring ones of the first capacitor electrodes 3315 in the second direction D2_3 at each of opposite sides of the second capacitor electrode 3335 in the third direction D3_3. That is, the neighboring ones of the first capacitor electrodes 3315 in the second direction D2_3 may be spaced apart from each other by the fifth insulation pattern 3260 to be electrically insulated from each other. Thus, a plurality of fifth insulation patterns 3260 may be spaced apart from each other in the second direction D2_3 at each of opposite sides of the second capacitor electrode 3335 in the third direction D3_3.

The fifth insulation pattern 3260 may also contact a sidewall of the first gate insulation layer 3200.

The fifth insulation pattern 3260 may include an oxide, e.g., silicon oxide, or an insulating nitride, e.g., silicon nitride.

Each of the first and second capacitor electrodes 3315 and 3335 may include, e.g., a metal, a metal nitride, a metal silicide, doped polysilicon, etc., and the dielectric layer 3320 may include a metal oxide having a high dielectric constant, e.g., hafnium oxide, zirconium oxide, etc.

The first and second insulating interlayers 3130 and 3370 may be sequentially stacked in the first direction D1_3, the first insulating interlayer 3130 may cover sidewalls of the first gate electrode structure and the first insulation patterns 3115, and the second insulating interlayer 3370 may be disposed on the first insulating interlayer 3130, the first gate electrode structure, the bit line 3250, the capacitor structure 3340, the third to fifth insulation patterns 3170, 3220 and 3260 and the second insulation layer 3150. Each of the first and second insulating interlayers 3130 and 3370 may include an oxide, e.g., silicon oxide.

Hereinafter, for convenience of description, among the first and second surfaces in the vertical direction of the cell structure CS_3, a surface facing a surface where the first gate electrode 3210 contacts the first word line contact 3380 will be referred to as a first front surface, and an opposite surface will be referred to as a first rear surface. Further, among the third and fourth surfaces in the vertical direction of the second substrate 3700, a surface on which the peripheral circuit pattern 3750 is disposed will be referred to as a second front surface of the second substrate 3700, and an opposite surface will be referred to as a second rear surface.

In example embodiments, the third semiconductor device may have a structure in which the first rear surface of the cell structure CS_3 and the second front surface of the second substrate 3700 face each other.

The first word line wiring structure WLICS1_3 may include a first word line contact 3380, a second word line contact 3812, a third word line contact 3814 and a first word line wiring 3816.

The first word line contact 3380 may extend through the first and second insulating interlayers 3130 and 3370 and the first gate insulation layer 3200 on the second region II_3 to contact upper surfaces of pads of the respective first gate electrodes 3210. The second word line contact 3812 may extend through a lower portion of the sixth insulating interlayer 3500, the second insulating interlayer 3370, the first insulating interlayer 3130, the fifth insulating interlayer 3400, the insulation layer structure, and the third insulating interlayer 3740 to contact the pad of the wiring structure 3760. The third word line contact 3814 may extend through a lower portion of the sixth insulating interlayer 3500 to contact an upper surface of the first word line contact 3380. The first word line wiring 3816 may extend in the second direction D2_3 within the sixth insulating interlayer 3500 to commonly contact upper surfaces of the second and third word line contacts 3812 and 3814. Meanwhile, the pad of the wiring structure 3760 may serve as a landing pad for the second word line contact 3812.

In example embodiments, a width in the horizontal direction of each of the second and third word line contacts 3812 and 3814 may increase away from the second front surface of the second substrate 3700.

The first bit line wiring structure BLICS1_3 may include a second bit line contact 3822, a first bit line wiring 3824 and a third bit line contact 3826.

The second bit line contact 3822 may extend through a lower portion of the fifth insulating interlayer 3400 to contact an upper surface of the insulation pattern structure. The first bit line wiring 3824 may extend in the second direction D2_3 within the fifth insulating interlayer 3400 to contact an upper surface of the second bit line contact 3822. The third bit line contact 3826 may extend through an upper portion of the fifth insulating interlayer 3400 to contact a lower surface of the bit line 3250 and an upper surface of the first bit line wiring 3824.

In example embodiments, a width in the horizontal direction of each of the second and third bit line contacts 3822 and 3826 may decrease away from the second front surface of the second substrate 3700.

Meanwhile, although not shown, the third semiconductor device may further include a third contact plug that extends through the second insulating interlayer 3370 to contact upper surfaces of the respective second capacitor electrodes 3335.

As illustrated above, in the third semiconductor device, the channel 3160 and the first capacitor electrode 3315 may be disposed at the same level as each of the first gate electrodes 3210, and thus, when compared to a case in which the first gate electrode 3210 is disposed over and/or under the channel 3160 and the first capacitor electrode 3315, a thickness in the first direction D1_3, that is, in the vertical direction of a memory cell including the first gate electrode 3210, the channel 3160 and the capacitor electrode 3315 may be reduced. Accordingly, a vertical thickness and a height of the upper surface of the semiconductor device may be reduced.

The channel 3160 may surround the sidewalls of the bit line 3250 and the third insulation pattern 3170, and the first capacitor electrodes 3315, the channels 3160 and the bit lines 3250 at opposite sides, respectively, in the third direction D3_3 may be symmetrical with reference to the extension portion of the second capacitor electrode 3335 extending in the second direction D2_3. Additionally, the bit line 3250, the first capacitor electrode 3315 and a portion of the channel 3160 therebetween may be disposed in the third direction D3_3 that is perpendicular to the extension direction of the first gate electrode 3210.

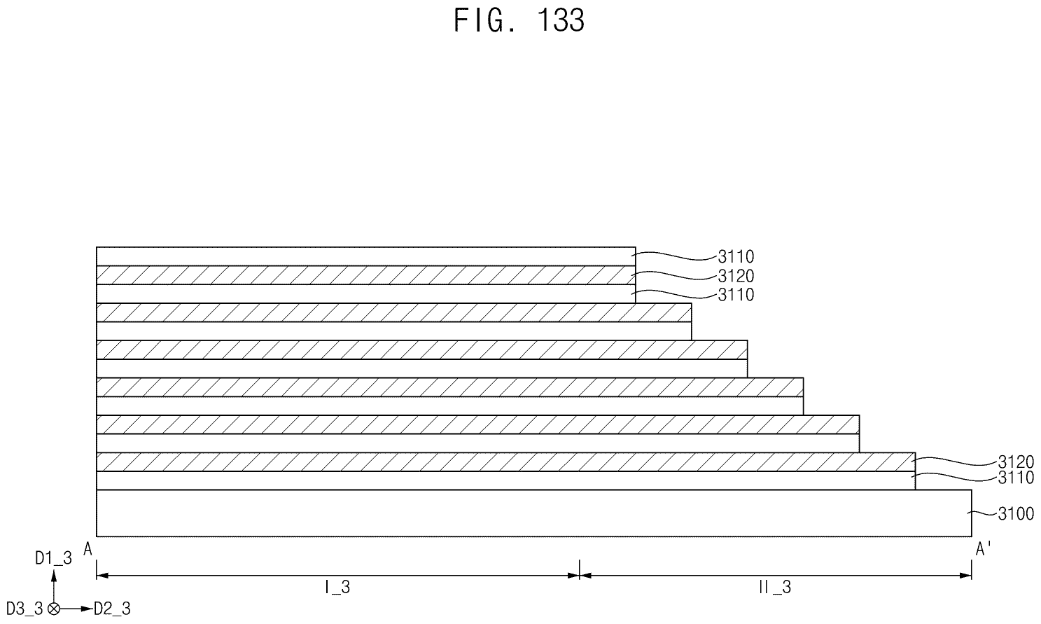

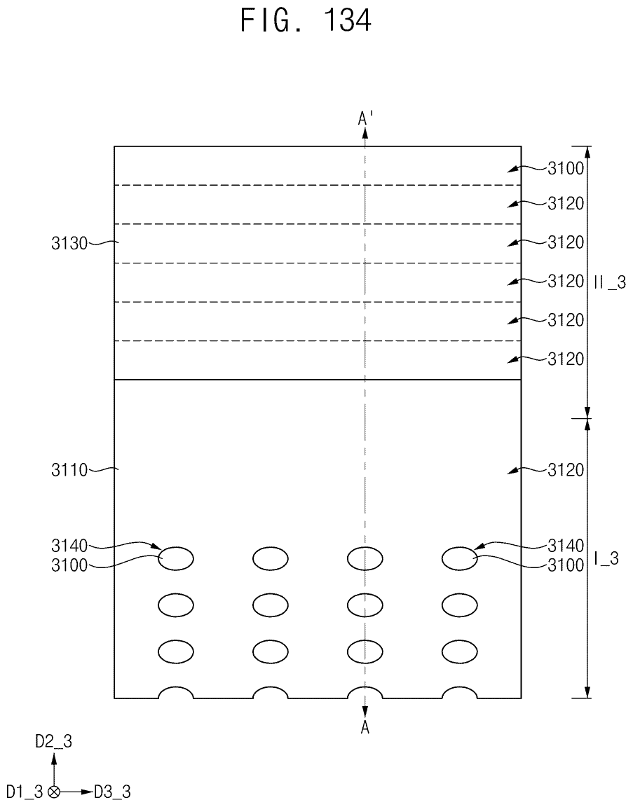

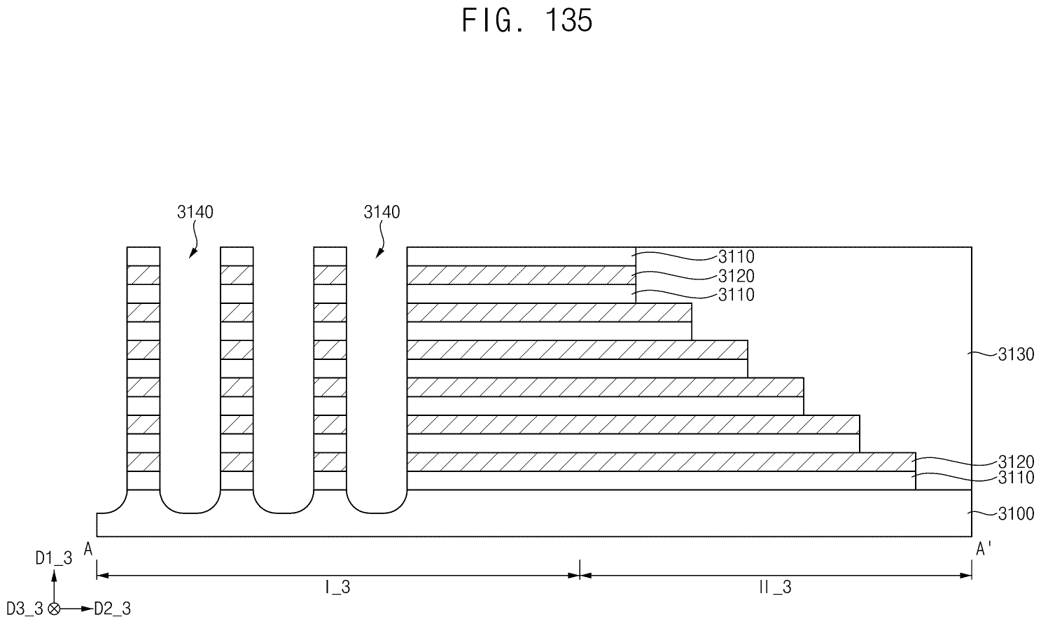

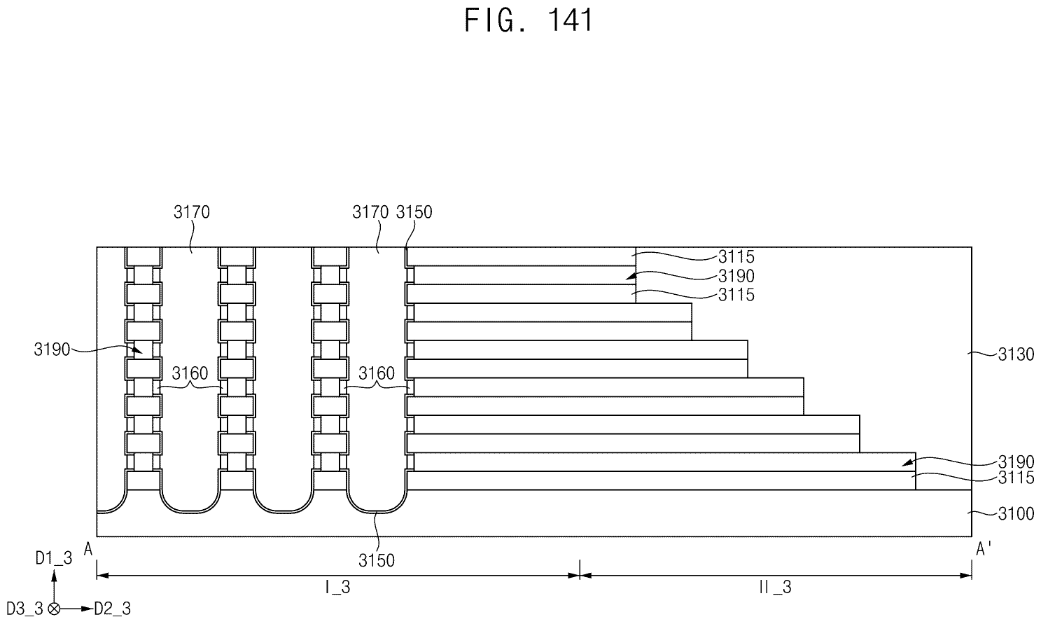

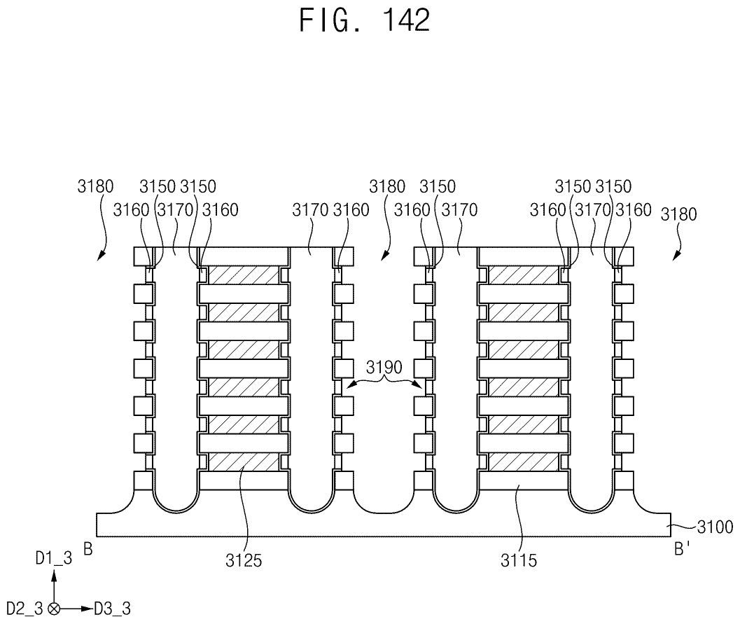

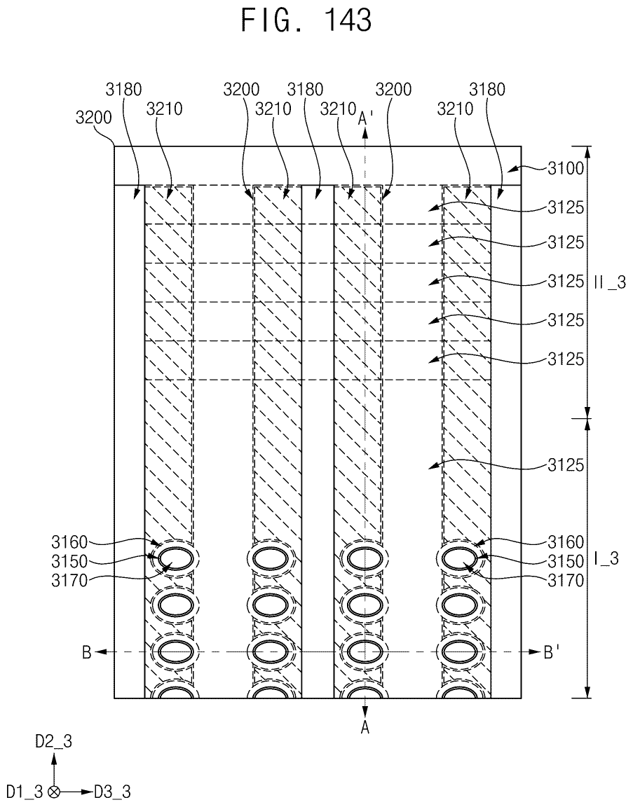

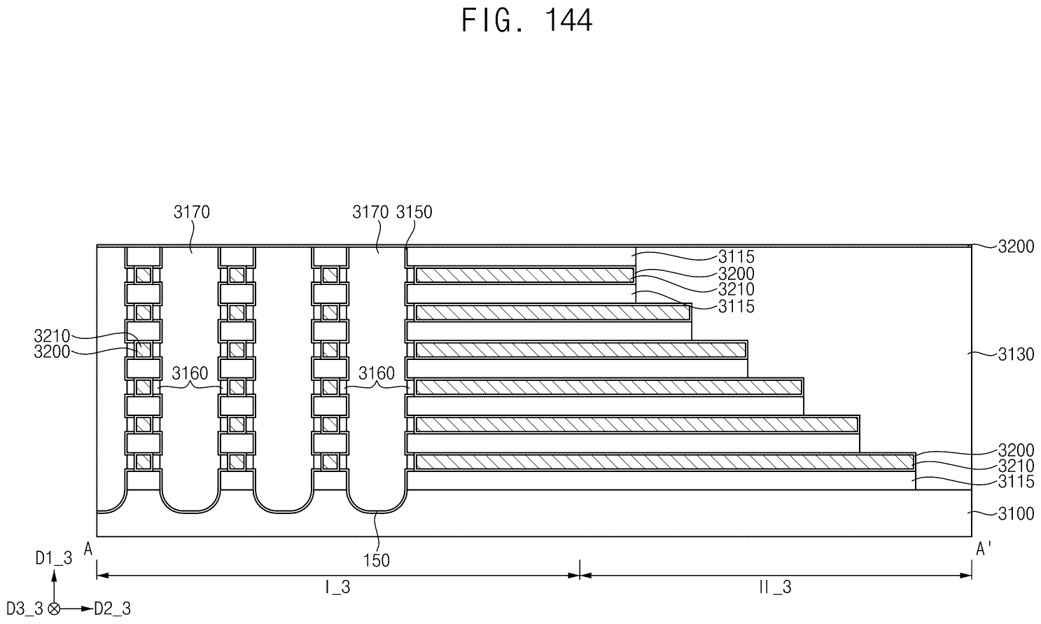

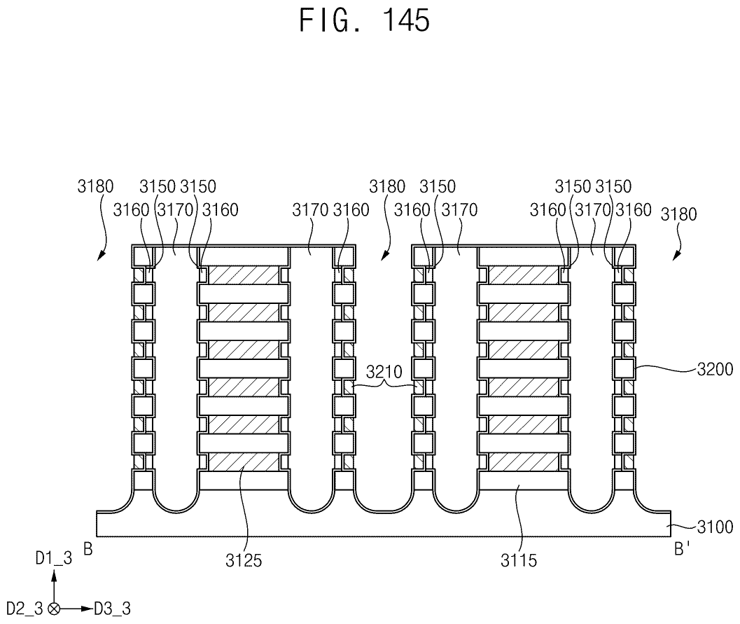

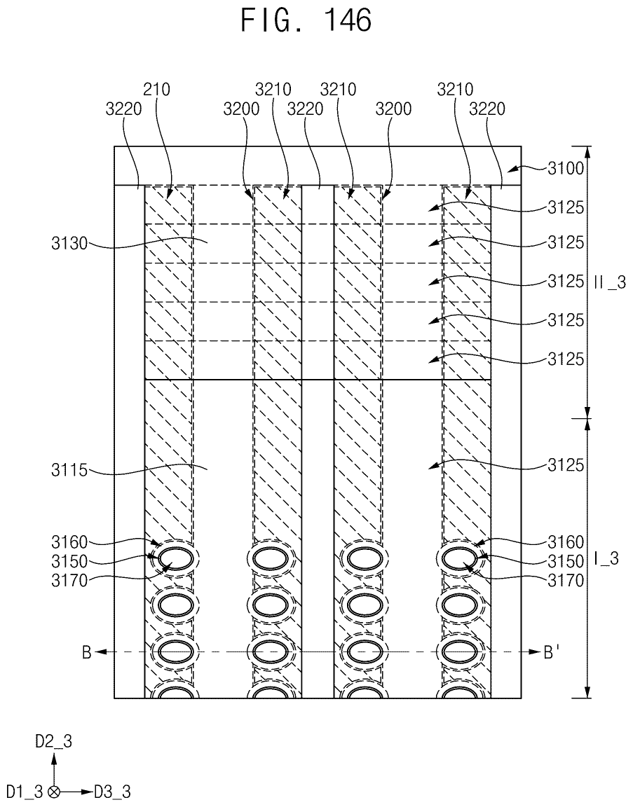

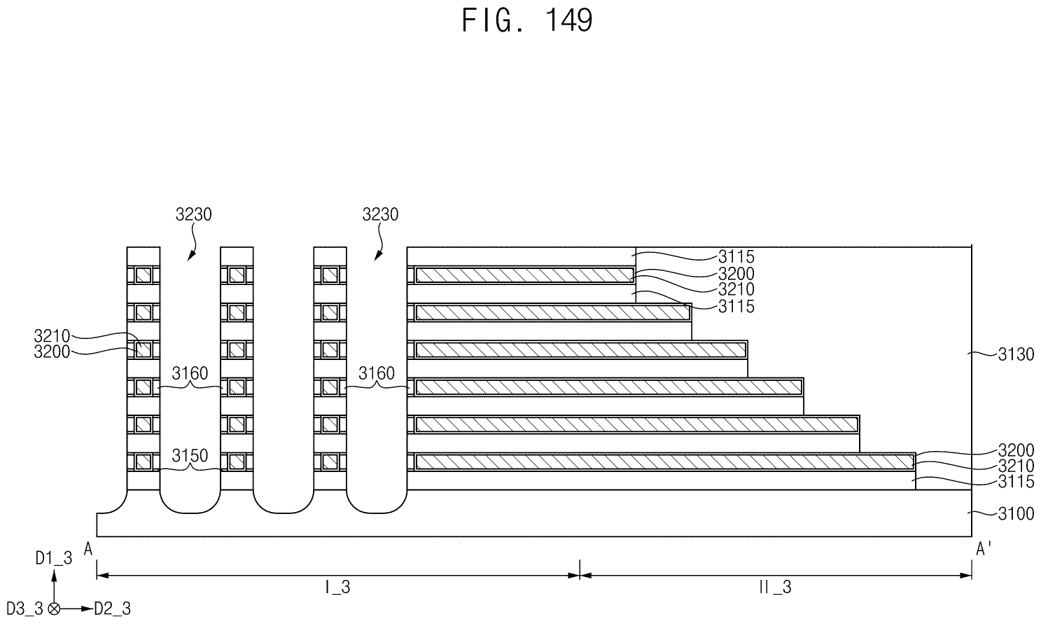

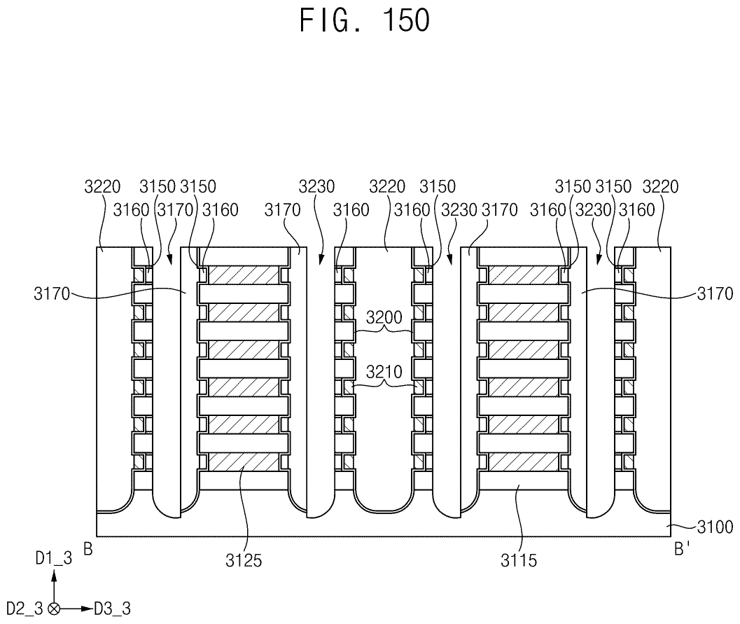

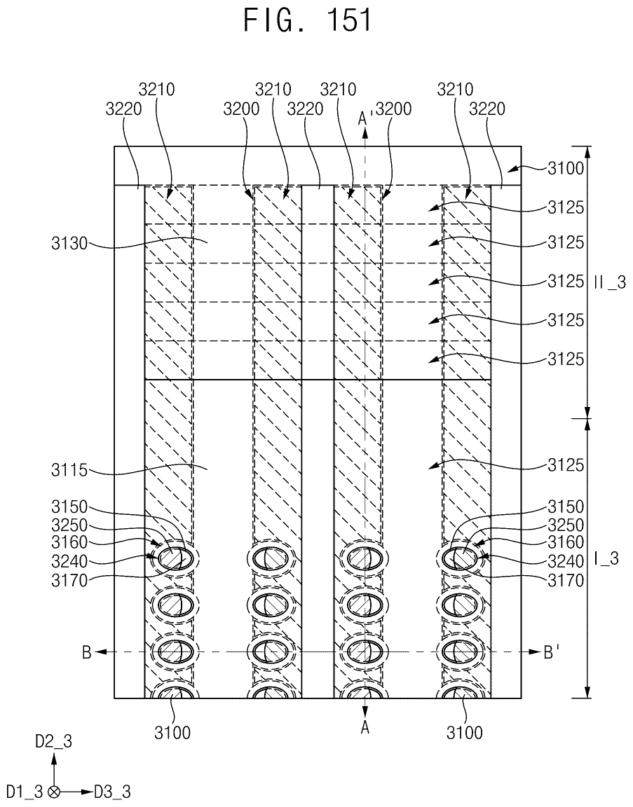

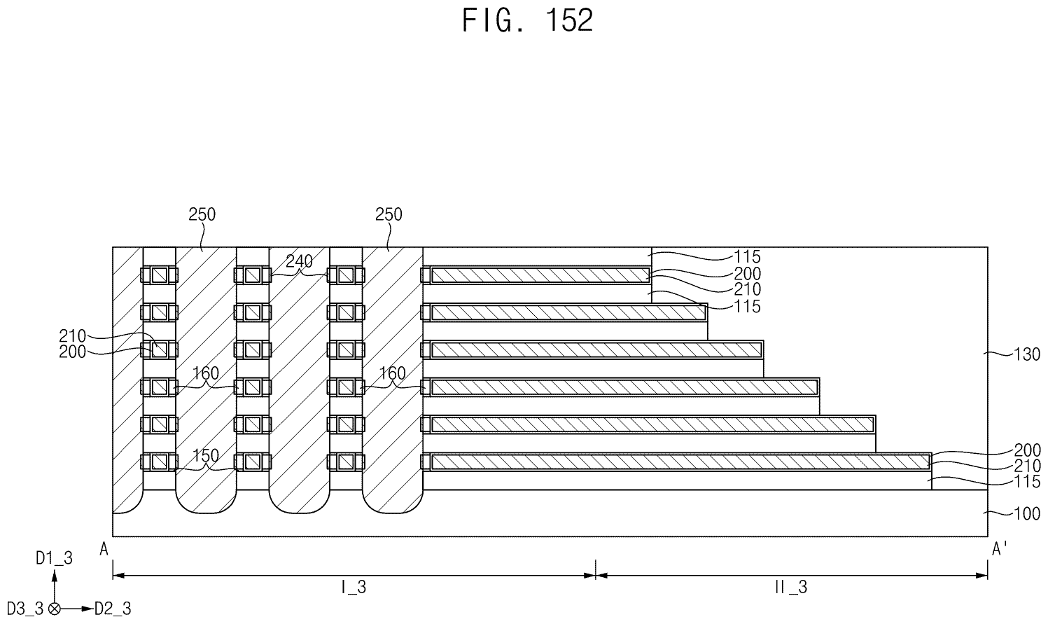

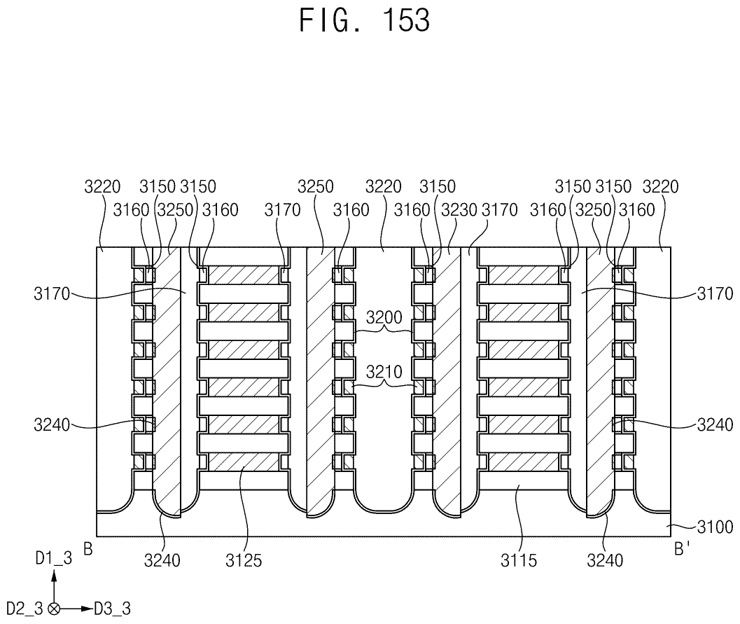

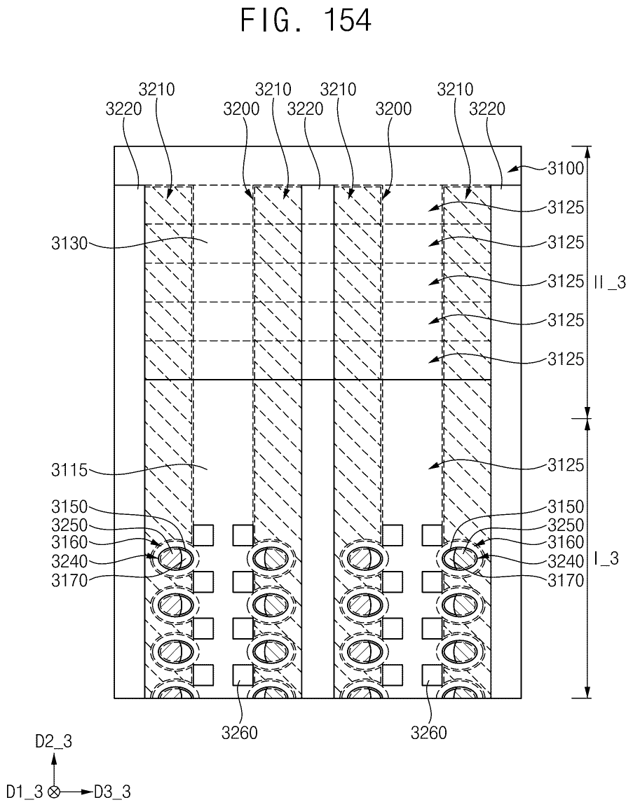

FIGS. 133 to 161 are plan views and cross-sectional views illustrating a method of manufacturing a third semiconductor device according to some example embodiments. Specifically, FIGS. 134, 138, 140, 143, 146, 148, 151, 154, 157 and 159 are plan views. FIGS. 133, 135-137, 139, 141, 144, 149, 152, 155 and 161 are cross-sectional views taken along lines A-A′ of corresponding plan views. FIGS. 142, 145, 147, 150, 153, 156, 158 and 160 are cross-sectional views taken along lines B-B′ of corresponding plan views.

Referring to FIG. 133, a first insulation layer 3110 and a first sacrificial layer 3120 may be alternately and repeatedly stacked on a first substrate 3100 including first and second regions I_3 and II_3 to form a mold layer, a photoresist pattern may be formed on the mold layer, and an etching process using the photoresist pattern as an etching mask and a trimming process on the photoresist pattern may be alternately and repeatedly performed to form a mold having a staircase shape.

The first insulation layer 3110 may include an oxide, e.g., silicon oxide, and the first sacrificial layer 3120 may include a material having an etching selectivity with respect to the first insulation layer 3110, e.g., an insulating nitride such as silicon nitride.

The mold may include step layers each of which may include the first insulation layer 3110 and the first sacrificial layer 3120 stacked in the first direction D1_3, and lengths in the second direction D2_3 of the step layers may decrease from a lowermost level to an uppermost level in a stepwise manner. Hereinafter, a portion of each of the step layers that is not overlapped by upper step layers in the first direction D1_3, that is, an end portion in the second direction D2_3 of each of the step layers may be referred to as a step.

In example embodiments, the steps of the mold may be formed on the second region II_3 of the first substrate 3100. In example embodiments, the steps of the mold may be formed on the second region II_3 of the first substrate 3100. In FIG. 133, steps arranged in the second direction D2_3 are formed at one side in the second direction D2_3 of the mold on the second region II_3 of the first substrate 3100.

FIG. 133 shows that each step layer includes the first insulation layer 3110 and the first sacrificial layer 3120 sequentially stacked in the first direction D1_3 in this order, however, the inventive concepts may not be limited thereto, and for example, each step layer may include the first sacrificial layer 3120 and the first insulation layer 3110 sequentially stacked in the first direction D1_3 in this order.

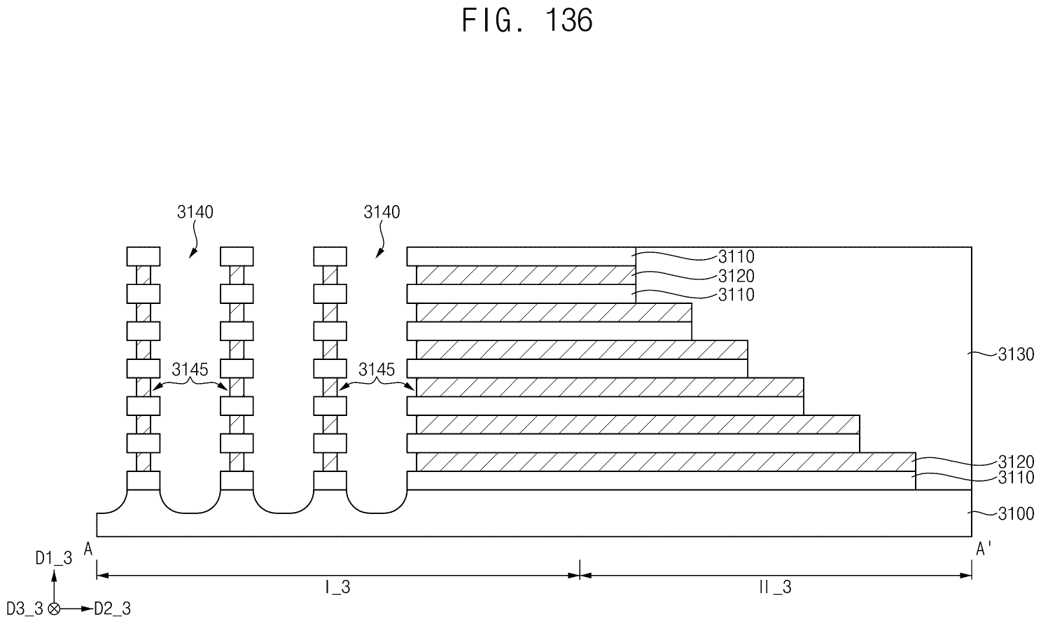

Referring to FIGS. 134 and 135, a first insulating interlayer 3130 may be formed on the first substrate 3100 to cover the mold, and a planarization process may be performed on the first insulating interlayer 3130 until an upper surface of the mold is exposed, and thus the first insulating interlayer 3130 may cover a sidewall of the mold.

The planarization process may include, e.g., a chemical mechanical polishing (CMP) process and/or an etch back process.

An etching process may be performed on a portion of the mold on the first region I_3 of the first substrate 3100 to form a first hole 3140 extending in the first direction D1_3 and exposing an upper surface of the first substrate 3100. The first hole 3140 may also extend through an upper portion of the first substrate 3100, and a plurality of first holes 3140 may be spaced apart from each other in the second and third directions D2_3 and D3_3. Each of the first holes 3140 may have a shape of, e.g., a circle, an ellipse, a polygon, a polygon with rounded corners, etc.

Referring to FIG. 136, a lateral portion of the first sacrificial layer 3120 exposed by the first hole 3140 may be removed to form a first recess 3145.

In example embodiments, the first recess 3145 may be formed by performing, e.g., a wet etching process on the first sacrificial layer 3120, and thus a plurality of first recesses 3145 connected to the first hole 3140 may be formed to be spaced apart from each other in the first direction D1_3. Each of the first recesses 3145 may have a shape of, e.g., a ring.

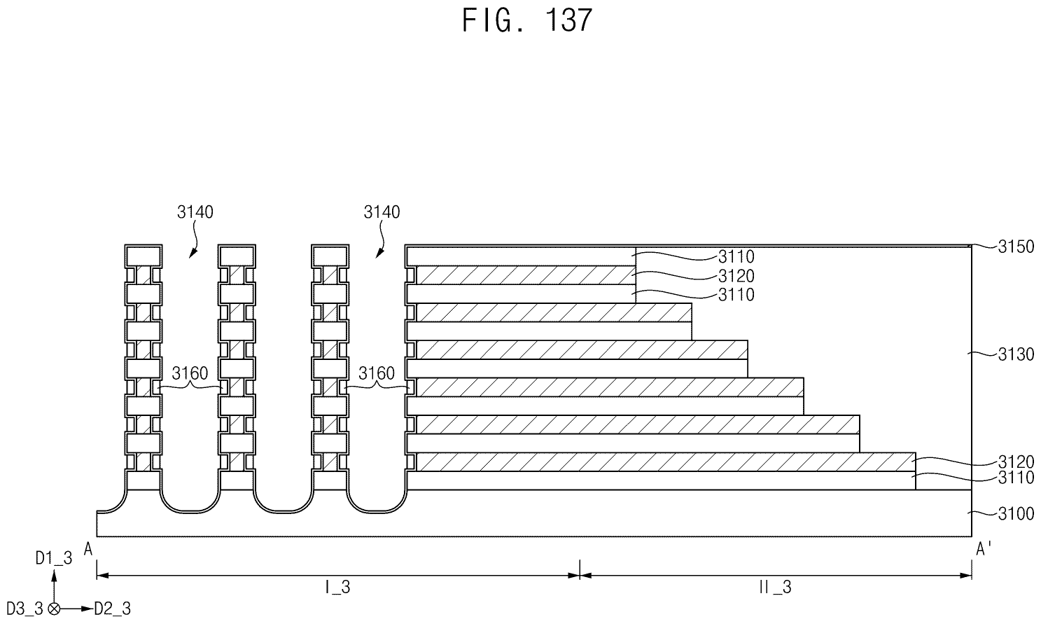

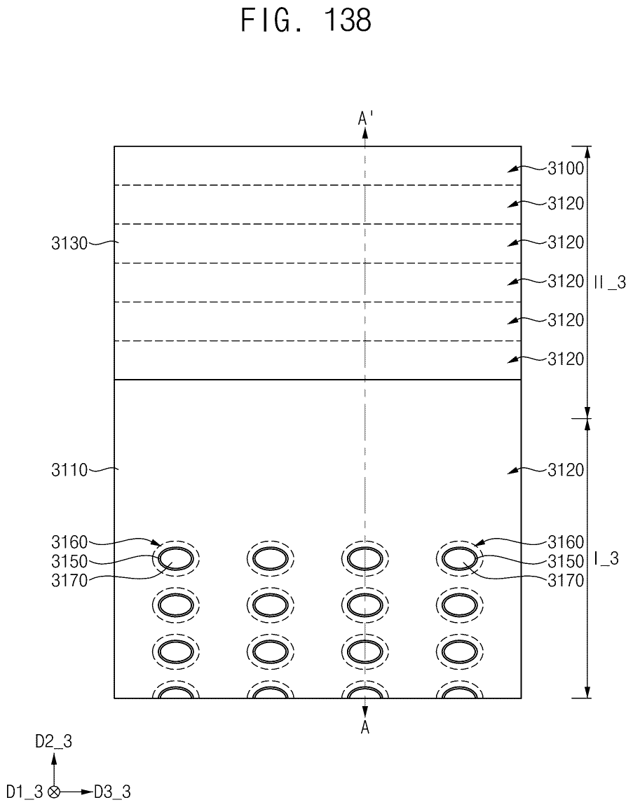

Referring to FIG. 137, a second insulation layer 3150 may be formed on inner walls of the first hole 3140 and the first recess 3145, an upper surface of the mold and an upper surface of the first insulating interlayer 3130, a channel layer may be formed on the second insulation layer 3150 to fill a portion of the first hole 3140 and the first recess 3145, and the channel layer may be partially removed to form a channel 3160.

The second insulation layer 3150 may include an oxide, e.g., silicon oxide, and in some cases, may be merged with the first insulation layer 3110.

The channel layer may be partially removed by, e.g., a wet etching process. In example embodiments, a plurality of channels 3160 may be spaced apart from each other in the first direction D1_3 along a sidewall of the first hole 3140, and each of the channels 3160 may have a shape of, e.g., a ring.

In example embodiments, a plurality of channels 3160 may be spaced apart from each other in the second and third directions D2_3 and D3_3 to form a channel array on the first region I_3 of the first substrate 3100. The channel array may include a plurality of channel columns, each of which may include a plurality of channels 3160 disposed in the second direction D2_3, spaced apart from each other in the third direction D3_3.

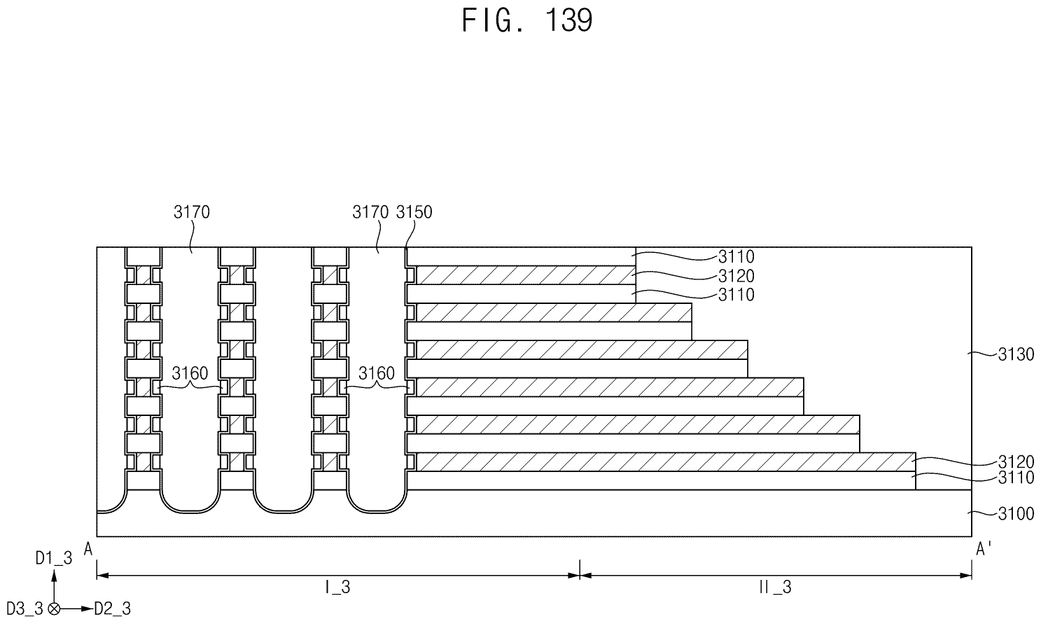

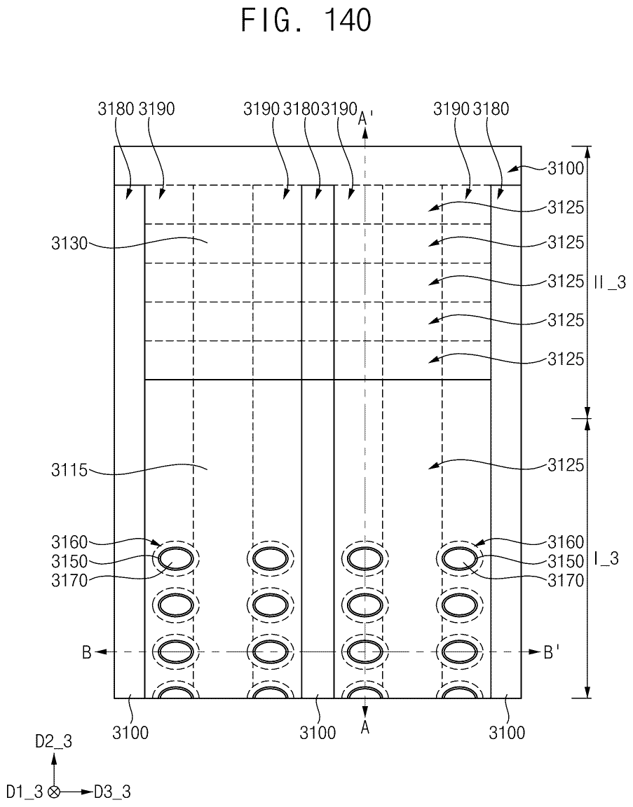

Referring to FIGS. 138 and 139, a third insulation layer may be formed on the second insulation layer 3150 and the channel 3160 to fill the first hole 3140, and a planarization process may be performed on the third insulation layer until the upper surface of the mold and an upper surface of the first insulating interlayer 3130 are exposed to form a third insulation pattern 3170 in the first hole 3140.

The third insulation pattern 3170 may have a shape of a pillar extending in the first direction D1_3, and a plurality of third insulation patterns 3170 may be spaced apart from each other in the second and third directions D2_3 and D3_3 on the first region I_3 of the first substrate 3100.

During the planarization process, a portion of the second insulation layer 3150 on the upper surface of the mold and the upper surface of the first insulating interlayer 3130 may also be removed.

Referring to FIGS. 140 to 142, a first opening 3180 may be formed through the mold to expose the upper surface of the first substrate 3100, and the first opening 3180 may also extend through the upper portion of the first substrate 3100.

In example embodiments, the first opening 3180 may extend to both opposite end portions of the mold in the second direction D2_3 on the first and second regions I_3 and II_3 of the first substrate 3100, and a plurality of first openings 3180 may be spaced apart from each other in the third direction D3_3. As the first opening 3180 is formed, the first insulation layer 3110 may be divided into a plurality of first insulation patterns 3115, each of which may extend in the second direction D2_3, spaced apart from each other in the third direction D3_3, and the first sacrificial layer 3120 may be divided into a plurality of first sacrificial patterns 3125, each of which may extend in the second direction D2_3, spaced apart from each other in the third direction D3_3.

In example embodiments, each of the first openings 3180 may be formed between neighboring ones of the channel columns in the third direction D3_3, and two channel columns may be disposed between neighboring ones of the first openings 3180.

A lateral portion of the first sacrificial pattern 3125 exposed by the first opening 3180 and a portion of the second insulation layer 3150 adjacent thereto may be removed to form a second recess 3190 exposing a sidewall of the channel 3160.

In example embodiments, the second recess 3190 may be formed by performing, e.g., a wet etching process on the first sacrificial pattern 3125 and the second insulation layer 3150, and a plurality of second recesses 3190 connected to the first opening 3180 may be formed to be spaced apart from each other in the first direction D1_3. Each of the second recesses 3190 may extend in the second direction D2_3 on the first and second regions I_3 and II_3 of the first substrate 3100. In some example embodiments, the second recess 3190 may expose most of each of the channels 3160 included in the channel column adjacent to the first opening 3180.

Referring to FIGS. 143 to 145, a first gate insulation layer 3200 may be formed on inner walls of the first opening 3180 and the second recess 3190, an upper surface of the third insulation pattern 3170, an upper surface of the second insulation layer 3150, the upper surface of the mold and the upper surface of the first insulating interlayer 3130, a first gate electrode layer may be formed on the first gate insulation layer 3200 to fill a portion of the first opening 3180 and the second recess 3190, and the first gate electrode layer may be partially removed to form a first gate electrode 3210.

The first gate insulation layer 3200 may include an oxide, e.g., silicon oxide, and in some cases, a portion of the second insulation layer 3150 contacting the first gate insulation layer 3200 may be merged thereto.

The first gate electrode layer may be partially removed by, e.g., a wet etching process. In example embodiments, the first gate electrode 3210 may extend in the second direction D2_3 at each of opposite sides in the third direction D3_3 of the first opening 3180, and thus a plurality of first gate electrode layers may be formed to be spaced apart from each other in the third direction D3_3. Each of the first gate electrodes 3210 may surround most of a sidewall of each of the channels 3160 included in the channel column, and the first gate insulation layer 3200 may be interposed between each of the first gate electrodes 3210 and each of the channels 3160.

A plurality of first gate electrodes 3210 may be spaced apart from each other in the first direction D1_3 to form a first gate electrode structure. The first gate electrode structure may have a shape of a staircase having a length in the second direction D2_3 that may decrease from a lowermost level to an uppermost level in a stepwise manner. Hereinafter, each of opposite end portions of each of the first gate electrodes 3210 in the first gate electrode structure that is not overlapped by upper ones of the first gate electrodes 3210 in the first direction D1_3 may be referred to as a pad.

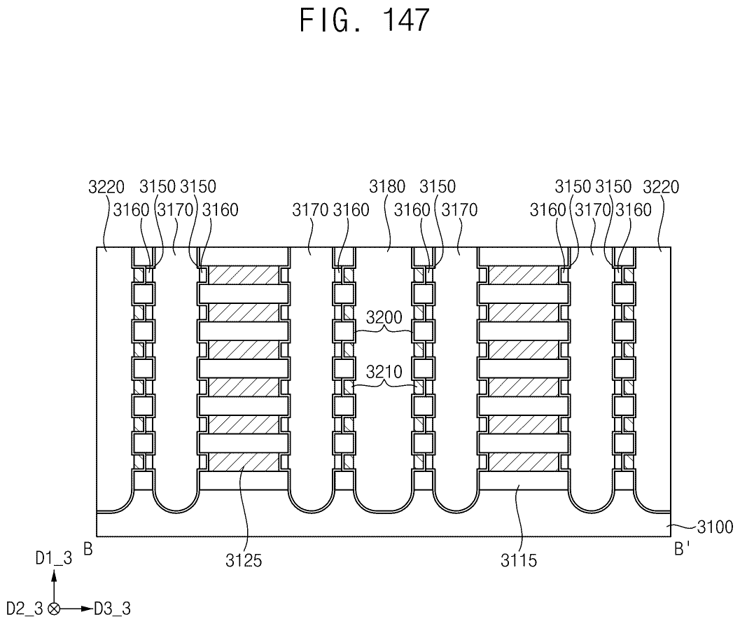

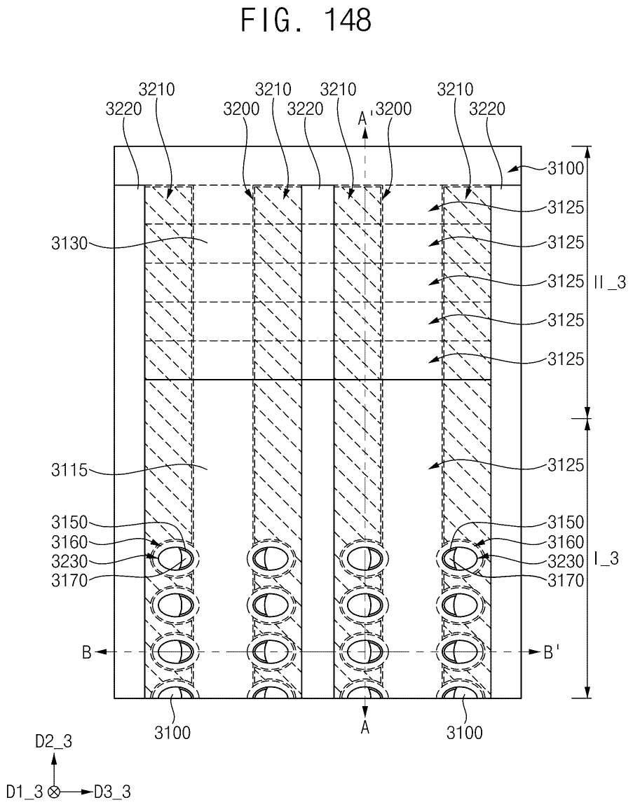

Referring to FIGS. 146 and 147, a fourth insulation layer may be formed on the first gate insulation layer 3200 and the first gate electrode 3210 to fill the first opening 3180, and a planarization process may be performed on the fourth insulation layer until the upper surfaces of the mold, the third insulation pattern 3170, the second insulation layer 3150 and the first insulating interlayer 3130 are exposed to form a fourth insulation pattern 3220 in the first opening 3180.

The fourth insulation pattern 3220 may extend in the second direction D2_3 on the first and second regions I_3 and II_3 of the first substrate 3100, and a plurality of fourth insulation patterns 3220 may be spaced apart from each other in the third direction D3_3.

During the planarization process, a portion of the first gate insulation layer 3200 on the upper surfaces of the mold, the third insulation pattern 3170 and the first insulating interlayer 3130 may also be removed.

Referring to FIGS. 148 to 150, a portion of the third insulation pattern 3170 and a portion of the second insulation layer 3150 adjacent thereto may be removed to form a second hole 3230 exposing the upper surface of the first substrate 3100.

As the second hole 3230 is formed, sidewalls of the channel 3160 and the first insulation pattern 3115 may partially exposed.

In example embodiments, a plurality of second holes 3230 may be spaced apart from each other in the second and third directions D2_3 and D3_3 on the first region I_3 of the first substrate 3100.

Referring to FIGS. 151 to 153, a first ohmic contact pattern 3240 may be formed on the sidewall of the channel 3160 exposed by the second hole 3230.

In example embodiments, the first ohmic contact pattern 3240 may be formed by forming a first metal layer on an inner wall of the second hole 3230, the upper surfaces of the third and fourth insulation patterns 3170 and 3220, the upper surface of the second insulation layer 3150, the upper surface of the mold and the upper surface of the first insulating interlayer 3130, and performing a heat treatment process on the first metal layer so that a metal included in the first metal layer and a semiconductor material included in the channel 3160 may be reacted with each other, and an unreacted portion of the first metal layer may be removed.

A plurality of first ohmic contact patterns 3240 may be spaced apart from each other in the first direction D1_3 on the first region I_3 of the first substrate 3100, and may also be spaced apart from each other in the second and third directions D2_3 and D3_3. Each of the first ohmic contact patterns 3240 may have a shape of, e.g., a portion of a ring.

The first ohmic contact pattern 3240 may also be formed on the upper surface of the first substrate 3100 including a semiconductor material and exposed by the second hole 3230.

A bit line layer may be formed on the first substrate 3100, the third and fourth insulation patterns 3170 and 3220, the second insulation layer 3150, the mold and the first insulating interlayer 3130 to fill the second hole 3230, and a planarization process may be performed on the bit line layer until the upper surface of the first insulating interlayer 3130 is exposed to form a bit line 3250 in the second hole 3230.

In example embodiments, a plurality of bit lines 3250 may be spaced apart from each other in the second and third directions D2_3 and D3_3 on the first region I_3 of the first substrate 3100, and each of the bit lines 3250 may have a shape of a pillar extending in the first direction D1_3. Each of the bit lines 3250 may contact the first ohmic contact pattern 3240, and may be electrically connected to the channels 3160 disposed in the first direction D1_3 through the first ohmic contact pattern 3240.

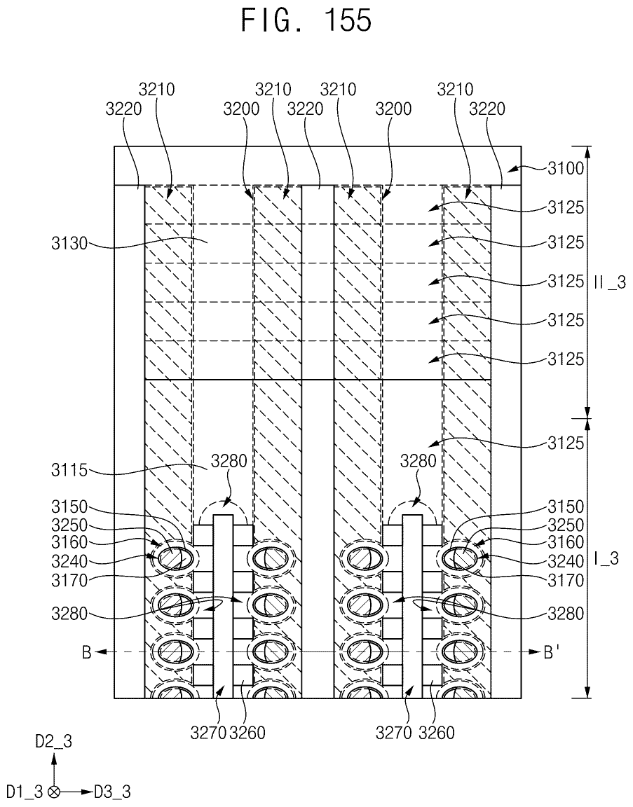

Referring to FIG. 154, a third hole may be formed through the mold to expose the upper surface of the first substrate 3100 on the first region I_3 of the first substrate 3100, and a fifth insulation pattern 3260 may be formed in the third hole.

The third hole may also extend through an upper portion of the first substrate 3100, and thus the fifth insulation pattern 3260 in the third hole may extend through the upper portion of the first substrate 3100. In example embodiments, the fifth insulation pattern 3260 may have a pillar shape extending in the first direction D1_3, and a plurality of fifth insulation patterns 3260 may be spaced apart from each other in the second and third directions D2_3 and D3_3 to form a fifth insulation pattern array.

The fifth insulation pattern array may include a plurality of fifth insulation pattern columns, each of which may include a plurality of fifth insulation patterns 3260 disposed in the second direction D2_3, spaced apart from each other in the third direction D3_3. Each of the fifth insulation patterns 3260 included in each of the fifth insulation pattern columns may extend through a portion of the mold between ones of the channels 3160 of a corresponding one of the channel columns, and may contact a sidewall of the first gate insulation layer 3200. Ones of the fifth insulation patterns 3260 included in respective ones of the fifth insulation pattern columns neighboring in the third direction D3_3 may be aligned with each other in the third direction D3_3.

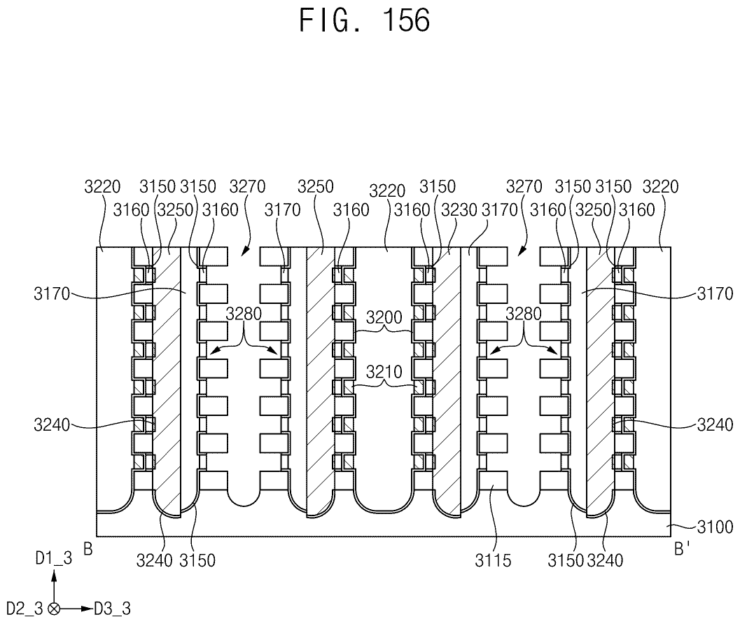

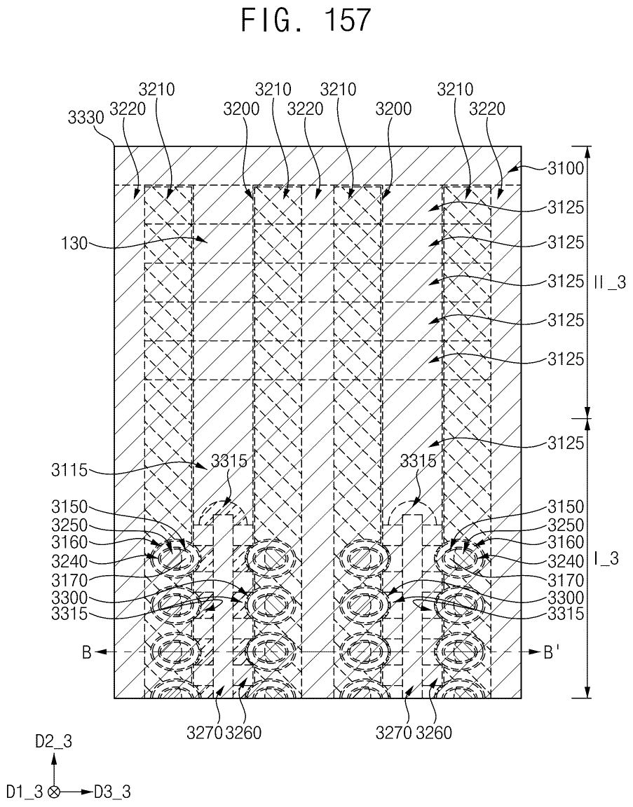

Referring to FIGS. 155 and 156, a second opening 3270 may be formed through the mold to expose the upper surface of the first substrate 3100 on the first region I_3 of the first substrate 3100, and a portion of the first sacrificial pattern 3125 exposed by the second opening 3270 and a portion of the second insulation layer 3150 adjacent thereto may be removed by, e.g., a wet etching process to form a third recess 3280.

In example embodiments, the second opening 3270 may extend in the second direction D2_3 between neighboring ones of the fifth insulation pattern columns in the third direction D3_3, and may expose sidewalls of the fifth insulation patterns 3260 included in the neighboring ones of the fifth insulation pattern columns. In example embodiments, a plurality of third recesses 3280 may be spaced apart from each other in the second direction D2_3 by the fifth insulation patterns 3260, and may also be spaced apart from each other in the first direction D1_3 by the first insulation patterns 3115. Each of the third recesses 3280 may expose a sidewall, particularly, a sidewall in the third direction D3_3 of a corresponding one of the channels 3160.

During the wet etching process, a portion of the first sacrificial pattern 3125 at each of end portions in the second direction D2_3 of the second opening 3270 may also be removed, and thus, in a plan view, the third recess 3280 may have a shape of a semi-circle adjacent to each of the end portions of the second opening 3270.

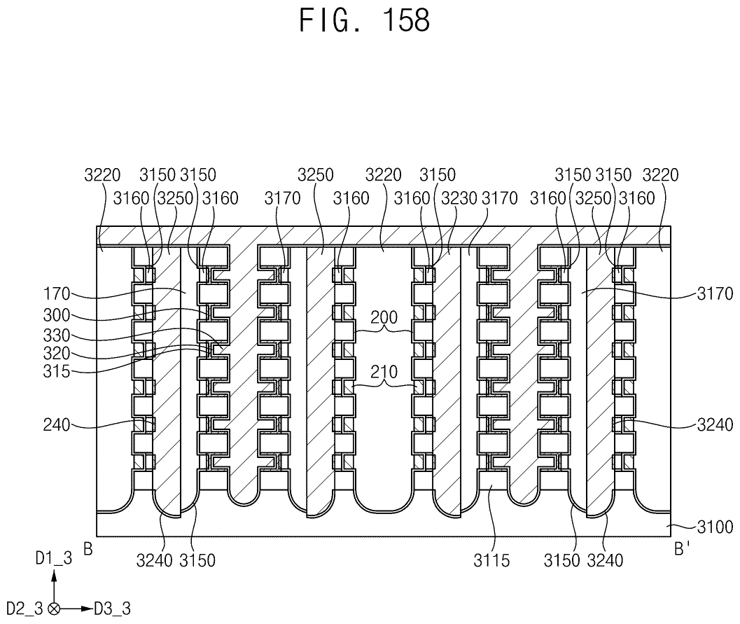

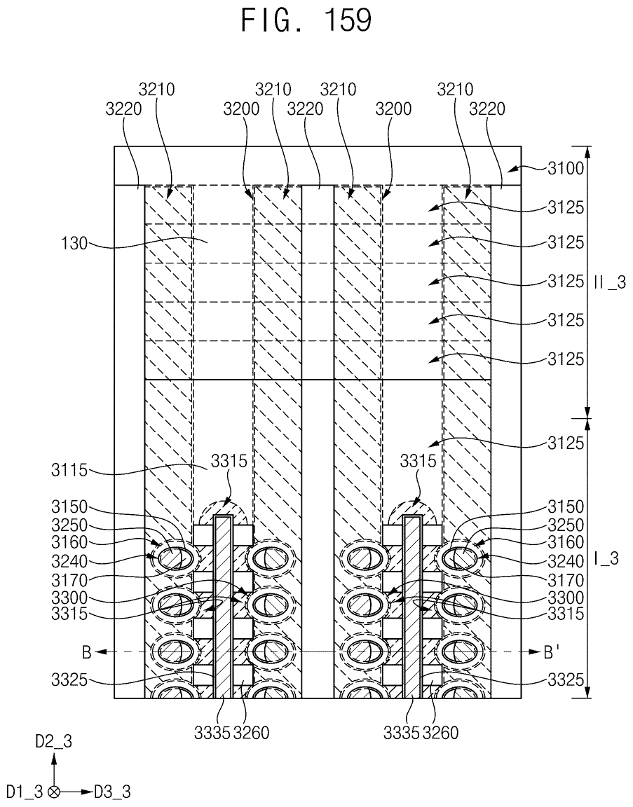

Referring to FIGS. 157 and 158, a second ohmic contact pattern 3300 may be formed on the sidewall of the channel 3160 exposed by the third recess 3280.

In example embodiments, the second ohmic contact pattern 3300 may be formed by forming a second metal layer on inner walls of the second opening 3270 and the third recess 3280, the upper surfaces of the third and fourth insulation patterns 3170 and 3220, the upper surface of the second insulation layer 3150, an upper surface of the bit line 3250, the upper surface of the mold and the upper surface of the first insulating interlayer 3130, and performing a heat treatment process on the second metal layer so that a metal included in the second metal layer and the semiconductor material included in the channel 3160 may be reacted with each other, and an unreacted portion of the second metal layer may be removed.

A plurality of second ohmic contact patterns 3300 may be spaced apart from each other in the first direction D1_3 on the first region I_3 of the first substrate 3100, and may also be spaced apart from each other in the second and third directions D2_3 and D3_3. Each of the second ohmic contact patterns 3240 may have a shape of, e.g., a portion of a ring.

The second ohmic contact pattern 3300 may also be formed on the upper surface of the first substrate 3100 including the semiconductor material and exposed by the second opening 3270.

A first capacitor electrode layer may be formed on the inner walls of the second opening 3270 and the third recess 3280, the upper surfaces of the third and fourth insulation patterns 3170 and 3220, the upper surface of the second insulation layer 3150, the upper surface of the bit line 3250, the upper surface of the mold and the upper surface of the first insulating interlayer 3130, forming a second sacrificial layer on the first capacitor electrode layer to fill the third recess 3280, and performing, e.g., a wet etching process on the second sacrificial layer to form a second sacrificial pattern in the third recess 3280, and thus a portion of the first capacitor electrode layer at an outside of the third recess 3280 may be exposed.

The exposed portion of the first capacitor electrode layer may be removed to form a first capacitor electrode 3315 on the inner wall of the third recess 3280, and the second sacrificial pattern may be removed. In example embodiments, a plurality of first capacitor electrodes 3315 may be spaced apart from each other in the first direction D1_3 on the first region I_3 of the first substrate 3100, and may also be spaced apart from each other in the second and third directions D2_3 and D3_3 to form a first capacitor electrode array. The first capacitor electrode array may include a plurality of first capacitor electrode columns, each of which may include the first capacitor electrodes 3315 spaced apart from each other in the second direction D2_3, spaced apart from each other in the third direction D3_3.

Each of the first capacitor electrodes 3315 may contact sidewalls of the second ohmic contact pattern 3300 and the second insulation layer 3150, and may be electrically connected to the channel 3160 through the second ohmic contact pattern 3300.

The first capacitor electrode 3315 may also be formed in the third recess 3280 adjacent to each of end portions of the second opening 3270 in the second direction D2_3, which may have a shape of, e.g., a semi-circle in a plan view.

A dielectric layer 3320 may be formed on the inner wall of the second opening 3270, the upper surfaces of the third and fourth insulation patterns 3170 and 3220, the upper surface of the second insulation layer 3150, the upper surface of the bit line 3250, the upper surface of the mold and the upper surface of the first insulating interlayer 3130, and a second capacitor electrode layer 3330 may be formed on the dielectric layer 3320 to fill the second opening 3270.

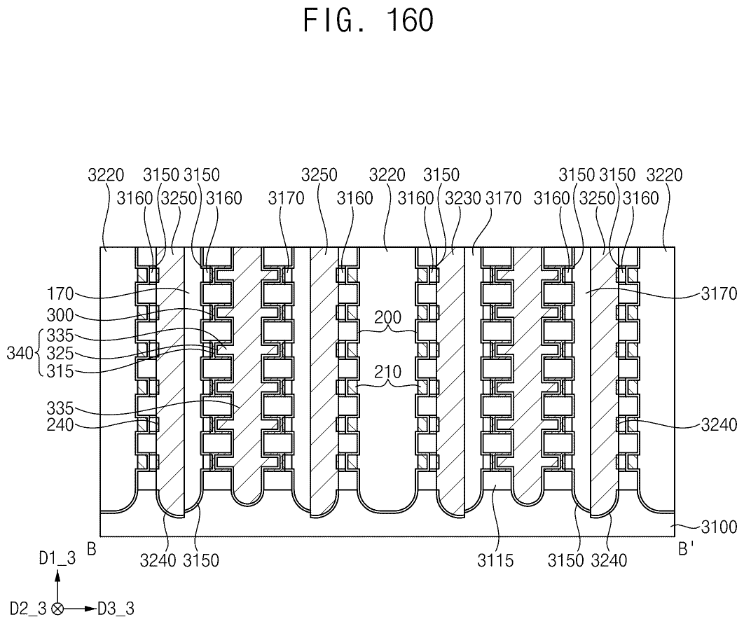

Referring to FIGS. 159 and 160, a planarization process may be performed on the second capacitor electrode layer 3330 and the dielectric layer 3320 until the upper surface of the mold is exposed so that the second capacitor electrode layer 3330 and the dielectric layer 3320 may be transformed into a second capacitor electrode 3335 and a dielectric pattern 3325, respectively.

The first capacitor electrode 3315, the dielectric pattern 3325 and the second capacitor electrode 3335 may collectively form a capacitor structure 3340.

In example embodiments, the second capacitor electrode 3335 may extend in the second direction D2_3 on the first region I_3 of the first substrate 3100, and a plurality of second capacitor electrodes 3335 may be spaced apart from each other in the third direction D3_3. The second capacitor electrode 3335 may include an extension portion extending in the second direction D2_3 and a first protrusion portion protruding in the third direction D3_3 from each of opposite sidewalls in the third direction D3_3 of the extension portion and facing the sidewall of the channel 3160. In example embodiments, the second capacitor electrode 3335 may include a plurality of first protrusion portions spaced apart from each other in the second and third directions D2_3 and D3_3, and may also be spaced apart from each other in the first direction D1_3.

The second capacitor electrode 3335 may further include a second protrusion portion protruding from each of end portions in the second direction D2_3 of the extension portion and having a shape of a semi-circle in a plan view.

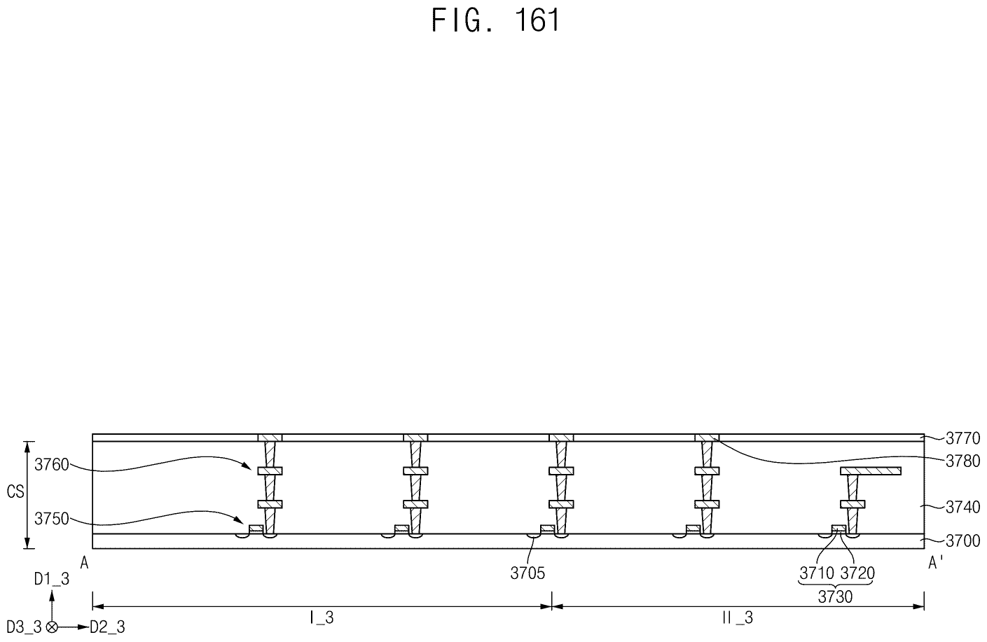

Referring to FIG. 161, peripheral circuit patterns 3750 such as transistors including, for example, a second gate structure 3730 and source/drain layers 3705, a wiring structure 3760 including contact plugs, wirings, vias and pads, and a third insulating interlayer 3740 covering the peripheral circuit patterns 3750 and the wiring structure 3760 may be formed on a second substrate 3700 including first and second regions I_3 and II_3 corresponding to the first and second regions I_3 and II_3 of the first substrate 3100, respectively. A second bonding layer 3770 may be formed on the third insulating interlayer 3740, and second bonding pads 3780 extending through the second bonding layer 3770 and respectively contacting upper surfaces of the vias may be formed.

Referring again to FIGS. 130 to 132, a second insulating interlayer 3370 may be formed on the third to fifth insulation patterns 3170, 3220 and 3260, the dielectric pattern 3325, the second capacitor electrode 3335, the second insulation layer 3150, the bit line 3250, the mold, and the first insulating interlayer 3370, and a first word line contact 3380 may be formed to extend through the first and second insulating interlayers 3130 and 3370 to contact a pad of a corresponding first gate electrode 3210.

Meanwhile, although not shown, a third contact plug that extends through the second insulating interlayer 3370 to contact an upper surface of a corresponding second capacitor electrode 3335 may also be formed.

A fourth insulating interlayer (not shown) may be formed on the second insulating interlayer 3370 and the first word line contact 3380, and a first handling substrate (not shown) may be bonded on the fourth insulating interlayer via a third bonding layer (not shown).

Thereafter, the first handling substrate may be flipped. Accordingly, since structures formed on the first substrate 3100 are flipped upside down, the following description will be based on this flipped orientation.

An upper portion of the first substrate 3100 may be removed through, for example, a grinding process, and accordingly, an upper surface of the first insulation pattern 3115 may be exposed. During the grinding process, the first insulation pattern 3115 may serve as a grinding endpoint.

During the grinding process, upper portions of the second insulation layer 3150, the third insulation pattern 3170, the fourth insulation pattern 3220, the first ohmic contact pattern 3240 and the bit line 3250 may also be removed together.

A fifth insulating interlayer 3400 and a first bit line wiring structure BLICS1_3 accommodated therein may be formed on the exposed upper surfaces of the second insulation layer 3150, the third insulation pattern 3170, the fourth insulation pattern 3220 and the bit line 3250, and a first bonding layer 3670 and a first bonding pad 3680 accommodated therein may be formed on the fifth insulating interlayer 3400.

The first handling substrate may be flipped again to bond the first and second bonding layers 3670 and 3770 to each other. Accordingly, since structures formed on the first handling substrate are flipped again upside down, the following description will be based on this flipped orientation.

The first handling substrate, the third bonding layer, and the fourth insulating interlayer may be removed from the second insulating interlayer 3370 through, for example, a grinding process and/or a chemical mechanical polishing (CMP) process.

A sixth insulating interlayer 3500 and a first word line wiring structure BLICS1_3 accommodated therein may be formed on the second insulating interlayer 3370 to complete the manufacture of the third semiconductor device.

As illustrated above, the mold including the first insulation layer 3110 and the first sacrificial layer 3120 may be formed on the first substrate 3100, the first hole 3140 may be formed through the mold, the portion of the first sacrificial layer 3120 adjacent to the first hole 3140 may be removed to form the first recess 3145, and the channel 3160 may be formed in the first recess 3145. The third insulation pattern 3170 may be formed in the first hole 3140, the first opening 3180 may be formed through the mold, and the portion of the first sacrificial layer 3120 adjacent to the first opening 3180 may be removed to form the second recess 3190, and the first gate electrode 3210 may be formed in the second recess 3190.

The third insulation pattern 3170 may be partially removed to form the second hole 3230, the bit line 3250 may be formed in the second hole 3230, the second opening 3270 may be formed through the mold, the portion of the first sacrificial layer 3120 adjacent to the second opening 3270 may be removed to form the third recess 3280 exposing the sidewall of the channel 3160, and the first capacitor electrode 3315 may be formed in the third recess 3280.

Thus, the channel 3160, the first gate electrode 3210 and the first capacitor electrode 3315 may be formed at the same level, so that the vertical thickness thereof may be reduced. Accordingly, the formation of the channel 3160, the first gate electrode 3210 and the first capacitor electrode 3315 may be easily performed.

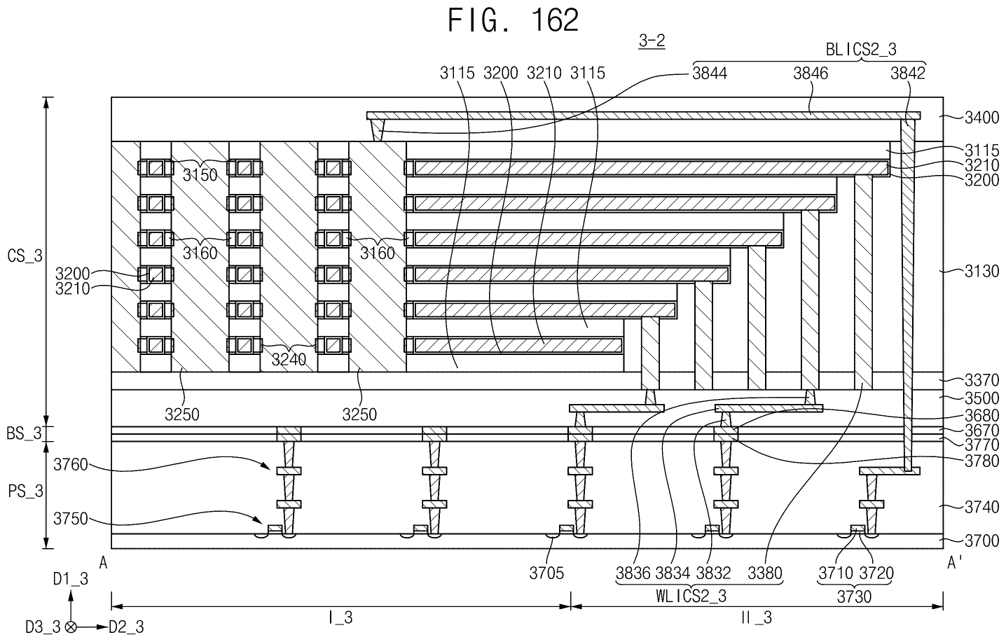

FIG. 162 is a cross-sectional view illustrating a third semiconductor device in accordance with a second example embodiment 3-2, which may correspond to FIG. 131.

The second example embodiment 3-2 of the third semiconductor device may be substantially the same as or similar to the first example embodiment 3-1 of the second semiconductor device shown in FIGS. 130 to 132, except for the arrangement of the cell structure CS_3 and the peripheral circuit structure PS_3, and including a second word line wiring structure WLICS2_3 and a second bit line wiring structure BLICS2_3 instead of the first word line wiring structure WLICS1_3 and the first bit line wiring structure BLICS1_3, respectively, and thus repeated explanations are omitted herein.

Referring to FIG. 162, the third semiconductor device may have a structure in which the first front surface of the cell structure CS_3 and the second front surface of the second substrate 3700 face each other.

The second word line wiring structure WLICS2_3 may include the first word line contact 3380, a fourth word line contact 3832, a second word line wiring 3834 and a fifth word line contact 3836.

The fourth word line contact 3832 may extend through a lower portion of the sixth insulating interlayer 3500 to contact an upper surface of the bonding pad structure. The second word line wiring 3834 may extend in the second direction D2_3 within the sixth insulating interlayer 3500 to contact an upper surface of the fourth word line contact 3832. The fifth word line contact 3836 may extend through an upper portion of the sixth insulating interlayer 600 to contact a lower surface of the first word line contact 3380 and an upper surface of the second word line wiring 3834.

In example embodiments, a width in the horizontal direction of each of the fourth and fifth word line contacts 3832 and 3836 may decrease away from the second front surface of the second substrate 3700.

The second bit line wiring structure BLICS2_3 may include a fourth bit line contact 3842, a fifth bit line contact 3844 and a second bit line wiring 3846.

The fourth bit line contact 3842 may extend through a lower portion of the fifth insulating interlayer 3400, the first insulating interlayer 3130, the second insulating interlayer 3370, the sixth insulating interlayer 3500, the bonding layer structure, and an upper portion of the third insulating interlayer 3740 to contact the pad of the wiring structure 3760. The fifth bit line contact 3844 may extend through a lower portion of the fifth insulating interlayer 3400 to contact an upper surface of the bit line 3250. The second bit line wiring 3846 may extend in the second direction D2_3 within the fifth insulating interlayer 3400 to commonly contact upper surfaces of the fourth and fifth bit line contacts 3842 and 3844. Meanwhile, the pad of the wiring structure 2760 may serve as a landing pad for the fourth bit line contact 3842.

In example embodiments, a width in the horizontal direction of each of the fourth and fifth bit line contacts 3842 and 3844 may increase away from the second front surface of the second substrate 3700.

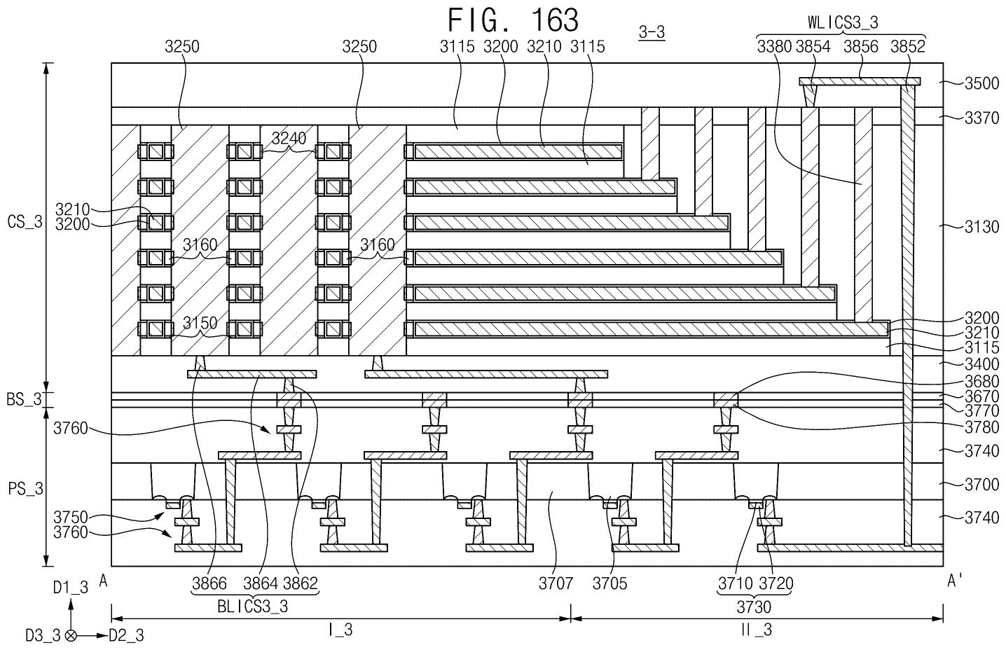

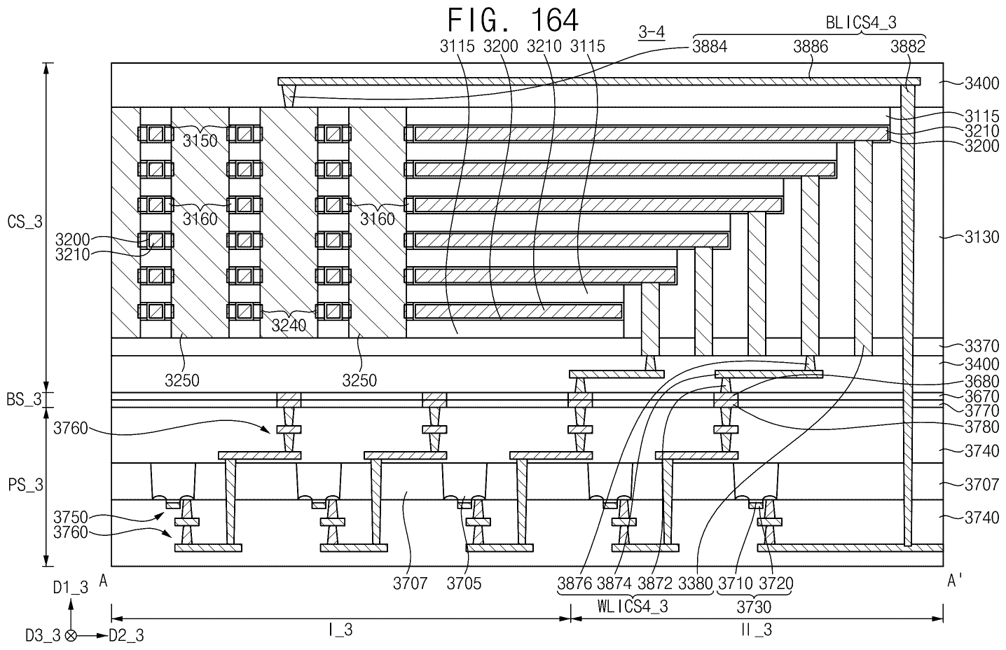

FIG. 163 is a cross-sectional view illustrating a third semiconductor device in accordance with a third example embodiment 3-3, which may correspond to FIG. 131.

The third example embodiment 3-3 of the third semiconductor device may be substantially the same as or similar to the first example embodiment 3-1 of the third semiconductor device shown in FIGS. 130 to 132, except for the arrangement of the cell structure CS_3 and the peripheral circuit structure PS_3, and including a third word line wiring structure WLICS3_3 and a third bit line wiring structure BLICS3_3 instead of the first word line wiring structure WLICS1_3 and the first bit line wiring structure BLICS1_3, respectively, and thus repeated explanations are omitted herein.

Referring to FIG. 163, the third example embodiment 3-3 of the third semiconductor device may have a structure in which the first rear surface of the cell structure CS_3 and the second rear surface of the second substrate 3700 face each other.

The peripheral circuit structure PS_3 included in the third semiconductor device may further include an isolation pattern 3707 substantially the same as or similar to the isolation pattern 1607 of the peripheral circuit structure PS_1 included in the first semiconductor device.

The third insulating interlayer 3740 may include an upper portion disposed on the second front surface of the second substrate 3700 on which the peripheral circuit pattern 3750 is formed and a lower portion disposed on the second rear surface of the second substrate 3700, and the wiring structure 3760 may include an upper portion disposed on the second front surface of the second substrate 3700 and a lower portion disposed on the second rear surface of the second substrate 3700. The upper and lower portions of the wiring structure 3760 may be electrically connected to each other through a contact plug extending through the isolation pattern 707.

The third word line wiring structure WLICS3_3 may include the first word line contact 3380, a sixth word line contact 3852, a seventh word line contact 3854 and a third word line wiring 3856.

The sixth word line contact 3852 may extend through a lower portion of the sixth insulating interlayer 3500, the second insulating interlayer 3370, the first insulating interlayer 3130, the fifth insulating interlayer 3400, the bonding layer structure, the lower portion of the third insulating interlayer 3740, the isolation pattern 707, and the upper portion of the third insulating interlayer 3740 to contact the pad of the wiring structure 3760. The seventh word line contact 3854 may extend through a lower portion of the sixth insulating interlayer 3500 to contact an upper surface of the first word line contact 3380. The third word line wiring 3856 may extend in the second direction D2_3 within the sixth insulating interlayer 3500 to commonly contact upper surfaces of the sixth and seventh word line contacts 3852 and 3854. Meanwhile, the pad of the wiring structure 2760 may serve as a landing pad for the sixth word line contact 3852.

In example embodiments, a width in the horizontal direction of each of the sixth and seventh word line contacts 3852 and 3854 may increase away from the second rear surface of the second substrate 3700.

The third bit line wiring structure BLICS3_3 may include a sixth bit line contact 3862, a third bit line wiring 3864 and a seventh bit line contact 3866.

The sixth bit line contact 3862 may extend through a lower portion of the fifth insulating interlayer 3400 to contact an upper surface of the bonding layer structure. The third bit line wiring 3864 may extend in the second direction D2_3 within the fifth insulating interlayer 3400 to contact an upper surface of the sixth bit line contact 3862. The seventh bit line contact 3866 may extend through an upper portion of the fifth insulating interlayer 3400 to contact a lower surface of the seventh bit line wiring 3864 and an upper surface of the third bit line wiring 3864.

In example embodiments, a width in the horizontal direction of each of the sixth and seventh bit line contacts 3862 and 3866 may decrease away from the second rear surface of the second substrate 3700.

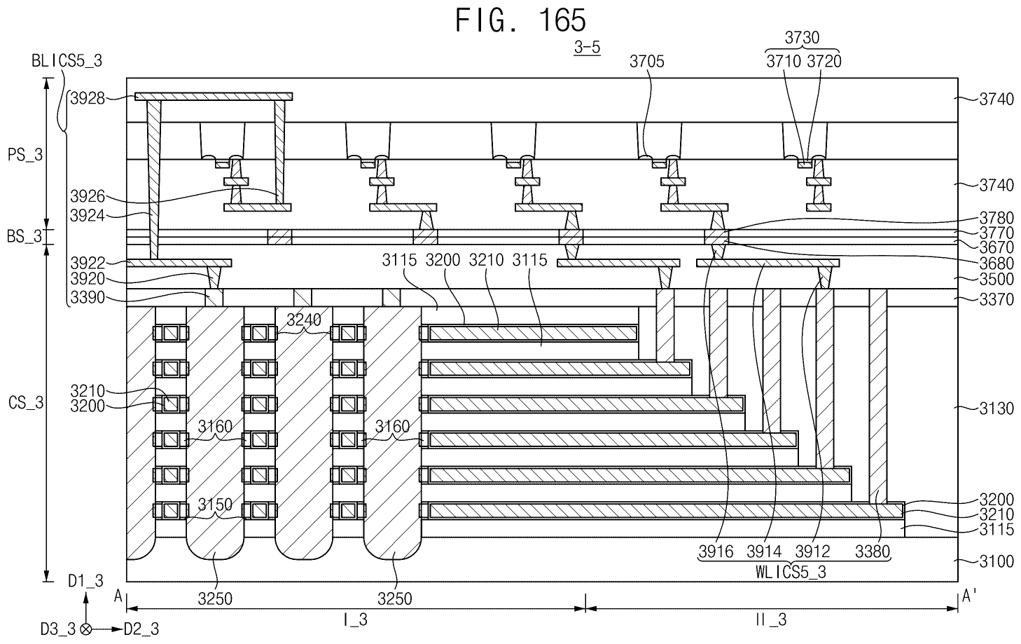

FIG. 164 is a cross-sectional view illustrating a third semiconductor device in accordance with a fourth example embodiment 3-4, which may correspond to FIG. 163.

The fourth example embodiment 3-4 of the third semiconductor device may be substantially the same as or similar to the third example embodiment 3-3 of the third semiconductor device shown in FIG. 163, except for the arrangement of the cell structure CS_3 and the peripheral circuit structure PS_3, and including a fourth word line wiring structure WLICS4_3 and a fourth bit line wiring structure BLICS4_3 instead of the third word line wiring structure WLICS3_3 and the third bit line wiring structure BLICS3_3, respectively, and thus repeated explanations are omitted herein.

Referring to FIG. 164, the fourth example embodiment 3-4 of the third semiconductor device may have a structure in which the first front surface of the cell structure CS_3 and the second rear surface of the second substrate 3700 face each other.

The fourth word line wiring WLICS4_3 may include the first word line contact 3380, an eighth word line contact 3872, a fourth word line wiring 3874 and a ninth word line contact 3876.

The eighth word line contact 3872 may extend through a lower portion of the sixth insulating interlayer 3500 to contact an upper surface of the insulation pattern structure. The fourth word line wiring 3874 may extend in the second direction D2_3 within the sixth insulating interlayer 3500 to contact an upper surface of the eighth word line contact 3872. The ninth word line contact 3876 may extend through an upper portion of the sixth insulating interlayer 3500 to contact a lower surface of the first word line contact 3380 and an upper surface of the fourth word line wiring 3874.

In example embodiments, a width in the horizontal direction of each of the eighth and ninth word line contacts 3872 and 3876 may decrease away from the second rear surface of the second substrate 3700.

The fourth bit line wiring BLICS4_3 may include an eighth bit line contact 3882, a ninth bit line contact 3884 and a fourth bit line wiring 3886.

The eighth bit line contact 3882 may extend through a lower portion of the fifth insulating interlayer 3400, the first insulating interlayer 3130, the second insulating interlayer 3370, the sixth insulating interlayer 3500, the insulation layer structure, the lower portion of the third insulating interlayer 3740, the isolation pattern 707, and the upper portion of the third insulating interlayer 3740 to contact the pad of the wiring structure 3760. The ninth bit line contact 3884 may extend through a lower portion of the fifth insulating interlayer 3400 to contact the upper surface of the bit line 3250. The fourth bit line wiring 3886 may extend in the second direction D2_3 within the fifth insulating interlayer 3400 to commonly contact upper surfaces of the eighth and ninth bit line contacts 3882 and 3884. Meanwhile, the pad of the wiring structure 2760 may serve as a landing pad for the eighth bit line contact 3882.

In example embodiments, a width in the horizontal direction of each of the eighth and ninth bit line contacts 3882 and 3884 may increase away from the second rear surface of the second substrate 3700.

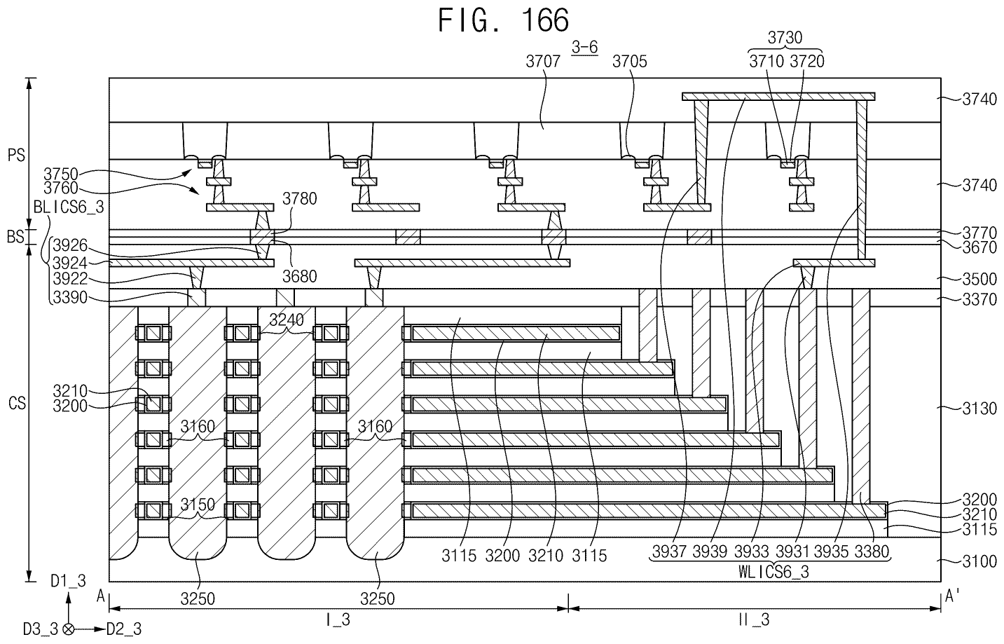

FIG. 165 is a cross-sectional view illustrating a third semiconductor device in accordance with a fifth example embodiment 3-5, which may correspond to FIG. 131.

The fifth example embodiment 3-5 of the third semiconductor device may be substantially the same as or similar to the first example embodiment 3-1 of the third semiconductor device shown in FIGS. 130 to 132, except for the arrangement of the cell structure CS_3 and the peripheral circuit structure PS_3, further including a first bit line contact 3390, and including a fifth word line wiring structure WLICS5_3 and a fifth bit line wiring structure BLICS5_3 instead of the first word line wiring structure WLICS1_3 and the first bit line wiring structure BLICS1_3, respectively, and thus repeated explanations are omitted herein.

Referring to FIG. 165, the fifth example embodiment 3-5 of the third semiconductor device may have a Periphery Over Cell (POC) structure in which a peripheral circuit structure PS_3 is disposed on a cell structure CS_3 including memory cells.

In example embodiments, the fifth example embodiment 3-5 of the third semiconductor device may have a structure in which the first front surface of the cell structure CS_3 and the second front surface of the second substrate 3700 face each other.

Meanwhile, in the process described with reference to FIGS. 130 to 132, the first substrate 3100 may remain without being removed.

The peripheral circuit structure PS_3 may further include an isolation pattern 3707 substantially the same as or similar to the isolation pattern 1607 of the peripheral circuit structure PS_1 included in the first semiconductor device.

The fifth word line wiring structure WLICS5_3 may include the first word line contact 3380, a tenth word line contact 3912, a fifth word line wiring 3914 and an eleventh word line contact 3916.

The tenth word line contact 3912 may extend through a lower portion of the sixth insulating interlayer 3500 to contact an upper surface of the first word line contact 3380. The fifth word line wiring 3914 may extend in the second direction D2_3 within the sixth insulating interlayer 3500 to contact an upper surface of the tenth word line contact 3912. The eleventh word line contact 3916 may extend through an upper portion of the sixth insulating interlayer 3500 to contact a lower surface of the bonding pad structure and an upper surface of the fifth word line wiring 3914.

In example embodiments, a width in the horizontal direction of each of the tenth and eleventh word line contacts 3912 and 3916 may increase away from an upper surface of the first substrate 3100.

The fifth bit line wiring structure BLICS5_3 may include the first bit line contact 3390, a tenth bit line contact 3920, a fifth bit line wiring 3922, an eleventh bit line contact 3924, a twelfth bit line contact 3926 and a sixth bit line wiring 3928.

The first bit line contact 3390 may extend through the second insulating interlayer 3370 on the first region I to contact an upper surface of the bit line 3250. The tenth bit line contact 3920 may extend through a lower portion of the sixth insulating interlayer 3500 to contact an upper surface of the first bit line contact 3390. The fifth bit line wiring 3922 may extend in the second direction D2_3 within the sixth insulating interlayer 3500 to contact an upper surface of the tenth bit line contact 3920. The eleventh bit line contact 3924 may extend through the lower portion of the third insulating interlayer 3740, the isolation pattern 707, the upper portion of the third insulating interlayer 3740, the bonding layer structure, and the upper portion of the sixth insulating interlayer 3500 to contact an upper surface of the fifth bit line wiring 3922. The twelfth bit line contact 3926 may extend through the lower portion of the third insulating interlayer 3740, the isolation pattern 707, and the upper portion of the third insulating interlayer 3740 to contact the pad of the wiring structure 3760. The sixth bit line wiring 3928 may extend in the second direction D2_3 within the lower portion of the third insulating interlayer 3740 to commonly contact upper surfaces of the eleventh and twelfth bit line contacts 2924 and 3926. Meanwhile, the fifth bit line wiring 3922 may serve as a landing pad for the eleventh bit line contact 3924.

In example embodiments, a width in the horizontal direction of each of the tenth to twelfth word line contacts 3920, 3924 and 3926 may increase away from an upper surface of the first substrate 3100.

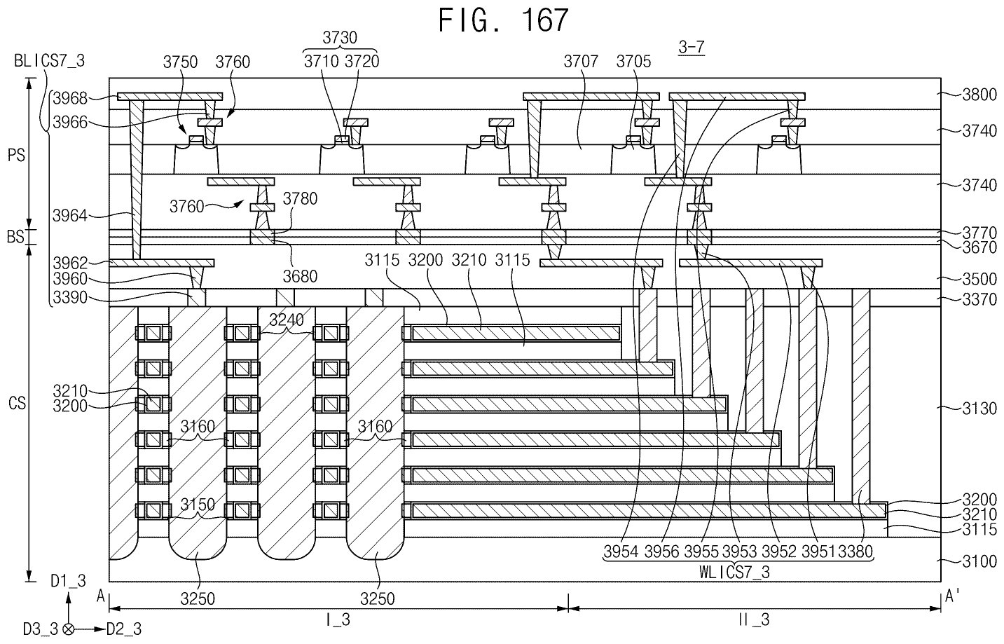

FIG. 166 is a cross-sectional view illustrating a third semiconductor device in accordance with a sixth example embodiment 3-6, which may correspond to FIG. 165.

The third semiconductor device may be substantially the same as or similar to the fifth example embodiment 3-5 of the third semiconductor device shown in FIG. 165, except for including a sixth word line wiring structure WLICS6_3 and a sixth bit line wiring structure BLICS6_3 instead of the fifth word line wiring structure WLICS5_3 and the fifth bit line wiring structure BLICS5_3, respectively, and thus repeated explanations are omitted herein.

Referring to FIG. 166, the sixth word line wiring structure WLICS6_3 may include the first word line contact 3380, a twelfth word line contact 3931, a sixth word line wiring 3933, a thirteenth word line contact 3935, a fourteenth word line contact 3937 and a seventh word line wiring 3939.

The twelfth word line contact 3931 may extend through a lower portion of the sixth insulating interlayer 3500 to contact an upper surface of the first word line contact 3380. The sixth word line wiring 3933 may extend in the second direction D2_3 within the sixth insulating interlayer 3500 to contact an upper surface of the twelfth word line contact 3931. The thirteenth word line contact 3935 may extend through the lower portion of the third insulating interlayer 3740, the isolation pattern 707, the upper portion of the third insulating interlayer 3740, the insulation layer structure, and an upper portion of the sixth insulating interlayer 3500 to contact an upper surface of the sixth word line wiring 3933. The fourteenth word line contact 3937 may extend through the lower portion of the third insulating interlayer 3740, the isolation pattern 707, and the upper portion of the third insulating interlayer 3740 to contact the pad of the wiring structure 3760. The seventh word line wiring 3939 may extend in the second direction D2_3 within the lower portion of the third insulating interlayer 3740 to contact upper surfaces of the thirteenth and fourteenth word line contacts 3935 and 3937. Meanwhile, the sixth word line wiring 3933 may serve as a landing pad for the thirteenth word line contact 3935.

In example embodiments, a width in the horizontal direction of each of the twelfth, thirteenth and fourteenth word line contacts 3931, 3935 and 3936 may increase away from an upper surface of the first substrate 3100.

The sixth bit line wiring structure BLICS6_3 may include the first bit line contact 3390, a thirteenth bit line contact 3942, a seventh bit line wiring 3944 and a fourteenth bit line contact 3946.

The thirteenth bit line contact 3942 may extend through a lower portion of the sixth insulating interlayer 3500 to contact an upper surface of the first bit line contact 3390. The seventh bit line wiring 3944 may extend in the second direction D2_3 within the sixth insulating interlayer 3500 to contact an upper surface of the thirteenth bit line contact 3942. The fourteenth bit line contact 3946 may extend through an upper portion of the sixth insulating interlayer 3500 to contact a lower surface of the insulation pattern and an upper surface of the seventh bit line wiring 3944.

In example embodiments, a width in the horizontal direction of each of the thirteenth and fourteenth bit line contacts 3942 and 3946 may increase away from an upper surface of the first substrate 3100.

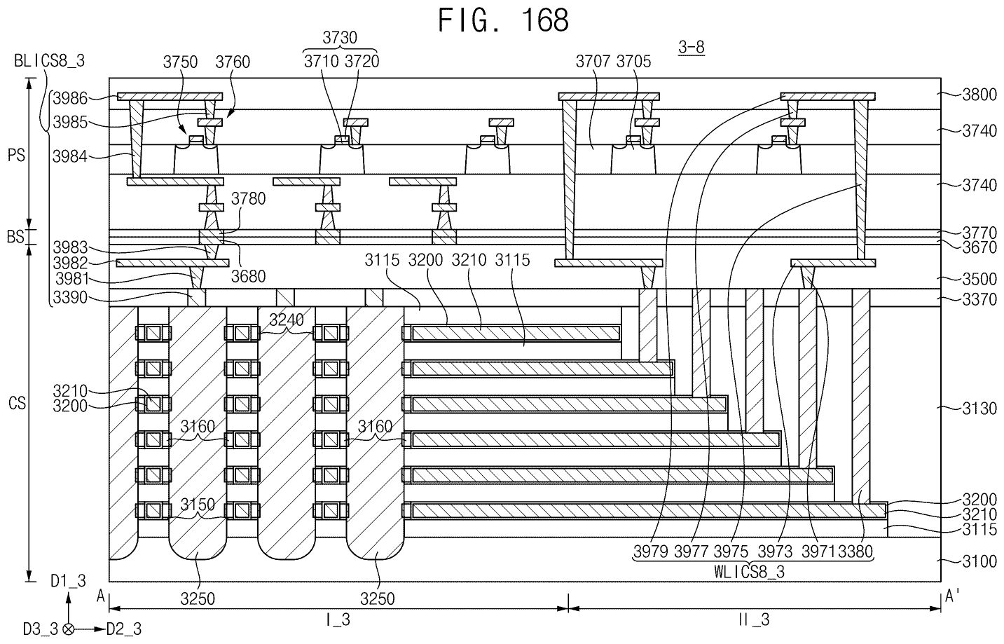

FIG. 167 is a cross-sectional view illustrating a third semiconductor device in accordance with a seventh example embodiment 3-7, which may correspond to FIG. 165.

The seventh example embodiment 3-7 of the third semiconductor device may be substantially the same as or similar to the fifth example embodiment 3-5 of the third semiconductor device shown in FIG. 165, except for the arrangement of the cell structure CS_3 and the peripheral circuit structure PS_3, and including a seventh word line wiring structure WLICS7_3 and a seventh bit line wiring structure BLICS7_3 instead of the fifth word line wiring structure WLICS5_3 and the fifth bit line wiring structure BLICS5_3, respectively, and thus repeated explanations are omitted herein.

Referring to FIG. 167, the seventh example embodiment 3-7 of the third semiconductor device may have a structure in which the first front surface of the cell structure CS_3 and the second rear surface of the second substrate 3700 face each other.

The third insulating interlayer 3740 of the peripheral circuit structure PS_3 may include an upper portion disposed on the second front surface of the second substrate 3700 on which the peripheral circuit pattern 3750 is formed and a lower portion disposed on the second rear surface of the second substrate 3700, and the wiring structure 3760 may include an upper portion disposed on the second front surface of the second substrate 3700 and a lower portion disposed on the second rear surface of the second substrate 3700. The upper and lower portions of the wiring structure 3760 may be electrically connected to each other through a contact plug extending through the isolation pattern 3707.

The peripheral circuit structure PS_3 may further include a seventh insulating interlayer 3800 formed on the third insulating interlayer 3740.

The seventh word line wiring structure WLICS7_3 may include the first word line contact 3380, a fifteenth word line contact 3951, an eighth word line wiring 3952, a sixteenth word line contact 3953, a seventeenth word line contact 3954, an eighteenth word line contact 3955 and a ninth word line wiring 3956.

The fifteenth word line contact 3951 may extend through a lower portion of the sixth insulating interlayer 3500 to contact an upper surface of the first word line contact 3380. The eighth word line wiring 3952 may extend in the second direction D2_3 within the sixth insulating interlayer 3500 to contact an upper surface of the fifteenth word line contact 3951. The sixteenth word line contact 3953 may extend through an upper portion of the sixth insulating interlayer 600 to contact a lower surface of the insulation pattern structure and an upper surface of the eighth word line wiring 3952. The seventeenth word line contact 3954 may extend through a lower portion of the seventh insulating interlayer 3800, the upper portion of the third insulating interlayer 3740, the isolation pattern 707, and the lower portion of the third insulating interlayer 3740 to be electrically connected to the lower portion of the wiring structure 3760. The eighteenth word line contact 3955 may extend through a lower portion of the seventh insulating interlayer 3800 and the upper portion of the third insulating interlayer 3740 to be electrically connected to the upper portion of the wiring structure 3760. The ninth word line wiring 3956 may commonly contact upper surfaces of the seventeenth and eighteenth word line contacts 3954 and 3955 within the seventh insulating interlayer 3800.

In example embodiments, a width in the horizontal direction of each of the fifteenth to nineteenth word line contacts 3951, 3953, 3954 and 3955 may increase away from an upper surface of the first substrate 3100.

The seventh bit line wiring structure BLICS7_3 may include the first bit line contact 3390, a fifteenth bit line contact 3960, an eighth bit line wiring 3962, a sixteenth bit line contact 3964, a seventeenth bit line contact 3966 and a ninth bit line wiring 3968.

The fifteenth bit line contact 3960 may extend through a lower portion of the sixth insulating interlayer 3500 to contact an upper surface of the first bit line contact 3390. The eighth bit line wiring 3962 may extend in the second direction D2_3 within the sixth insulating interlayer 3500 to contact an upper surface of the fifteenth bit line contact 3960. The sixteenth bit line contact 3964 may extend through a lower portion of the seventh insulating interlayer 3800, the upper portion of the third insulating interlayer 3740, the isolation pattern 707, the lower portion of the third insulating interlayer 3740, the insulation layer structure, and an upper portion of the sixth insulating interlayer 3500 to contact an upper surface of the eighth bit line wiring 3962. The seventeenth bit line contact 3966 may extend through a lower portion of the seventh insulating interlayer 3800 and the upper portion of the third insulating interlayer 3740 to be electrically connected to the upper portion of the wiring structure 3760. The ninth bit line wiring 3968 may extend in the second direction D2_3 within the seventh insulating interlayer 3800 to commonly contact upper surfaces of the sixteenth and seventeenth bit line contacts 3964 and 3966. Meanwhile, the eighth bit line wiring 3962 may serve as a landing pad for the sixteenth bit line contact 3964.

In example embodiments, a width in the horizontal direction of each of the fifteenth to seventeenth bit line contacts 3960, 3964 and 3966 may increase away from an upper surface of the first substrate 3100.

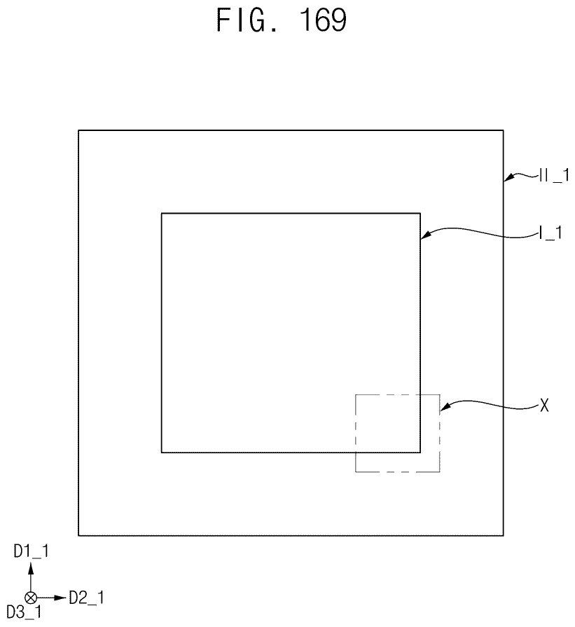

FIG. 168 is a cross-sectional view illustrating a third semiconductor device in accordance with an eighth example embodiment 3-8, which may correspond to FIG. 167.

The eighth example embodiment 3-8 of the third semiconductor device may be substantially the same as or similar to the seventh example embodiment 3-7 of the third semiconductor device shown in FIG. 167, except for including an eighth word line wiring structure WLICS8_3 and an eighth bit line wiring structure BLICS8_3 instead of the seventh word line wiring structure WLICS7_3 and the seventh bit line wiring structure BLICS7_3, respectively, and thus repeated explanations are omitted herein.

Referring to FIG. 168, the eighth word line wiring structure WLICS8_3 may include the first word line contact 3380, a nineteenth word line contact 3971, a tenth word line wiring 3973, a twentieth word line contact 3975, a twenty-first word line contact 3977 and an eleventh word line wiring 3979.

The nineteenth word line contact 3971 may extend through a lower portion of the sixth insulating interlayer 3500 to contact an upper surface of the first word line contact 3380. The tenth word line wiring 3973 may extend in the second direction D2_3 within the sixth insulating interlayer 3500 to contact an upper surface of the nineteenth word line contact 3971. The twentieth word line contact 3975 may extend through a lower portion of the seventh insulating interlayer 3800, the upper portion of the third insulating interlayer 3740, the isolation pattern 707, the lower portion of the third insulating interlayer 730, the insulation layer structure, and an upper portion of the sixth insulating interlayer 3500 to contact an upper surface of the tenth word line wiring 3973. The twenty-first word line contact 3977 may extend through a lower portion of the seventh insulating interlayer 3800 and the upper portion of the third insulating interlayer 3740 to be electrically connected to the upper portion of the wiring structure 3760. The eleventh word line wiring 3979 may extend in the second direction D2_3 within the seventh insulating interlayer 3800 to commonly contact upper surfaces of the twentieth and twenty-first word line contacts 3975 and 3977. Meanwhile, the eighth bit line wiring 3962 may serve as a landing pad for the sixteenth bit line contact 3964.

In example embodiments, a width in the horizontal direction of each of the nineteenth to twenty-first word line contacts 3971, 3975 and 3977 may increase away from an upper surface of the first substrate 3100.

The eighth bit line wiring structure BLICS8_3 may include the first bit line contact 3390, an eighteenth bit line contact 3981, a tenth bit line wiring 3982, a nineteenth bit line contact 3983, a twentieth bit line contact 3984, a twenty-first bit line contact 3985 and an eleventh bit line wiring 3986.

The eighteenth bit line contact 3981 may extend through a lower portion of the sixth insulating interlayer 3500 to contact an upper surface of the first bit line contact 3390. The tenth bit line wiring 3982 may extend in the second direction D2_3 within the sixth insulating interlayer 3500 to contact an upper surface of the eighteenth bit line contact 3981. The nineteenth bit line contact 3983 may extend through the upper portion of the sixth insulating interlayer 3500 to contact a lower surface of the insulation pattern structure and an upper surface of the tenth bit line wiring 3982. The twentieth bit line contact 3984 may extend through a lower portion of the seventh insulating interlayer 3800, the upper portion of the third insulating interlayer 3740, the isolation pattern 707, and the lower portion of the third insulating interlayer 3740 to be electrically connected to the lower portion of the wiring structure 3760. The twenty-first bit line contact 3985 may extend through a lower portion of the seventh insulating interlayer 3800 and the upper portion of the third insulating interlayer 3740 to be electrically connected to the upper portion of the wiring structure 3760. The eleventh bit line wiring 3986 may extend in the second direction D2_3 within the seventh insulating interlayer 3800 to commonly contact upper surfaces of the twentieth and twenty-first bit line contacts 3984 and 3985.

In example embodiments, a width in the horizontal direction of each of the eighteenth to twenty-second bit line contacts 3984 may increase away from an upper surface of the first substrate 3100.

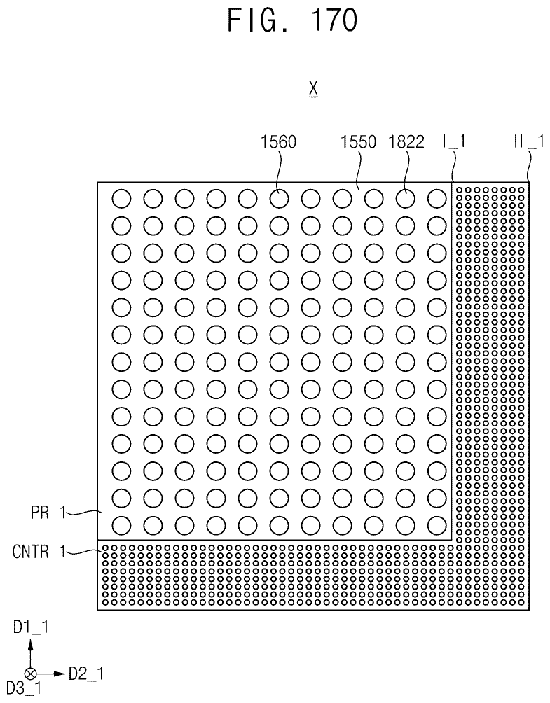

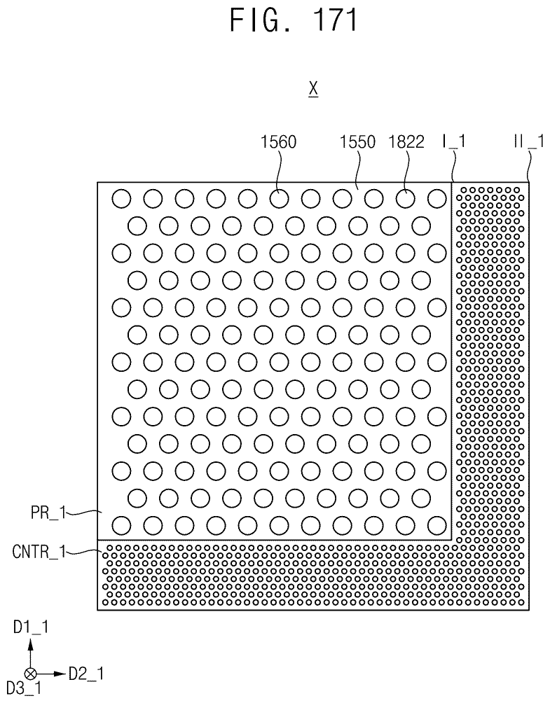

FIGS. 169 and 170 are plan views and horizontal cross-sectional views illustrating a layout of the bonding pad structure and the first bit line contact 1822 extending through the bonding layer structure included in the first example embodiment 1-1 of the first semiconductor device according to some example embodiments. Specifically, FIG. 169 is a plan view, and FIG. 170 is an enlarged horizontal cross-sectional view at an interface of the first and second bonding layers 1550 and 1670 of region X of FIG. 169.

Referring to FIGS. 169 and 170, the interface of the first and second bonding layers 1550 and 1670 may include a pad region PR_1 where the first bonding pad 1560 is disposed and a contact region CNTR_1 where the fourteenth bit line contact 1927 is disposed.

In example embodiments, a plurality of first bonding pads 1560 may be spaced apart from each other in the first and second directions D1_1 and D2_1 at a first interface portion of the first and second bonding layers 1550 and 1670 in the first region I_1 of the first semiconductor device. Accordingly, the first interface portion of the first and second bonding layers 1550 and 1670 in the first region I_1 of the first semiconductor device may correspond to the pad region PR_1.

In example embodiments, a plurality of first bit line contacts 1822 may be spaced apart from each other in the first and second directions D1_1 and D2_1 at a second interface portion of the first and second bonding layers 1550 and 1670 in the second region II_1 of the first semiconductor device. Accordingly, the second interface portion of the first and second bonding layers 1550 and 1670 in the second region II_1 of the first semiconductor device may correspond to the contact region CNTR_1.

In example embodiments, the first bonding pads 1560 in the pad region PR_1 may be arranged to have, for example, a lattice pattern when viewed from above. In example embodiments, the first bit line contacts 1822 in the contact region CNTR_1 may be arranged to have, for example, a lattice pattern when viewed from above.

In example embodiments, a planar area of the first bonding pad 1560 or a planar area of the second bonding pad 1680 at the interface of the first and second bonding layers 1550 and 1670 is greater than a cross-sectional area of the fourteenth bit line contact 1927 at the interface of the first and second bonding layers 1550 and 1670. In example embodiments, a number of first bonding pads 1560 per unit area at the first interface portion of the first and second bonding layers 1550 and 1670 in the first region I_1 or the pad region PR_1 is smaller than a number of fourteenth bit line contacts 1927 per unit area at the second interface portion of the first and second bonding layers 1550 and 1670 in the second region II_1 or the contact region CNTR_1.

In the first semiconductor device, since the second gate electrode 1235 is electrically connected to the peripheral circuit pattern 1650 through the bonding pad structure at the first region I_1, integration density of the first semiconductor device may be improved compared to a case where both the second gate electrode 1235 and the bit line structure 1490 are electrically connected to the peripheral circuit pattern 1650 through contacts extending through the bonding layer structure in the second region II_1.

Additionally, compared to a case where both the second gate electrode 1235 and the bit line structure 1490 are electrically connected to the peripheral circuit pattern 1650 through the bonding pad structure, the number of bonding pad structures including the second bonding pad 1560 that occupies a relatively large planar area may be reduced, and thus integration density of the first semiconductor device may be improved.

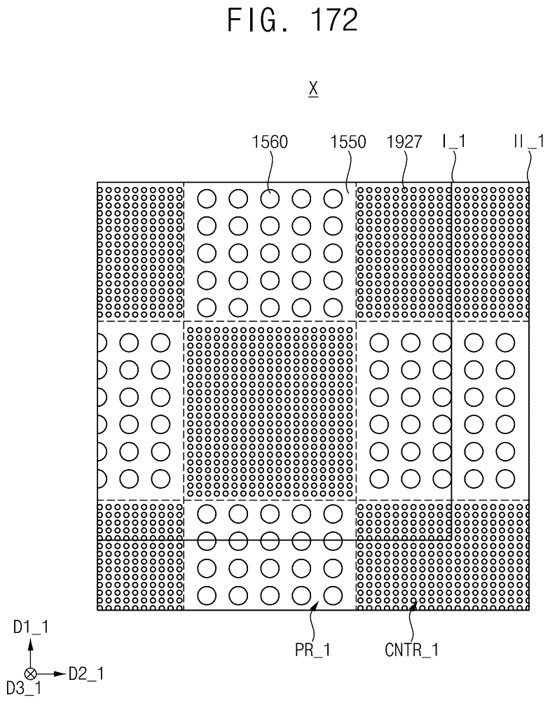

FIG. 171 is a horizontal cross-sectional view illustrating a first semiconductor device according to some example embodiments, which may correspond to FIG. 170.

In example embodiments, the first bonding pads 1560 in the pad region PR_1 may be arranged to have, for example, a honeycomb pattern when viewed from above. In example embodiments, the first bit line contacts 1822 in the contact region CNTR_1 may be arranged to have, for example, a honeycomb pattern when viewed from above.

The example embodiments of FIGS. 169 to 171 may be similarly applied to the bonding pad structure, and word line contacts or bit line contacts extending through the bonding layer structure of each of the first to third semiconductor devices.

Further, the number of bonding pad structures and the number of word line contacts or bit line contacts extending through the bonding layer structure are not limited to the embodiments of FIGS. 169 to 171.

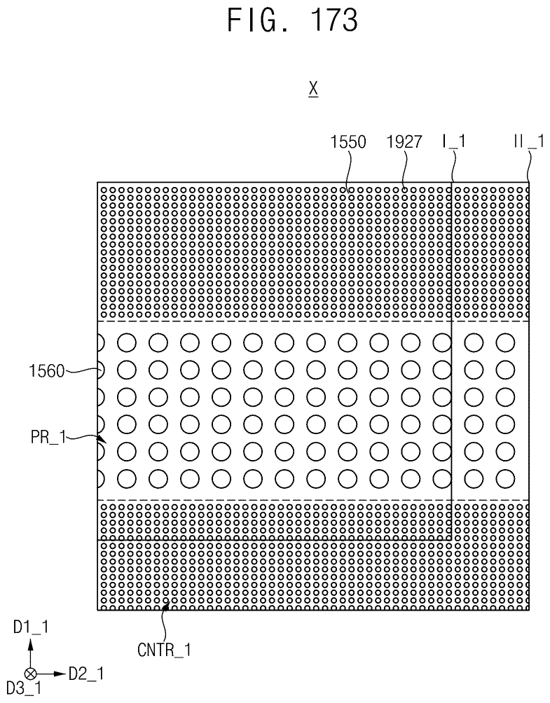

FIG. 172 is a horizontal cross-sectional view illustrating a layout of the bonding pad structure and a fourteenth bit line contact 1927 extending through the bonding layer structure included in the fifth example embodiment 1-5 of the first semiconductor device according to some example embodiments, which may correspond to FIG. 170.

In example embodiments, a plurality of pad regions PR_1 may be spaced apart from each other in the first and second directions D1_1 and D2_1. In example embodiments, the contact region CNTR_1 may be disposed between the pad regions PR_1 neighboring each other in the first direction D1_1 or between the pad regions PR_1 neighboring each other in the second direction D2_1. In example embodiments, the pad region PR_1 and the contact region CNTR_1 may be arranged together to have, for example, a chessboard pattern when viewed from above.

In example embodiments, the pad region PR may at least partially overlap not only with the first region I_1 of the first semiconductor device, but also with the second region II_1 of the first semiconductor device in the third direction D3_1. In example embodiments, the contact region CNTR_1 may at least partially overlap not only with the second region II_1 of the first semiconductor device, but also with the first region I_1 of the first semiconductor device in the third direction D3_1.

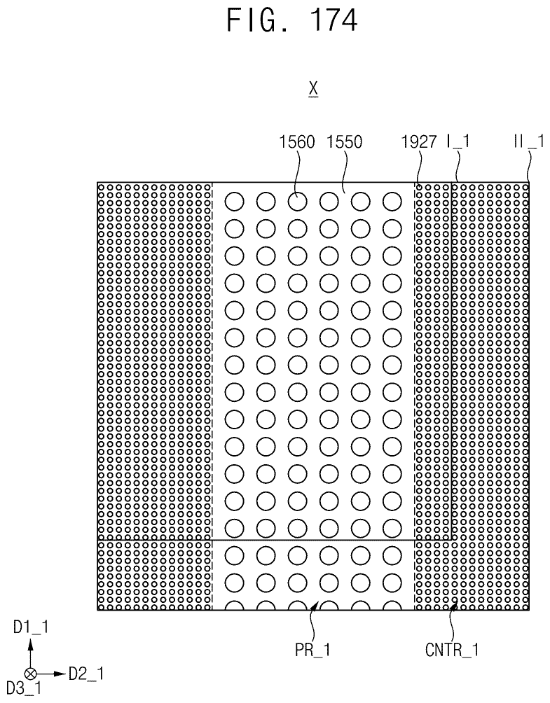

FIG. 173 is a cross-sectional view illustrating a first semiconductor device according to some example embodiments, which may correspond to FIG. 170.

In example embodiments, a plurality of pad regions PR_1 may extend in the second direction D2_1 and be spaced apart from each other in the first direction D1_1. In example embodiments, a plurality of contact regions CNTR_1 may extend in the second direction D2_1 and be spaced apart from each other in the first direction D1_1. In example embodiments, the pad regions PR_1 and the contact regions CNTR_1 may be alternately and repeatedly arranged in the first direction D1_1.

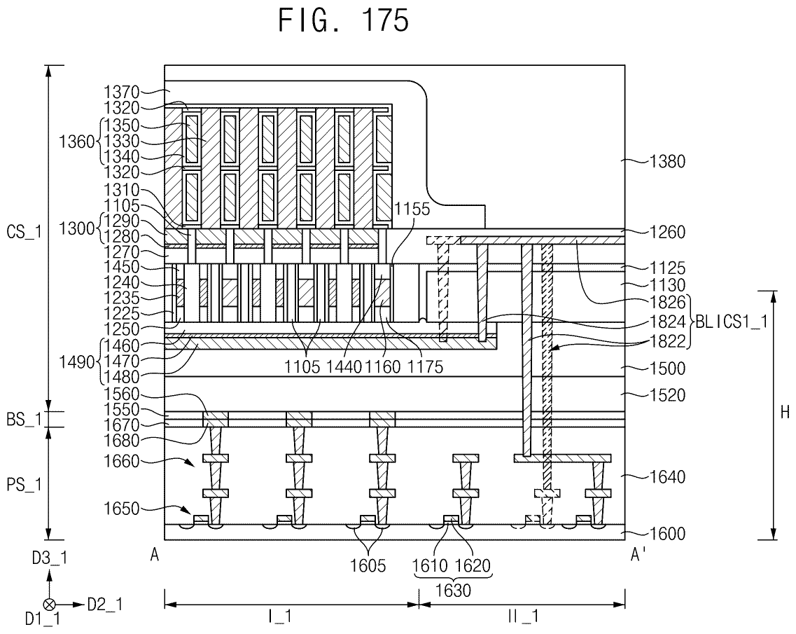

FIG. 174 is a cross-sectional view illustrating a first semiconductor device according to some example embodiments, which may correspond to FIG. 170.

In example embodiments, a plurality of pad regions PR_1 may extend in the first direction D1_1 and be spaced apart from each other in the second direction D2_1. In example embodiments, a plurality of contact regions CNTR_1 may extend in the first direction D1_1 and be spaced apart from each other in the second direction D2_1. In example embodiments, the pad regions PR_1 and the contact regions CNTR_1 may be alternately and repeatedly arranged in the second direction D2_1.

Meanwhile, the layouts of the pad region PR_1 and the contact region CNTR_1 shown in FIGS. 172 to 174 may be applied to the bonding pad structure and word line contacts or bit line contacts extending through the bonding layer structure in the sixth to eighth example embodiments 1-6, 1-7 and 1-8 of the first semiconductor device, the fifth to eighth example embodiments 2-5, 2-6, 2-7 and 2-8 of the second semiconductor device, and the fifth to eighth example embodiments 3-5, 3-6, 3-7 and 3-8 of the third semiconductor device.

Further, the layouts of the pad region PR_1 and the contact region CNTR_1 shown in FIGS. 172 to 174 are not limited to the embodiments.

FIG. 175 is a cross-sectional view illustrating the first example embodiment 1-1 of the first semiconductor device according to some example embodiments, which may correspond to FIG. 2.

Referring to FIG. 175, as described above, the first bit line contact 1822 may extend through the insulation layer structure to contact the pad of the wiring structure 1660. In example embodiments, a plurality of first bit line contacts 1822 may be spaced apart from each other in the first and second directions D1_1 and D2_1, and may respectively contact a plurality of pads of the wiring structure 1660 spaced apart from each other in the first and second directions D1_1 and D2_1.

Heights in the third direction D3_1 from the second front surface of the second substrate 1600 of the pads of the wiring structure 1660 that the first bit line contacts 1822 respectively contact may not be constant. That is, at least some of the pads of the wiring structure 1660 may be spaced apart from each other in the third direction D_3. In this case, since a separation distance in the horizontal direction of the pads of the wiring structure 1660 may be reduced compared to a case where the pads of the wiring structure 1660 are disposed at the same height in the third direction D3_1 from the second front surface of the second substrate 1600, integration density of the first semiconductor device may be improved.

The example embodiment of FIG. 175 may be applied to components serving as landing pads in each of the first to third semiconductor devices.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the inventive concepts have been shown and described with reference to exemplary embodiments thereof, it will be apparent to those of ordinary skill in the art that various modifications in form and details may be made thereto without departing from the spirit and scope of the inventive concepts as set forth by the following claims.

1. A semiconductor device comprising:
a peripheral circuit structure including a peripheral circuit pattern on a first front surface of a substrate;
a bonding structure including a bonding layer structure on the peripheral circuit structure and a bonding pad structure therein;
a cell structure on the bonding structure and including
a channel extending in a vertical direction, the vertical direction being perpendicular to an upper surface of the substrate,
a word line at a side of the channel and extending in a first direction, the first direction being parallel to the upper surface of the substrate,
a bit line structure at one end of the channel in the vertical direction and extending in a second direction, the second direction being parallel to the upper surface of the substrate and crossing the first direction, and
a capacitor at another end of the channel in the vertical direction and electrically connected thereto;
a word line wiring structure electrically connecting the peripheral circuit pattern and the word line through a word line contact, the word line contact contacting an upper surface of the bonding pad structure; and
a bit line wiring structure electrically connecting the peripheral circuit pattern and the bit line structure through a bit line contact, the bit line contact extending through the bonding layer structure.

2. The semiconductor device according to claim 1, wherein
the bonding layer structure includes
a first bonding layer and a second bonding layer sequentially stacked on the peripheral circuit structure, and
the bonding pad structure includes a first bonding pad and a second bonding pad in the first bonding layer and the second bonding layer, respectively, and
a planar area of the first bonding pad or a planar area of the second bonding pad at an interface of the first bonding layer and the second bonding layer is greater than a cross-sectional area of the bit line contact at the interface of the first bonding layer and the second bonding layer.

3. The semiconductor device according to claim 2, wherein
the substrate includes a cell array region and an extension region surrounding the cell array region,
a plurality of bonding pad structures including the bonding pad structure are spaced apart from each other in the first direction and the second direction on the cell array region of the substrate, and
a plurality of bit line contacts including the bit line contact are spaced apart from each other in the first direction and the second direction on the extension region of the substrate.

4. The semiconductor device according to claim 3, wherein a number of the plurality of bonding pad structures per unit area at the interface of the first bonding layer and the second bonding layer of the cell array region of the substrate is smaller than a number of the plurality of bit line contacts per unit area at the interface of the first bonding layer and the second bonding layer of the extension region of the substrate.

5. The semiconductor device according to claim 3, wherein
the peripheral circuit structure further includes
a plurality of landing pads electrically connected to the peripheral circuit pattern, and
the plurality of landing pads are spaced apart from each other in the first direction, the second direction, and the vertical direction, and
the plurality of bit line contacts extend through the bonding structure and contact upper surfaces of the plurality of landing pads, respectively.

6. The semiconductor device according to claim 1, wherein
a surface of the cell structure in the vertical direction adjacent to the capacitor is defined as a second front surface,
an opposite surface thereof is defined as a second rear surface, and
the second rear surface of the cell structure and the first front surface of the substrate face each other.

7. The semiconductor device according to claim 6, wherein an upper surface of the bit line contact is between an upper surface of the channel and a lower surface of the capacitor.

8. The semiconductor device according to claim 1, wherein
a surface of the cell structure in the vertical direction adjacent to the capacitor is defined as a second front surface,
an opposite surface thereof is defined as a second rear surface, and
the second front surface of the cell structure and the first front surface of the substrate face each other.

9. The semiconductor device according to claim 8, wherein an upper surface of the bit line contact is higher than an upper surface of the bit line structure based on the first front surface of the substrate.

10. The semiconductor device according to claim 1, wherein the bonding pad structure includes copper.

11. A semiconductor device comprising:
a cell structure including
a channel extending in a first direction,
a word line at a side of the channel and extending in a second direction, the second direction being perpendicular to the first direction;
a bit line structure at one end of the channel in the first direction and extending in a third direction, the third direction being perpendicular to each of the first direction and the second direction, and
a capacitor at another end of the channel in the first direction and electrically connected thereto;
a peripheral circuit structure at a side of the cell structure in the first direction and including a peripheral circuit pattern on a first front surface among the first front surface and a first rear surface of a substrate in the first direction;
a bonding structure between the cell structure and the peripheral circuit structure and including a bonding layer structure and a bonding pad structure therein;
a word line wiring structure electrically connecting the peripheral circuit pattern and the word line through a word line contact, the word line contact contacting a lower surface of the bonding pad structure; and
a bit line wiring structure electrically connecting the peripheral circuit pattern and the bit line structure through a bit line contact, the bit line contact extending through the bonding layer structure.

12. The semiconductor device according to claim 11, wherein
the substrate includes a cell array region and an extension region surrounding the cell array region,
the bonding layer structure includes a first bonding layer and a second bonding layer sequentially stacked on the peripheral circuit structure,
an interface of the first bonding layer and the second bonding layer includes a pad region on the bonding pad structure and a contact region on the bit line contact, and
a plurality of bonding pad structures including the bonding pad structure are spaced apart from each other in second and third directions in the pad region, and a plurality of bit line contacts including the bit line contact are spaced apart from each other in the second and third directions in the contact region.

13. The semiconductor device according to claim 12, wherein
a plurality of pad regions including the pad region are spaced apart from each other in the second and third directions,
a plurality of contact regions including the contact region are spaced apart from each other in the second and third directions, and
when viewed from above, the plurality of pad regions and the plurality of contact regions are arranged together in a chess board pattern.

14. The semiconductor device according to claim 12, wherein
a plurality of pad regions including the pad region extend in the second direction and are spaced apart from each other in the third direction,
a plurality of contact regions including the contact region extend in the second direction and are spaced apart from each other in the third direction, and
the plurality of pad regions and the plurality of contact regions are arranged alternately and repeatedly along the third direction.

15. The semiconductor device according to claim 12, wherein
a plurality of pad regions including the pad region extend in the third direction and are spaced apart from each other in the second direction,
a plurality of contact regions including the contact region extend in the third direction and are spaced apart from each other in the second direction, and
the plurality of pad regions and the plurality of contact regions are arranged alternately and repeatedly along the second direction.

16.-23. (canceled)

24. A semiconductor device comprising:
a peripheral circuit structure including a peripheral circuit pattern on a first front surface of a substrate;
a bonding structure including a bonding layer structure on the peripheral circuit structure and a bonding pad structure therein;
a cell structure on the bonding structure and including
a channel extending in a vertical direction, the vertical direction being perpendicular to an upper surface of the substrate,
a word line at a side of the channel and extending in a first direction, the first direction being parallel to the upper surface of the substrate,
a back gate electrode at another side of the channel and extending in the first direction,
a bit line structure at one end of the channel in the vertical direction and extending in a second direction, the second direction being parallel to the upper surface of the substrate and crossing the first direction, and
a capacitor at another end of the channel in the vertical direction and electrically connected thereto;
a word line wiring structure electrically connecting the peripheral circuit pattern and the word line through a word line contact extending through the bonding layer structure; and
a bit line wiring structure electrically connecting the peripheral circuit pattern and the bit line structure through a bit line contact contacting an upper surface of the bonding pad structure.

25. The semiconductor device according to claim 24, wherein
the bonding layer structure includes a first bonding layer and a second bonding layer sequentially stacked on the peripheral circuit structure, and the bonding pad structure includes a first bonding pad and a second bonding pad in the first bonding layer and the second bonding layer, respectively, and
a planar area of the first bonding pad or a planar area of the second bonding pad at an interface of the first bonding layer and the second bonding layer is greater than a cross-sectional area of the word line contact at the interface of the first bonding layer and the second bonding layer.

26. The semiconductor device according to claim 25, wherein the substrate includes a cell array region and an extension region surrounding the cell array region, and a plurality of bonding pad structures including the bonding pad structure are spaced apart from each other in the first direction and the second direction on the cell array region of the substrate, and a plurality of word line contacts including the word line contact are spaced apart from each other in the first direction and the second direction on the extension region of the substrate.

27. The semiconductor device according to claim 26, wherein a number of the plurality of bonding pad structures per unit area at the interface of the first bonding layer and the second bonding layer of the cell array region of the substrate is smaller than a number of the plurality of word line contacts per unit area at the interface of the first bonding layer and the second bonding layer of the extension region of the substrate.

28. The semiconductor device according to claim 26, wherein
the peripheral circuit structure further includes a plurality of landing pads electrically connected to the peripheral circuit pattern and spaced apart from each other in the first direction, the second direction, and the vertical direction, and
the plurality of word line contacts extend through the bonding structure and contact upper surfaces of the plurality of landing pads spaced apart in the vertical direction, respectively.

29.-128. (canceled)
